(19) United States
(12) Patent Application Publication
(10) Pub. No.: US 2024/0268229 A1
(43) Pub. Date: Aug. 8, 2024

(54) LIGHT EMITTING ELEMENT AND FUSED POLYCYCLIC COMPOUND FOR THE LIGHT EMITTING ELEMENT

(71) Applicant: Samsung Display Co., Ltd., Yongin-si (KR)

(72) Inventors: Keigo HOSHI, Yokohama (JP); Ryuhei FURUE, Yokohama (JP); Yoshiro SUGITA, Yokohama (JP)

(21) Appl. No.: 18/490,682

(22) Filed: Oct. 19, 2023

(30) Foreign Application Priority Data
Jan. 20, 2023 (KR) 10-2023-0008620

(51) Int. Cl. H10K 85/60; C07F 5/02; C09K 11/06

(52) U.S. Cl. CPC H10K 85/658; C07F 5/027; C09K 11/06; H10K 50/12

(57) ABSTRACT

A light emitting element may include a first electrode, a second electrode on the first electrode, at least one functional layer which is disposed between the first electrode and the second electrode and includes a fused polycyclic compound represented by Formula 1, the fused polycyclic compound including at least one electron-withdrawn group at the meta position with respect to the boron atom in the fused ring core of the fused polycyclic compound.

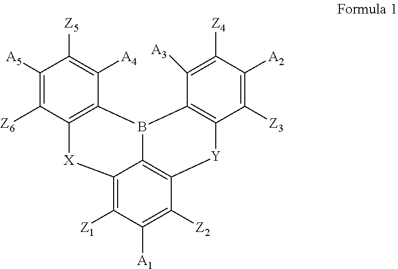

### CROSS-REFERENCE TO RELATED APPLICATION

This application claims priority to and benefits of Korean Patent Application No. 10-2023-0008620, filed on Jan. 20, 2023, in the Korean Intellectual Property Office, the entire content of which is hereby incorporated by reference.

### BACKGROUND

### 1. Field

One or more embodiments of the present disclosure relate to a light emitting element and a fused polycyclic compound utilized in the light emitting element.

### 2. Description of Related Art

Recently, the development of an organic electroluminescence display device as an image display device is being actively conducted. Unlike liquid crystal display devices and/or the like, the organic electroluminescence display is a self-luminescent display device in which holes and electrons respectively (e.g., separately) injected from a first electrode and a second electrode recombine in an emission layer of the organic electroluminescence display, and thus a luminescent material including an organic compound in the emission layer emits light to implement display (e.g., of an image).

In the application of an organic electroluminescence device to a display device, there is a demand for an organic electroluminescence device having a low driving voltage, a high luminous efficiency, and a long service life (lifespan), and thus the development on materials, for an organic electroluminescence device, capable of stably attaining such characteristics is being continuously required and/or pursued.

In recent years, in order to implement a highly efficient organic electroluminescence device, technologies pertaining to phosphorescence emission utilizing triplet state energy or fluorescence utilizing triplet-triplet annihilation (TTA) in which singlet excitons are generated by collision of triplet excitons are being particularly developed, and thermally activated delayed fluorescence (TADF) materials utilizing delayed fluorescence phenomenon are being developed and/or exploited.

### SUMMARY

One or more aspects of embodiments of the present disclosure are directed toward a light emitting element in which luminous efficiency and an element service life (lifespan) are improved.

One or more aspects of embodiments of the present disclosure are directed toward a fused polycyclic compound capable of improving luminous efficiency and an element service life of a light emitting element.

Additional aspects will be set forth in part in the description which follows and, in part, will be apparent from the description, or may be learned by practice of the presented embodiments.

One or more embodiments of the present disclosure provide a light emitting element including a first electrode, a second electrode on the first electrode, and at least one functional layer which is between the first electrode and the second electrode and may include a fused polycyclic compound represented by Formula 1:

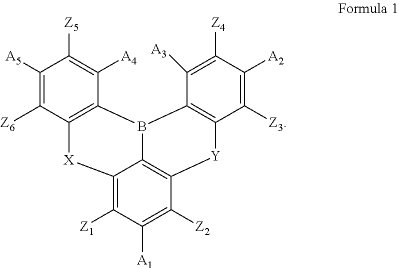

In Formula 1, X and Y may each independently be O, S, or a substituent represented by Formula 2, A₁ may be hydrogen, deuterium, a halogen, a cyano group, a nitro group, a substituted or unsubstituted amine group, an unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, A₂ to A₅ may each independently be hydrogen, deuterium, a halogen, a cyano group, a nitro group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, Z₁ to Z₆ may each independently be hydrogen, deuterium, a halogen, a cyano group, a nitro group, a substituted or unsubstituted amine group, an unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or a substituent represented by Formula 3, at least one selected from among Z₁ to Z₆ may be a cyano group or a substituent represented by Formula 3, and when each of X and Y is 0, the embodiment in which each of Z₄ and Z₅ is a hydrogen atom is excluded, and embodiment in which the fused polycyclic compound represented by Formula 1 includes an adamantyl group is excluded.

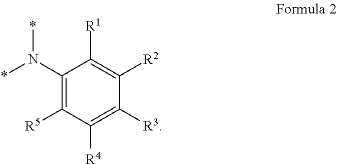

In Formula 2, R₁ to R₅ may each independently be hydrogen, deuterium, a halogen, a cyano group, a nitro group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, when each of R₁ to R₅ is a substituted or unsubstituted heteroaryl group having 2 to 30 ring-forming carbon atoms, the embodiment in which the heteroaryl group contains a nitrogen atom as a ring-forming atom is excluded, and when in Formula 1, any one of Z₄ or Z₅ is a cyano group or a substituted or unsubstituted pyridine group, at least one selected from among R₁ to R₅ in Formula 2 may be a substituted or unsubstituted aryl group having 6 to 30 ring-forming carbon atoms, or a substituted or unsubstituted heteroaryl group having 2 to 30 ring-forming carbon atoms, and -* is a position linked to Formula 1.

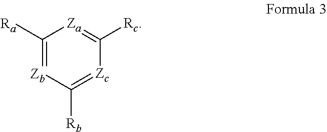

In Formula 3, at least one selected from among Zₐ to Z_{c} is N, the rest are CR_{d}, Rₐ to R_{d} may each independently be hydrogen, deuterium, a halogen, a cyano group, a nitro group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and one selected from among Rₐ to R_{d} may be a position linked to Formula 1.

In one or more embodiments, the at least one functional layer may include an emission layer, a hole transport region between the first electrode and the emission layer, and an electron transport region between the emission layer and the second electrode, and the emission layer may include the fused polycyclic compound.

In one or more embodiments, the emission layer may be to emit delayed fluorescence.

In one or more embodiments, the emission layer may be to emit light having a luminescence center wavelength of about 430 nm to about 490 nm.

In one or more embodiments, the substituent by Formula 3 may be represented by any one selected from among Formula 3-1-1 to Formula 3-1-7:

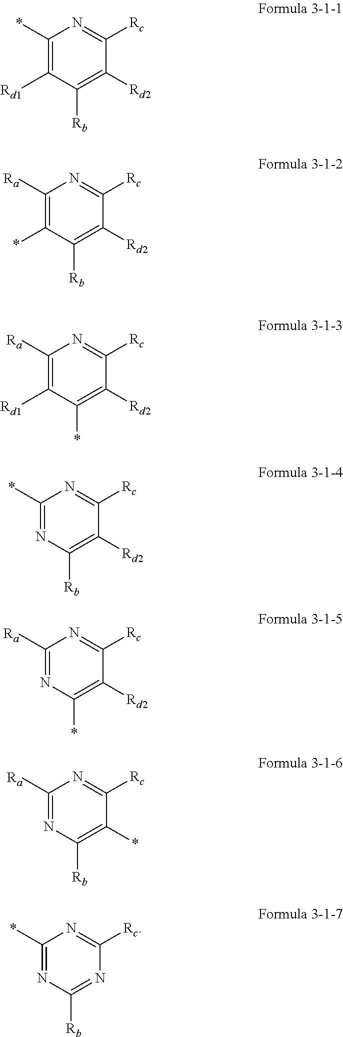

In Formula 3-1-1 to Formula 3-1-7, R_{d1} and R_{d2} may each independently be hydrogen, deuterium, a halogen, a cyano group, a nitro group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and -* is a position linked to Formula 1.

In Formula 3-1-1 to Formula 3-1-7, the same as defined in Formula 3 may be applied to Rₐ to R_{c}.

In one or more embodiments, the substituent by Formula 3 may be represented by any one selected from among Formula 3-2-1 to Formula 3-2-7:

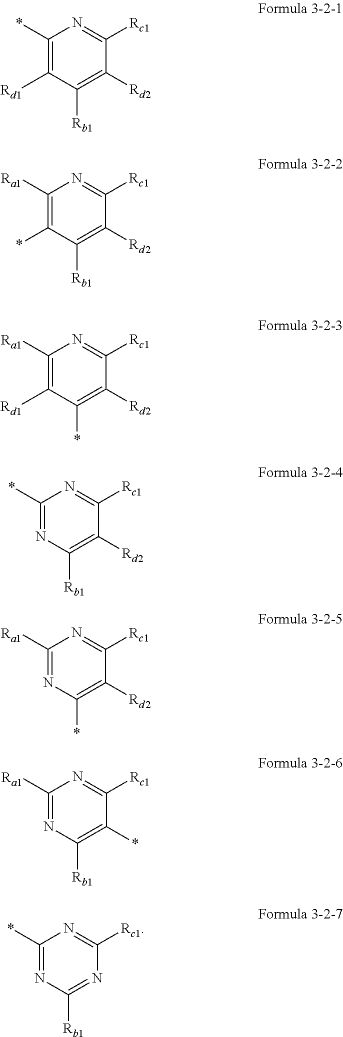

In Formula 3-2-1 to Formula 3-2-7, Rₐ₁, R_{b1}, R_{c1}, R_{d1}, and R_{d2} may each independently be hydrogen, deuterium, a halogen, a cyano group, a nitro group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, in Formula 3-2-1, Formula 3-2-4, and Formula 3-2-7, at least one of R_{b1} or R_{c1} may be a substituted or unsubstituted aryl group having 6 to 30 ring-forming carbon atoms, in Formula 3-2-2 and Formula 3-2-6, at least one of Rₐ₁, R_{b1}, or R_{c1} may be a substituted or unsubstituted aryl group having 6 to 30 ring-forming carbon atoms, and in Formula 3-2-3 and Formula 3-2-5 above, at least one of Rₐ₁ or R_{c1} may be a substituted or unsubstituted aryl group having 6 to 30 ring-forming carbon atoms, and -* is a position linked to Formula 1.

In one or more embodiments, the fused polycyclic compound represented by Formula 1 above may be represented by Formula 1-1-1 or Formula 1-1-2:

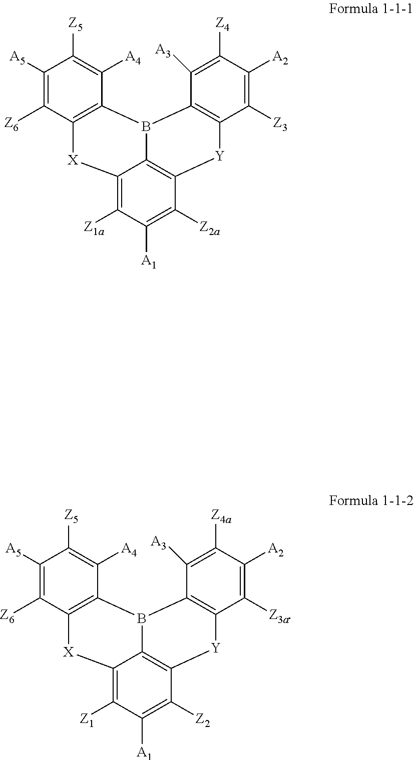

In Formula 1-1-1 and Formula 1-1-2, Z₁ₐ to Z₄ₐ may each independently be hydrogen, deuterium, a halogen, a cyano group, a nitro group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or a substituent represented by Formula 3, in Formula 1-1-1, at least one of Z₁a or Z₂a may be a cyano group or a substituent represented by Formula 3, and in Formula 1-1-2, at least one of Z₃ₐ or Z₄a is a cyano group or a substituent represented by Formula 3.

In Formula 1-1-1 and Formula 1-1-2, the same as defined in Formula 1 may be applied to X, Y, A₁ to A₅, and Z₁ to Z₆.

In one or more embodiments, the fused polycyclic compound represented by Formula 1 may be represented by any one selected from among Formula 1-2-1 to Formula 1-2-3:

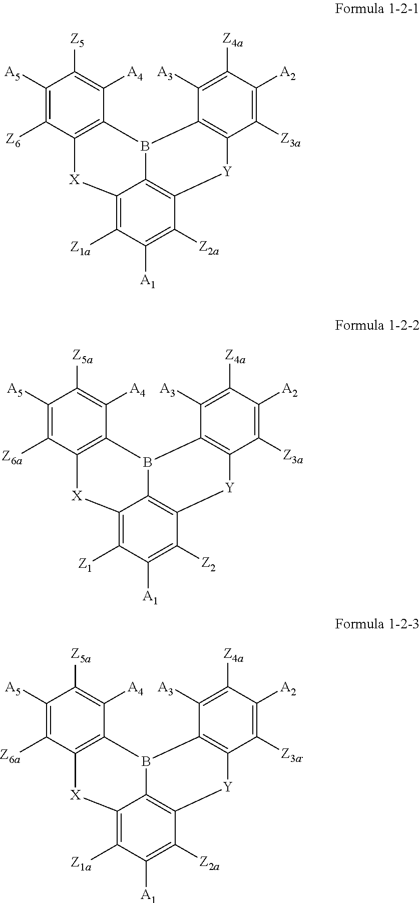

In Formula 1-2-1 to Formula 1-2-3, Z₁ₐ to Z₆ₐ may each independently be hydrogen, deuterium, a halogen, a cyano group, a nitro group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or a substituent represented by Formula 3, in Formula 1-2-1, at least one of Z₁a or Z₂ₐ and at least one of Z₃ₐ or Z₄ₐ may each independently be a cyano group or a substituent represented by Formula 3, in Formula 1-2-2, at least one of Z₃ₐ or Z₄a and at least one of Z₅a or Z₆a may each independently be a cyano group or a substituent represented by Formula 3, and in Formula 1-2-3, at least one of Z₁a or Z₂ₐ, at least one of Z₃ₐ or Z₄ₐ, and at least one of Z₅a or Z₆a may each independently be a cyano group or a substituent represented by Formula 3.

In Formula 1-2-1 to Formula 1-2-3, the same as defined in Formula 1 may be applied to X, Y, A₁ to A₅, and Z₁, Z₂, Z₅, and Z₆.

In one or more embodiments, the fused polycyclic compound represented by Formula 1 may be represented by any one selected from among Formula 1-3-1 to Formula 1-3-4:

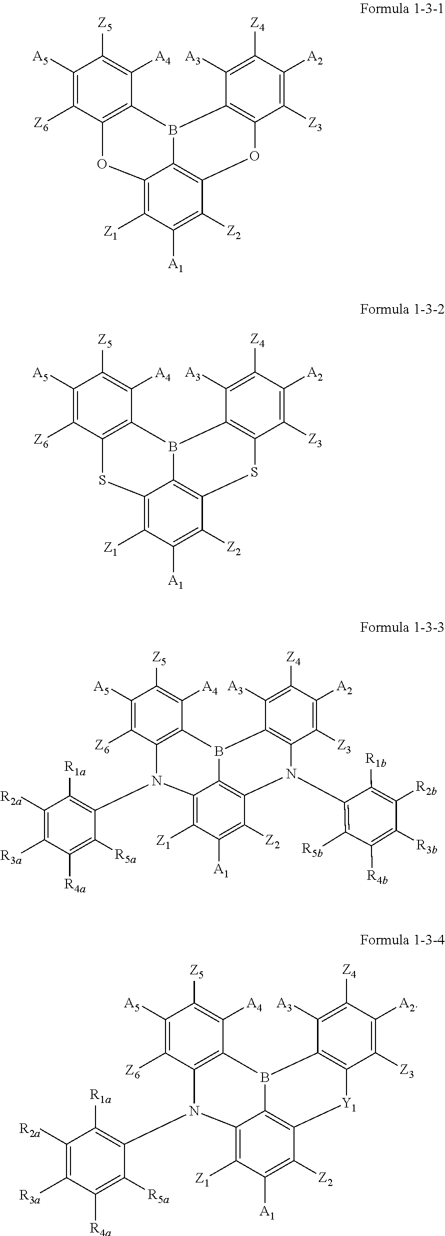

In Formula 1-3-1 to Formula 1-3-4, Y₁ may be O or S, R₁ₐ to R₅ₐ and R_{1b} to R_{5b} may each independently be hydrogen, deuterium, a halogen, a cyano group, a nitro group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, when in Formula 1-3-3 and Formula 1-3-4, each of R₁ₐ to R₅ₐ and R_{1b} to R_{b5} is a substituted or unsubstituted heteroaryl group having 2 to 30 ring-forming carbon atoms, the embodiment in which the heteroaryl group contains a nitrogen atom as a ring-forming carbon atom is excluded, when in Formula 1-3-3, any one of Z₄ or Z₅ is a cyano group or a substituted or unsubstituted pyridine group, at least one selected from among R₁ₐ to R₅ₐ and at least one selected from among R_{1b} to R_{5b} may each independently be a substituted or unsubstituted aryl group having 6 to 30 ring-forming carbon atoms, or a substituted or unsubstituted heteroaryl group having 2 to 30 ring-forming carbon atoms, and when in Formula 1-3-4, any one selected from among Z₄ and Z₅ is a cyano group or a substituted or unsubstituted pyridine group, at least one selected from among R₁ₐ to R₅ₐ may each independently be a substituted or unsubstituted aryl group having 6 to 30 ring-forming carbon atoms, or a substituted or unsubstituted heteroaryl group having 2 to 30 ring-forming carbon atoms.

In Formula 1-3-1 to Formula 1-3-4, the same as defined in Formula 1 above may be applied to A₁ to A₅, and Z₁ to Z₆.

In one or more embodiments, the fused polycyclic compound represented by Formula 1 may be represented by Formula 1-4:

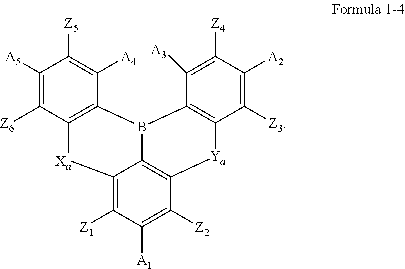

In Formula 1-4, Xₐ and Yₐ may each independently be represented by any one selected from among Formula 2-1 to Formula 2-7, and when any one selected from among Z₄ and Z₅ is a cyano group or a substituted or unsubstituted pyridine group, Xₐ and Yₐ may each independently be represented by any one selected from among Formula 2-2 to Formula 2-7:

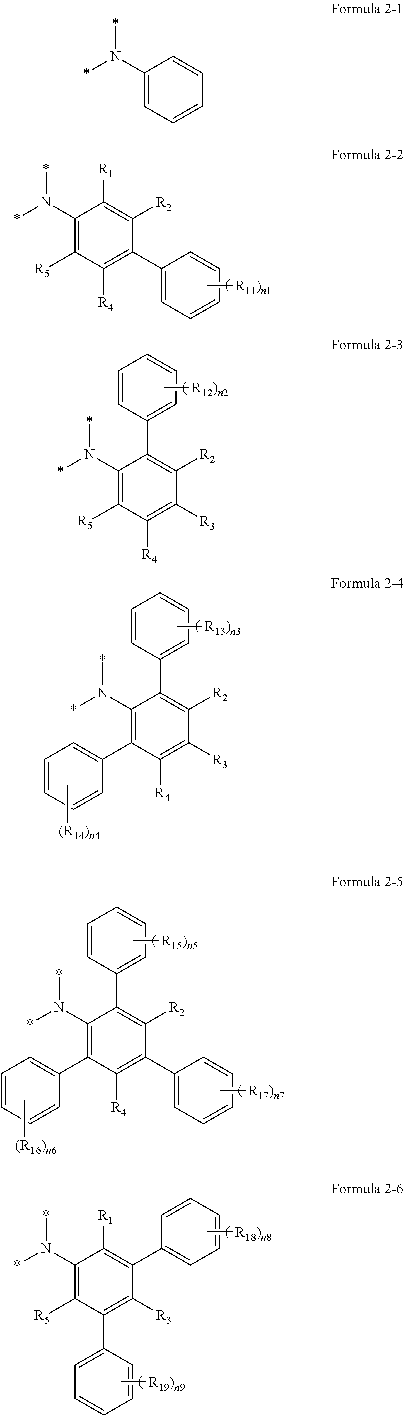

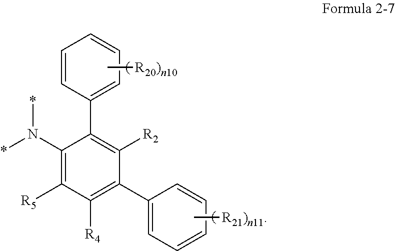

In Formula 2-1 to Formula 2-7 above, R₁₁ to R₂₁ may each independently be hydrogen, deuterium, a halogen, a cyano group, a nitro group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and n1 to n11 may each independently be an integer of 0 to 5.

In Formula 2-1 to Formula 2-7, the same as defined in Formula 2 may be applied to R₁ to R₅.

In Formula 1-4, the same as defined in Formula 1 may be applied to A₁ to A₅, and Z₁ to Z₆.

In one or more embodiments, the fused polycyclic compound represented by Formula 1 may be represented by any one selected from among Formula 1-5-1 to Formula 1-5-7:

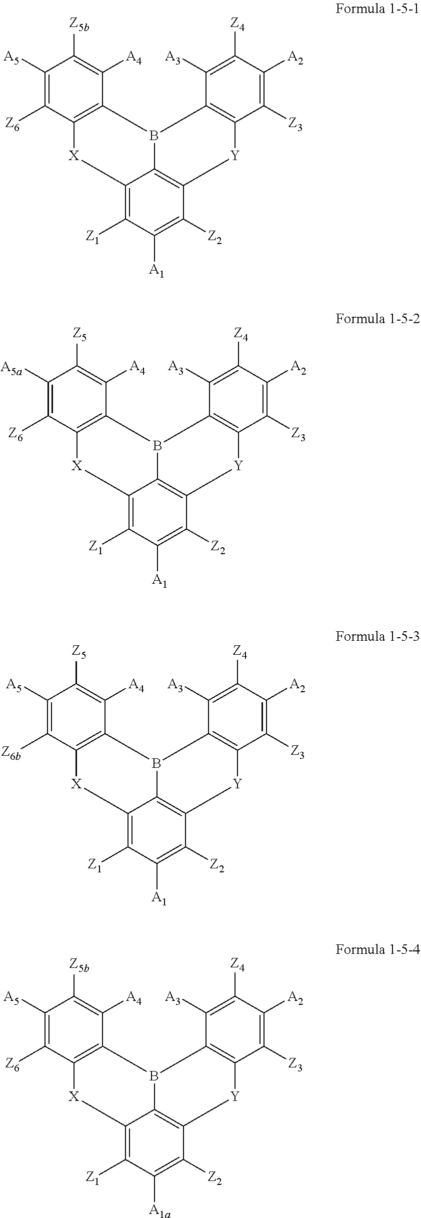

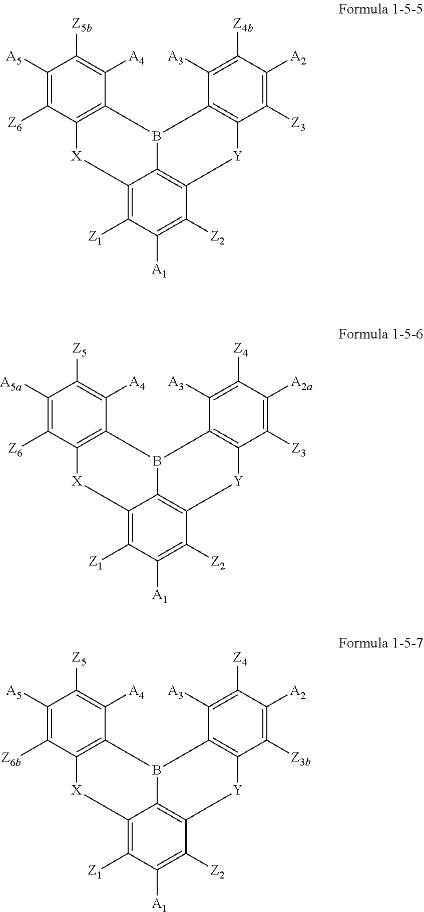

In Formula 1-5-1 to Formula 1-5-7, Z_{3b} to Z_{6b}, A₂ₐ, and A₅ₐ may each independently be a substituted or unsubstituted alkyl group having 1 to 10 carbon atoms, or represented by Formula A-1 or Formula A-2, A₁ₐ may be an unsubstituted alkyl group having 1 to 10 carbon atoms or represented by Formula A-1 or Formula A-2, in Formula 1-5-1 and Formula 1-5-4, at least one selected from among Z₁ to Z₄ and Z₆ may be a cyano group or a substituent represented by Formula 3, in Formula 1-5-2 and Formula 1-5-6, at least one selected from among Z₁ to Z₆ may be a cyano group or a substituent represented by Formula 3, in Formula 1-5-3, at least one selected from among Z₁ to Z₅ may be a cyano group or a substituent represented by Formula 3 above, in Formula 1-5-5, at least one selected from among Z₁ to Z₃ and Z₆ may be a cyano group or a substituent represented by Formula 3, and in Formula 1-5-7, at least one selected from among Z₁, Z₂, Z₄, and Z₅ is a cyano group or a substituent represented by Formula 3.

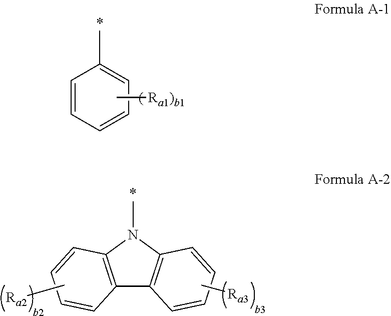

In Formula A-1 to Formula A-2, Rₐ₁ to Rₐ₃ may each independently be hydrogen, deuterium, a halogen, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, b1 is an integer of 0 to 5, b2 and b3 may each independently be an integer of 0 to 4, and -* is a position linked to Formula 1-5-1 to Formula 1-5-7.

In Formula 1-5-1 to Formula 1-5-7, the same as defined in Formula 1 may be applied to X, Y, A₁ to A₅, and Z₁ to Z₆.

In one or more embodiments, the fused polycyclic compound represented by Formula 1 may be represented by any one selected from among Formula 1-6-1 to Formula 1-6-8:

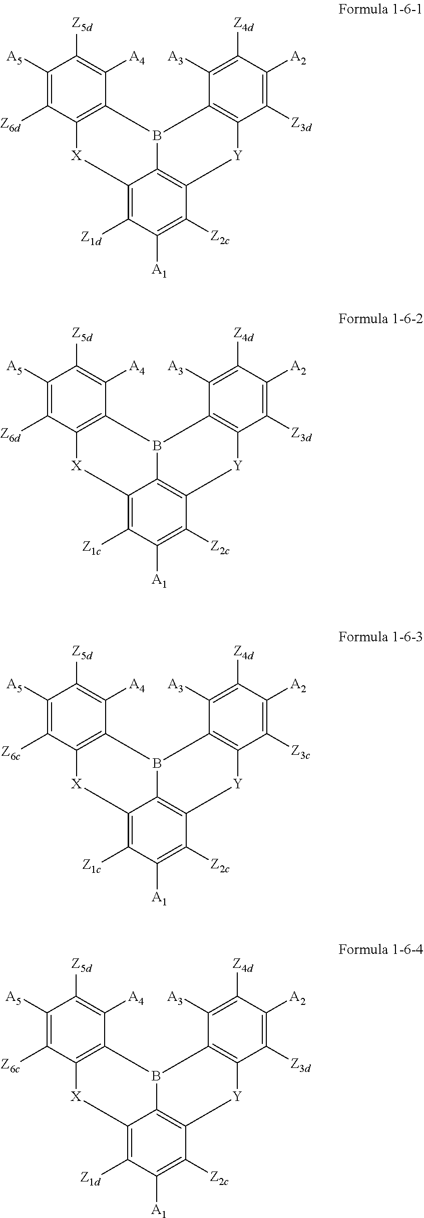

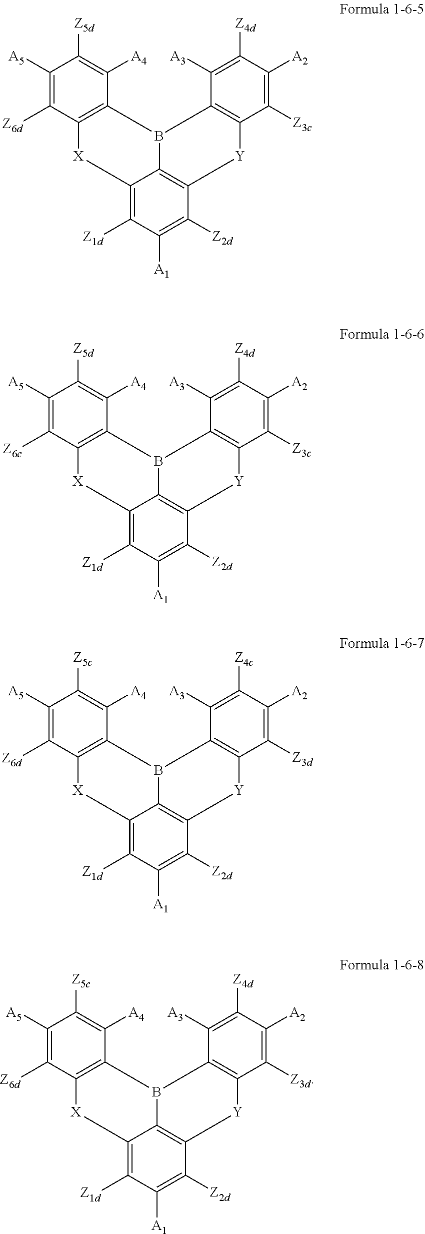

In Formula 1-6-1 to Formula 1-6-8, Z_{1d} to Z_{6d} may each independently be hydrogen, deuterium, a halogen, a cyano group, a nitro group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and Z_{1c} to Z_{6c} may each independently be a cyano group or a substituent represented by Formula 3.

In Formula 1-6-1 to Formula 1-6-8, the same as defined in Formula 1 may be applied to X, Y, and A₁ to A₅.

In one or more embodiments of the present disclosure, a fused polycyclic compound is represented by Formula 1.

### BRIEF DESCRIPTION OF THE DRAWINGS

The accompanying drawings are included to provide a further understanding of the present disclosure, and are incorporated in and constitute a part of this specification. The drawings illustrate example embodiments of the present disclosure and, together with the description, serve to explain principles of the present disclosure.

Above and/or other aspects of the present disclosure should become apparent and appreciated from the following description of embodiments taken in conjunction with the accompanying drawings. In the drawings:

FIG. 1 is a plan view of a display device according to one or more embodiments of the present disclosure;

FIG. 2 is a cross-sectional view of a display device according to one or more embodiments of the present disclosure;

FIG. 3 is a cross-sectional view schematically illustrating a light emitting element according to one or more embodiments of the present disclosure;

FIG. 4 is a cross-sectional view schematically illustrating a light emitting element according to one or more embodiments of the present disclosure;

FIG. 5 is a cross-sectional view schematically illustrating a light emitting element according to one or more embodiments of the present disclosure;

FIG. 6 is a cross-sectional view schematically illustrating a light emitting element according to one or more embodiments of the present disclosure;

FIG. 7 and FIG. 8 each are a cross-sectional view of a display device according to one or more embodiments of the present disclosure;

FIG. 9 is a cross-sectional view illustrating a display device according to one or more embodiments of the present disclosure;

FIG. 10 is a cross-sectional view illustrating a display device according to one or more embodiments of the present disclosure; and

FIG. 11 is a view illustrating a vehicle in which display devices are disposed according to one or more embodiments of the present disclosure.

### DETAILED DESCRIPTION

The present disclosure may be modified in one or more suitable manners and have many forms, and thus specific embodiments will be exemplified in the drawings and described in more detail in the detailed description of the present disclosure. It should be understood, however, that it is not intended to limit the present disclosure to the particular forms disclosed, but rather, is intended to cover all modifications, equivalents, and alternatives falling within the spirit and scope of the present disclosure.

When explaining each of drawings, like reference numbers are utilized for referring to like elements. In the accompanying drawings, the dimensions of each structure may be exaggeratingly illustrated for clarity of the present disclosure. It will be understood that, although the terms “first,” “second,” etc., may be utilized herein to describe one or more suitable components, these components should not be limited by these terms. These terms are only utilized to distinguish one component from another.

For example, a first component could be termed a second component, and, similarly, a second component could be termed a first component, without departing from the scope of example embodiments of the present disclosure. As utilized herein, the singular forms, “a,” “an,” “one,” and “the” are intended to include the plural forms as well, unless the context clearly indicates otherwise. Further, the utilization of “may” when describing embodiments of the present disclosure refers to “one or more embodiments of the present disclosure”.

In the present disclosure, it will be understood that the terms “comprise(s),” “include(s),” “have/has,” and/or the like specify the presence of features, numbers, steps, operations, component, parts, or combinations thereof disclosed in the disclosure, but do not exclude the possibility of presence or addition of one or more other features, numbers, steps, operations, component, parts, or combinations thereof. As used herein, the terms “and”, “or”, and “and/or” may include any and all combinations of one or more of the associated listed items. Expressions such as “at least one of,” “one of,” and “selected from,” when preceding a list of elements, modify the entire list of elements and do not modify the individual elements of the list. For example, “at least one of a, b, or c”, “at least one selected from a, b, and c”, “at least one selected from among a to c”, etc., may indicate only a, only b, only c, both (e.g., simultaneously) a and b, both (e.g., simultaneously) a and c, both (e.g., simultaneously) b and c, all of a, b, and c, or variations thereof. The “/” utilized herein may be interpreted as “and” or as “or” depending on the situation.

In the present disclosure, when a layer, a film, a region, or a plate is referred to as being “on” or “in an upper portion of” another layer, film, region, or plate, it may be not only “directly on” the layer, film, region, or plate, but intervening layers, films, regions, or plates may also be present. Opposite this, when a layer, a film, a region, or a plate is referred to as being “below”, “in a lower portion of” another layer, film, region, or plate, it can be not only directly under the layer, film, region, or plate, but intervening layers, films, regions, or plates may also be present. In some embodiments, it will be understood that when a part is referred to as being “on” another part, it can be disposed above the other part, or disposed under the other part as well. In some embodiments, “directly on” may refer to that there are no additional layers, films, regions, plates, etc., between a layer, a film, a region, a plate, etc. and the other part. For example, “directly on” may refer to two layers or two members are disposed without utilizing an additional member such as an adhesive member therebetween.

In the present disclosure, the term “substituted or unsubstituted” may refer to substituted or unsubstituted with at least one substituent selected from the group consisting of deuterium, a halogen, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. In some embodiments, each of the substituents exemplified above may be substituted or unsubstituted. For example, a biphenyl group may be interpreted as an aryl group or a phenyl group substituted with a phenyl group.

In the present disclosure, the phrase “bonded to an adjacent group to form a ring” may refer to that a group is bonded to an adjacent group to form a substituted or unsubstituted hydrocarbon ring, or a substituted or unsubstituted heterocycle. The hydrocarbon ring may include an aliphatic hydrocarbon ring and/or an aromatic hydrocarbon ring. The heterocycle may include an aliphatic heterocycle and/or an aromatic heterocycle. The hydrocarbon ring and the heterocycle may be monocyclic or polycyclic. In some embodiments, the rings formed by two adjacent groups being bonded to each other may be connected to another ring to form a spiro structure.

In the present disclosure, the term “adjacent group” may refer to a substituent substituted for an atom which is directly linked to an atom substituted with a corresponding substituent, another substituent substituted for an atom which is substituted with a corresponding substituent, or a substituent sterically positioned at the nearest position to a corresponding substituent. For example, two methyl groups in 1,2-dimethylbenzene may be interpreted as “adjacent groups” to each other, and two ethyl groups in 1,1-diethylcyclopentane may be interpreted as “adjacent groups” to each other. In some embodiments, two methyl groups in 4,5-dimethylphenanthrene may be interpreted as “adjacent groups” to each other.

In the present disclosure, examples of the halogen may include fluorine, chlorine, bromine, or iodine.

In the present disclosure, an alkyl group may be linear or branched. The number of carbons in the alkyl group may be 1 to 50, 1 to 30, 1 to 20, 1 to 10, or 1 to 6. Examples of the alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-heneicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., but embodiments of the present disclosure are not limited thereto.

In the present disclosure, a cycloalkyl group may refer to a cyclic alkyl group. The number of carbons in the cycloalkyl group may be 3 to 50, 3 to 30, 3 to 20, or 3 to 10. Examples of the cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, etc., but embodiments of the present disclosure are not limited thereto.

In the present disclosure, an alkenyl group refers to a hydrocarbon group including at least one carbon-carbon double bond in the middle or terminal of an alkyl group having 2 or more carbon atoms. The alkenyl group may be linear or branched. The number of carbon atoms in the alkenyl group is not specifically limited, for example, may be 2 to 30, 2 to 20, or 2 to 10. Examples of the alkenyl group may include a vinyl group, a 1-butenyl group, a 1-pentenyl group, a 1,3-butadienyl aryl group, a styrenyl group, a styryl vinyl group, etc., but embodiments of the present disclosure are not limited thereto.

In the present disclosure, an alkynyl group refers to a hydrocarbon group including at least one carbon-carbon triple bond in the middle or terminal of an alkyl group having 2 or more carbon atoms. The alkynyl group may be linear or branched. Although the number of carbon atoms is not specifically limited, it may be 2 to 30, 2 to 20, or 2 to 10. Examples of the alkynyl group may include an ethynyl group, a propynyl group, etc., but embodiments of the present disclosure are not limited thereto.

In the present disclosure, a hydrocarbon ring group refers to any functional group or substituent derived from an aliphatic hydrocarbon ring. The hydrocarbon ring group may be a saturated hydrocarbon ring group having 5 to 20 ring-forming carbon atoms.

In the present disclosure, an aryl group refers to any functional group or substituent derived from an aromatic hydrocarbon ring. The aryl group may be a monocyclic aryl group or a polycyclic aryl group. The number of ring-forming carbon atoms in the aryl group may be 6 to 30, 6 to 20, or 6 to 15. Examples of the aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., but embodiments of the present disclosure are not limited thereto.

In the present disclosure, a fluorenyl group may be substituted, and two substituents may be bonded to each other to form a spiro structure. Examples of the substituted fluorenyl group are as follows. However, embodiments of the present disclosure are not limited thereto.

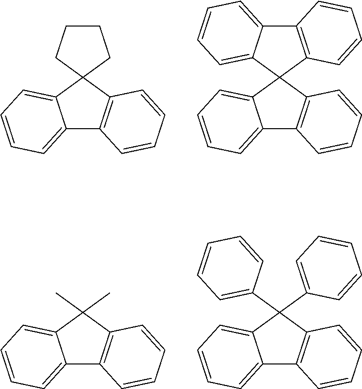

A heterocyclic group utilized herein may refer to any functional group or substituent derived from a ring containing at least one of B, O, N, P, Si, or Se as a heteroatom. The heterocyclic group may include an aliphatic heterocyclic group and/or an aromatic heterocyclic group. The aromatic heterocyclic group may be a heteroaryl group. The aliphatic heterocycle and the aromatic heterocycle may be monocyclic or polycyclic.

In the present disclosure, a heterocyclic group may contain at least one of B, O, N, P, Si or S as a heteroatom. When the heterocyclic group contains two or more heteroatoms, the two or more heteroatoms may be the same as or different from each other. The heterocyclic group may be a monocyclic heterocyclic group or a polycyclic heterocyclic group, and may include a heteroaryl group. The number of ring-forming carbon atoms in the heterocyclic group may be 2 to 30, 2 to 20, or 2 to 10.

In the present disclosure, an aliphatic heterocyclic group may include at least one of B, O, N, P, Si, or S as a heteroatom. The number of ring-forming carbon atoms in the aliphatic heterocyclic group may be 2 to 30, 2 to 20, or 2 to 10. Examples of the aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc., but embodiments of the present disclosure are not limited thereto.

In the present disclosure, a heteroaryl group may contain at least one of B, O, N, P, Si, or S as a heteroatom. When the heteroaryl group contains two or more heteroatoms, the two or more heteroatoms may be the same as or different from each other. The heteroaryl group may be a monocyclic heterocyclic group or a polycyclic heterocyclic group. The number of ring-forming carbon atoms in the heteroaryl group may be 2 to 30, 2 to 20, or 2 to 10. Examples of the heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc., but embodiments of the present disclosure are not limited thereto.

In the present disclosure, the above description of the aryl group may be applied to an arylene group except that the arylene group is a divalent group. The above description of the heteroaryl group may be applied to a heteroarylene group except that the heteroarylene group is a divalent group.

In the present disclosure, a silyl group may include an alkylsilyl group and/or an arylsilyl group. Examples of the silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc., but embodiments of the present disclosure are not limited thereto.

In the present disclosure, the number of ring-forming carbon atoms in a carbonyl group is not specifically limited, for example, may be 1 to 40, 1 to 30, or 1 to 20. For example, the carbonyl group may have the following structures, but embodiments of the present disclosure are not limited thereto.

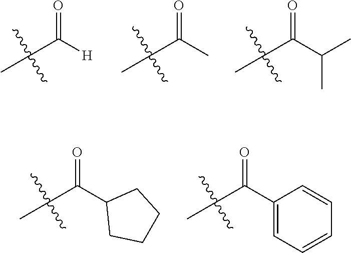

In the present disclosure, the number of carbon atoms in a sulfinyl group or the sulfonyl group is not particularly limited, for example, may be 1 to 30. The sulfinyl group may include an alkyl sulfinyl group and/or an aryl sulfinyl group. The sulfonyl group may include an alkyl sulfonyl group and/or an aryl sulfonyl group.

In the present disclosure, a thio group may include an alkylthio group and/or an arylthio group. The thio group may refer to that a sulfur atom is bonded to the alkyl group or the aryl group defined above. Examples of the thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, but embodiments of the present disclosure are not limited thereto.

In the present disclosure, an oxy group may refer to that an oxygen atom is bonded to the alkyl group or the aryl group defined above. The oxy group may include an alkoxy group and/or an aryl oxy group. The alkoxy group may be a linear chain, a branched chain, or a ring. The number of carbon atoms in the alkoxy group is not specifically limited, but may be, for example, 1 to 20 or 1 to 10. Examples of the oxy group may include methoxy, ethoxy, n-propoxy, isopropoxy, butoxy, pentyloxy, hexyloxy, octyloxy, nonyloxy, decyloxy, benzyloxy, etc., but embodiments of the present disclosure are not limited thereto.

A boron group utilized herein may refer to that a boron atom is bonded to the alkyl group or the aryl group defined above. The boron group may include an alkyl boron group and/or an aryl boron group. Examples of the boron group may include a dimethylboron group, a trimethylboron group, a t-butyldimethylboron group, a diphenylboron group, a phenylboron group, etc., but embodiments of the present disclosure are not limited thereto.

In the present disclosure, the number of carbon atoms in an amine group is not specifically limited, for example, may be 1 to 30. The amine group may include an alkyl amine group and/or an aryl amine group. Examples of the amine group may include a methylamine group, a dimethylamine group, a phenylamine group, a diphenylamine group, a naphthylamine group, a 9-methyl-anthracenylamine group, etc., but embodiments of the present disclosure are not limited thereto.

In the present disclosure, the alkyl group among an alkylthio group, an alkylsulfoxy group, an alkylaryl group, an alkylamino group, an alkyl boron group, an alkyl silyl group, and an alkyl amine group may be the same as the examples of the alkyl group described above.

In the present disclosure, the aryl group among an aryloxy group, an arylthio group, an arylsulfoxy group, an arylamino group, an arylboron group, an arylsilyl group, an arylamine group may be the same as the examples of the aryl group described above.

In the present disclosure, a direct linkage may refer to a single bond.

In the present disclosure,

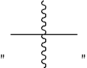

and “-*” refer to a position to be connected.

Hereinafter, embodiments of the present disclosure will be described in more detail with reference to the accompanying drawings. In the present disclosure, term “light emitting device” may be utilized interchangeably with the term “light emitting element.”

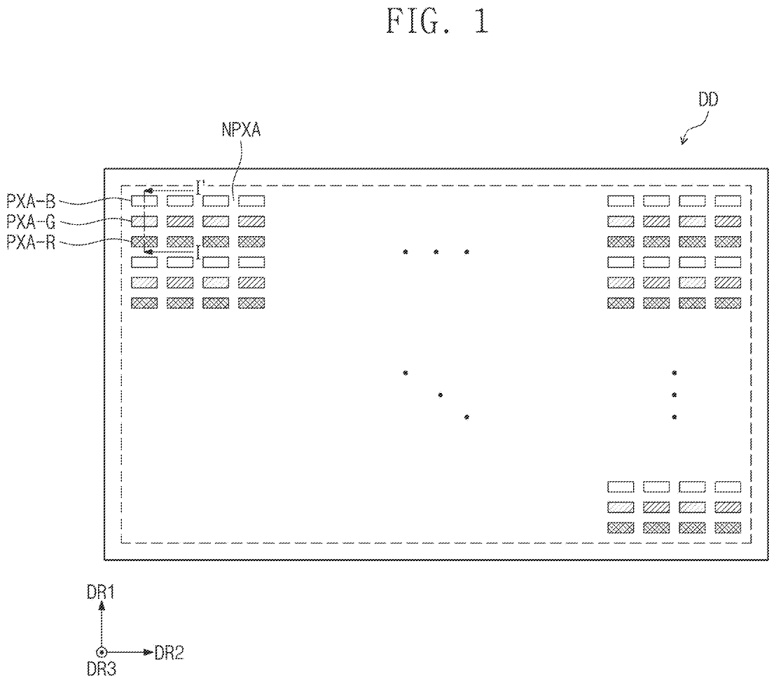

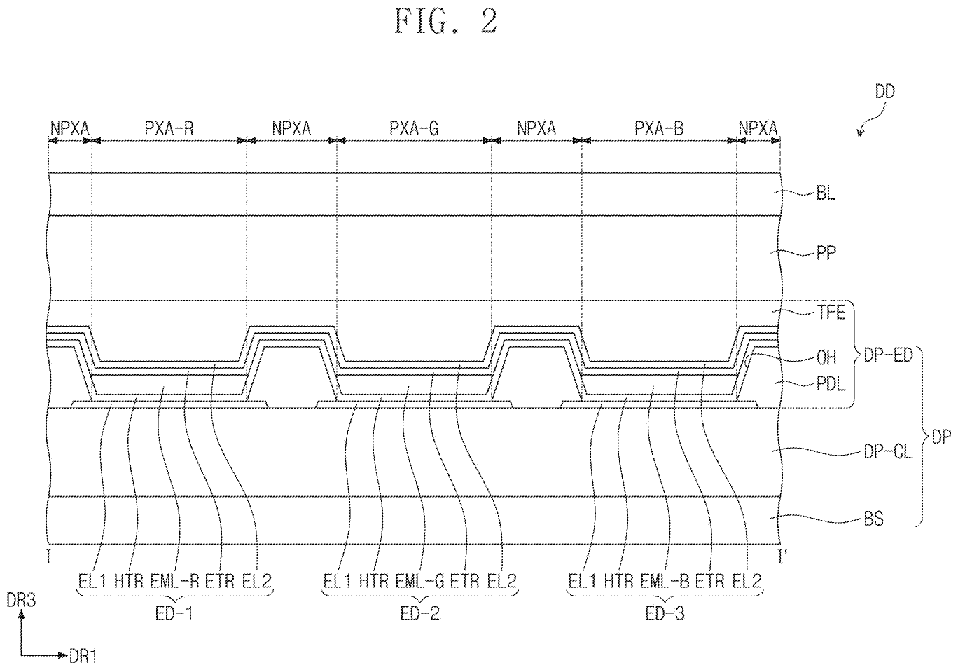

FIG. 1 is a plan view illustrating a display apparatus DD according to one or more embodiments of the present disclosure. FIG. 2 is a cross-sectional view of the display apparatus DD according to one or more embodiments of the present disclosure. FIG. 2 is a cross-sectional view illustrating a part taken along line I-I′ of FIG. 1.

The display apparatus DD may include a display panel DP and an optical layer PP disposed on the display panel DP. The display panel DP may include light emitting devices ED-1, ED-2, and ED-3. The display apparatus DD may include a plurality of light emitting devices ED-1, ED-2, and ED-3. The optical layer PP may be disposed on the display panel DP to control reflected light in the display panel DP due to external light. The optical layer PP may include, for example, a polarization layer and/or a color filter layer. In some embodiments, unlike the configuration illustrated in the drawing, the optical layer PP may not be provided in the display apparatus DD.

A base substrate BL may be disposed or provided on the optical layer PP. The base substrate BL may be a member which provides a base surface on which the optical layer PP disposed. The base substrate BL may be a glass substrate, a metal substrate, a plastic substrate, etc. However, embodiments of the present disclosure are not limited thereto, and the base substrate BL may be an inorganic layer, an organic layer, or a composite material layer. In some embodiments, the base substrate BL may not be provided.

The display apparatus DD according to one or more embodiments may further include a filling layer. The filling layer may be disposed between a display device layer DP-ED and the base substrate BL. The filling layer may be an organic material layer. The filling layer may include at least one of an acrylic-based resin, a silicone-based resin, or an epoxy-based resin.

The display panel DP may include a base layer BS, a circuit layer DP-CL provided on the base layer BS, and a display device layer DP-ED. The display device layer DP-ED may include a pixel defining film PDL, the light emitting devices ED-1, ED-2, and ED-3 each disposed between portions of the pixel defining film PDL, and an encapsulation layer TFE disposed on the light emitting devices ED-1, ED-2, and ED-3.

The base layer BS may be a member which provides a base surface on which the display device layer DP-ED is disposed. The base layer BS may be a glass substrate, a metal substrate, a plastic substrate, etc. However, embodiments of the present disclosure are not limited thereto, and the base layer BS may be an inorganic layer, an organic layer, or a composite material layer.

In one or more embodiments, the circuit layer DP-CL may be disposed on the base layer BS, and the circuit layer DP-CL may include a plurality of transistors. Each of the transistors may include a control electrode, an input electrode, and an output electrode. For example, in some embodiments, the circuit layer DP-CL may include switching transistor(s) and driving transistor(s) for driving the light emitting devices ED-1, ED-2, and ED-3 of the display device layer DP-ED.

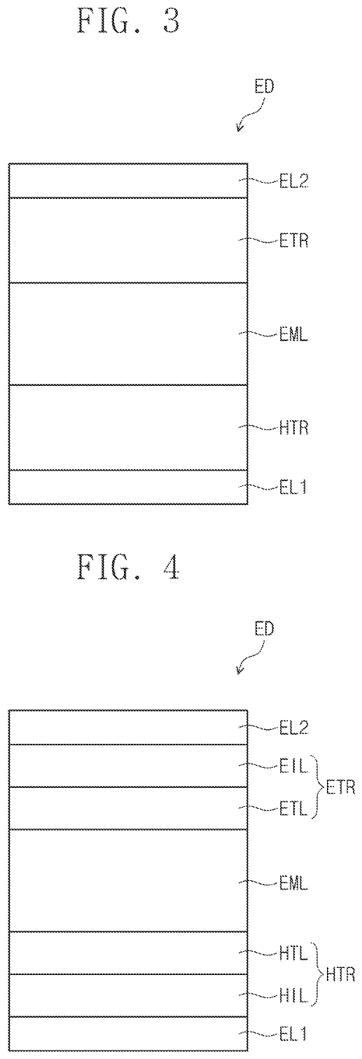

Each of the light emitting devices ED-1, ED-2, and ED-3 may have a structure of one of light emitting devices ED of embodiments according to FIGS. 3 to 6, which will be described later. Each of the light emitting devices ED-1, ED-2, and ED-3 may include a first electrode EL1, a hole transport region HTR, respective emission layers EML-R, EML-G, and EML-B, an electron transport region ETR, and a second electrode EL2.

FIG. 2 illustrates an embodiment in which the respective emission layers EML-R, EML-G, and EML-B of the light emitting devices ED-1, ED-2, and ED-3 are disposed in openings OH defined in the pixel defining film PDL, and the hole transport region HTR, the electron transport region ETR, and the second electrode EL2 are provided as a common layer in the entire light emitting devices ED-1, ED-2, and ED-3. However, embodiments of the present disclosure are not limited thereto, for example, in some embodiments, the hole transport region HTR and the electron transport region ETR may be provided by being patterned inside the openings OH defined in the pixel defining film PDL. For example, in some embodiments, the hole transport region HTR, the respective emission layers EML-R, EML-G, and EML-B, and the electron transport region ETR of the light emitting devices ED-1, ED-2, and ED-3 may be provided by being patterned in an inkjet printing method.

The encapsulation layer TFE may cover the light emitting devices ED-1, ED-2, and ED-3. The encapsulation layer TFE may seal the display device layer DP-ED. The encapsulation layer TFE may be a thin film encapsulation layer. The encapsulation layer TFE may be formed by laminating one layer or a plurality of layers. The encapsulation layer TFE may include at least one insulation layer. In some embodiments, the encapsulation layer TFE may include at least one inorganic film (hereinafter, an encapsulation-inorganic film). In some embodiments, the encapsulation layer TFE may include at least one organic film (hereinafter, an encapsulation-organic film) and at least one encapsulation-inorganic film.

The encapsulation-inorganic film protects the display device layer DP-ED from moisture/oxygen, and the encapsulation-organic film protects the display device layer DP-ED from foreign substances such as dust particles. The encapsulation-inorganic film may include silicon nitride, silicon oxynitride, silicon oxide, titanium oxide, aluminum oxide, and/or the like, but embodiments of the present disclosure are not particularly limited thereto. The encapsulation-organic film may include an acrylic-based compound, an epoxy-based compound, and/or the like. In some embodiments, the encapsulation-organic film may include a photopolymerizable organic material, but embodiments of the present disclosure are not particularly limited thereto.

The encapsulation layer TFE may be disposed on the second electrode EL2 and may be disposed filling the opening OH.

Referring to FIG. 1 and FIG. 2, the display apparatus DD may include a non-light emitting region NPXA and light emitting regions PXA-R, PXA-G, and PXA-B. The light emitting regions PXA-R, PXA-G, and PXA-B may be regions in which light generated by the respective light emitting devices ED-1, ED-2, and ED-3 is emitted.

The light emitting regions PXA-R, PXA-G, and PXA-B may be spaced apart from each other on a plane.

Each of the light emitting regions PXA-R, PXA-G, and PXA-B may be a region divided by the pixel defining film PDL. The non-light emitting areas NPXA may be areas between adjacent light emitting areas PXA-R, PXA-G, and PXA-B, which correspond to the pixel defining film PDL. In some embodiments, the light emitting regions PXA-R, PXA-G, and PXA-B may respectively correspond to pixels. The pixel defining film PDL may divide the light emitting devices ED-1, ED-2, and ED-3. The respective emission layers EML-R, EML-G, and EML-B of the light emitting devices ED-1, ED-2, and ED-3 may be disposed in openings OH defined in the pixel defining film PDL and separated from each other.

The light emitting regions PXA-R, PXA-G, and PXA-B may be divided into a plurality of groups according to the color of light generated from the light emitting devices ED-1, ED-2, and ED-3. In the display apparatus DD of one or more embodiments illustrated in FIG. 1 and FIG. 2, three light emitting regions PXA-R, PXA-G, and PXA-B, which emit red light, green light, and blue light, respectively, are exemplarily illustrated. For example, in one or more embodiments, the display device DD may include a red light emitting region PXA-R, a green light emitting region PXA-G, and a blue light emitting region PXA-B that are separated from each other.

In the display apparatus DD according to one or more embodiments, the plurality of light emitting devices ED-1, ED-2 and ED-3 may be to emit light beams having wavelengths different from each other. For example, in an embodiment, the display apparatus DD may include a first light emitting device ED-1 that emits red light, a second light emitting device ED-2 that emits green light, and a third light emitting device ED-3 that emits blue light. For example, in some embodiments, the red light emitting region PXA-R, the green light emitting region PXA-G, and the blue light emitting region PXA-B of the display apparatus DD may correspond to the first light emitting device ED-1, the second light emitting device ED-2, and the third light emitting device ED-3, respectively.

However, embodiments of the present disclosure are not limited thereto, and the first to third light emitting devices ED-1, ED-2, and ED-3 may be to emit light beams in substantially the same wavelength range or at least one light emitting device may be to emit a light beam in a wavelength range different from the others. For example, in some embodiments, the first to third light emitting devices ED-1, ED-2, and ED-3 may all emit blue light.

The light emitting regions PXA-R, PXA-G, and PXA-B in the display apparatus DD according to an embodiment may be arranged in a stripe form. Referring to FIG. 1, a plurality of red light emitting regions PXA-R may be arranged with each other along a second direction axis DR2, a plurality of green light emitting regions PXA-G may be arranged with each other along the second direction axis DR2, and a plurality of blue light emitting regions PXA-B may be arranged with each other along the second direction axis DR2. In some embodiments, the red light emitting region PXA-R, the green light emitting region PXA-G, and the blue light emitting region PXA-B may be alternately arranged in the stated order along a first direction axis DR1.

FIG. 1 and FIG. 2 illustrate that all the light emitting regions PXA-R, PXA-G, and PXA-B have similar area, but embodiments of the present disclosure are not limited thereto. Thus, the light emitting regions PXA-R, PXA-G, and PXA-B may have different areas from each other according to the wavelength range of the emitted light. The areas of the light emitting regions PXA-R, PXA-G, and PXA-B may refer to areas when viewed on a plane defined by the first direction axis DR1 and the second direction axis DR2 (e.g., the areas in a plan view).

In some embodiments, an arrangement form of the light emitting regions PXA-R, PXA-G, and PXA-B is not limited to the configuration illustrated in FIG. 1, and the order in which the red light emitting region PXA-R, the green light emitting region PXA-G, and the blue light emitting region PXA-B are arranged may be provided in one or more suitable combinations according to the characteristics of display quality required in the display apparatus DD. For example, in some embodiments, the arrangement form of the light emitting regions PXA-R, PXA-G, and PXA-B may be a pentile (PENTILE®) arrangement form (for example, an RGBG matrix, an RGBG structure, or an RGBG matrix structure), or a diamond (Diamond Pixel™) arrangement form (e.g., a display (e.g., an OLED display) containing red, blue, and green (RGB) light-emitting regions arranged in the shape of diamonds). PENTILE® is a duly registered trademark of Samsung Display Co., Ltd. Diamond Pixel™ is a trademark of Samsung Display Co., Ltd.

In some embodiments, the areas of the light emitting regions PXA-R, PXA-G, and PXA-B may be different from each other. For example, in an embodiment, the area of the green light emitting region PXA-G may be smaller than that of the blue light emitting region PXA-B, but embodiments of the present disclosure are not limited thereto.

Hereinafter, FIG. 3 to FIG. 6 are cross-sectional views schematically showing light emitting devices according to one or more embodiments of the present disclosure. The light emitting device ED of one or more embodiments may include a first electrode EL1, a hole transport region HTR, an emission layer EML, an electron transport region ETR, and a second electrode EL2 stacked in order (e.g., in the stated order).

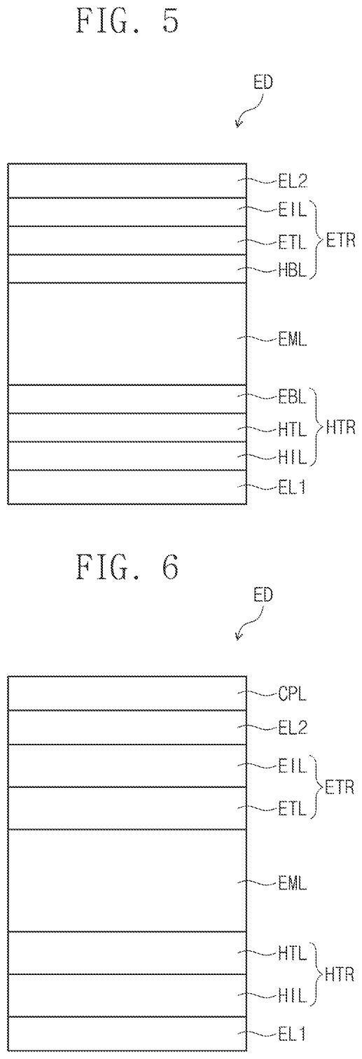

Compared with FIG. 3, FIG. 4 illustrates a cross-sectional view of a light emitting device ED of an embodiment, in which a hole transport region HTR may include a hole injection layer HIL and a hole transport layer HTL, and an electron transport region ETR may include an electron injection layer EIL and an electron transport layer ETL. Compared with FIG. 3, FIG. 5 illustrates a cross-sectional view of a light emitting device ED of an embodiment, in which a hole transport region HTR may include a hole injection layer HIL, a hole transport layer HTL, and an electron blocking layer EBL, and an electron transport region ETR may include an electron injection layer EIL, an electron transport layer ETL, and a hole blocking layer HBL. Compared with FIG. 4, FIG. 6 illustrates a cross-sectional view of a light emitting device ED of an embodiment including a capping layer CPL disposed on a second electrode EL2.

The first electrode EL1 has conductivity (e.g., is a conductor). The first electrode EL1 may be formed of a metal material, a metal alloy, and/or a conductive compound. The first electrode EL1 may be an anode or a cathode. However, embodiments of the present disclosure are not limited thereto. In some embodiments, the first electrode EL1 may be a pixel electrode. The first electrode EL1 may be a transmissive electrode, a transflective electrode, or a reflective electrode. The first electrode EL1 may include at least one selected from among silver (Ag), magnesium (Mg), copper (Cu), aluminum (Al), platinum (Pt), palladium (Pd), gold (Au), nickel (Ni), neodymium (Nd), iridium (Ir), chromium (Cr), lithium (Li), calcium (Ca), lithium fluoride (LiF), molybdenum (Mo), titanium (Ti), tungsten (W), indium (In), tin (Sn), zinc (Zn), one or more compounds each being of two or more selected therefrom, one or more mixtures each being of two or more selected therefrom, and/or one or more oxides thereof.

When the first electrode EL1 is a transmissive electrode, the first electrode EL1 may include a transparent metal oxide such as indium tin oxide (ITO), indium zinc oxide (IZO), zinc oxide (ZnO), and/or indium tin zinc oxide (ITZO). When the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, a compound thereof, or a mixture thereof (e.g., a mixture of Ag and Mg). In some embodiments, the first electrode EL1 may have a multilayer structure including a reflective film or a transflective film formed of the above-described materials, and a transparent conductive film formed of ITO, IZO, ZnO, ITZO, etc. For example, in some embodiments, the first electrode EL1 may have a three-layer structure of ITO/Ag/ITO, but embodiments of the present disclosure are not limited thereto. The first electrode EL1 may include one of the above-described metal materials, combinations of at least two metal materials of the above-described metal materials, oxides of the above-described metal materials, and/or the like. A thickness of the first electrode EL1 may be from about 700 Å to about 10,000 Å. For example, in one or more embodiments, the thickness of the first electrode EL1 may be from about 1,000 Å to about 3,000 Å.

The hole transport region HTR may be provided on the first electrode EL1. The hole transport region HTR may include at least one of a hole injection layer HIL, a hole transport layer HTL, a buffer layer or an emission-auxiliary layer, or an electron blocking layer EBL. A thickness of the hole transport region HTR may be, for example, from about 50 Å to about 15,000 Å.

The hole transport region HTR may have a single layer formed of a single material, a single layer formed of a plurality of different materials, or a multilayer structure including a plurality of layers formed of a plurality of different materials.

For example, in one or more embodiments, the hole transport region HTR may have a single layer structure of a hole injection layer HIL or a hole transport layer HTL, or may have a single layer structure formed of a hole injection material and a hole transport material. In some embodiments, the hole transport region HTR may have a single layer structure formed of a plurality of different materials, or a structure in which a hole injection layer HIL/hole transport layer HTL, a hole injection layer HIL/hole transport layer HTL/buffer layer, a hole injection layer HIL/buffer layer, a hole transport layer HTL/buffer layer, or a hole injection layer HIL/hole transport layer HTL/electron blocking layer EBL are stacked in order (e.g., in the stated order) from the first electrode EL1, but embodiments of the present disclosure are not limited thereto.

The hole transport region HTR may be formed utilizing one or more suitable methods such as a vacuum deposition method, a spin coating method, a casting method, a Langmuir-Blodgett (LB) method, an inkjet printing method, a laser printing method, and/or a laser induced thermal imaging (LITI) method.

In one or more embodiments, the hole transport region HTR may include a compound represented by Formula H-1:

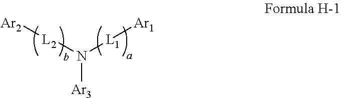

In Formula H-1, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. a and b may each independently be an integer of 0 to 10. In some embodiments, when a or b is an integer of 2 or greater, a plurality of L₁'s and L₂'s may each independently be a substituted or unsubstituted arylene group having 6 to 30 ring-forming carbon atoms, or a substituted or unsubstituted heteroarylene group having 2 to 30 ring-forming carbon atoms.

In Formula H-1, Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. In some embodiments, in Formula H-1, Ar₃ may be a substituted or unsubstituted aryl group having 6 to 30 ring-forming carbon atoms, or a substituted or unsubstituted heteroaryl group having 2 to 30 ring-forming carbon atoms.

The compound represented by Formula H-1 may be a monoamine compound. In some embodiments, the compound represented by Formula H-1 may be a diamine compound in which at least one selected from among Ar₁ to Ar₃ may include an amine group as a substituent. In some embodiments, the compound represented by Formula H-1 may be a carbazole-based compound including a substituted or unsubstituted carbazole group in at least one of Ar₁ or Ar₂, or a fluorene-based compound including a substituted or unsubstituted fluorene group in at least one of Ar₁ or Ar₂.

The compound represented by Formula H-1 may be represented by any one selected from among compounds in Compound Group H. However, the compounds listed in Compound Group H are mere examples, and the compounds represented by Formula H-1 are not limited to those represented in Compound Group H:

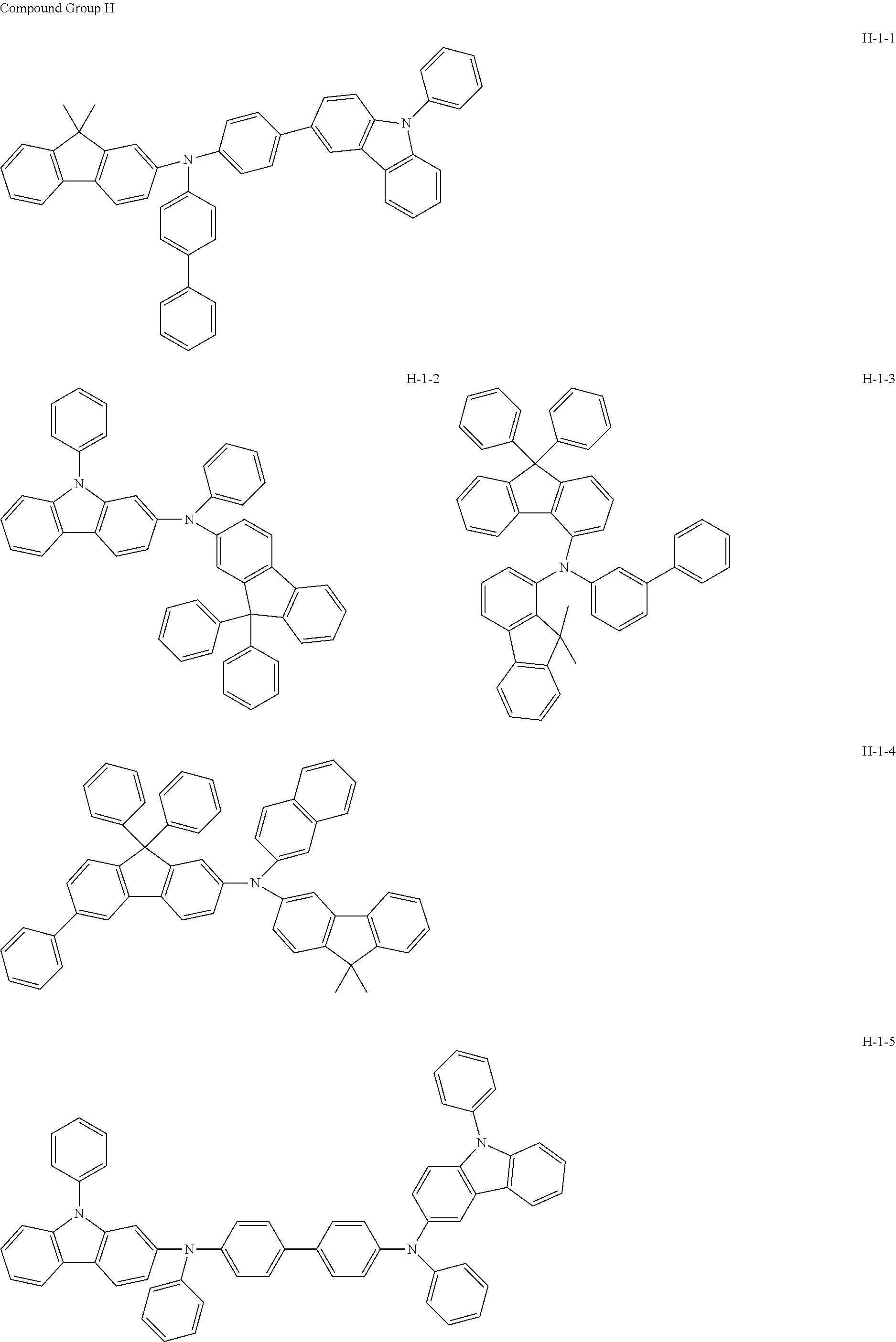 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21 ; CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21 ; c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1]

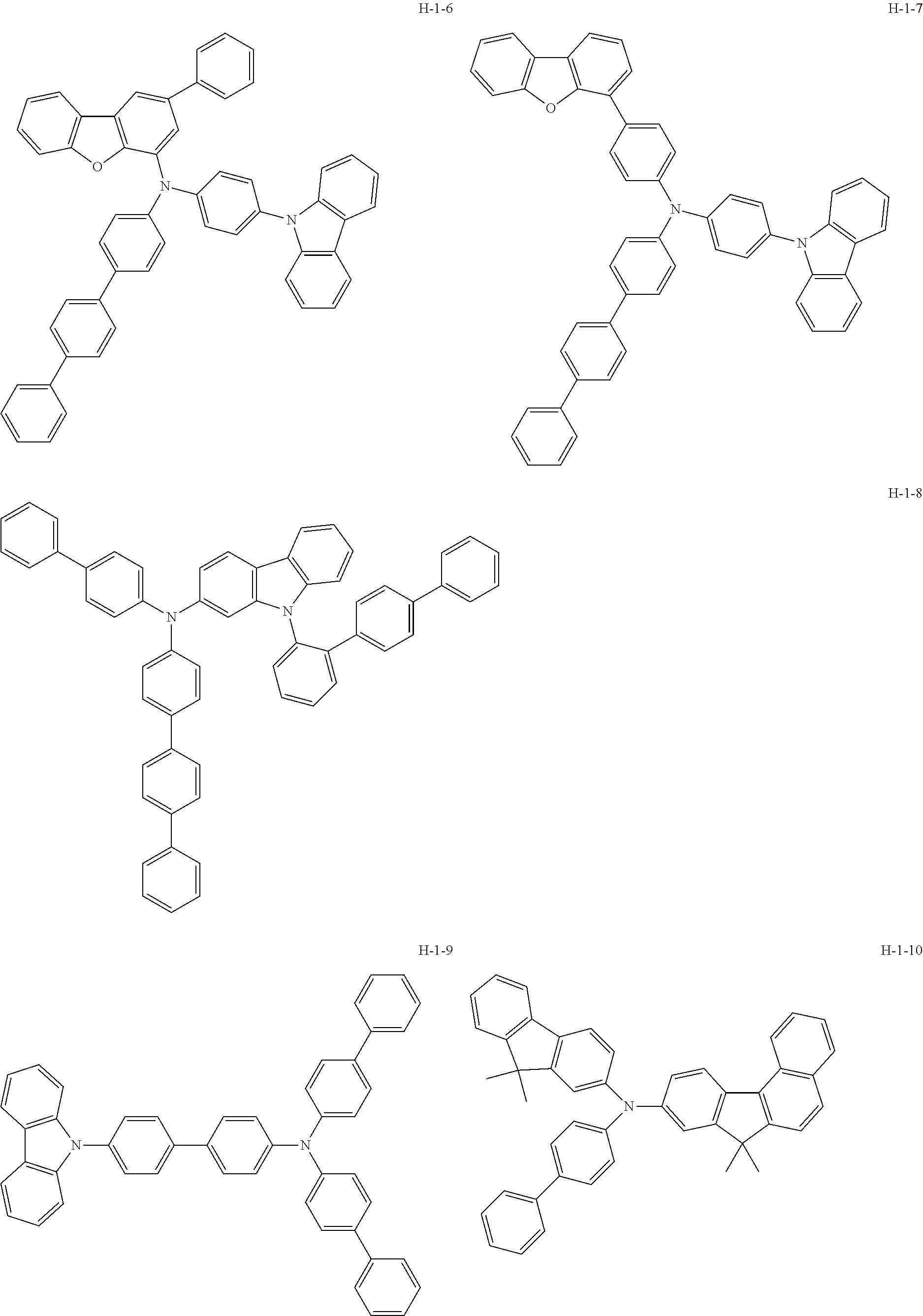 [SMILES: c1ccc(-c2ccc(-c3ccc(N(c4ccc(-n5c6ccccc6c6ccccc65)cc4)c4cc(-c5ccccc5)cc5c4oc4ccccc45)cc3)cc2)cc1 ; c1ccc(-c2ccc(-c3ccc(N(c4ccc(-c5cccc6c5oc5ccccc56)cc4)c4ccc(-n5c6ccccc6c6ccccc65)cc4)cc3)cc2)cc1 ; c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; CC1(C)c2ccccc2-c2ccc(N(c3ccc(-c4ccccc4)cc3)c3ccc4c(c3)C(C)(C)c3ccc5ccccc5c3-4)cc21]

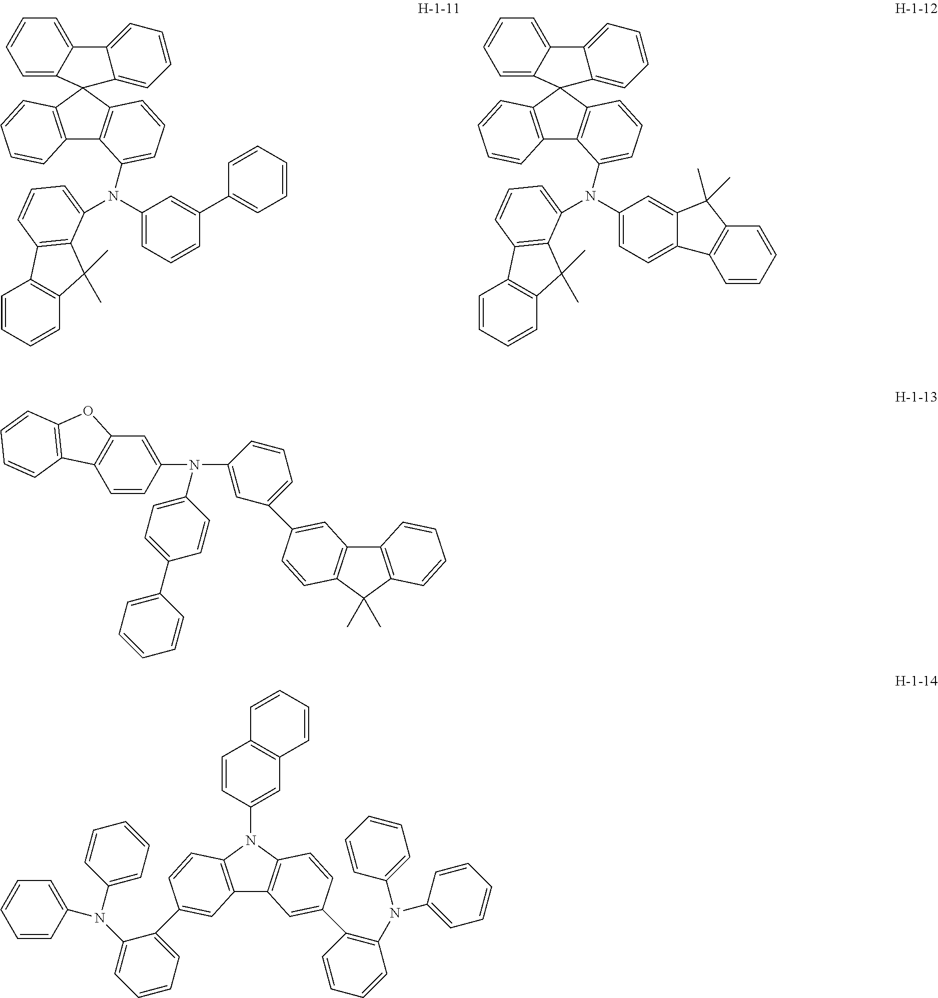 [SMILES: CC1(C)c2ccccc2-c2cccc(N(c3cccc(-c4ccccc4)c3)c3cccc4c3-c3ccccc3C43c4ccccc4-c4ccccc43)c21 ; CC1(C)c2ccccc2-c2ccc(N(c3cccc4c3-c3ccccc3C43c4ccccc4-c4ccccc43)c3cccc4c3C(C)(C)c3ccccc3-4)cc21 ; CC1(C)c2ccccc2-c2cc(-c3cccc(N(c4ccc(-c5ccccc5)cc4)c4ccc5c(c4)oc4ccccc45)c3)ccc21 ; c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1]

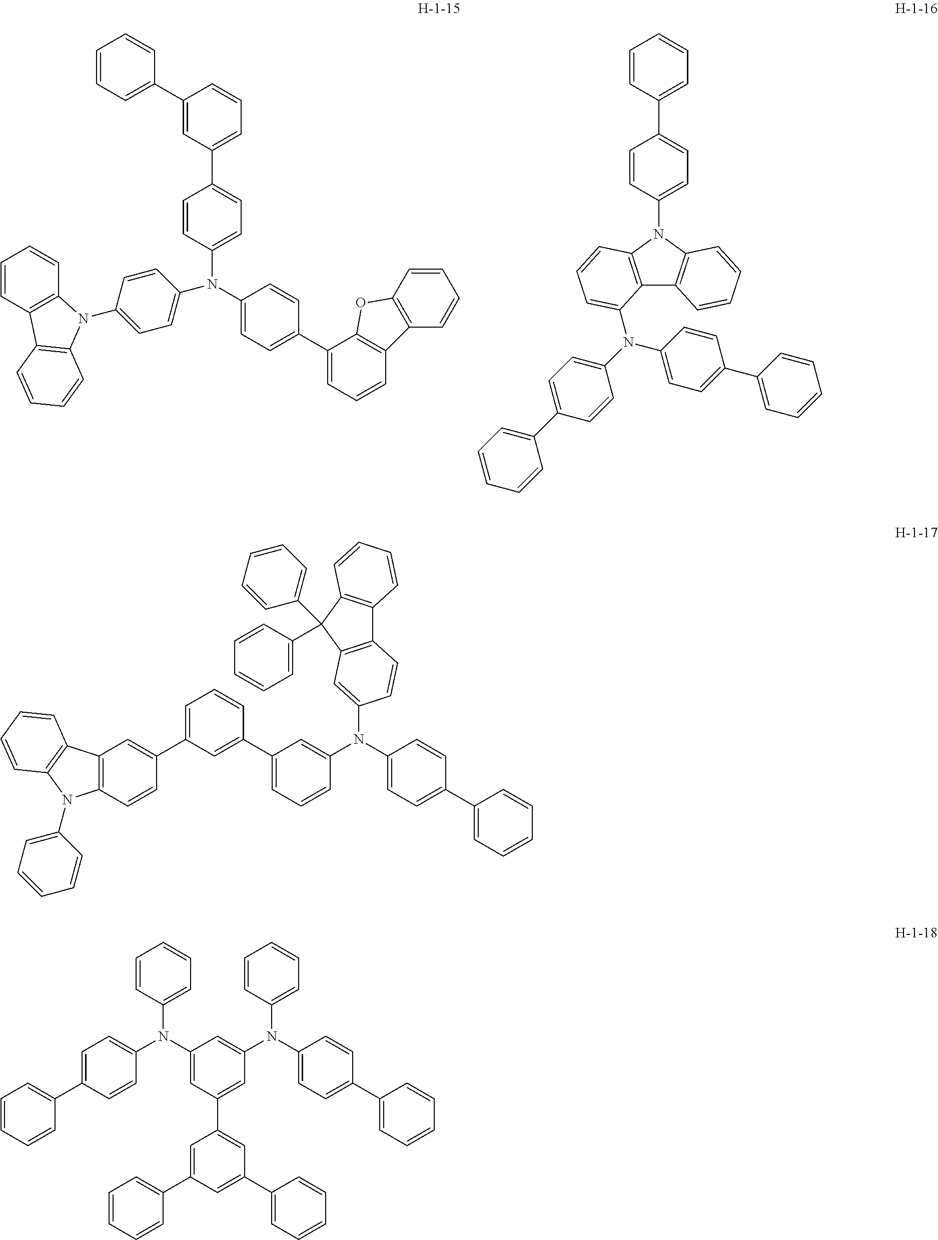 [SMILES: c1ccc(-c2cccc(-c3ccc(N(c4ccc(-c5cccc6c5oc5ccccc56)cc4)c4ccc(-n5c6ccccc6c6ccccc65)cc4)cc3)c2)cc1 ; c1ccc(-c2ccc(N(c3ccc(-c4ccccc4)cc3)c3cccc4c3c3ccccc3n4-c3ccc(-c4ccccc4)cc3)cc2)cc1 ; c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1]

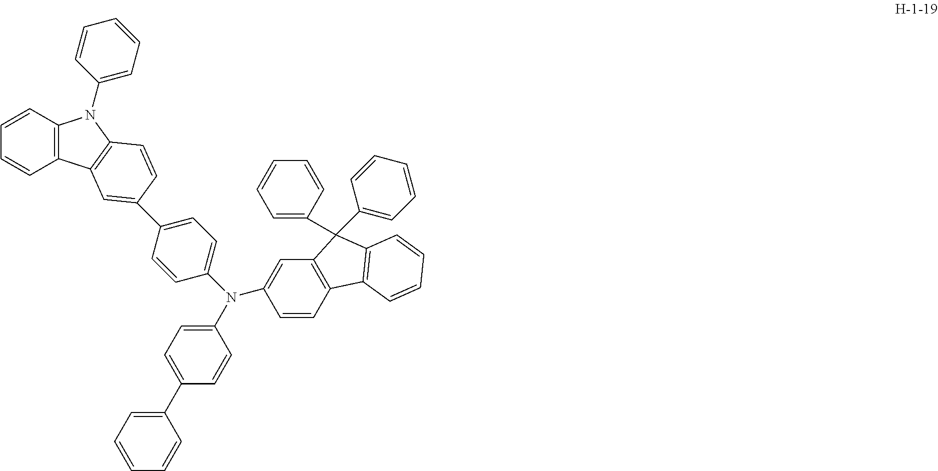 [SMILES: c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

In one or more embodiments, the hole transport region HTR may include at least one selected from a phthalocyanine compound such as copper phthalocyanine; N¹,N^{1′}-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino] triphenylamine (m-MTDATA), 4,4′,4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalen-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], dipyrazino[2,3-f: 2′,3′-h]quinoxaline-2,3,6,7,10,11-hexacarbonitrile (HATCN), etc.

In one or more embodiments, the hole transport region HTR may include at least one selected from a carbazole-based derivative such as N-phenyl carbazole or polyvinyl carbazole, a fluorene-based derivative, a triphenylamine-based derivative such as N,N′-bis(3-methylphenyl)-N,N′-diphenyl-[1,1-biphenyl]-4,4′-diamine (TPD) or 4,4′,4″-tris(N-carbazolyl)triphenylamine (TCTA), N,N′-di(naphthalen-1-yl)-N,N′-diphenyl-benzidine (NPB), 4,4′-cyclohexylidene bis[N,N-bis(4-methylphenyl]benzenamine](TAPC), 4,4′-bis[N,N′-(3-tolyl)amino]-3,3′-dimethylbiphenyl (HMTPD), 1,3-bis(N-carbazolyl)benzene (mCP), etc.

In some embodiments, the hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The hole transport region HTR may include at least one of the above-described compounds of the hole transport region in at least one of a hole injection layer HIL, a hole transport layer HTL, or an electron blocking layer EBL.

A thickness of the hole transport region HTR may be from about 100 Å to about 10,000 Å, for example, from about 100 Å to about 5,000 Å. When the hole transport region HTR includes a hole injection layer HIL, the hole injection layer HIL may have, for example, a thickness of about 30 Å to about 1,000 Å. When the hole transport region HTR includes a hole transport layer HTL, the hole transport layer HTL may have a thickness of about 250 Å to about 1,000 Å. For example, when the hole transport region HTR includes an electron blocking layer EBL, the electron blocking layer EBL may have a thickness of about 10 Å to about 1,000 Å. When the thicknesses of the hole transport region HTR, the hole injection layer HIL, the hole transport layer HTL, and the electron blocking layer EBL satisfy the above-described ranges, satisfactory hole transport properties may be achieved without a substantial increase in driving voltage.

In one or more embodiments, the hole transport region HTR may further include a charge generating material to increase conductivity in addition to the above-described materials. The charge generating material may be dispersed uniformly or non-uniformly in the hole transport region HTR. The charge generating material may be, for example, a p-dopant. The p-dopant may include at least one of a halogenated metal compound, a quinone derivative, a metal oxide, or a cyano group-containing compound, but embodiments of the present disclosure are not limited thereto. For example, in some embodiments, the p-dopant may include a metal halide compound such as CuI and/or RbI, a quinone derivative such as tetracyanoquinodimethane (TCNQ) and/or 2,3,5,6-tetrafluoro-7,7′8,8-tetracyanoquinodimethane (F4-TCNQ), a metal oxide such as tungsten oxide and/or molybdenum oxide, a cyano group-containing compound such as dipyrazino[2,3-f: 2′,3′-h] quinoxaline-2,3,6,7,10,11-hexacarbonitrile (HATCN) and/or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., but embodiments of the present disclosure are not limited thereto.

As described above, the hole transport region HTR may further include at least one of the buffer layer or the electron blocking layer EBL in addition to the hole injection layer HIL and the hole transport layer HTL. The buffer layer may compensate for a resonance distance according to the wavelength of light emitted from the emission layer EML and may thus increase light emission efficiency. A material that may be included in the hole transport region HTR may be utilized as a material to be included in the buffer layer. The electron blocking layer EBL is a layer that serves to prevent or reduce the electron injection from the electron transport region ETR to the hole transport region HTR.

The emission layer EML may be provided on the hole transport region HTR. The emission layer EML may have a thickness of, for example, about 100 Å to about 1,000 Å, or about 100 Å to about 300 Å. The emission layer EML may have a single layer formed of a single material, a single layer formed of multiple different materials, or a multi-layered structure having a plurality of layers formed of multiple different materials.

The light emitting device ED of one or more embodiments may include a fused polycyclic compound represented by Formula 1 in at least one functional layer disposed between the first electrode EL1 and the second electrode EL2. The emission layer EML in the light emitting device ED according to one or more embodiments may include a fused polycyclic compound of one or more embodiments. In one or more embodiments, the emission layer EML may include the fused polycyclic compound of one or more embodiments as a dopant. The fused polycyclic compound of one or more embodiments may be a dopant material of the emission layer EML. In the present disclosure, the fused polycyclic compound of one or more embodiments, which will be described later, may be referred to as a first compound.

The fused polycyclic compound of an embodiment may include a structure in which a plurality of aromatic rings are fused via a boron atom, a first heteroatom, and a second heteroatom. For example, the fused polycyclic compound of an embodiment may include a structure in which first to third aromatic rings are fused via one boron atom, a first heteroatom, and a second heteroatom. The first to third aromatic rings each may be linked to the boron atom, the first aromatic ring and the second aromatic ring may be linked to each other via the first heteroatom, and the first aromatic ring and the third aromatic ring may be linked to each other via the second heteroatom. In one or more embodiments, the first to third aromatic rings may each be 6-membered aromatic hydrocarbon rings. For example, in some embodiments, the first to third aromatic rings may be benzene rings. In one or more embodiments, the first heteroatom and the second heteroatom may each independently be an oxygen atom (O), a sulfur atom (S), or a nitrogen atom (N). In the present disclosure, the boron atom, the first heteroatom, and the second heteroatom, and the first to third aromatic rings which are fused via the boron atom, the first heteroatom, and the second heteroatom may be referred to as “fused ring core.”

The fused polycyclic compound of an embodiment may include a first substituent linked to the fused ring core. The first substituent may be linked to at least one selected from among the first to third aromatic rings. The fused polycyclic compound of an embodiment may include at least one first substituent. The first substituent may be an electron withdrawing group. In one or more embodiments, the first substituent may be a cyano group or a substituted or unsubstituted 6-membered heteroaryl group containing N as a ring-forming atom. For example, in some embodiments, the first substituent may be a cyano group, a substituted or unsubstituted pyridine group, a substituted or unsubstituted pyrazine group, or a substituted or unsubstituted 1,3,5-triazine group. The first substituent may be directly linked to the fused ring core without an additional linker. In the present disclosure, the first substituent may refer to a substituent represented by Formula 3 which will be described later.

In one or more embodiments, the first substituent may be substituted at the meta position with respect to the boron atom in the fused ring core. The fused ring core may be represented by Formula R₁. In the fused polycyclic compound of an embodiment, the first to third aromatic rings included in the fused ring core may each independently include two carbon atoms at the meta positions with respect to the boron atom. The first aromatic ring may include first carbon and second carbon, which are two carbon atoms at the meta positions with respect to the carbon atom, linked to the boron atom, among carbon atoms constituting the first aromatic ring. The second aromatic ring may include third carbon and fourth carbon, which are two carbon atoms at the meta positions with respect to the carbon atom, linked to the boron atom, among carbon atoms constituting the second aromatic ring. The third aromatic ring may include fifth carbon and sixth carbon, which are two carbon atoms at the meta positions with respect to the carbon atom, linked to the boron atom, among carbon atoms constituting the third aromatic ring. In one or more embodiments, the first substituent may be linked to at least one selected from among the first to sixth carbon. For example, referring to Formula R₁, the first substituent may be substituted at least one position selected from among a1 carbon to a6 carbon.

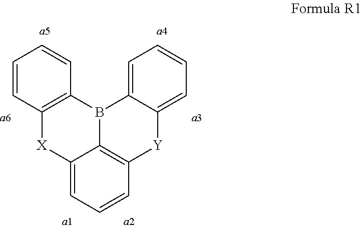

In Formula R₁, X and Y may each independently be O, S, or NR′. Here, R′ may refer to a substituted or unsubstituted phenyl group. For example, in some embodiments, R′ may refer to a benzene ring substituted with substituents represented by R₁ to R₅ in a substituent represented by Formula 2 which will be described later. In some embodiments, for convenience of description, substituents linked to first to third benzene rings in Formula R₁ are omitted.

The fused polycyclic compound of an embodiment may be represented by Formula 1:

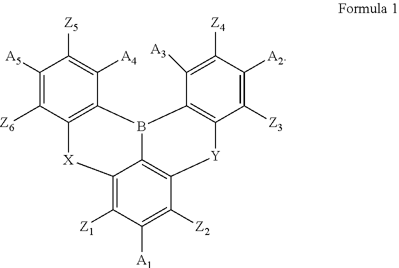

In Formula 1, X and Y may each independently be O, S, or a substituent represented by Formula 2.

In Formula 1, A₁ may be hydrogen, deuterium, a halogen, a cyano group, a nitro group, a substituted or unsubstituted amine group, an unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In the fused polycyclic compound represented by Formula 1 of an embodiment, the embodiment in which A₁ is a substituted alkyl group is excluded. In one or more embodiments, A₁ may be hydrogen, deuterium, an unsubstituted methyl group, an unsubstituted t-butyl group, a substituted or unsubstituted phenyl group, a substituted or unsubstituted terphenyl group, or a substituted or unsubstituted carbazole group.

In Formula 1, A₂ to A₅ may each independently be hydrogen, deuterium, a halogen, a cyano group, a nitro group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, in one or more embodiments, A₂ to A₅ may each independently be hydrogen, deuterium, a substituted or unsubstituted t-butyl group, a substituted or unsubstituted phenyl group, or a substituted or unsubstituted carbazole group.

In Formula 1, Z₁ to Z₆ may each independently be hydrogen, deuterium, a halogen, a cyano group, a nitro group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or a substituent represented by Formula 3. For example, in one or more embodiments, Z₁ to Z₆ may each independently be hydrogen, deuterium, a cyano group, a substituted or unsubstituted phenyl group, or a substituent represented by Formula 3.

In Formula 1, at least one selected from among Z₁ to Z₆ is a cyano group, or a substituent represented by a Formula 3.

In the fused polycyclic compound represented by Formula 1, when each of X and Y is O, the embodiment in which each of Z₄ and Z₅ is hydrogen is excluded. For example, in one or more embodiments, when each of X and Y is O, each of Z₄ and Z₅ is not a hydrogen atom, but deuterium, a halogen, a cyano group, a nitro group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or a substituent represented by Formula 3.

In one or more embodiments, the embodiment in which the fused polycyclic compound represented by Formula 1 includes an adamantyl group is excluded. For example, in one or more embodiments, the fused polycyclic compound represented by Formula 1 may not include (e.g., may exclude) an adamantyl moiety in the molecular structure. In one or more embodiments, the embodiment in which the fused polycyclic compound represented by Formula 1 includes a substituted or unsubstituted spiroadamantanefluorene group is excluded. For example, in Formula 1, the embodiment in which each of A₁ to A₅, and Z₁ to Z₆ is a substituted or unsubstituted spiroadamantanefluorene group may be excluded. In the present disclosure, the “spiroadamantanefluorene group” may refer to a spiro[adamantane-2,9′-fluorene]group having S1 structure:

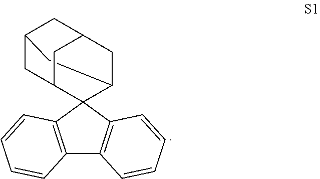 [SMILES: c1ccc2c(c1)-c1ccccc1C21C2CC3CC(C2)CC1C3]

In one or more embodiments, the embodiment in which the fused polycyclic compound represented by Formula 1 includes a cycloalkyl group may be excluded. For example, the embodiment in which the fused polycyclic compound represented by Formula 1 includes a substituted or unsubstituted cyclohexyl group may be excluded. However, embodiments of the present disclosure are not limited thereto.

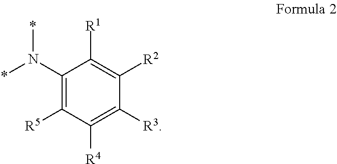

In Formula 2, R₁ to R₅ may each independently be hydrogen, deuterium, a halogen, a cyano group, a nitro group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, in some embodiments, R₁ to R₅ may each independently be hydrogen, deuterium, or a substituted or unsubstituted phenyl group.

In some embodiments, when each of R₁ to R₅ is a substituted or unsubstituted heteroaryl group having 2 to 30 ring-forming carbon atoms, the embodiment in which the heteroaryl group contains nitrogen as a ring-forming atom is excluded. For example, the embodiment in which each of R₁ to R₅ is a substituted or unsubstituted 6-membered heteroaryl group having N as a ring-forming atom is excluded.

In some embodiments, in Formula 1, when any one selected from among Z₄ and Z₅ is a cyano group or a substituted or unsubstituted pyridine group, at least one selected from among R₁ to R₅ in Formula 2 is a substituted or unsubstituted aryl group having 6 to 30 ring-forming carbon atoms, or a substituted or unsubstituted heteroaryl group having 2 to 30 ring-forming carbon atoms. In one or more embodiments, in Formula 1, when any one selected from among Z₄ and Z₅ is a cyano group or a substituted or unsubstituted pyridine group, at least one selected from among R₁ to R₅ in Formula 2 may be a substituted or unsubstituted aryl group having 6 to 30 ring-forming carbon atoms. For example, in some embodiments, in Formula 1, when any one selected from among Z₄ and Z₅ is a cyano group or a substituted or unsubstituted pyridine group, at least one selected from among R₁ to R₅ in Formula 2 may be a substituted or unsubstituted phenyl group.

In Formula 2, -* is a position linked to Formula 1.

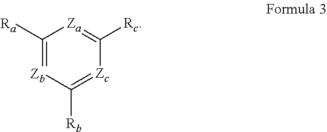

In Formula 3, at least one selected from among Zₐ to Z_{c} may be N, and the rest may be CR_{d}. For example, in some embodiments, one selected from among Zₐ to Z_{c} may be N, and the rest may be CR_{d}. In some embodiments, two selected from among Zₐ to Z_{c} may be N, and the rest may be CR_{d}. In some embodiments, Zₐ to Z_{c} may all be N.

In Formula 3, Rₐ to R_{d} may each independently be hydrogen, deuterium, a halogen, a cyano group, a nitro group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, in some embodiments, Rₐ to R_{d} may each independently be hydrogen, deuterium, or a substituted or unsubstituted phenyl group.

In Formula 3, one selected from among Rₐ to R_{d} is a position linked to Formula 1.

In one or more embodiments, the substituent represented by Formula 3 may be represented by any one selected from among Formula 3-1-1 to Formula 3-1-7:

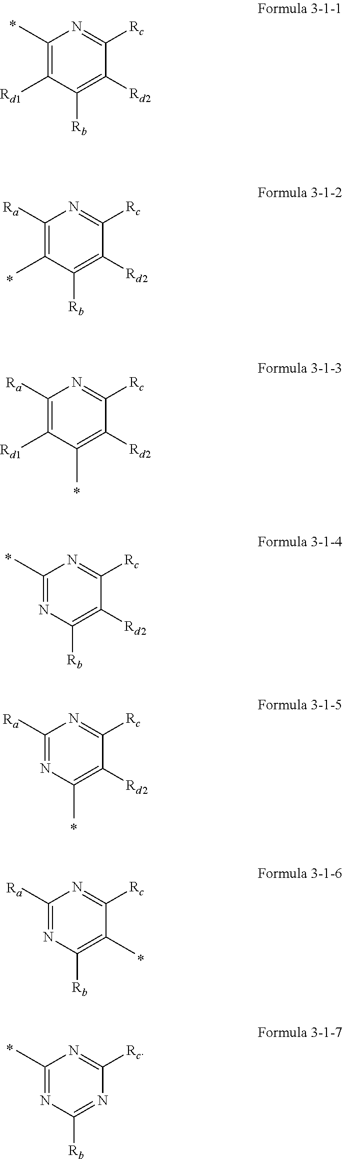

In Formula 3-1-1 to Formula 3-1-7, R_{d1} and R_{d2} may each independently be hydrogen, deuterium, a halogen, a cyano group, a nitro group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, in one or more embodiments, R_{d1} and R_{d2} may each independently be hydrogen or deuterium.

In Formula 3-1-1 to Formula 3-1-7, -* is a position linked to Formula 1.

In Formula 3-1-1 to Formula 3-1-7, the same as described in Formula 3 may be applied to Rₐ to R_{c}.

In one or more embodiments, the substituent represented by Formula 3 may be represented by any one selected from among Formula 3-2-1 to Formula 3-2-7:

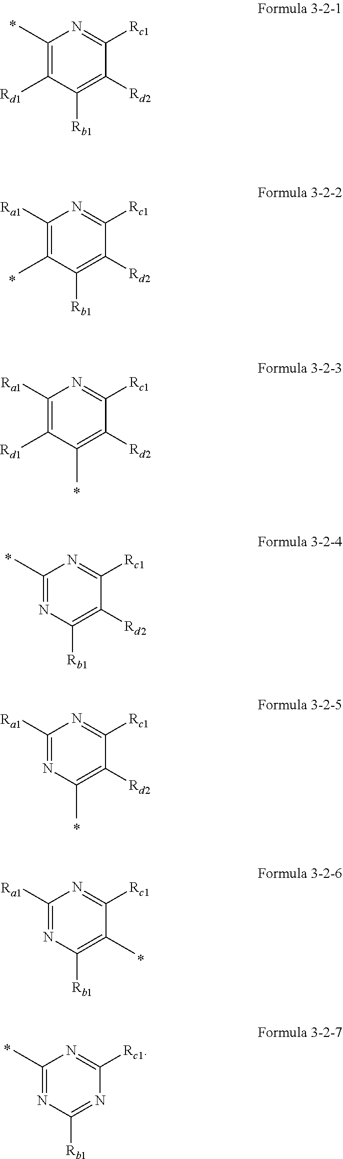

In Formula 3-2-1 to Formula 3-2-7, Rₐ₁, R_{b1}, R_{c1}, R_{d1}, and R_{d2} may each independently be hydrogen, deuterium, a halogen, a cyano group, a nitro group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, in one or more embodiments, Rₐ₁, R_{b1}, R_{c1}, R_{d1}, and R_{d2} may each independently be hydrogen, deuterium, or a substituted or unsubstituted phenyl group.

In Formula 3-2-1, Formula 3-2-4, and Formula 3-2-7, at least one of R_{b1} or R_{c1} may be a substituted or unsubstituted aryl group having 6 to 30 ring-forming carbon atoms. For example, in some embodiments, in Formula 3-2-1, Formula 3-2-4, and Formula 3-2-7, at least one of R_{b1} or R_{c1} may be a substituted or unsubstituted phenyl group.

In Formula 3-2-2 and Formula 3-2-6, at least one of Rₐ₁, R_{b1}, or R_{c1} may be a substituted or unsubstituted aryl group having 6 to 30 ring-forming carbon atoms. For example, in some embodiments, in Formula 3-2-2 and Formula 3-2-6, at least one of Rₐ₁, R_{b1}, or R_{c1} may be a substituted or unsubstituted phenyl group.

In Formula 3-2-3 and Formula 3-2-5, at least one of Rₐ₁ or R_{c1} may be a substituted or unsubstituted aryl group having 6 to 30 ring-forming carbon atoms. For example, in some embodiments, in Formula 3-2-3 and Formula 3-2-5, at least one of Rₐ₁ or R_{c1} may be a substituted or unsubstituted phenyl group.

In Formula 3-2-1 to Formula 3-2-7, -* is a position linked to Formula 1.

In one or more embodiments, the fused polycyclic compound represented by Formula 1 may be represented by Formula 1-1-1 or Formula 1-1-2:

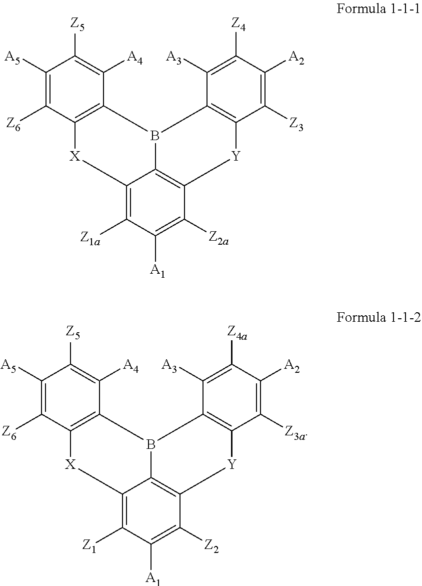

In Formula 1-1-1 to Formula 1-1-2, Z₁ₐ to Z₄ₐ may each independently be hydrogen, deuterium, a halogen, a cyano group, a nitro group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or a substituent represented by Formula 3. For example, in one or more embodiments, Z₁ₐ to Z₄ₐ may each independently be hydrogen, deuterium, a cyano group, a substituted or unsubstituted phenyl group, or a substituent represented by Formula 3.

In Formula 1-1-1, at least one of Z₁ₐ or Z₂ₐ may be a cyano group or a substituent represented by Formula 3. For example, in some embodiments, in Formula 1-1-1, at least one of Z₁ₐ or Z₂ₐ may be a cyano group or a substituent represented by Formula 3, and the other (the remainder) may be hydrogen, deuterium, a halogen, a nitro group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In some embodiments, in Formula 1-1-1, each of Z₁ₐ and Z₂ₐ may be a cyano group or a substituent represented by Formula 3.

In Formula 1-1-2, at least one of Z₃ₐ or Z₄ₐ may be a cyano group or a substituent represented by Formula 3. For example, in one or more embodiments, in Formula 1-1-2, at least one of Z₃ₐ or Z₄ₐ may be a cyano group or a substituent represented by Formula 3, and the other (the remainder) may be hydrogen, deuterium, a halogen, a nitro group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In some embodiments, in Formula 1-1-2, each of Z₃a and Z₄ₐ may be a cyano group or a substituent represented by Formula 3.

In Formula 1-1-1 and Formula 1-1-2, the same as described in Formula 1 may be applied to X, Y, A₁ to A₅, and Z₁ to Z₆.

In one or more embodiments, the fused polycyclic compound represented by Formula 1 may be represented by any one selected from among Formula 1-2-1 to Formula 1-2-3:

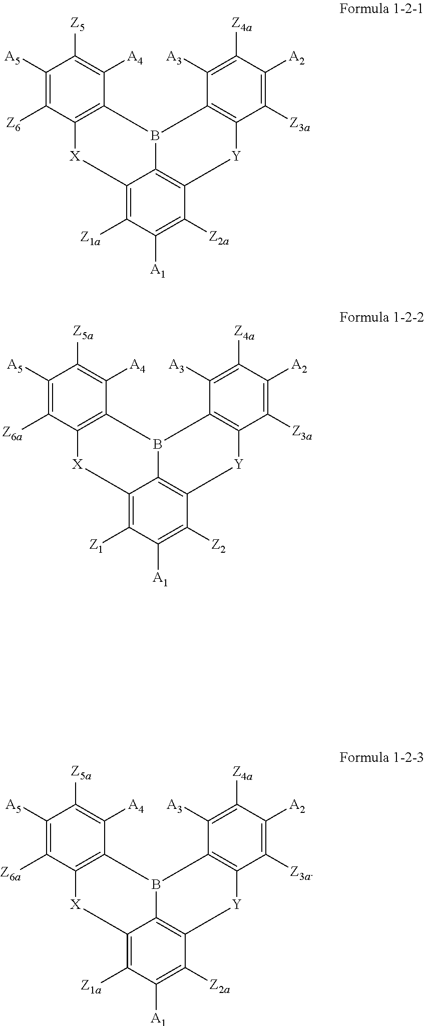

In Formula 1-2-1 to Formula 1-2-3, Z₁ₐ to Z₆ₐ may each independently be hydrogen, deuterium, a halogen, a cyano group, a nitro group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or a substituent represented by Formula 3. For example, in some embodiments, Z₁ₐ to Z₆a may each independently be hydrogen, deuterium, a cyano group, a substituted or unsubstituted phenyl group, or a substituent represented by Formula 3.

In Formula 1-2-1, at least one of Z₁a or Z₂ₐ and at least one of Z₃ₐ or Z₄ₐ may each independently be a cyano group or a substituent represented by Formula 3. For example, in some embodiments, in Formula 1-2-1, one selected from among Zia and Z₂ₐ and one selected from among Z₃a and Z₄ₐ may each independently be a cyano group or a substituent represented by Formula 3. In some embodiments, in Formula 1-2-1, Z₁ₐ, Z₂ₐ, and one selected from among Z₃a and Z₄ₐ may be a cyano group or a substituent represented by Formula 3. In some embodiments, in Formula 1-2-1, one of Z₁ₐ and Z₂ₐ, and Z₃a and Z₄ₐ may each independently be a cyano group or a substituent represented by Formula 3. In some embodiments, Z₁ₐ, Z₂ₐ, Z₃a, and Z₄a may each independently be a cyano group or a substituent represented by Formula 3.

In Formula 1-2-2, at least one of Z₃ₐ or Z₄a and at least one of Z₅a or Z₆a may each independently be a cyano group or a substituent represented by Formula 3. For example, in some embodiments, in Formula 1-2-2, one selected from among Z₃a and Z₄a and one selected from among Z₅a and Z₆a may each independently be a cyano group or a substituent represented by Formula 3. In some embodiments, in Formula 1-2-2, Z₃a, Z₄ₐ, and one selected from among Z₅a and Z₆a may be a cyano group or a substituent represented by Formula 3. In some embodiments, in Formula 1-2-2, one selected from among Z₃a and Z₄ₐ, and Z₅a and Z₆a may each independently be a cyano group or a substituent represented by Formula 3. In some embodiments, Z₃a, Z₄ₐ, Z₅a, and Z₆a may each independently be a cyano group or a substituent represented by Formula 3.

In Formula 1-2-3, at least one of Z₁ₐ or Z₂ₐ, at least one of Z₃ₐ or Z₄ₐ, and at least one of Z₅a or Z₆a may each independently be a cyano group or a substituent represented by Formula 3.

In Formula 1-2-1 to Formula 1-2-3, the same as described in Formula 1 may be applied to X, Y, A₁ to A₅, and Z₁, Z₂, Z₅, and Z₆.

In one or more embodiments, the fused polycyclic compound represented by Formula 1 may be represented by any one selected from among Formula 1-3-1 to Formula 1-3-4:

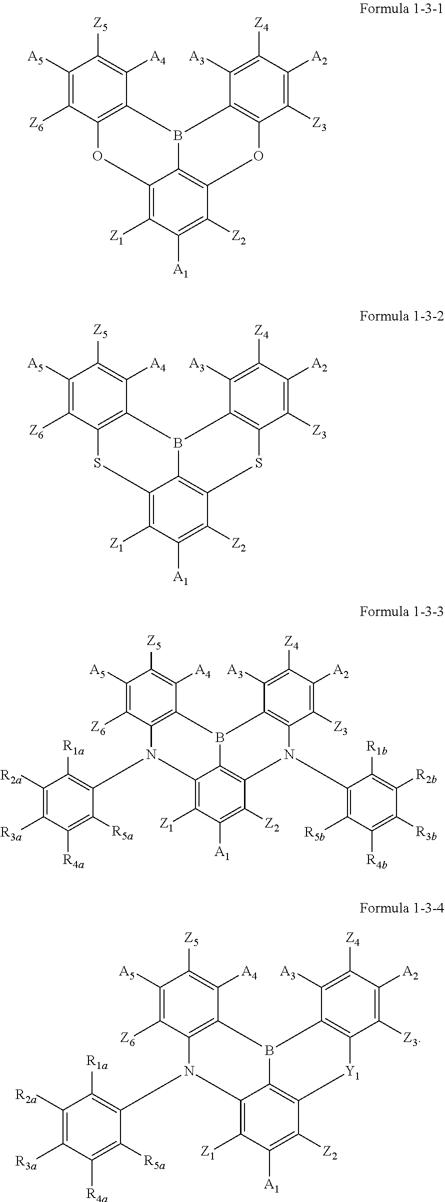

In Formula 1-3-4, Y₁ may be O or S.

In Formula 1-3-3 and Formula 1-3-4, R₁ₐ to R₅ₐ and R_{1b} to R_{5b} may each independently be hydrogen, deuterium, a halogen, a cyano group, a nitro group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, in some embodiments, R₁ₐ to R₅ₐ, and R_{1b} to R_{5b} may each independently be hydrogen, deuterium, or a substituted or unsubstituted phenyl group.

In Formula 1-3-3 and Formula 1-3-4, when each of R₁ₐ to R₅ₐ and Rib to R_{5b} is a substituted or unsubstituted heteroaryl group having 2 to 30 ring-forming carbon atoms, the embodiment in which the heteroaryl group contains nitrogen as a ring-forming atom may be excluded. For example, in one or more embodiments, in Formula 1-3-3 and Formula 1-3-4, the embodiment in which each of R₁ₐ to R₅ₐ, and R_{1b} to R_{5b} is a substituted or unsubstituted 6-membered heteroaryl group having N as a ring-forming atom may be excluded.

In Formula 1-3-3, when any one selected from among Z₄ and Z₅ is a cyano group or a substituted or unsubstituted pyridine group, at least one selected from among R₁ₐ to R₅ₐ and at least one selected from among R_{1b} to R_{5b} may each independently be a substituted or unsubstituted aryl group having 6 to 30 ring-forming carbon atoms, or a substituted or unsubstituted heteroaryl group having 2 to 30 ring-forming carbon atoms. In one or more embodiments, in Formula 1-3-3, when any one selected from among Z₄ and Z₅ is a cyano group or a substituted or unsubstituted pyridine group, at least one selected from among R₁ₐ to R₅ₐ and at least one selected from among R_{1b} to R_{5b} may each independently be a substituted or unsubstituted aryl group having 6 to 30 ring-forming carbon atoms. For example, in some embodiments, in Formula 1-3-3, when any one selected from among Z₄ and Z₅ is a cyano group or a substituted or unsubstituted pyridine group, at least one selected from among R₁ₐ to R₅ₐ and at least one selected from among R_{1b} to R_{5b} may each independently be a substituted or unsubstituted phenyl group.

In Formula 1-3-4, when any one selected from among Z₄ and Z₅ is a cyano group or a substituted or unsubstituted pyridine group, at least one selected from among R₁ₐ to R₅ₐ may each independently be a substituted or unsubstituted aryl group having 6 to 30 ring-forming carbon atoms, or a substituted or unsubstituted heteroaryl group having 2 to 30 ring-forming carbon atoms. In one or more embodiments, in Formula 1-3-4, when any one selected from among Z₄ and Z₅ is a cyano group or a substituted or unsubstituted pyridine group, at least one selected from among R₁ₐ to R₅ₐ may be a substituted or unsubstituted aryl group having 6 to 30 ring-forming carbon atoms. For example, in some embodiments, in Formula 1-3-4, when any one selected from among Z₄ and Z₅ is a cyano group or a substituted or unsubstituted pyridine group, at least one selected from among R₁ₐ to R₅ₐ may be a substituted or unsubstituted phenyl group.

In Formula 1-3-1 to Formula 1-3-4, the same as described in Formula 1 may be applied to A₁ to A₅, and Z₁ to Z₆.

In one or more embodiments, the fused polycyclic compound represented by Formula 1 may be represented by Formula 1-4:

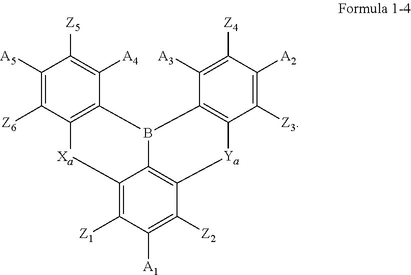

In Formula 1-4, Xₐ and Yₐ may each independently be represented by any one selected from among Formula 2-1 to Formula 2-7.

In one or more embodiments, in Formula 1-4, when any one selected from among Z₄ and Z₅ is a cyano group or a substituted or unsubstituted pyridine group, Xₐ and Yₐ may each independently be represented by any one selected from among Formula 2-2 to Formula 2-7:

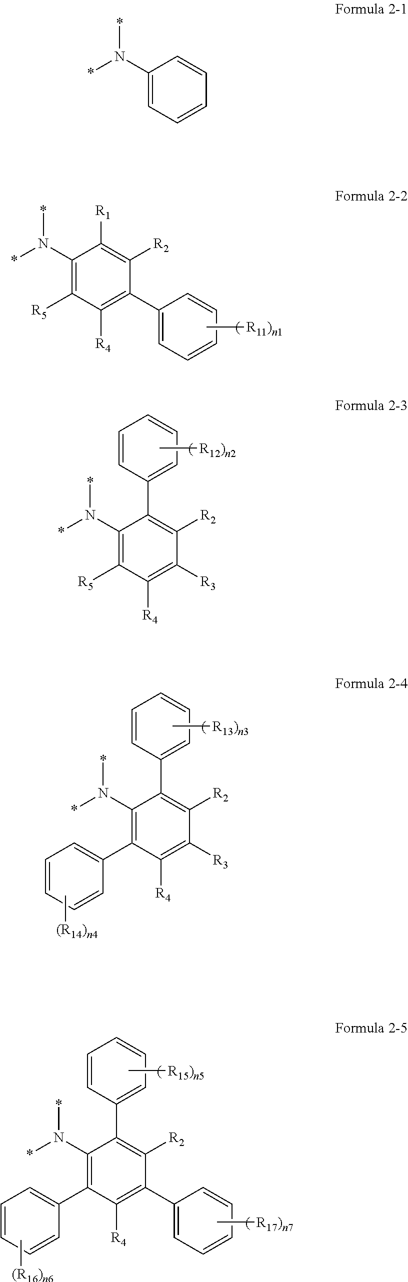

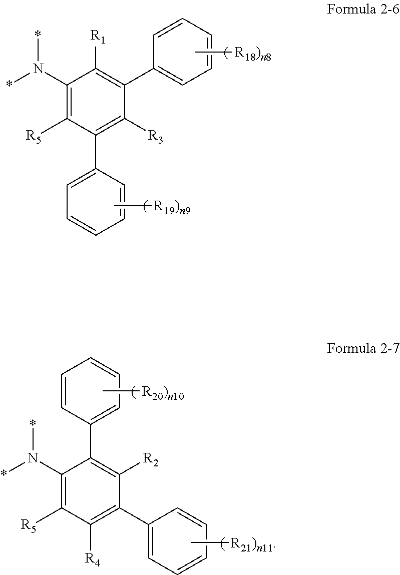

In Formula 2-2 to Formula 2-7, R₁₁ to R₂₁ may each independently be hydrogen, deuterium, a halogen, a cyano group, a nitro group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, in some embodiments, R₁₁ to R₂₁ may each independently be hydrogen or deuterium.

In Formula 2-2 to Formula 2-7, n1 to n11 may each independently be an integer of 0 to 5. In Formula 2-2 to Formula 2-7, when each of n1 to n11 is 0, the fused polycyclic compound of an embodiment may not be substituted with any of R₁₁ to R₂₁.

In Formula 2-2 to Formula 2-7, the embodiment in which each of n1 to n11 is 5 and R₁₁'s to R₂₁'s are each hydrogen may be the same as the embodiment in which each of n1 to n11 is 0 in Formula 2-2 and Formula 2-7. When each of n1 to n11 is an integer of 2 or more, a plurality of R₁₁'s to R₂₁'s may each be the same or at least one selected from among the plurality of R₁₁'s to R₂₁'s may be different from the others.

In Formula 2-2 to Formula 2-7, the same as described in Formula 2 may be applied to R₁ to R₅.

In Formula 1-4, the same as described in Formula 1 may be applied to A₁ to A₅, and Z₁ to Z₆.

In one or more embodiments, the fused polycyclic compound represented by Formula 1 may be represented by any one selected from among Formula 1-5-1 to Formula 1-5-7:

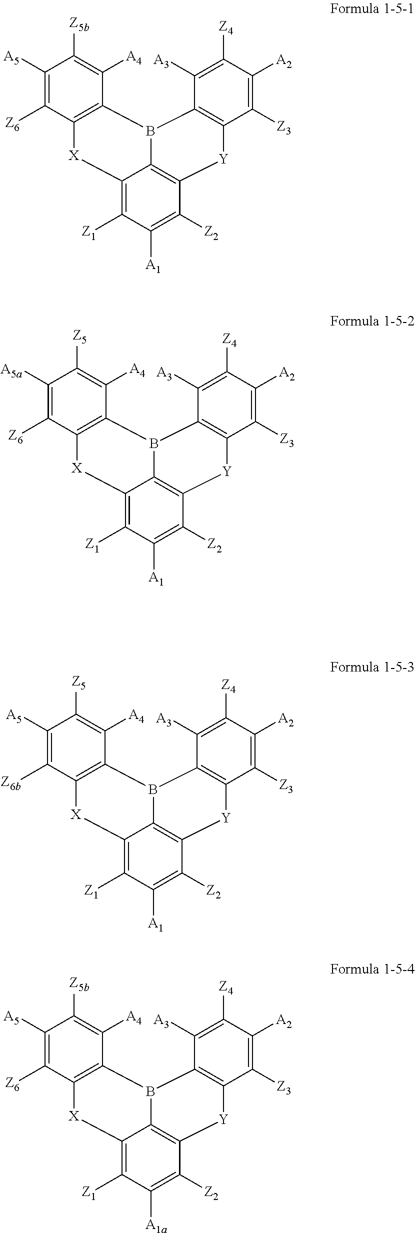

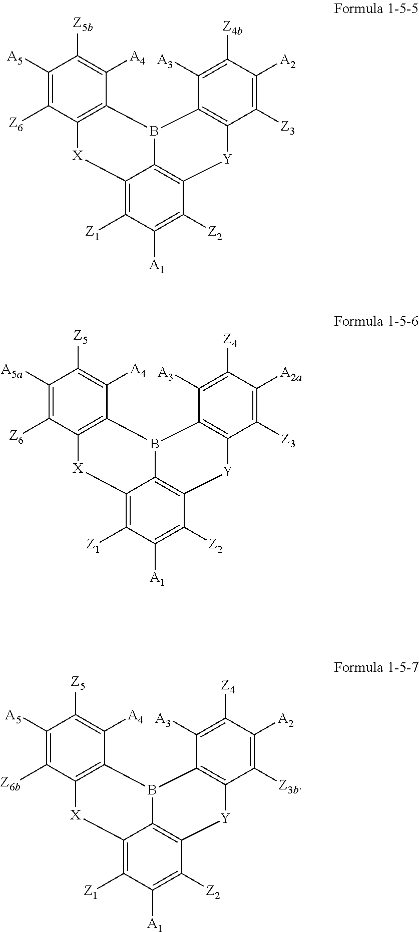

In Formula 1-5-1 to Formula 1-5-7, Z_{3b} to Z₆b, A₂ₐ, and A₅ₐ may each independently be a substituted or unsubstituted alkyl group having 1 to 10 carbon atoms, or represented by Formula A-1 or Formula A-2. For example, in one or more embodiments, Z_{3b} to Z_{6b}, A₂ₐ, and A₅ₐ may each independently be a substituted or unsubstituted t-butyl group, or represented by Formula A-1 or Formula A-2.

In Formula 1-5-4, A₁ₐ may be an unsubstituted alkyl group having 1 to 10 carbon atoms, or represented by Formula A-1 or Formula A-2. For example, in one or more embodiments, A₁ₐ may be an unsubstituted methyl group, an unsubstituted t-butyl group, or represented by Formula A-1 or Formula A-2.

In Formula 1-5-1 and Formula 1-5-4, at least one selected from among Z₁ to Z₄ and Z₆ may be a cyano group or a substituent represented by Formula 3.

In Formula 1-5-2 and Formula 1-5-6, at least one selected from among Z₁ to Z₆ may be a cyano group or a substituent represented by Formula 3.

In Formula 1-5-3, at least one selected from among Z₁ to Z₅ may be a cyano group or a substituent represented by Formula 3.

In Formula 1-5-5, at least one selected from among Z₁ to Z₃ and Z₆ may be a cyano group or a substituent represented by Formula 3.

In Formula 1-5-7, at least one selected from among Z₁, Z₂, Z₄ and Z₅ may be a cyano group or a substituent represented by Formula 3.

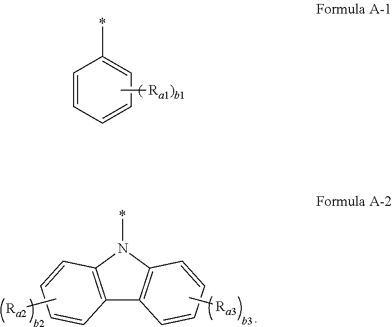

In Formula A-1 and Formula A-2, Rₐ₁ to Rₐ₃ may each independently be hydrogen, deuterium, a halogen, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, in some embodiments, Rₐ₁ to Rₐ₃ may each independently be hydrogen, a deuterium, a cyano group, a substituted or unsubstituted t-butyl group, or a substituted or unsubstituted phenyl group.

In Formula A-1, b1 is an integer of 0 to 5. In Formula A-1, when b1 is 0, the fused polycyclic compound of an embodiment may not be substituted with Rₐ₁. In Formula A-1, the embodiment in which b1 is 5 and Rₐ₁'s are all hydrogen may be the same as the embodiment in which b1 is 0 in Formula A-1. When b1 is an integer of 2 or greater, a plurality of Rₐ₁'s may be all the same or at least one selected from among the plurality of Rₐ₁'s may be different from the others.

In Formula A-2, b2 and b3 may each independently be an integer of 0 to 4. In Formula A-2, when each of b2 and b3 is 0, the fused polycyclic compound of an embodiment may not be substituted with each of Rₐ₂ and Rₐ₃. In Formula A-2, the embodiment in which each of b2 and b3 is 4 and Rₐ₂'s and Rₐ₃'s are each hydrogen may be the same as the embodiment in which each of b2 and b3 is 0 in Formula A-2. When each of b2 and b3 is an integer of 2 or more, a plurality of Rₐ₂'s and Rₐ₃'s each may be the same or at least one selected from among the plurality of Rₐ₂'s and Rₐ₃'s may be different from the others.

In Formula A-1 and Formula A-2, -* is a position linked to Formula 1-5-1 to Formula 1-5-7.

In Formula 1-5-1 to Formula 1-5-7, the same as described in Formula 1 may be applied to X, Y, A₁ to A₅, and Z₁ to Z₆.

In one or more embodiments, the fused polycyclic compound represented by Formula 1 may be represented by any one selected from among Formula 1-6-1 to Formula 1-6-8:

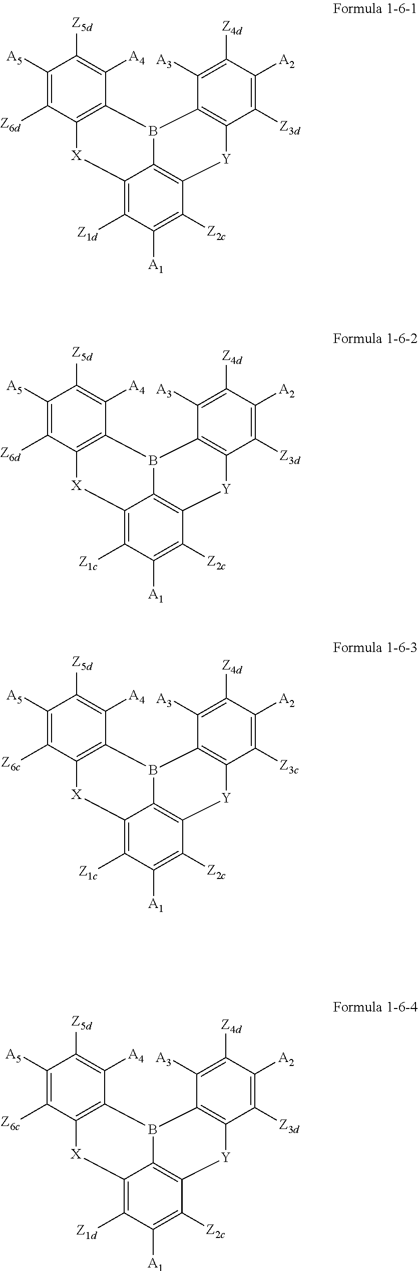

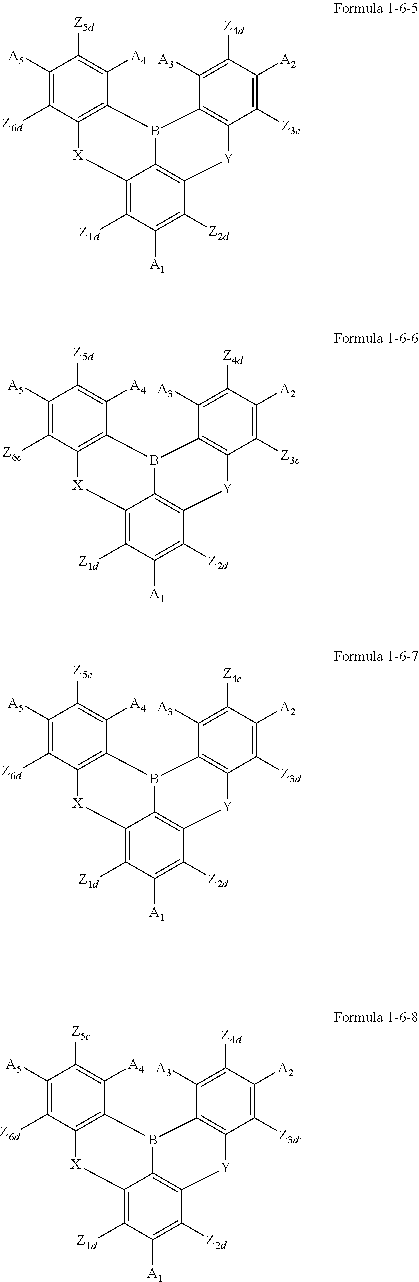

In Formula 1-6-1 to Formula 1-6-8, Z_{1d} to Z_{6d} may each independently be hydrogen, deuterium, a halogen, a cyano group, a nitro group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or a substituent represented by Formula 3. In one or more embodiments, Z_{1d} to Z_{6d} may each independently be hydrogen, deuterium, a cyano group, a substituted or unsubstituted phenyl group, or a substituent represented by Formula 3.

In Formula 1-6-1 to Formula 1-6-8, Z₁ₑ to Z₆ₑ may each independently be a cyano group or a substituent represented by Formula 3.

In Formula 1-6-1 to Formula 1-6-8, the same as described in Formula 1 may be applied to X, Y, and A₁ to A₅.

In one or more embodiments, the fused polycyclic compound represented by Formula 1 may include at least one deuterium atom as a substituent.

The fused polycyclic compound of an embodiment may be any one selected from among compounds represented in Compound Group 1. The light emitting device ED of an embodiment may include at least one fused polycyclic compound selected from among the compounds represented in Compound Group 1 in the emission layer EML.

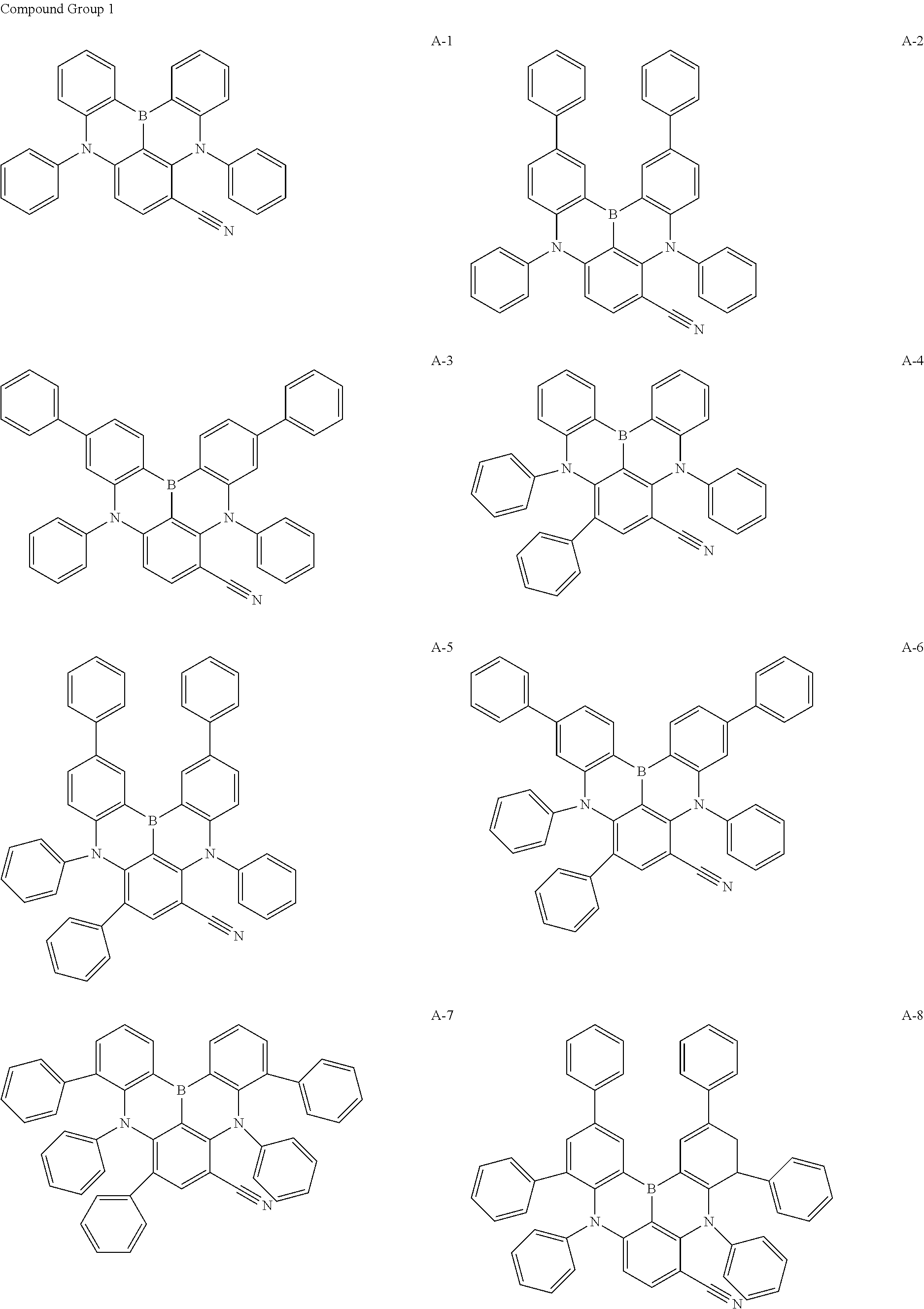

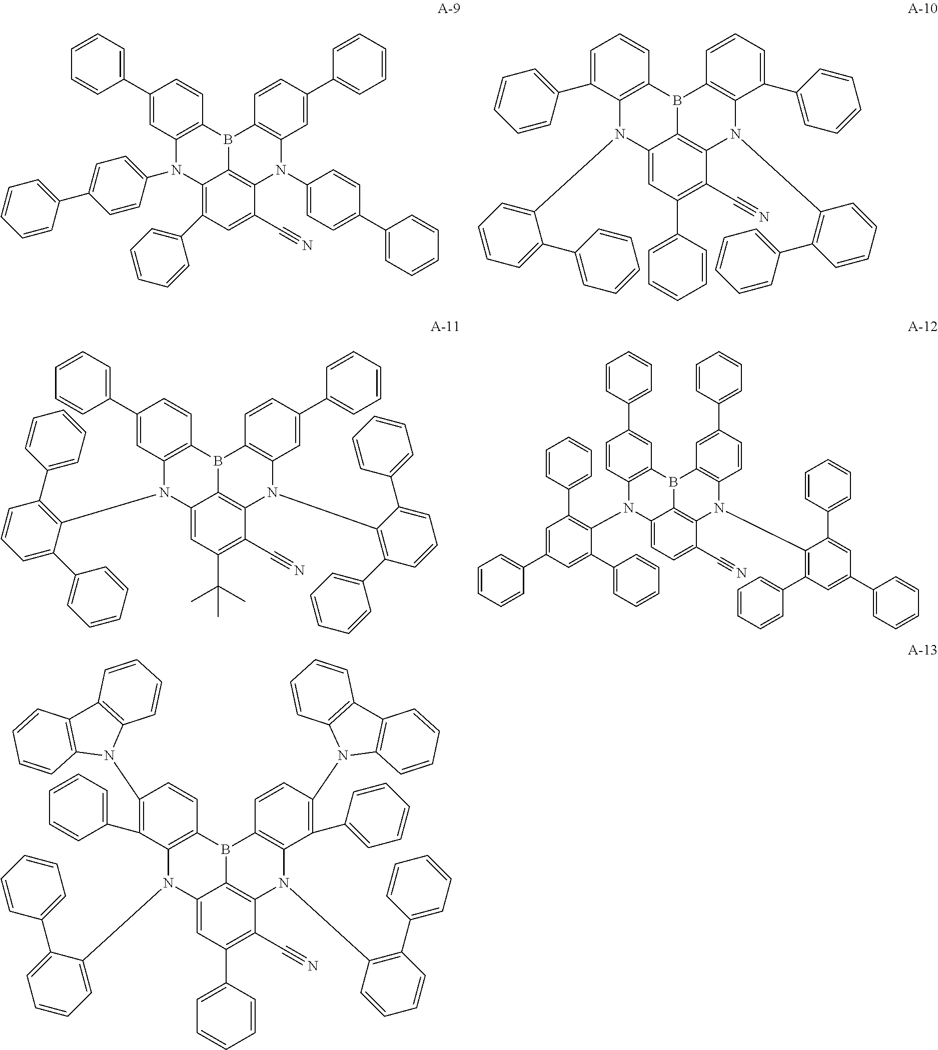

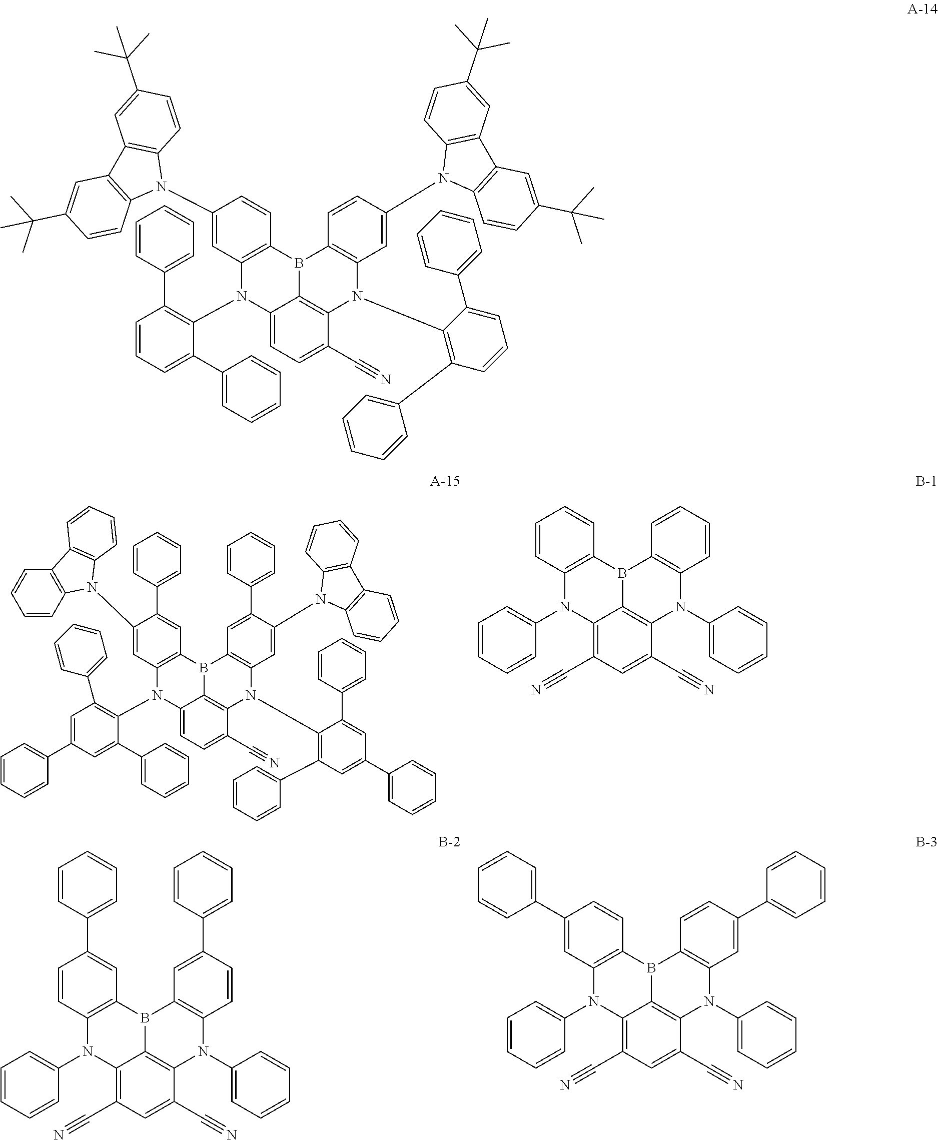

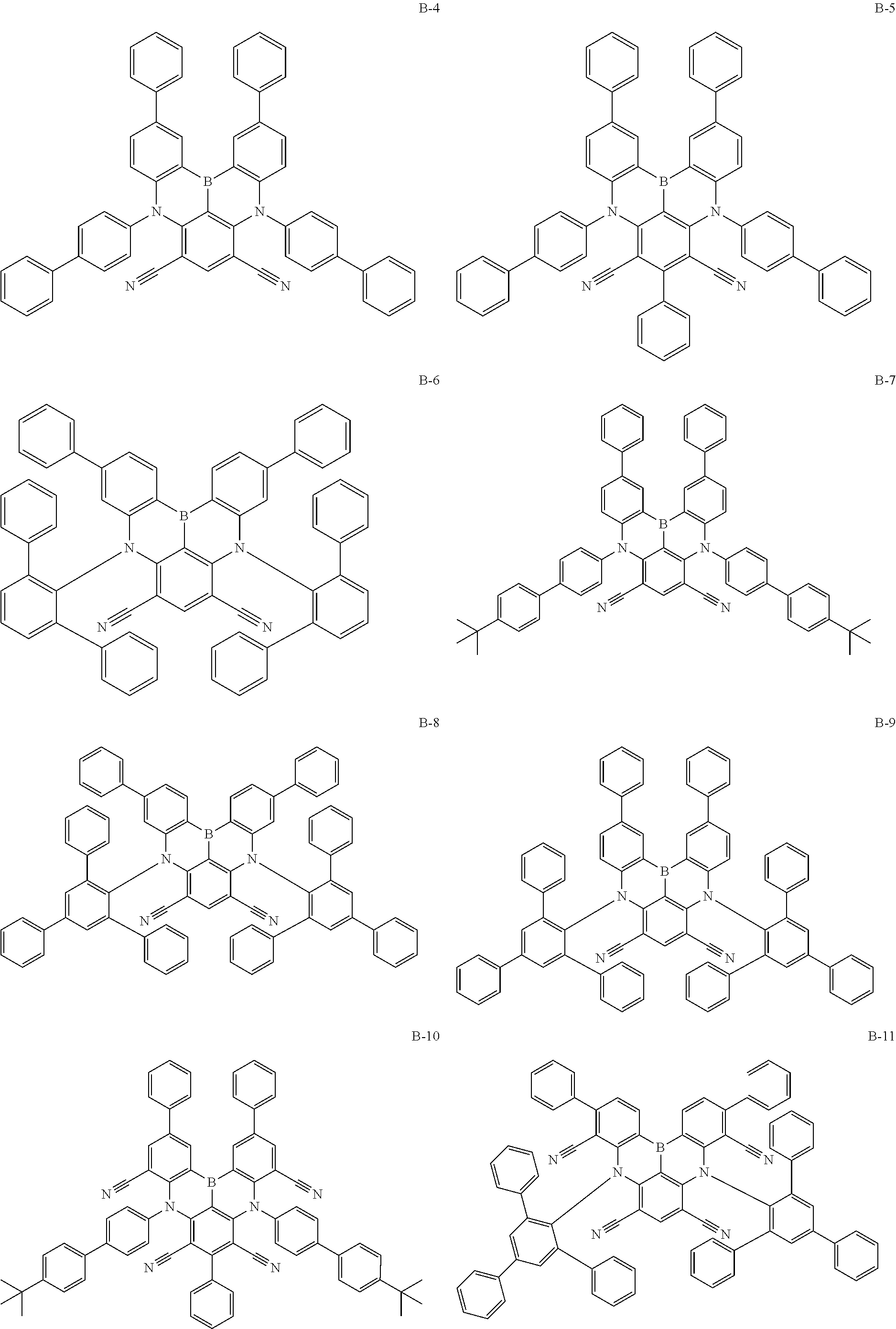

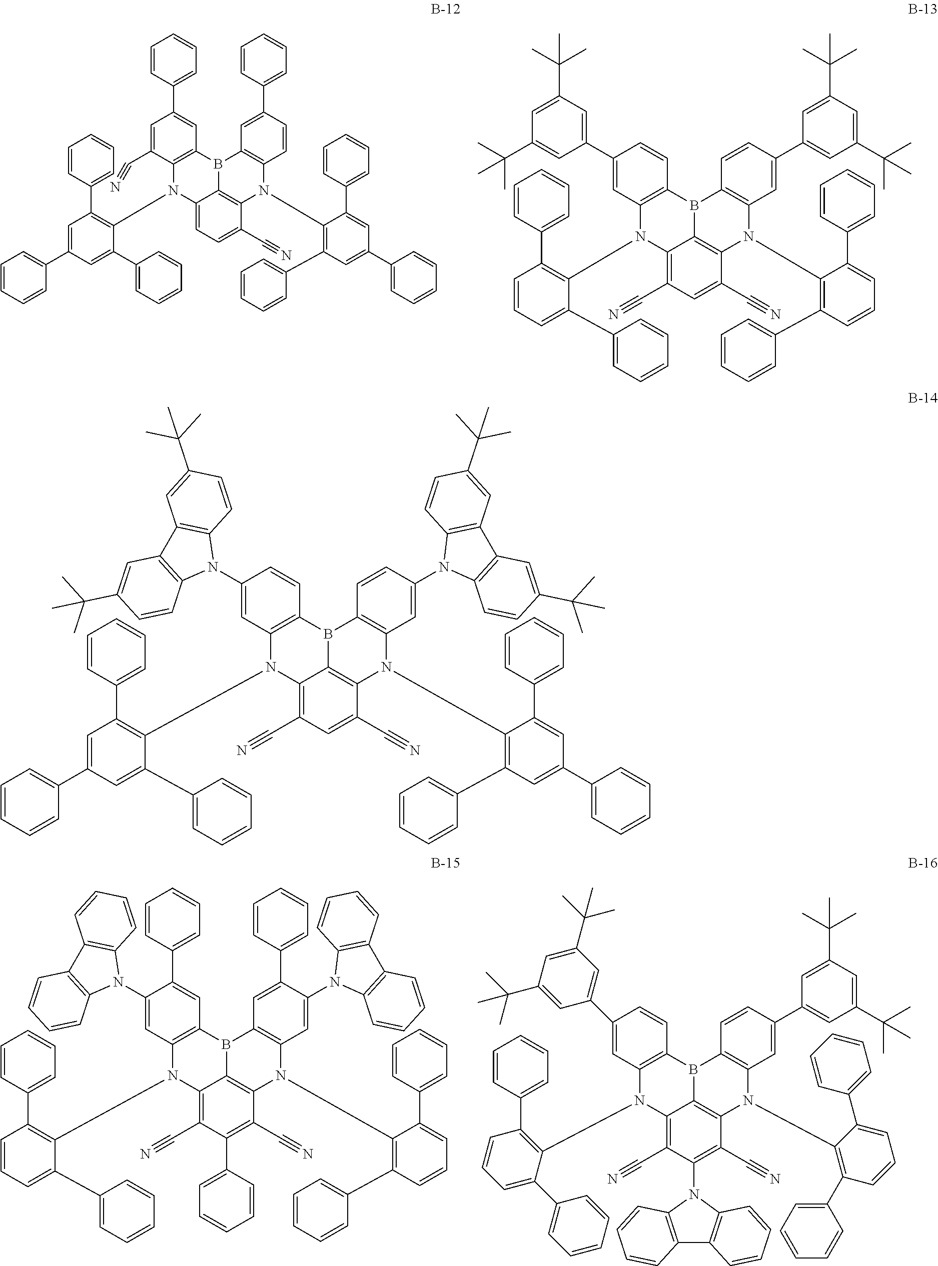

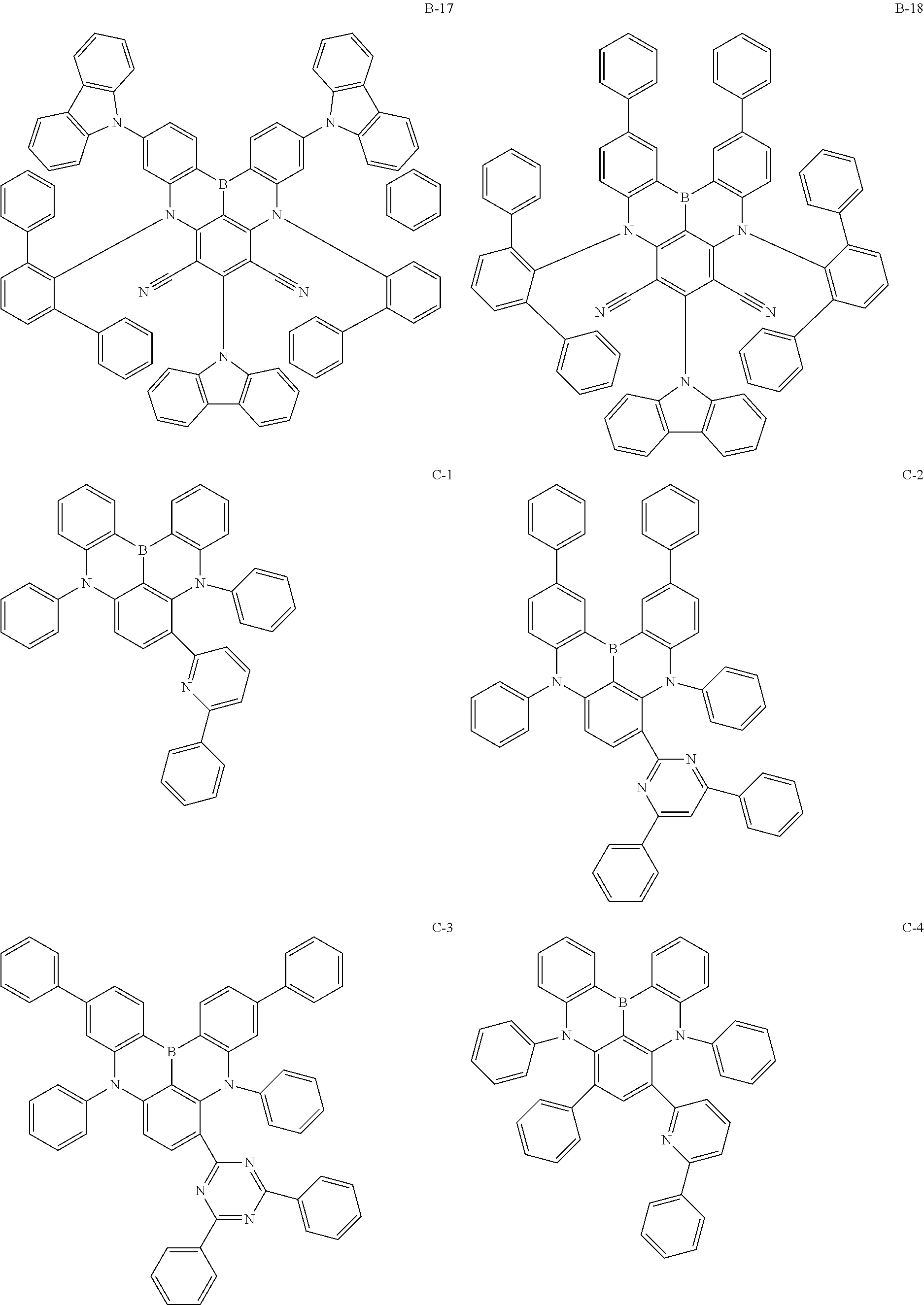

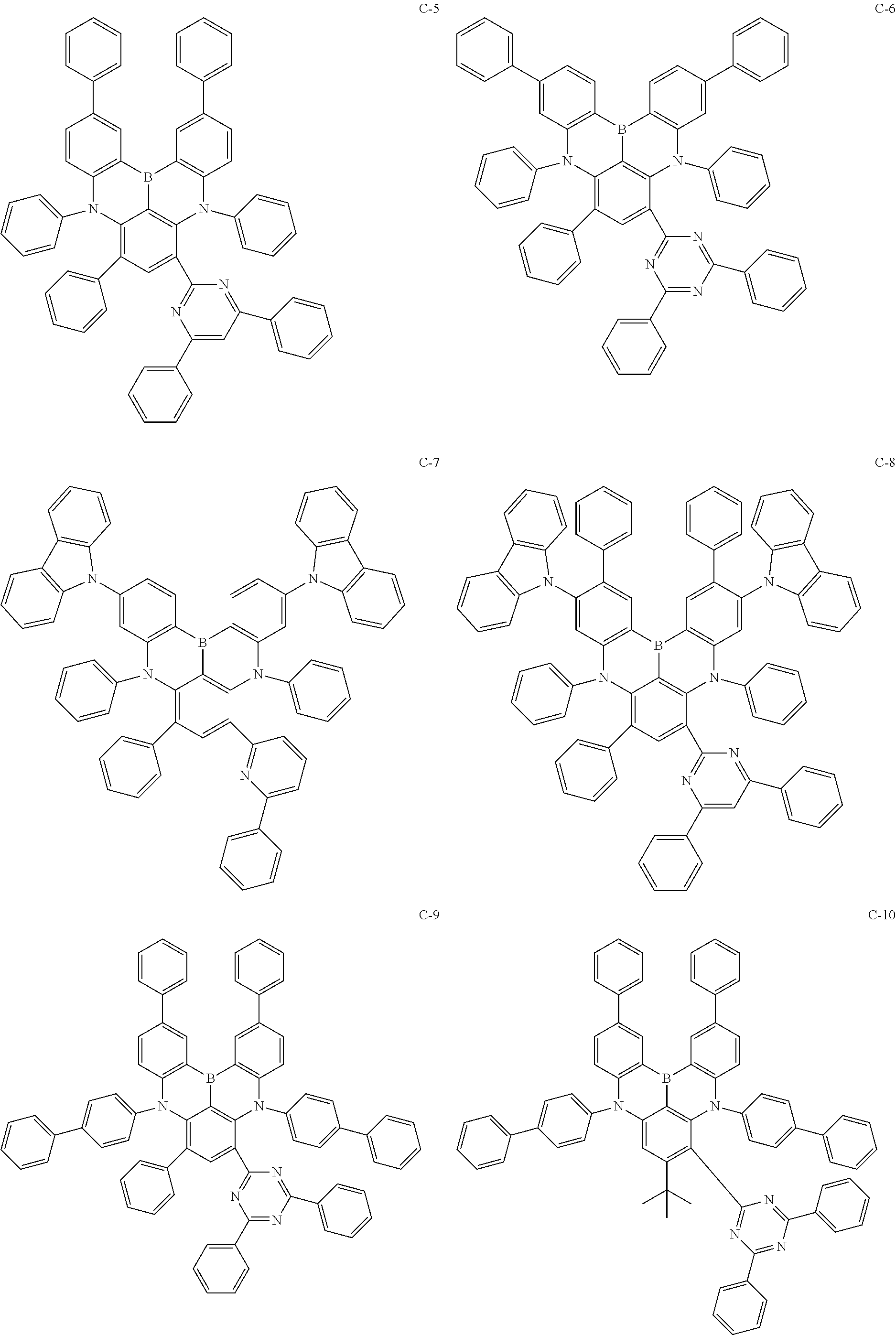

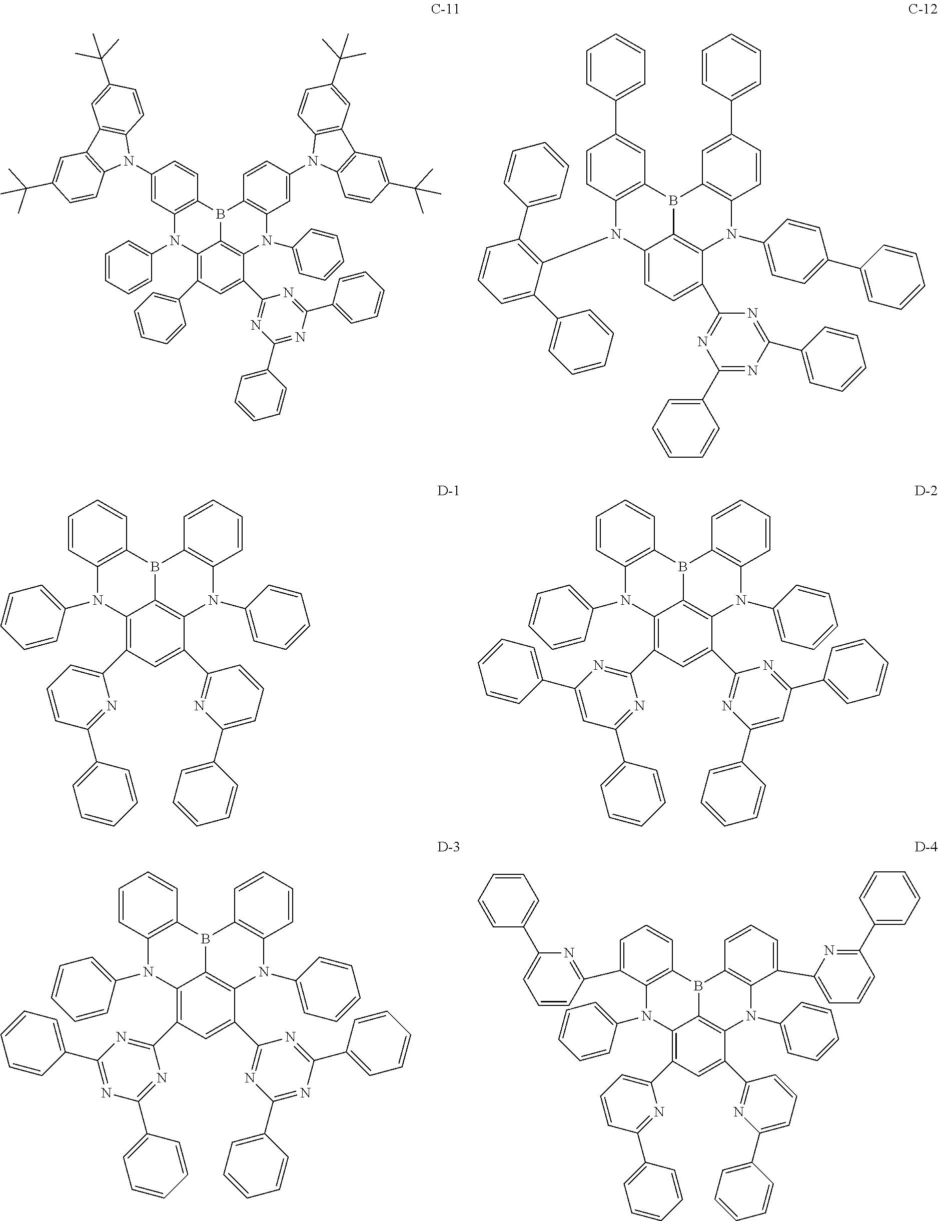

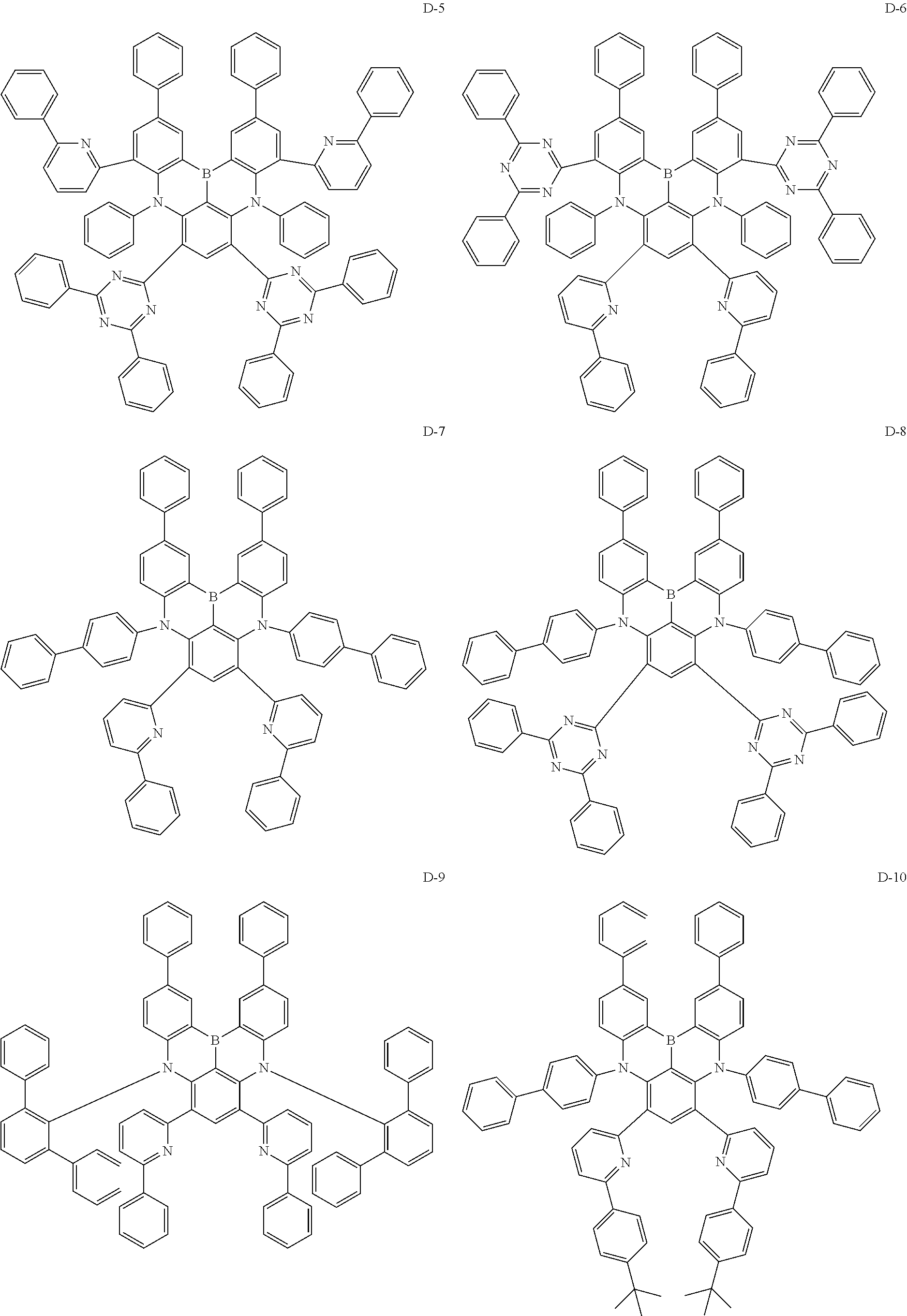

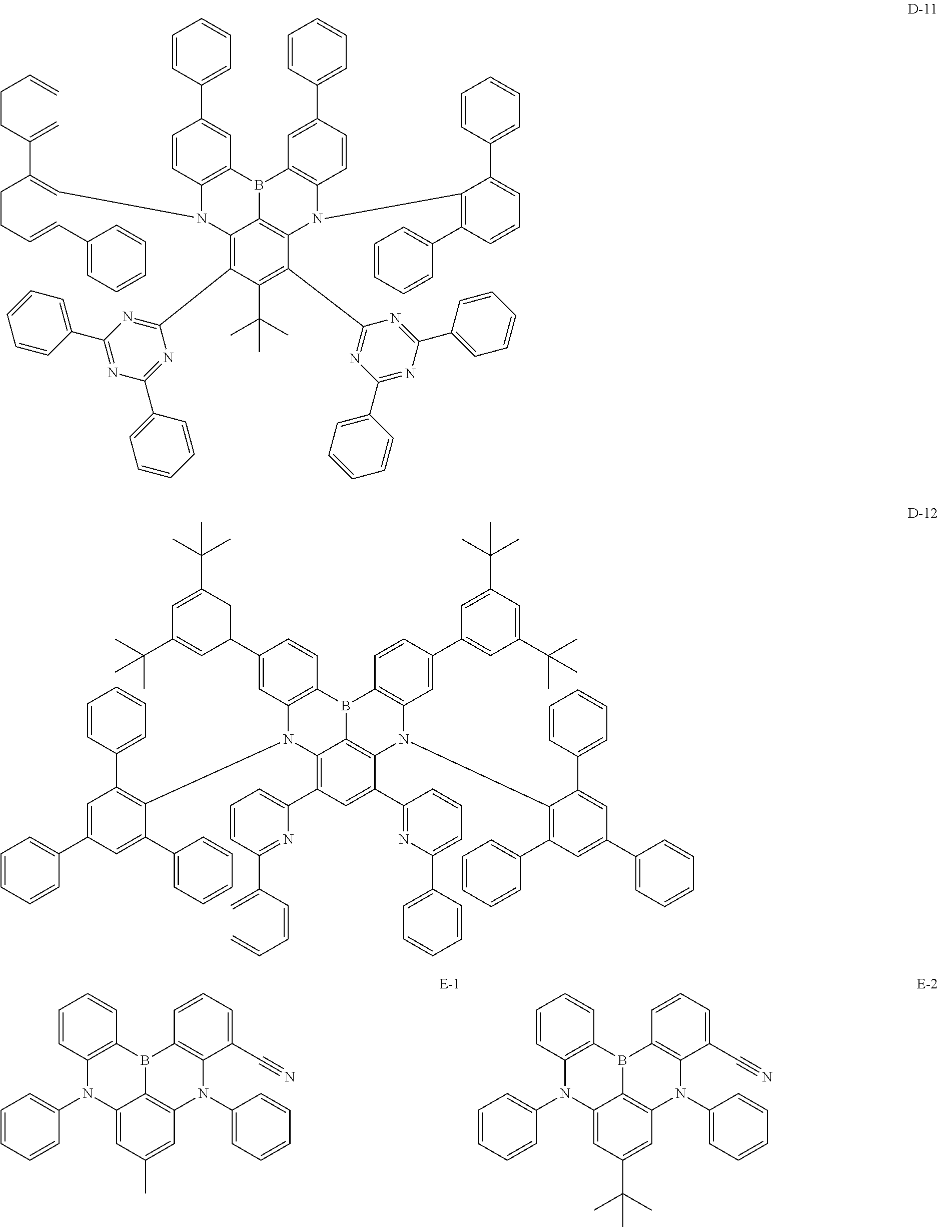

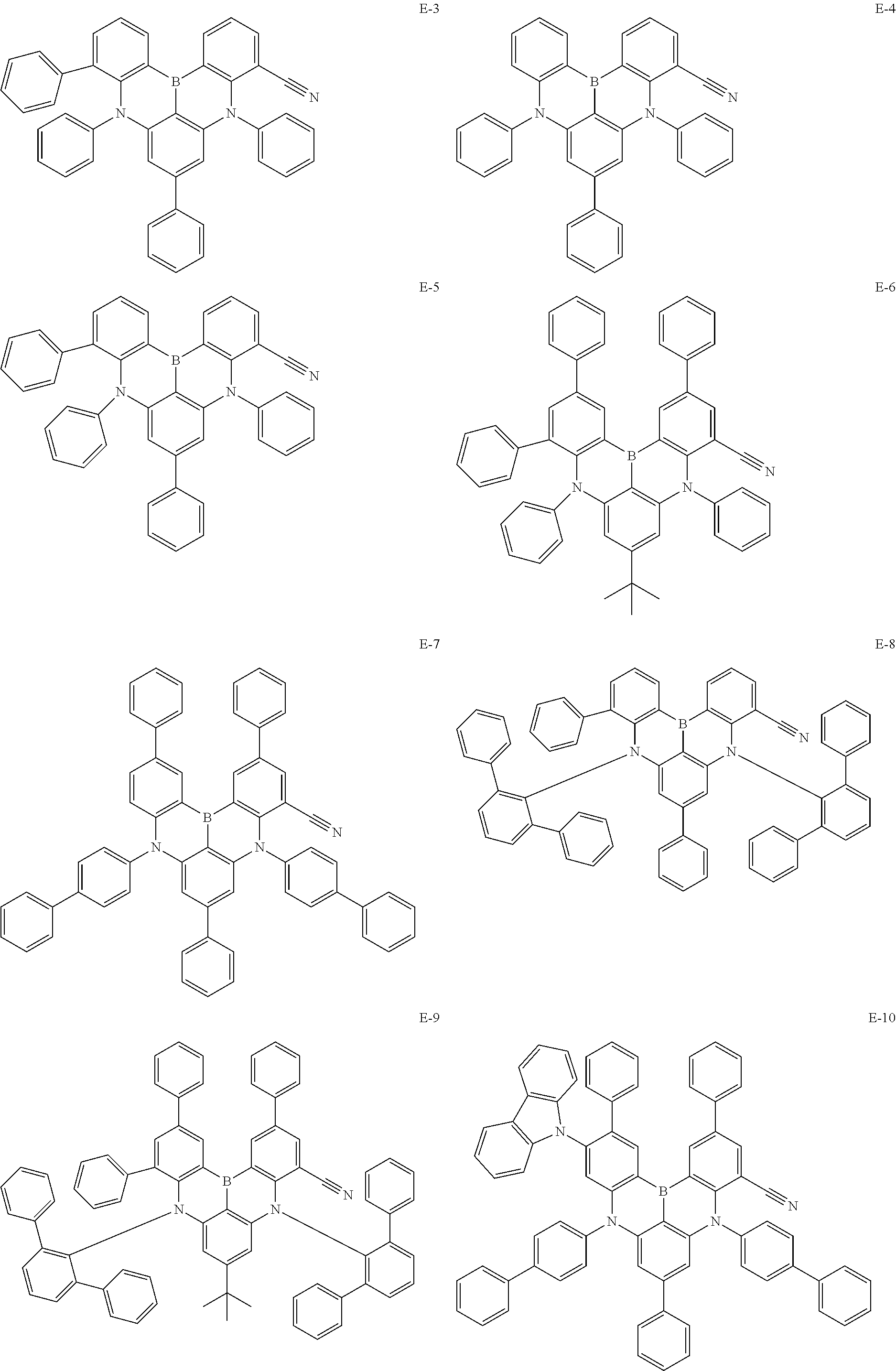

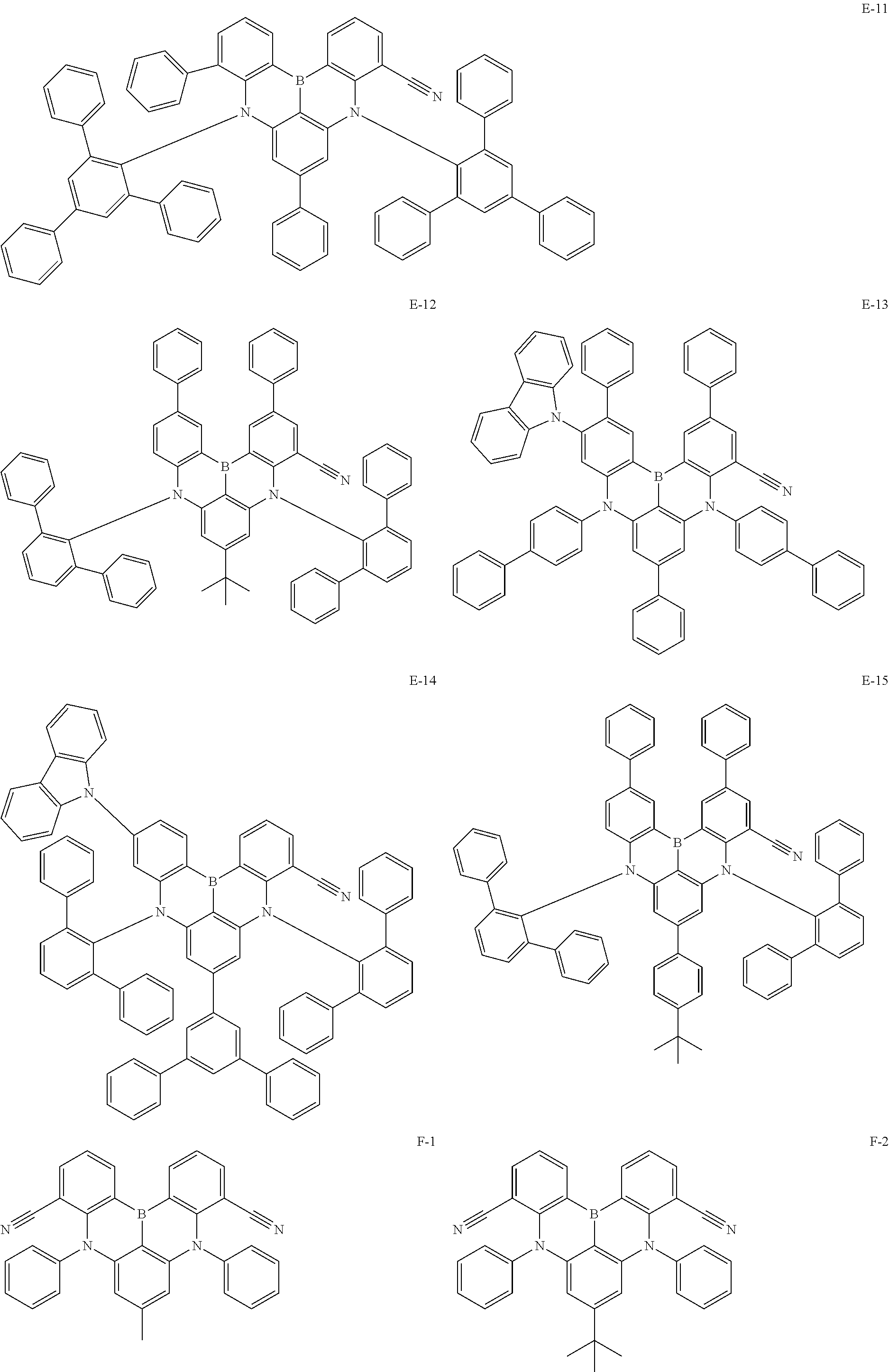

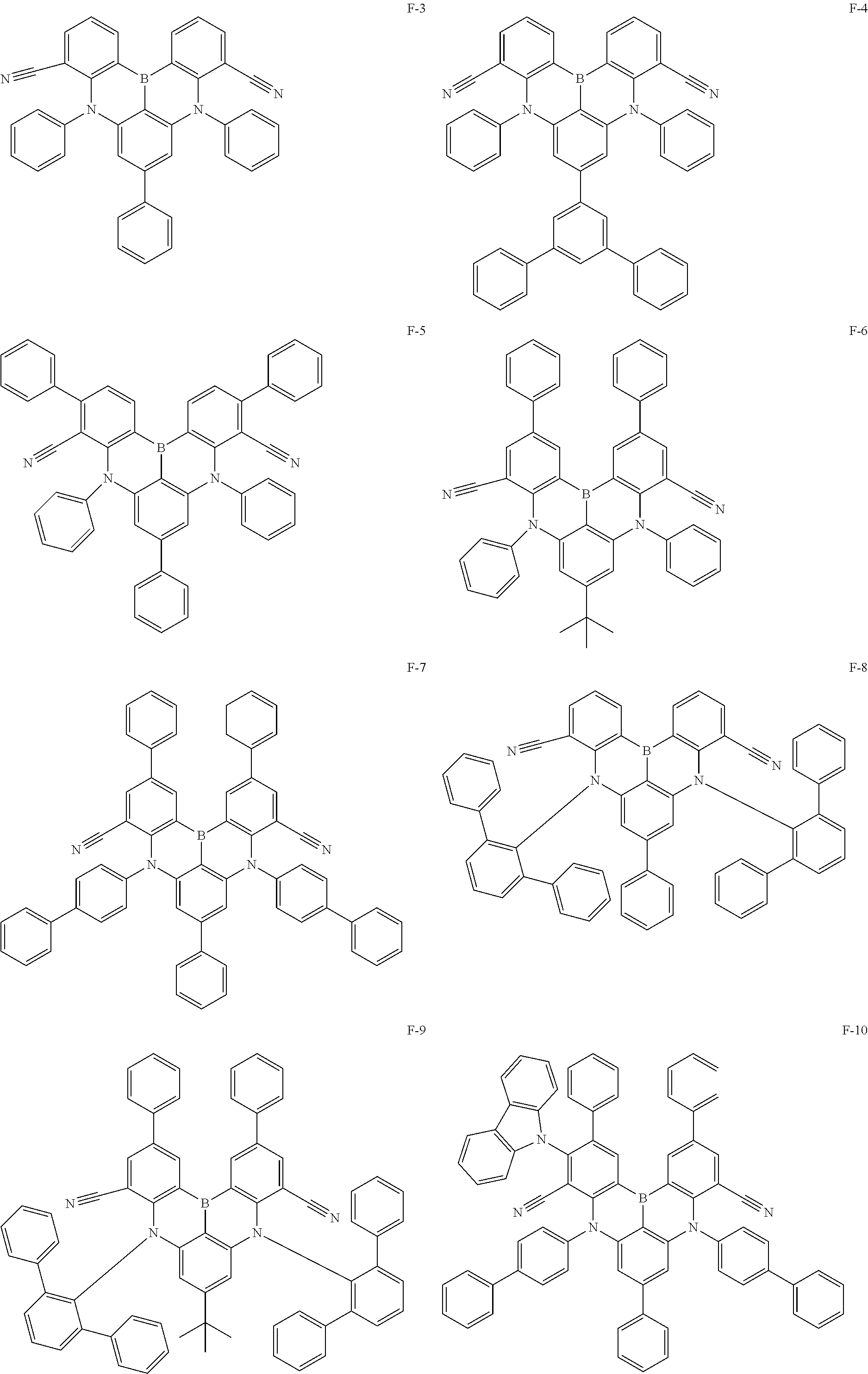

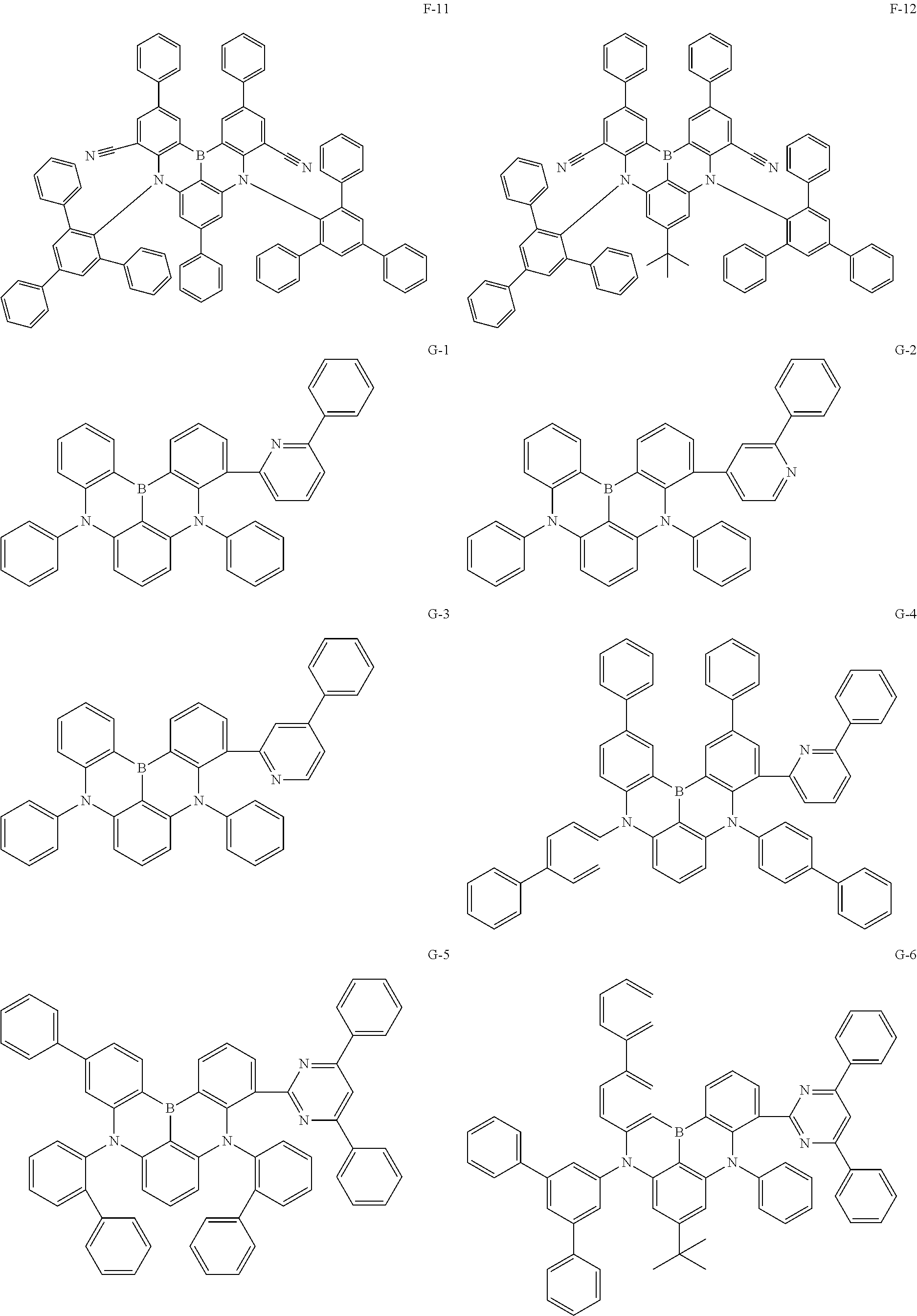

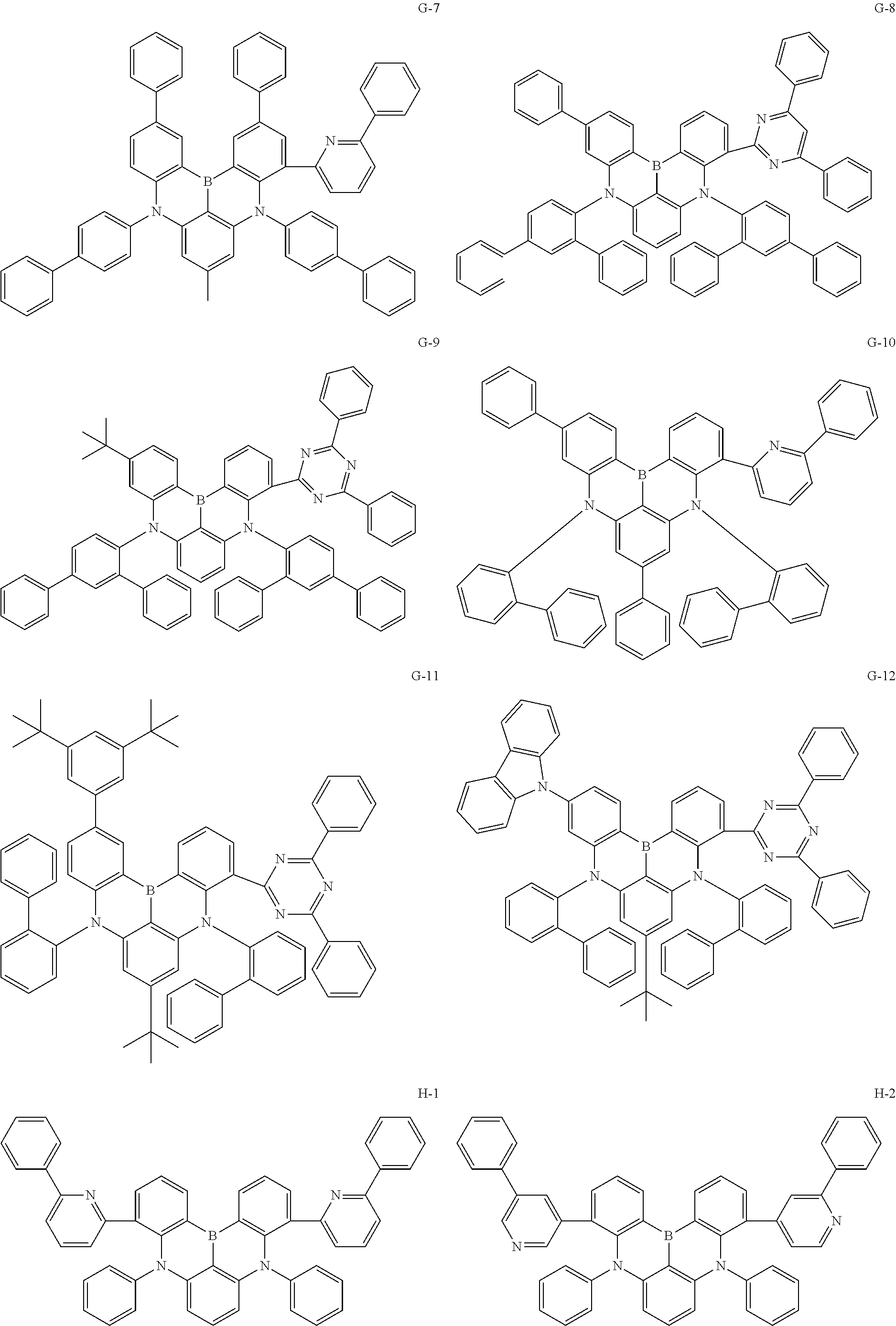

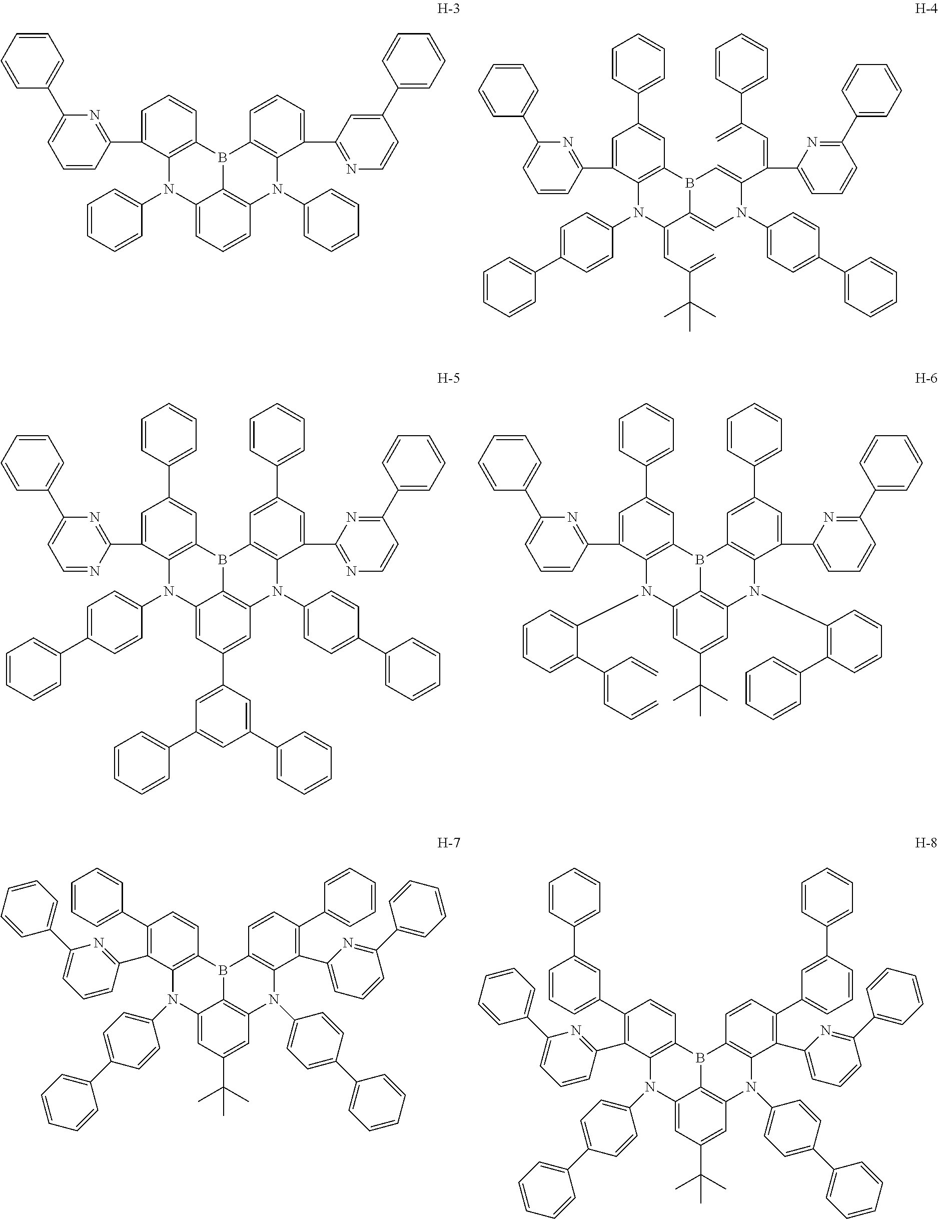

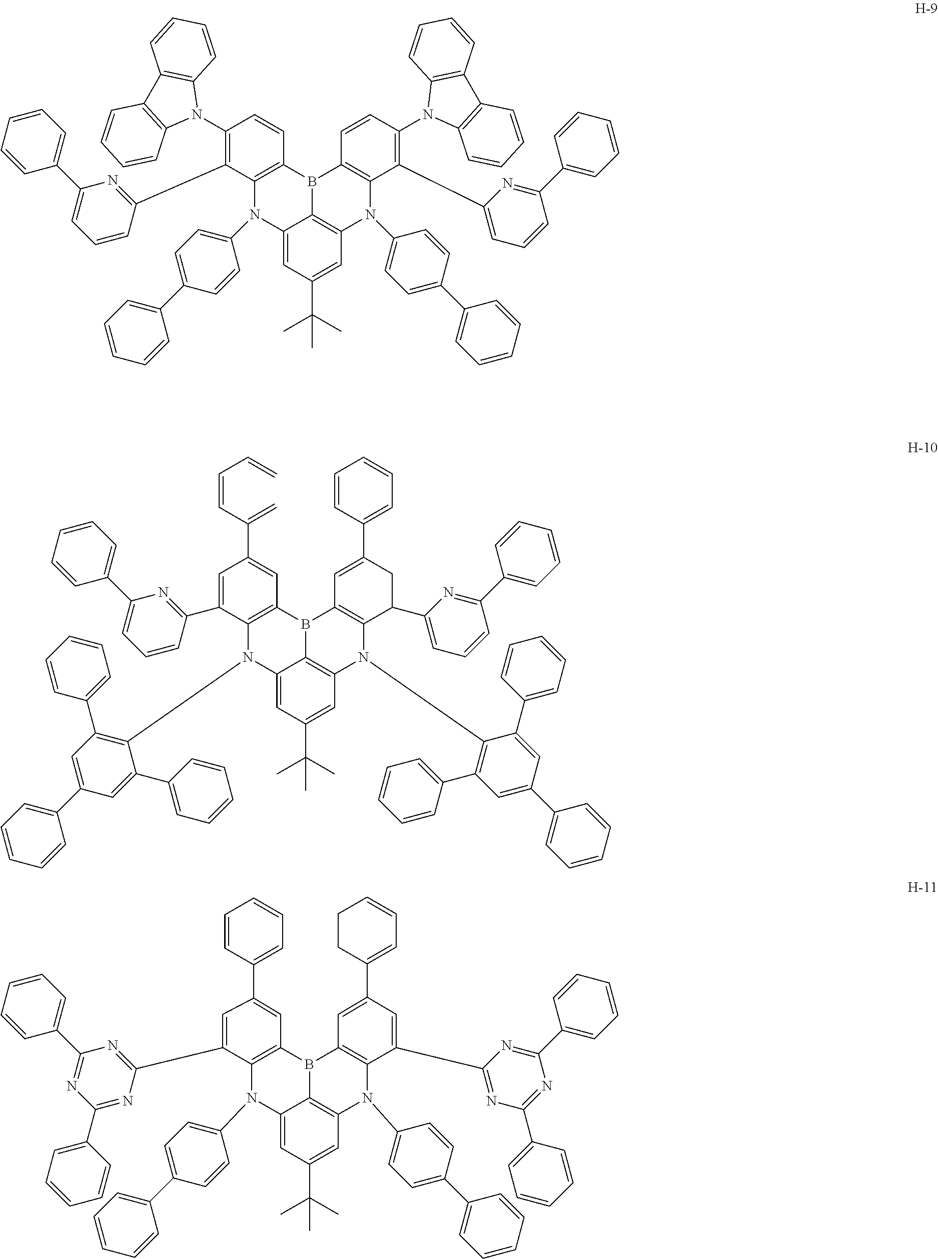

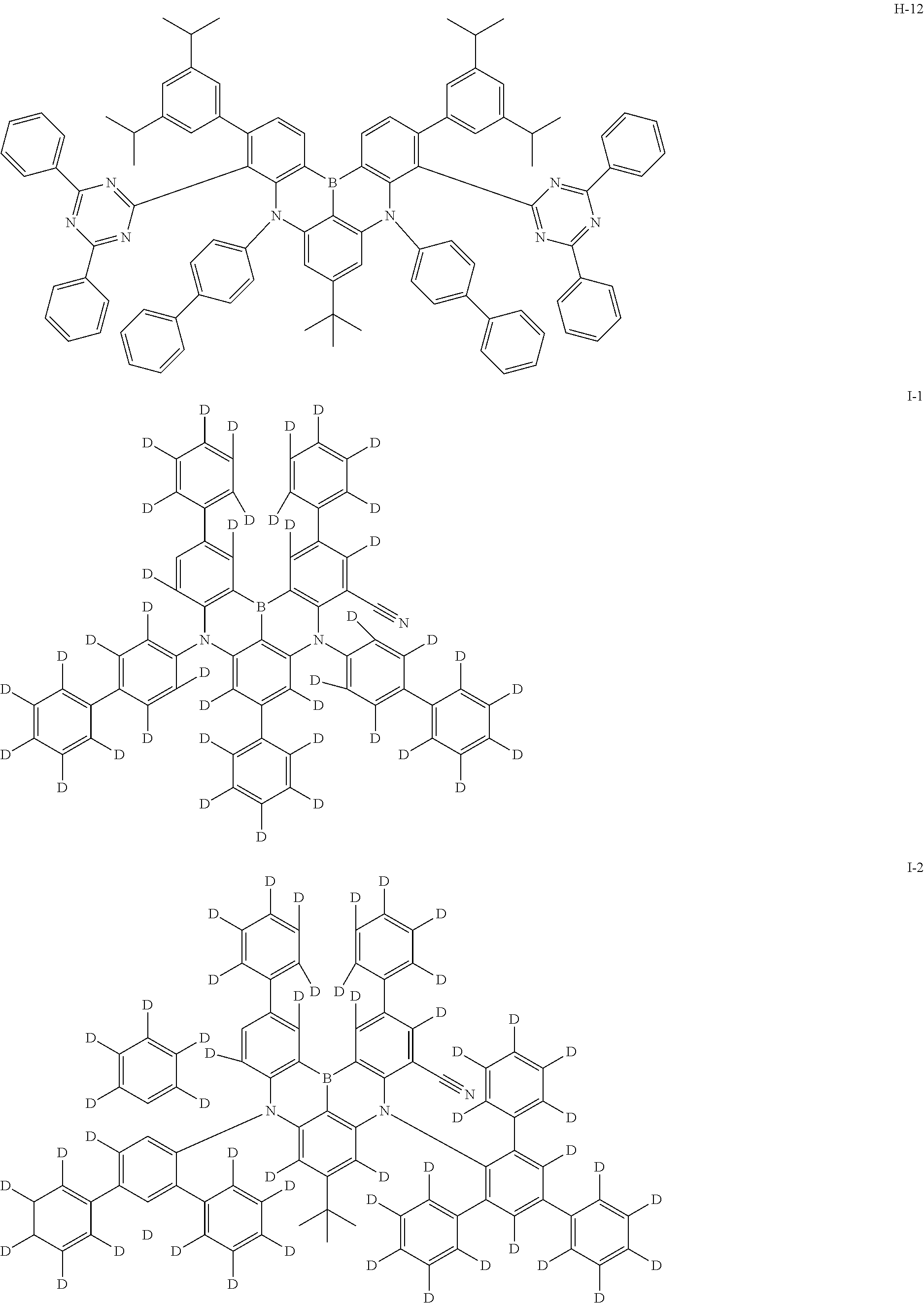

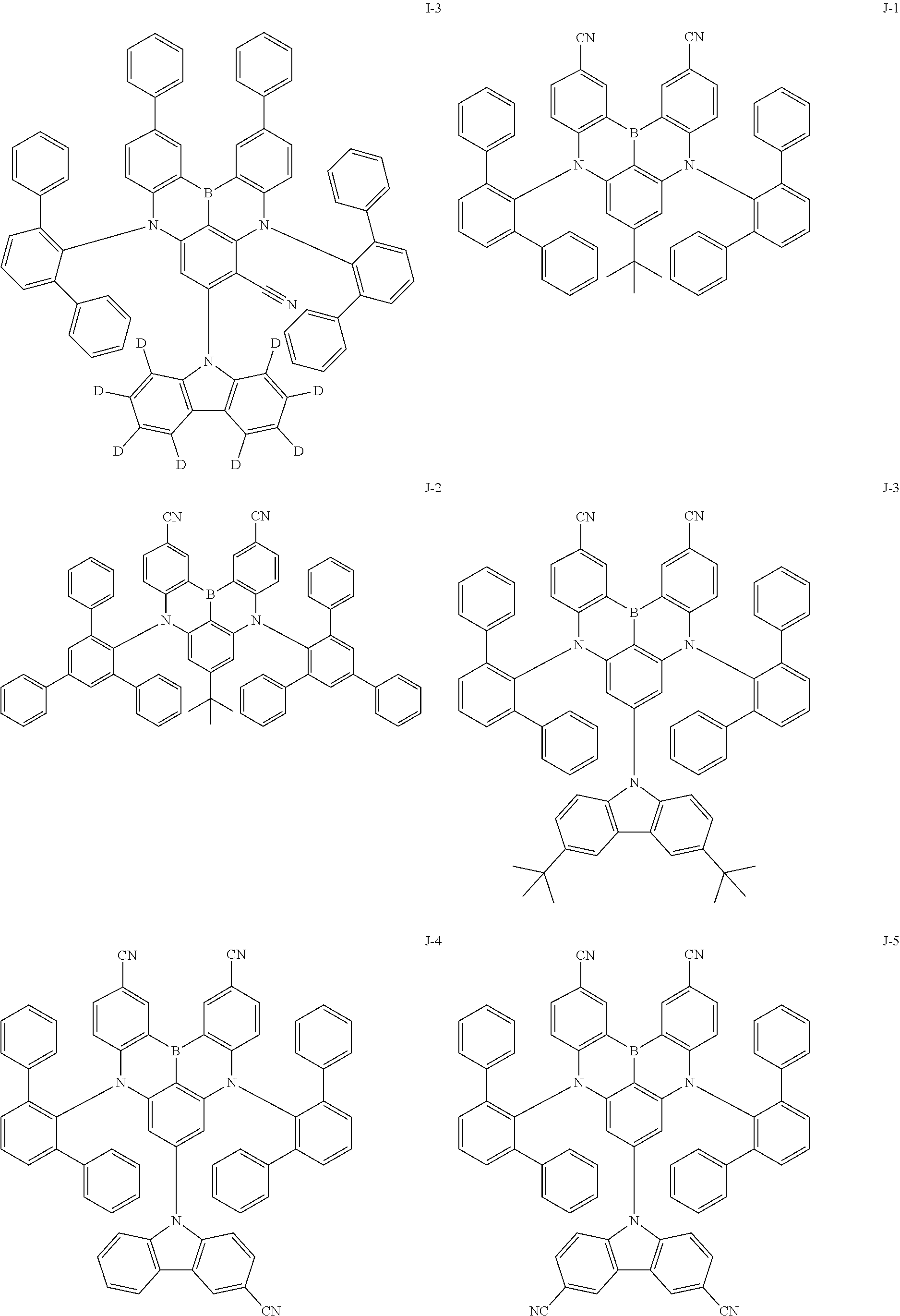

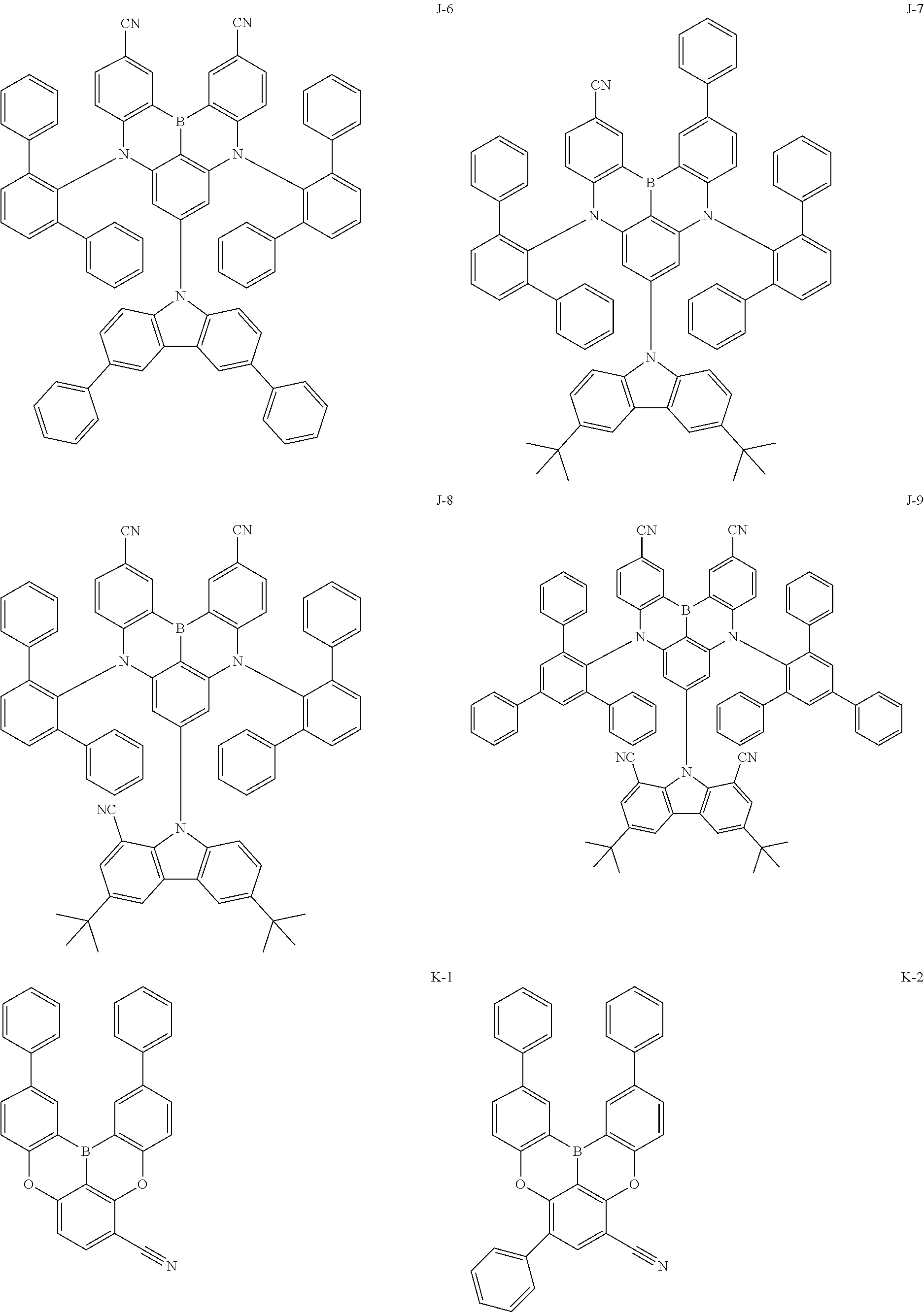

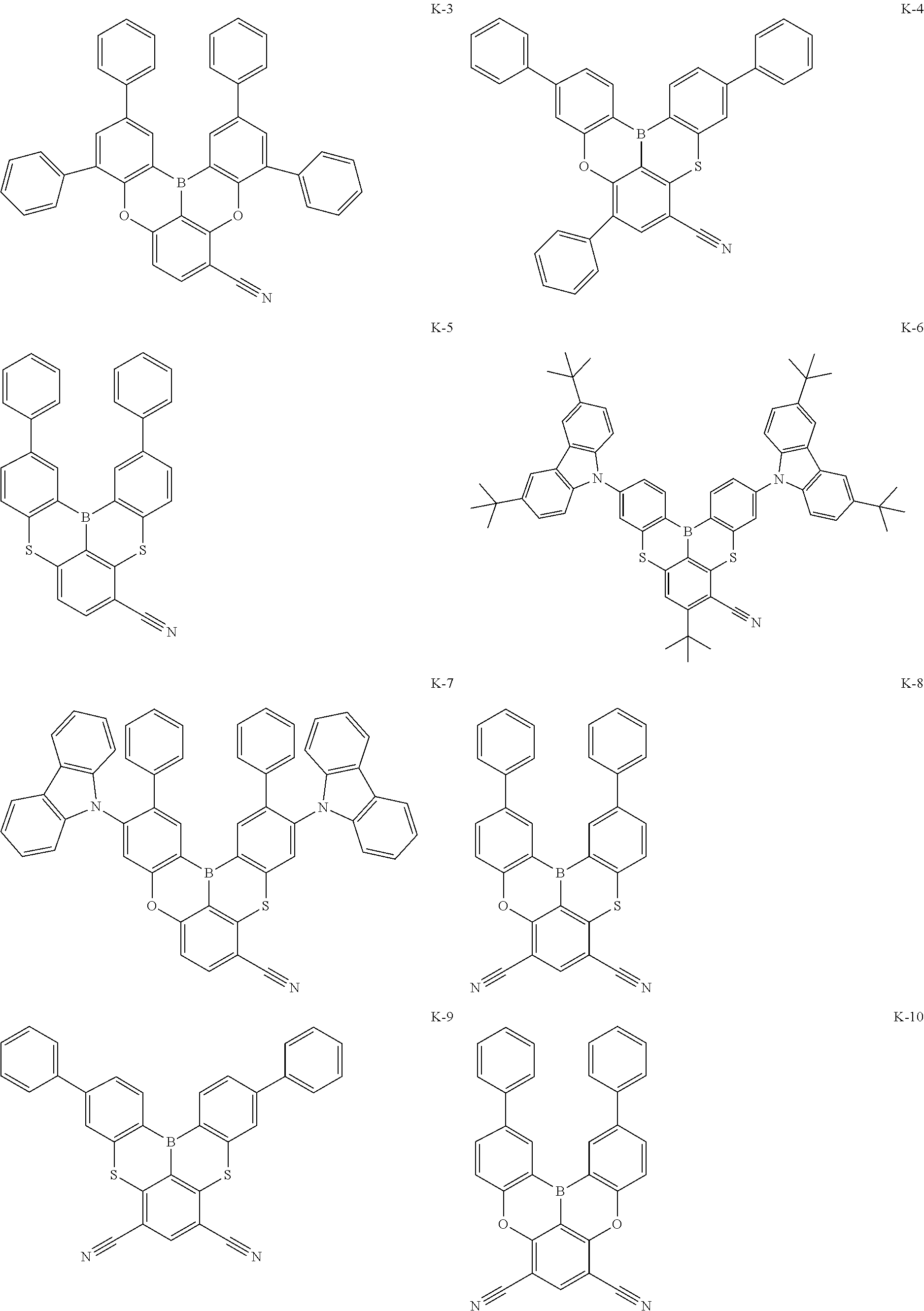

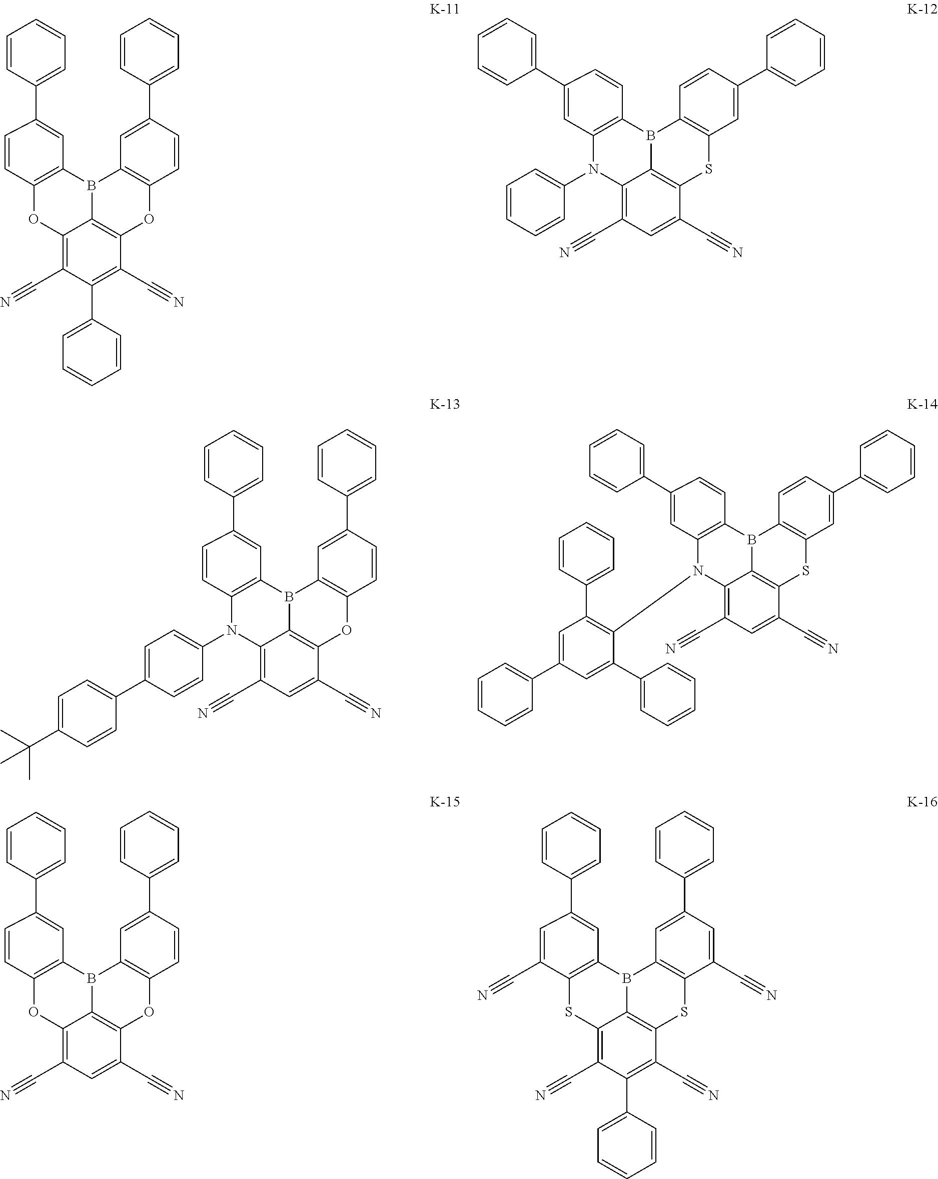

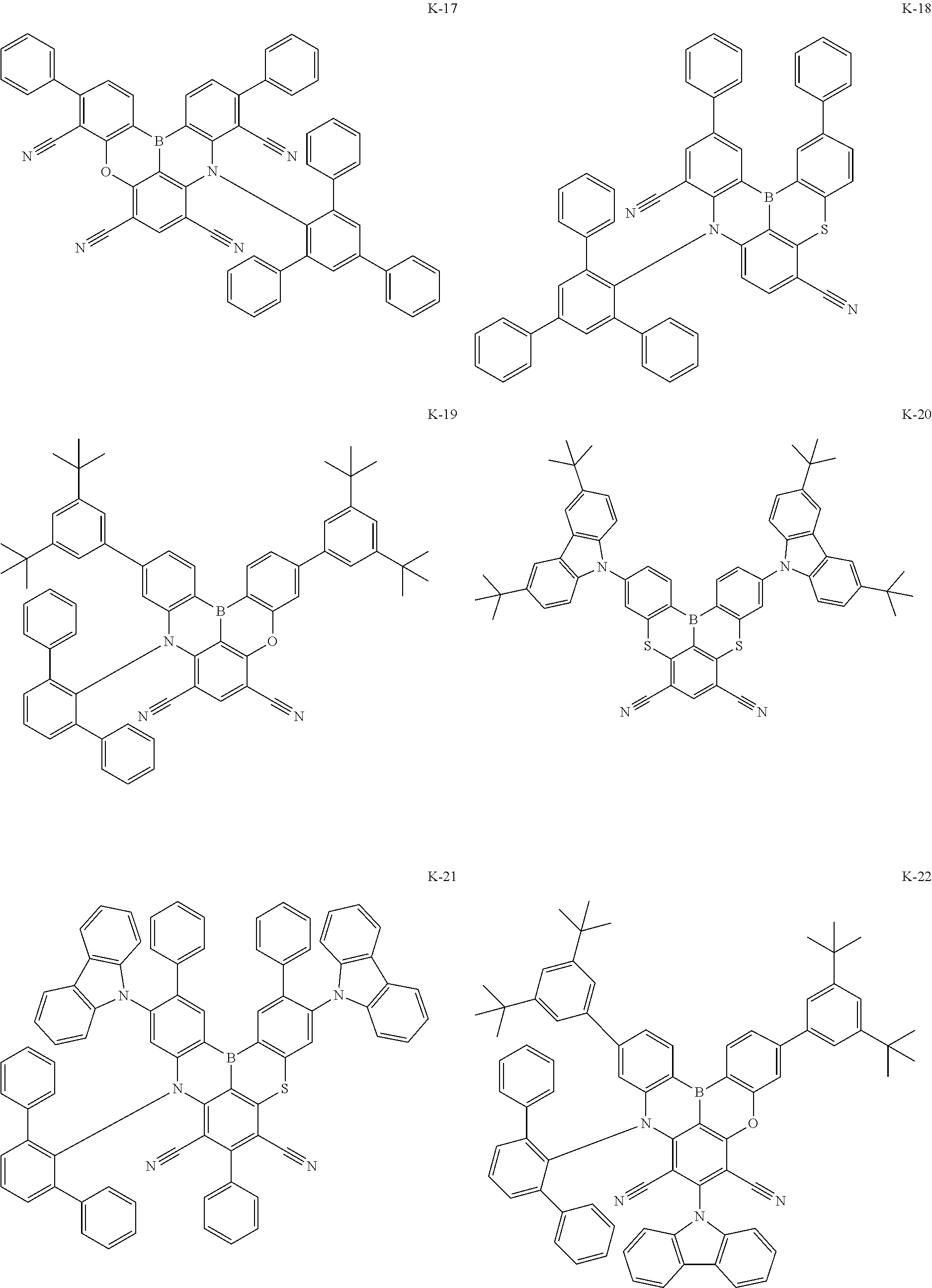

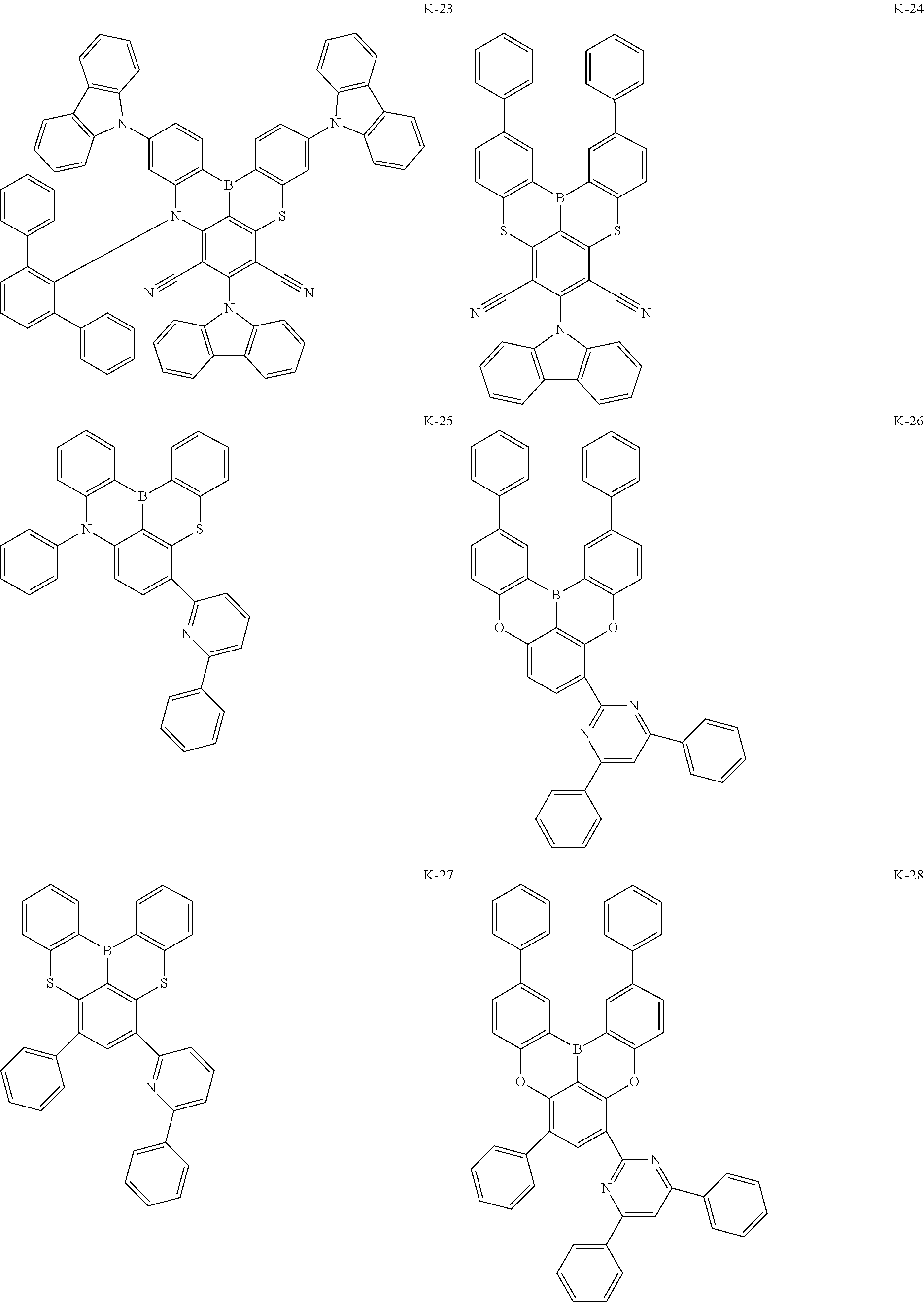

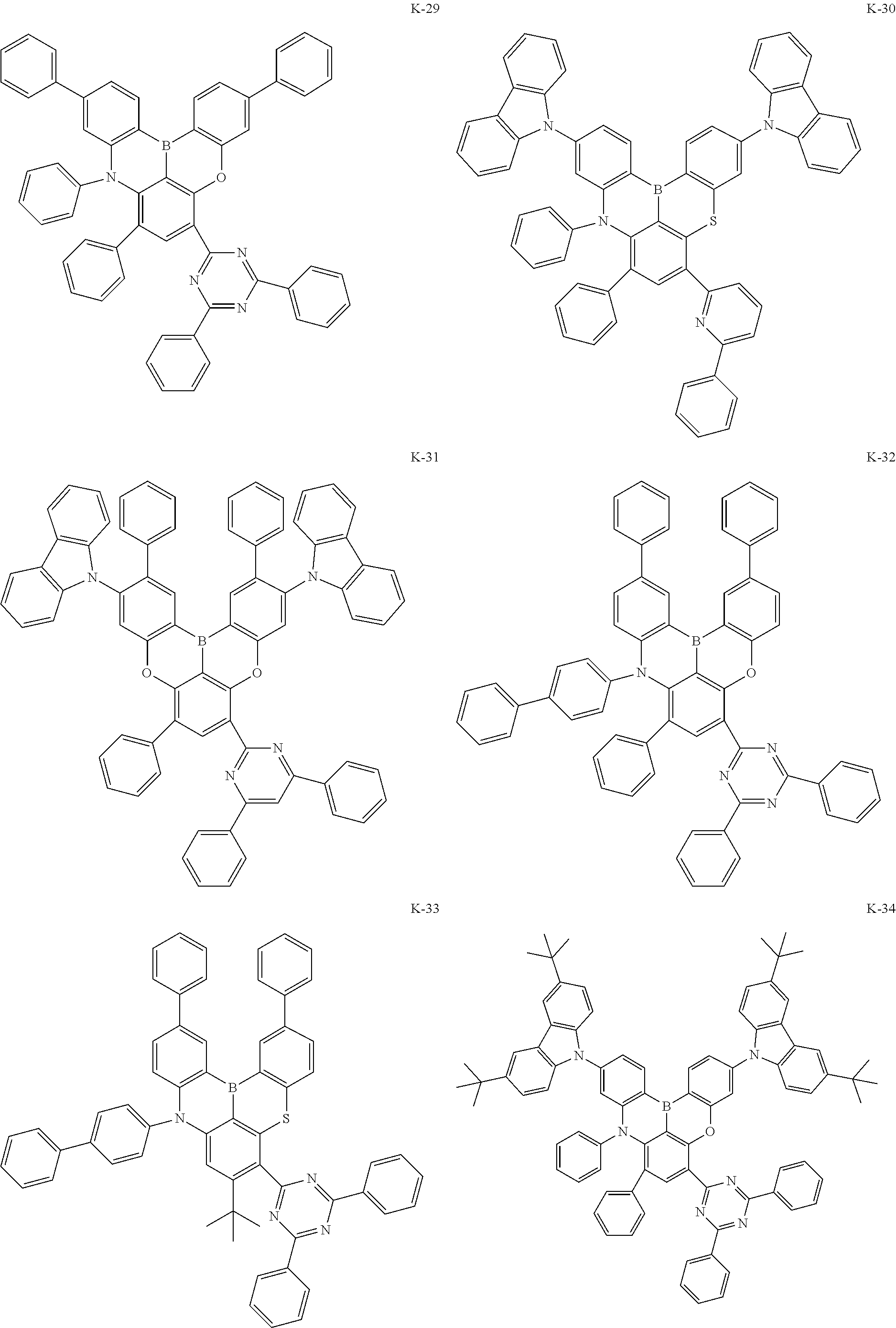

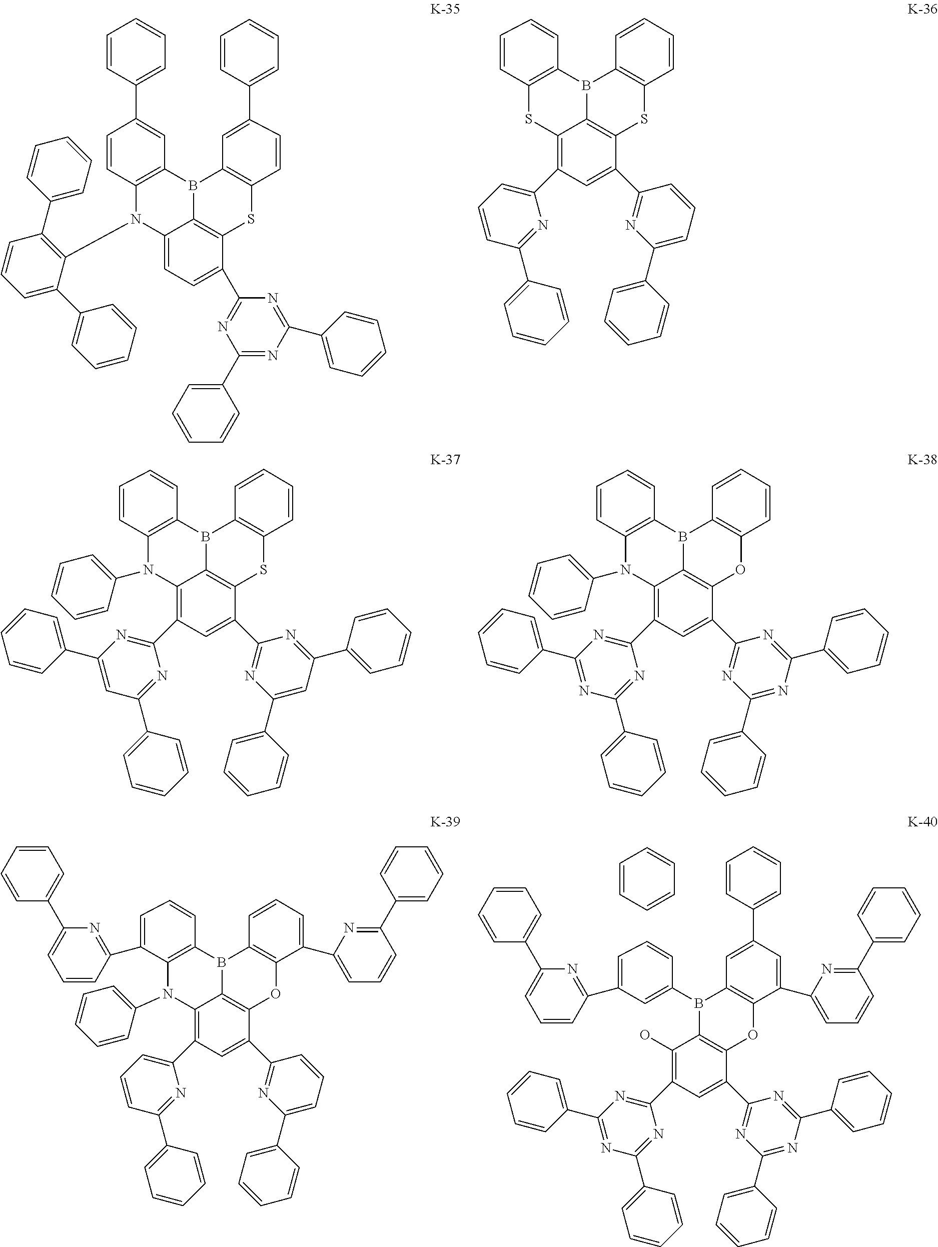

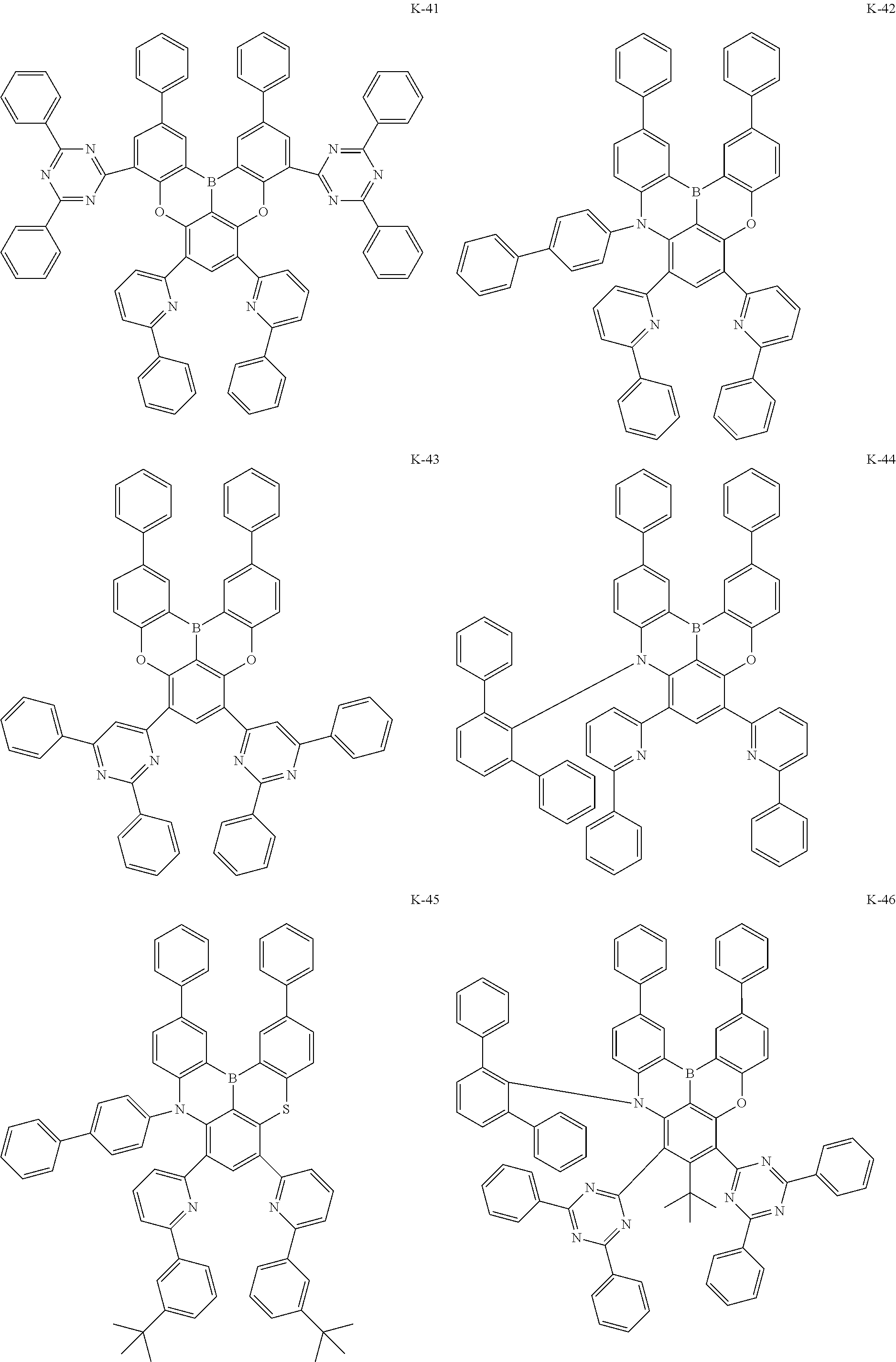

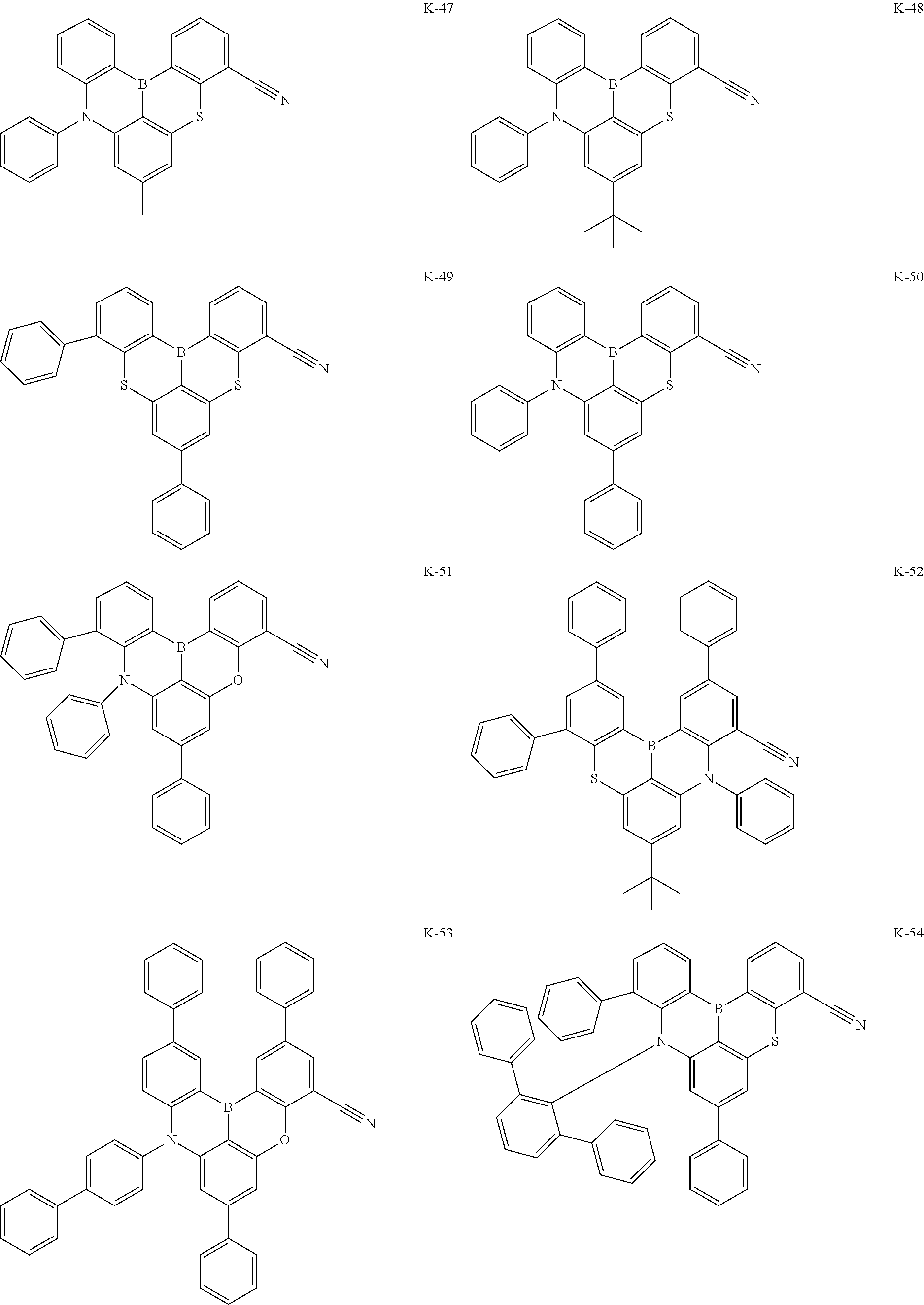

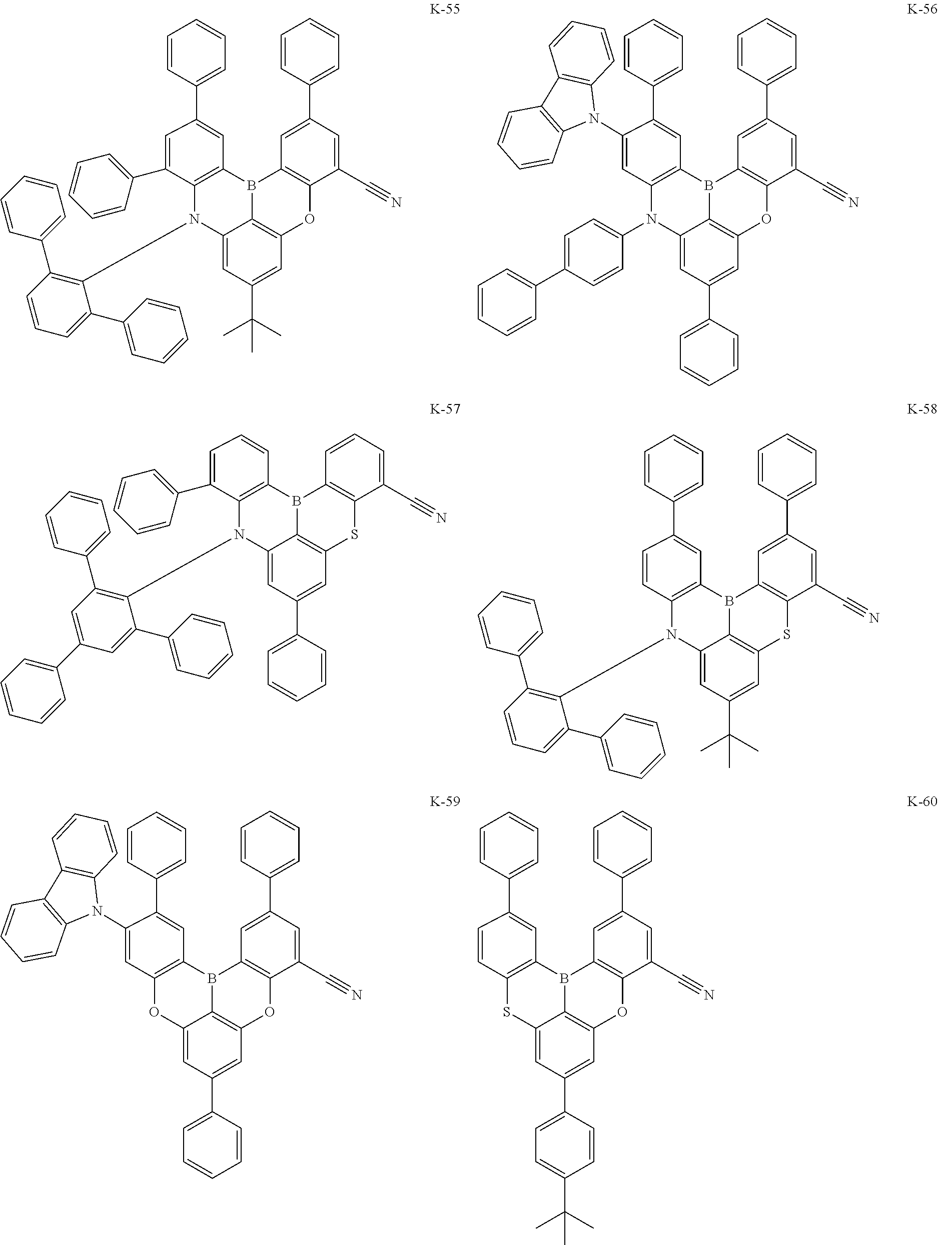

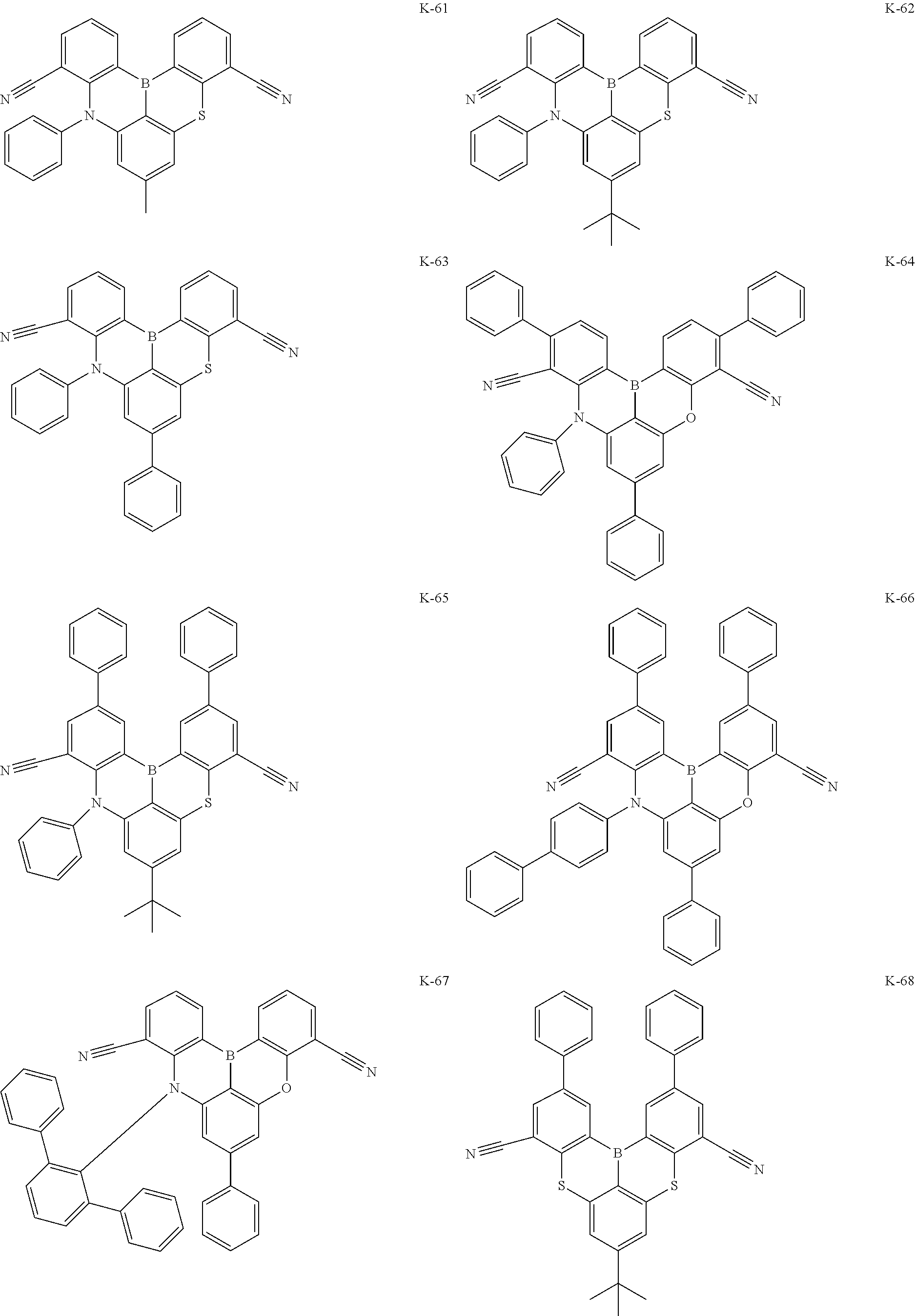

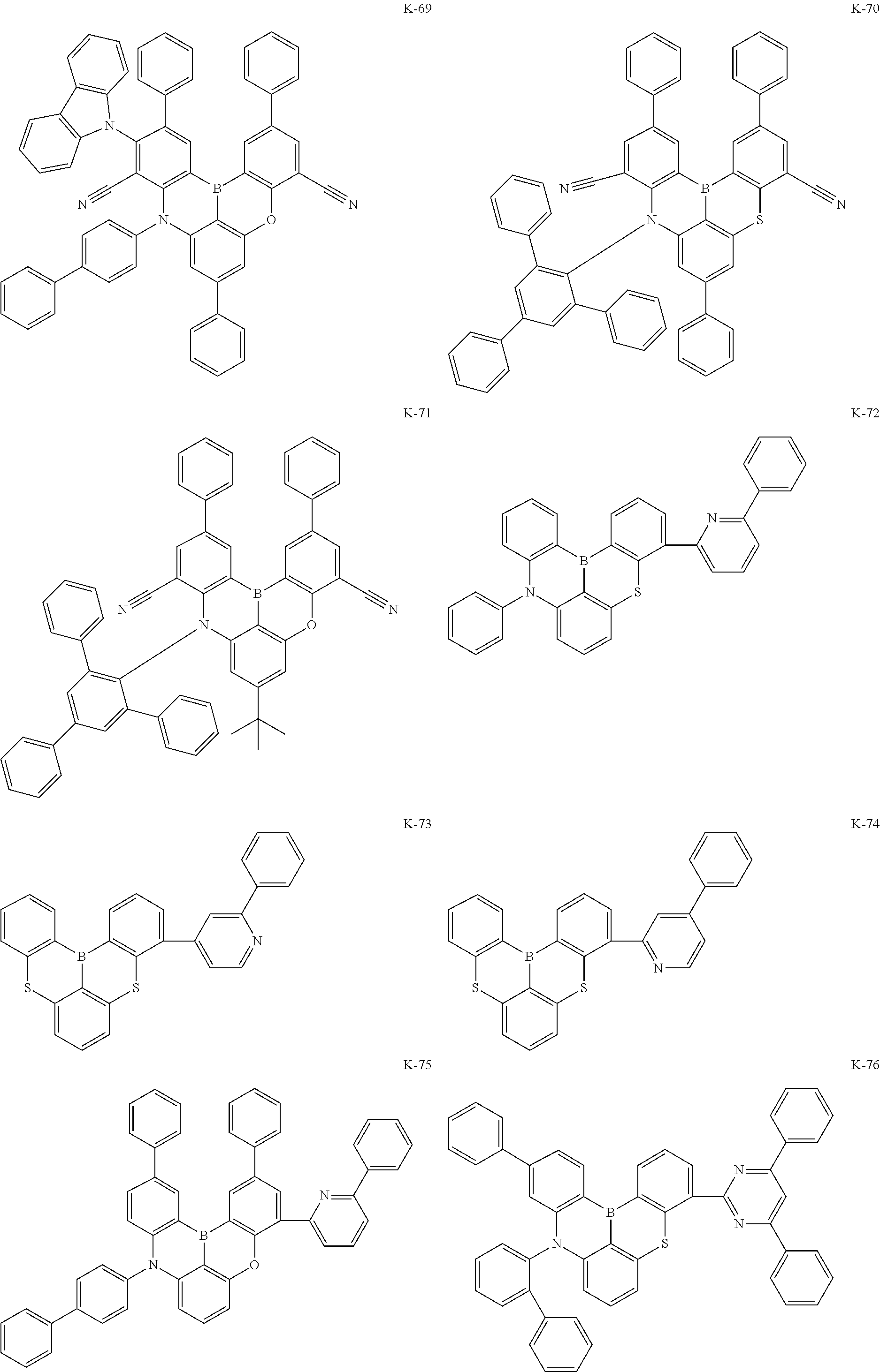

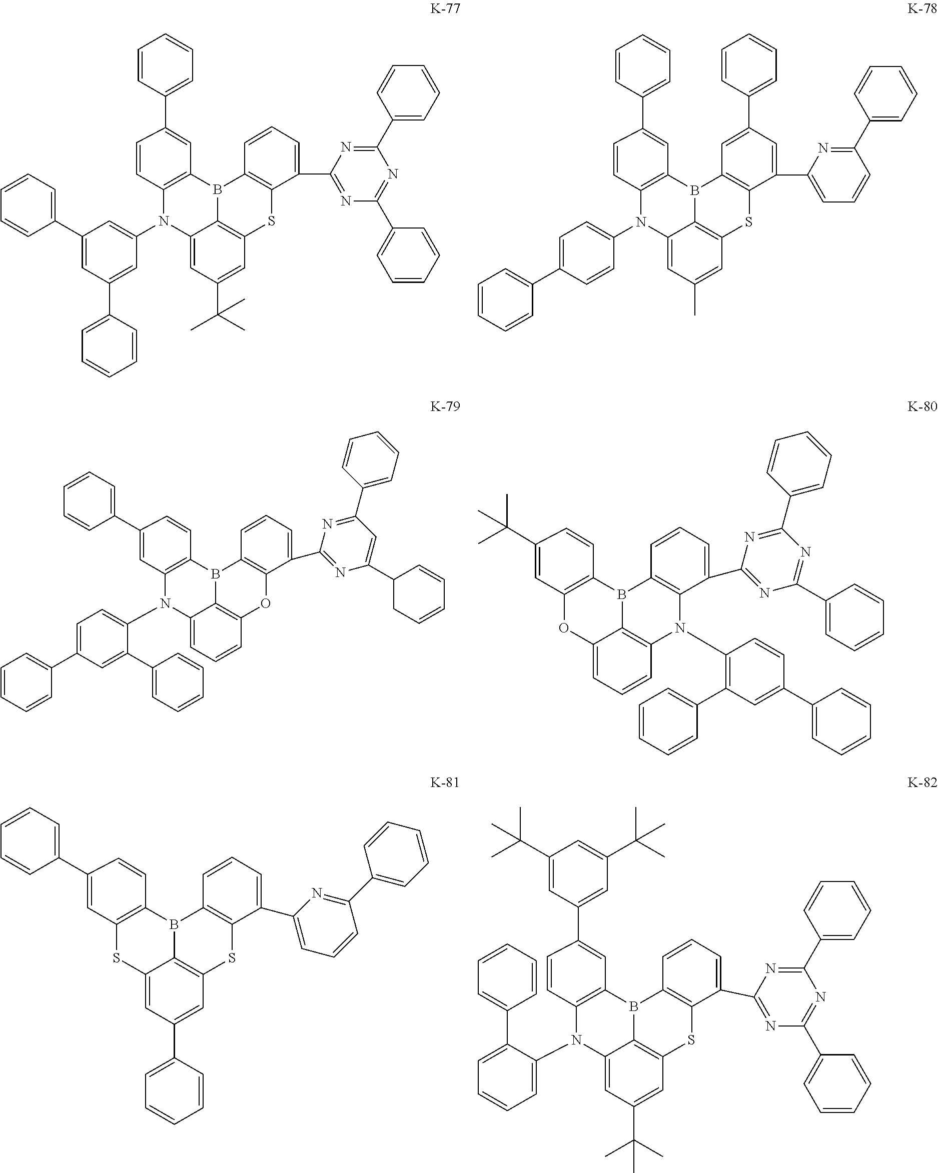

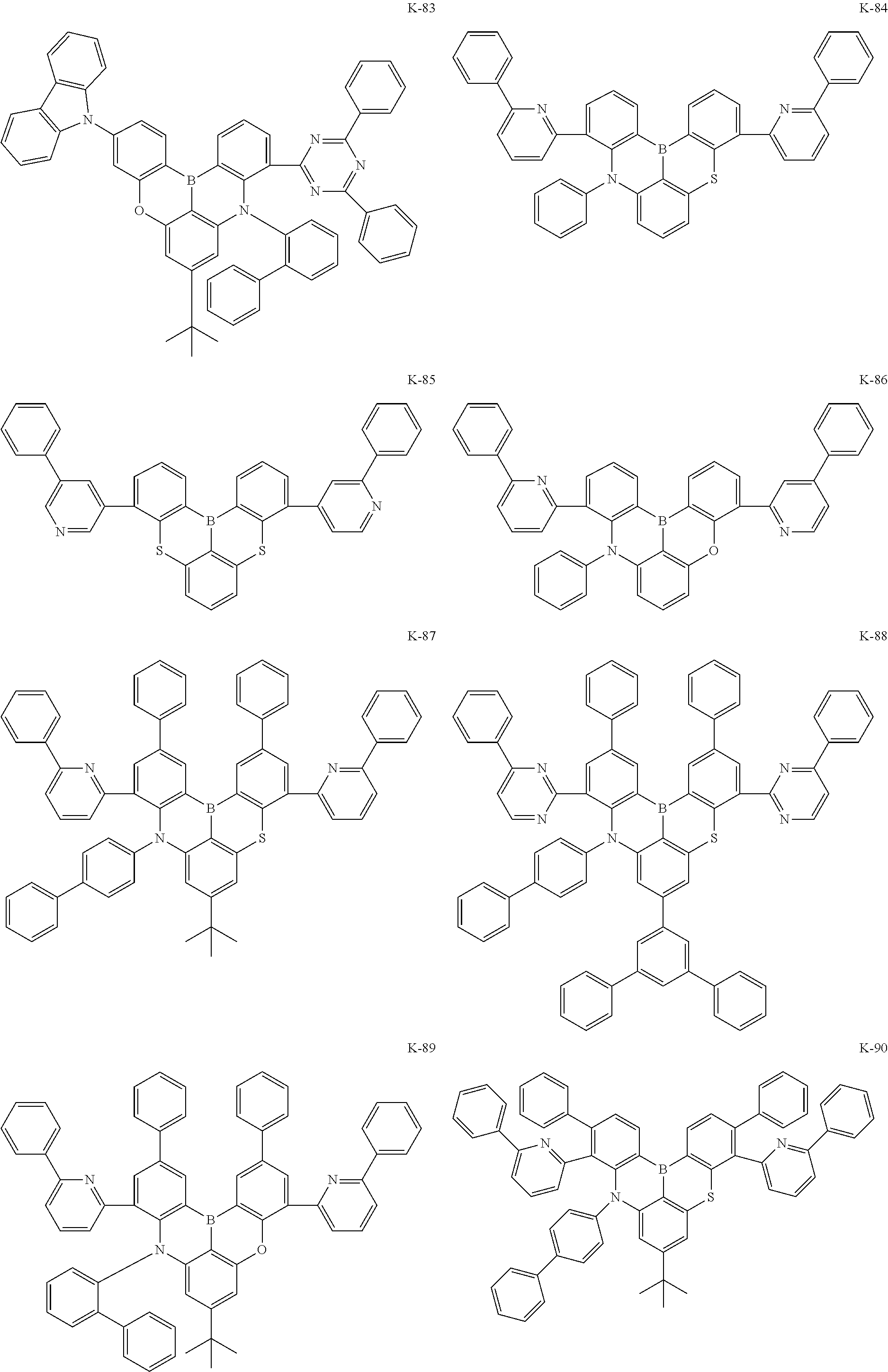

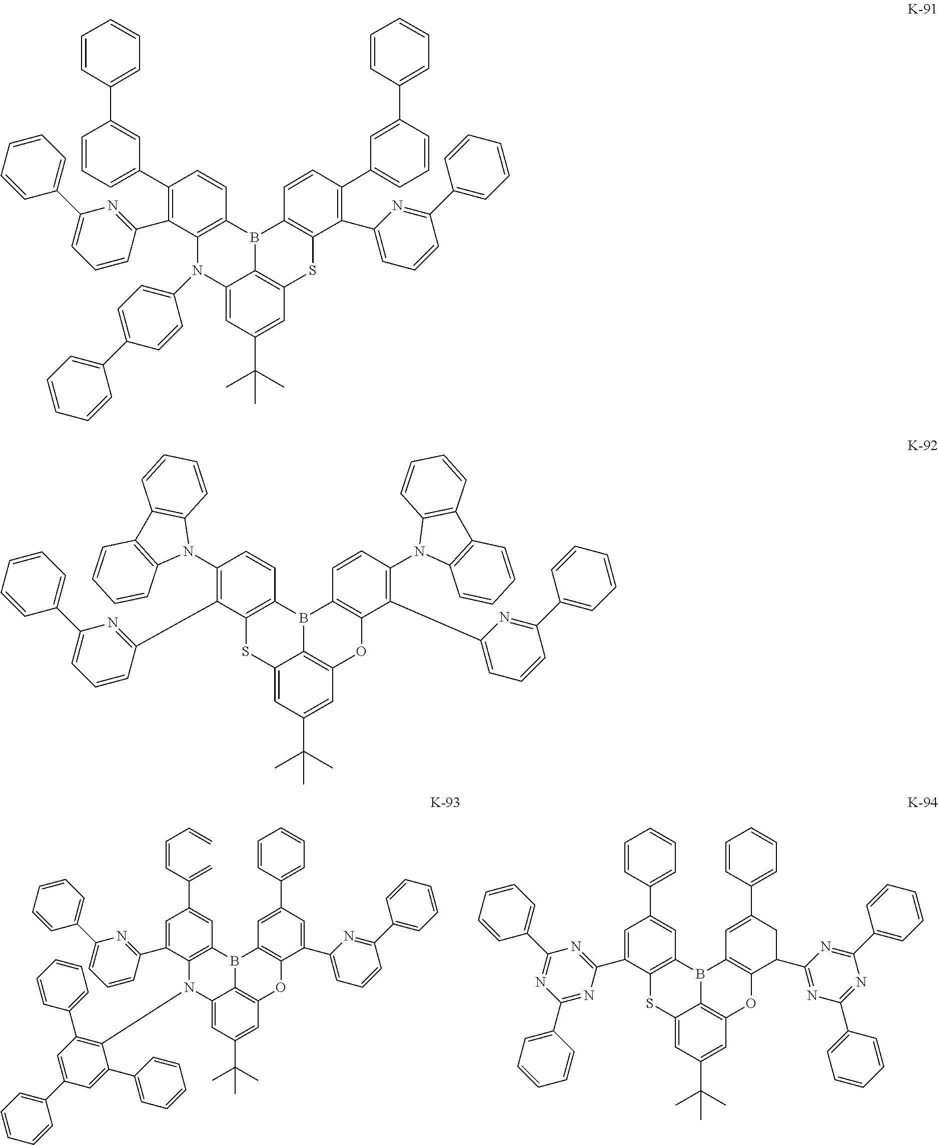

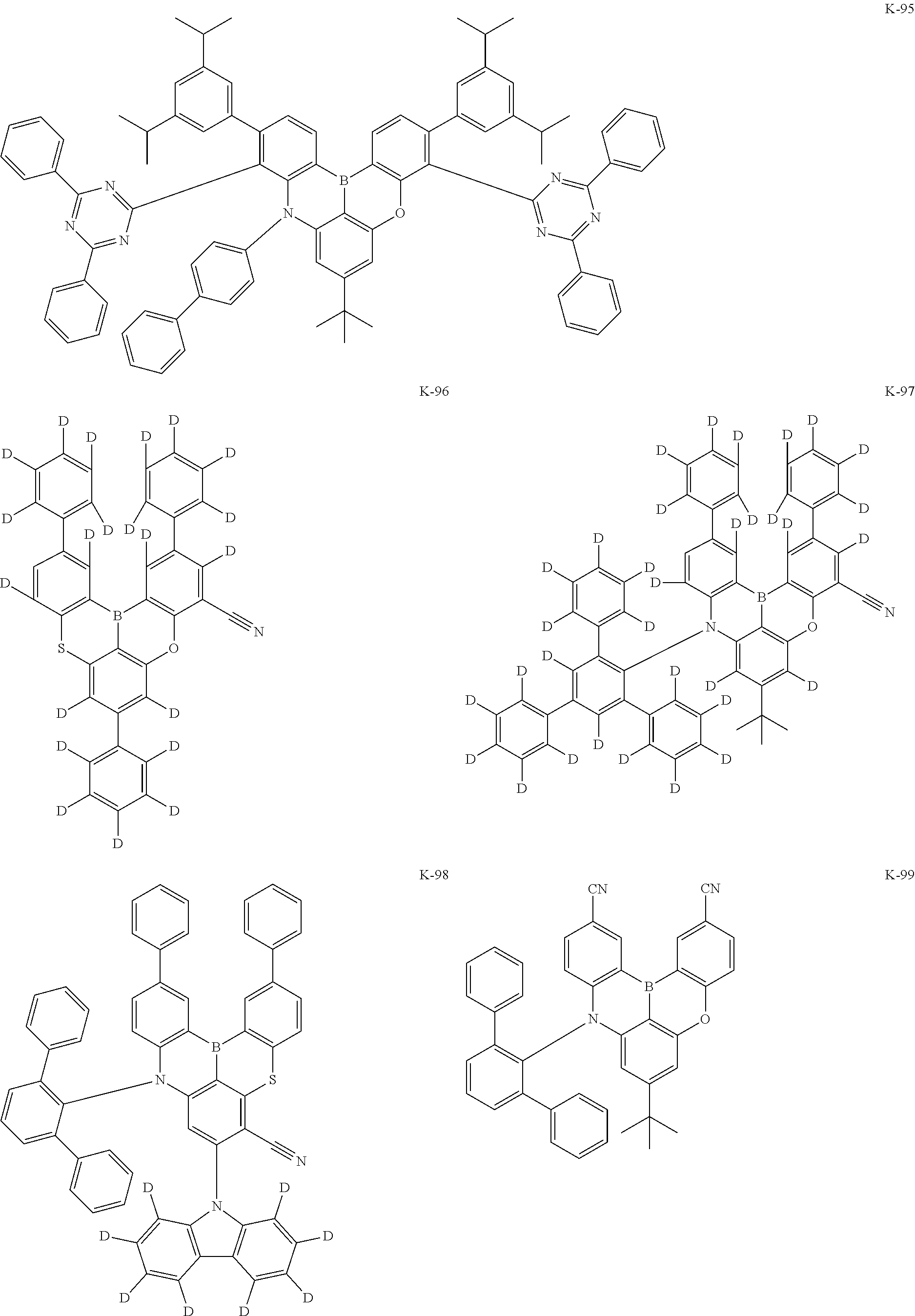

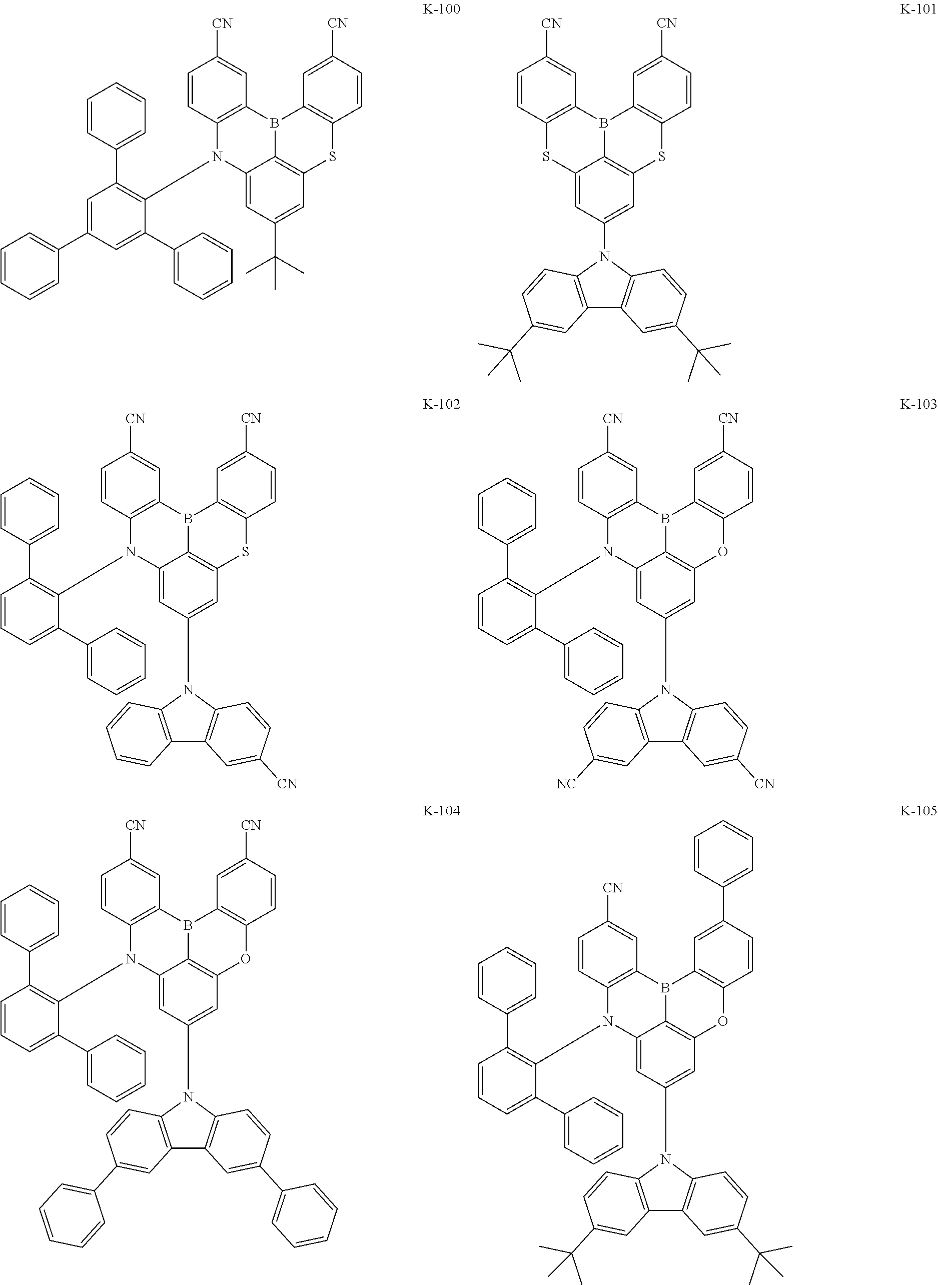

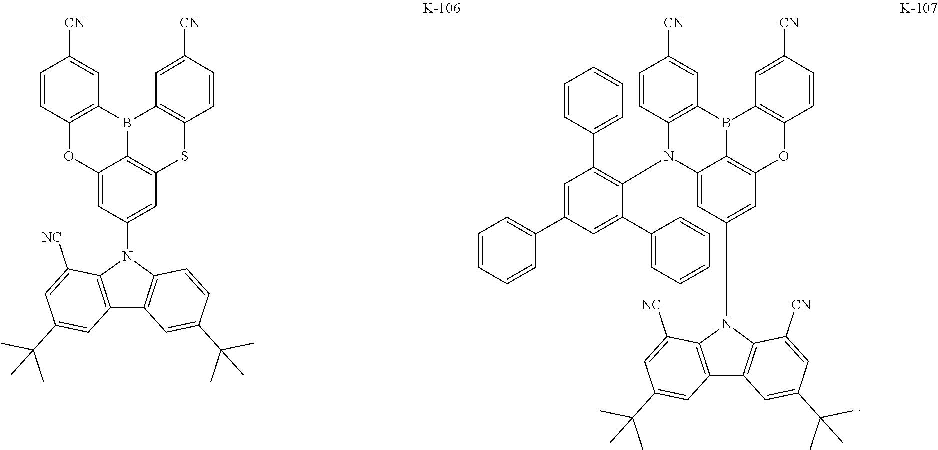 [SMILES: CC(C)(C)c1ccc2c(c1)c1cc(C(C)(C)C)cc(C#N)c1n2-c1cc2c3c(c1)Sc1ccc(C#N)cc1B3c1cc(C#N)ccc1O2 ; CC(C)(C)c1cc(C#N)c2c(c1)c1cc(C(C)(C)C)cc(C#N)c1n2-c1cc2c3c(c1)N(c1c(-c4ccccc4)cc(-c4ccccc4)cc1-c1ccccc1)c1ccc(C#N)cc1B3c1cc(C#N)ccc1O2]

In the embodiment compounds presented in Compound Group 1, “D” refers to deuterium.

The fused polycyclic compound represented by Formula 1 according to one or more embodiments has a structure in which the first substituent is introduced at a certain position, and thus may achieve high luminous efficiency and long service life.

The fused polycyclic compound of an embodiment may have a structure in which a plurality of aromatic rings are fused via the boron atom, the first heteroatom, and the second heteroatom, and a structure in which the first substituent is linked, as a substituent, to at least one selected from among the first to third aromatic rings constituting the fused ring. The first substituent may be linked to carbon at the meta position with respect to the boron atom. The first substituent is an electron withdrawing group, and may be a cyano group or a 6-membered heteroaryl group containing a nitrogen atom as a ring-forming atom. In the fused polycyclic compound of an embodiment, the fused ring core may include the first to sixth carbon which are carbon at the meta position with respect to the carbon atom, linked to the boron atom, among carbon atoms constituting the first to third aromatic rings, and the first substituent may be linked to at least one selected from among the first to sixth carbon.

The fused polycyclic compound of an embodiment may effectively maintain a trigonal planar structure of the boron atom through the steric hindrance effect, by the first substituent introduced at a specific position. The boron atom may have electron deficiency characteristics by an empty p-orbital, may form a bond with other nucleophiles, and thus be changed into a tetrahedral structure, which may cause deterioration of the element. According to the present disclosure, the fused polycyclic compound represented by Formula 1 includes the first substituent introduced at a specific position, may effectively protect the empty p-orbital of the boron atom, and thus may prevent or reduce the deterioration phenomenon due to the structural change. In addition, the fused polycyclic compound of an embodiment may have an increase in the luminous efficiency because the intermolecular interaction may be suppressed or reduced to control the formation of excimer or exciplex by the introduction of the first substituent. In one or more embodiments, the fused polycyclic compound includes the first substituent, a dihedral angle between a plane containing the fused ring core structure having the boron atom at the center thereof and a plane containing the first substituent may increase, and thus the intermolecular distance increases so that there is an effect of reducing Dexter energy transfer. The Dexter energy transfer is a phenomenon in which a triplet exciton moves between molecules, and increases when the intermolecular distance is short, and may become a factor that increases a quenching phenomenon due to the increase of triplet concentration.

According to the present disclosure, the fused polycyclic compound of an embodiment has an increase in the distance between adjacent molecules due to the large steric hindrance structure to thereby suppress or reduce the Dexter energy transfer, and thus may suppress or reduce the deterioration of service life due to the increase of triplet concentration. Therefore, when the fused polycyclic compound of an embodiment is applied to the emission layer EML of the light emitting device ED, the luminous efficiency may be increased and the device service life may also be improved.

The fused polycyclic compound represented by Formula 1 according to an embodiment includes the first substituent at a specific position, and thus may easily control the emission wavelength and have an improvement in the chemical stability of the material. The fused polycyclic compound of an embodiment has a structure in which the first substituent, an electron withdrawing substituent, is substituted at a specific position of the fused ring core, and thus may have a strong bonding structure between the first substituent and the fused ring core, thereby increasing the chemical stability of the material in itself. The electron donating substituents such as an amine group and a carbazole group is linked to the fused ring core to form a nitrogen-carbon bond, and thus may have a bond energy lower than a carbon-carbon bond, thereby reducing the chemical stability of the material in itself. According to the present disclosure, in the fused polycyclic compound of an embodiment, the first substituent is linked to the fused ring core to form a carbon-carbon bond, and thus the bond is strengthened, thereby increasing the chemical stability of the material in itself. In some embodiments, although the electron donating substituent is substituted at the fused ring core, the introduction of the first substituent, an electron withdrawing group, may withdraw an unshared electron pair of the nitrogen atom included in the electron donating substituent, and thus the bond-dissociation energy (BDE) of a nitrogen-carbon bond is strengthened, thereby increasing the chemical stability of the material in itself. In some embodiments, the fused polycyclic compound according to an embodiment may control the emission wavelength through the torsion in the molecule, electron density control, and/or the like by the introduction of the first substituent at a specific position, and thus it is able to control the emission wavelength within a desired or suitable wavelength range. For example, the emission wavelength with a shift of about several nanometers to about several score nanometers may be easily controlled or selected according to the substitution position and/or substitution number and/or the like of the first substituent.

The emission spectrum of the fused polycyclic compound represented by Formula 1 of an embodiment may have a full width of half maximum (FWHM) of about 10 nm to about 50 nm, or a FWHM of about 20 nm to about 40 nm. The emission spectrum of the first compound (the fused polycyclic compound) represented by Formula 1 of an embodiment has the above range of FWHM, thereby improving luminous efficiency when applied to a light emitting element.

In one or more embodiments, the fused polycyclic compound represented by Formula 1 of an embodiment may be a thermally activated delayed fluorescence emitting material. Furthermore, the fused polycyclic compound represented by Formula 1 of an embodiment may be a thermally activated delayed fluorescence dopant having a difference (ΔE_{ST}) between a lowest triplet exciton energy level (T1 level) and a lowest singlet exciton energy level (S1 level) of about 0.6 eV or less. In some embodiments, the fused polycyclic compound represented by Formula 1 of an embodiment may be a thermally activated delayed fluorescence dopant having a difference (ΔE_{ST}) between a lowest triplet exciton energy level (T1 level) and a lowest singlet exciton energy level (S1 level) of 0.2 eV or less.

In one or more embodiments, the fused polycyclic compound represented by Formula 1 of an embodiment may be a luminescent material having a luminescence center wavelength in a wavelength region of about 430 nm to about 490 nm. For example, in some embodiments, the fused polycyclic compound represented by Formula 1 of an embodiment may be a blue thermally activated delayed fluorescence (TADF) dopant. However, embodiments of the present disclosure are not limited thereto, when the fused polycyclic compound of an embodiment is utilized as a luminescent material, the first compound (the fused polycyclic compound) may be utilized as a dopant material that emits light in one or more suitable wavelength regions, such as a red emitting dopant or a green emitting dopant.

In one or more embodiments, the emission layer EML in the light emitting device ED may be to emit delayed fluorescence. For example, the emission layer EML may be to emit thermally activated delayed fluorescence (TADF).

In some embodiments, the emission layer EML of the light emitting device ED may be to emit blue light. For example, the emission layer EML of the organic electroluminescence device ED of an embodiment may be to emit blue light in the wavelength range of about 490 nm or less. However, embodiments of the present disclosure are not limited thereto, and the emission layer EML may be to emit green light or red light.

In one or more embodiments, the fused polycyclic compound of an embodiment may be included in the emission layer EML. The fused polycyclic compound of an embodiment may be included as a dopant material in the emission layer EML. The fused polycyclic compound of an embodiment may be a thermally activated delayed fluorescence material. The fused polycyclic compound of an embodiment may be utilized as a thermally activated delayed fluorescence dopant. For example, in the light emitting device ED of an embodiment, the emission layer EML may include, as a thermally activated delayed fluorescence dopant, at least one selected from among the fused polycyclic compounds represented in Compound Group 1 as described above. However, a utilization of the fused polycyclic compound of an embodiment is not limited thereto.

In one or more embodiments, the emission layer EML may include multiple compounds. The emission layer EML of an embodiment may include the fused polycyclic compound represented by Formula 1, i.e., the first compound, and at least one selected from among a second compound represented by Formula HT-1, a third compound represented by Formula ET-1, and a fourth compound represented by Formula D-1.

In one or more embodiments, the emission layer EML may include the first compound represented by Formula 1 and further include at least one selected from among a second compound represented by Formula HT-1 and a third compound represented by Formula ET-1.

In one or more embodiments, the emission layer EML may include a second compound represented by Formula HT-1. In some embodiments, the second compound may be utilized as a hole transport host material in the emission layer EML.

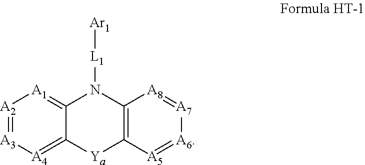

In Formula HT-1, A₁ to A₈ may each independently be N or CR₅₁. For example, in some embodiments, all A₁ to A₈ may be CR₅₁. In some embodiments, any one selected from among A₁ to A₈ may be N, and the remainder may be CR₅₁.

In Formula HT-1, L₁ may be a direct linkage, a substituted or unsubstituted arylene group of 6 to 30 ring-forming carbon atoms, or a substituted or unsubstituted heteroarylene group of 2 to 30 ring-forming carbon atoms. For example, in some embodiments, L₁ may be a direct linkage, a substituted or unsubstituted phenylene group, a substituted or unsubstituted divalent biphenyl group, a substituted or unsubstituted divalent carbazole group, and/or the like, but embodiments of the present disclosure are not limited thereto.

In Formula HT-1, Yₐ may be a direct linkage, CR₅₂R₅₃, or SiR₅₄R₅₅. For example, it may refer to that two 6-membered (e.g., benzene) rings connected with the nitrogen atom of Formula HT-1 may be connected via a direct linkage,

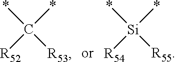

In Formula HT-1, when Yₐ is a direct linkage, the compound represented by Formula HT-1 may include a carbazole moiety.

In Formula HT-1, Ar₁ may be a substituted or unsubstituted aryl group of 6 to 30 ring-forming carbon atoms, or a substituted or unsubstituted heteroaryl group of 2 to 30 ring-forming carbon atoms. For example, in one or more embodiments, Ar₁ may be a substituted or unsubstituted carbazole group, a substituted or unsubstituted dibenzofuran group, a substituted or unsubstituted dibenzothiophene group, a substituted or unsubstituted biphenyl group, and/or the like, but embodiments of the present disclosure are not limited thereto.

In Formula HT-1, R₅₁ to R₅₅ may each independently be hydrogen, deuterium, a halogen, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 60 ring-forming carbon atoms. In some embodiments, each of R₅₁ to R₅₅ may be combined with an adjacent group to form a ring. For example, in some embodiments, R₅₁ to R₅₅ may each independently be hydrogen or deuterium. R₅₁ to R₅₅ may each independently be an unsubstituted methyl group or an unsubstituted phenyl group.

In one or more embodiments, the second compound represented by Formula HT-1 may be represented by any one selected from among compounds represented in Compound Group 2. The emission layer EML may include at least one selected from among the compounds represented in Compound Group 2 as a hole transport host material.

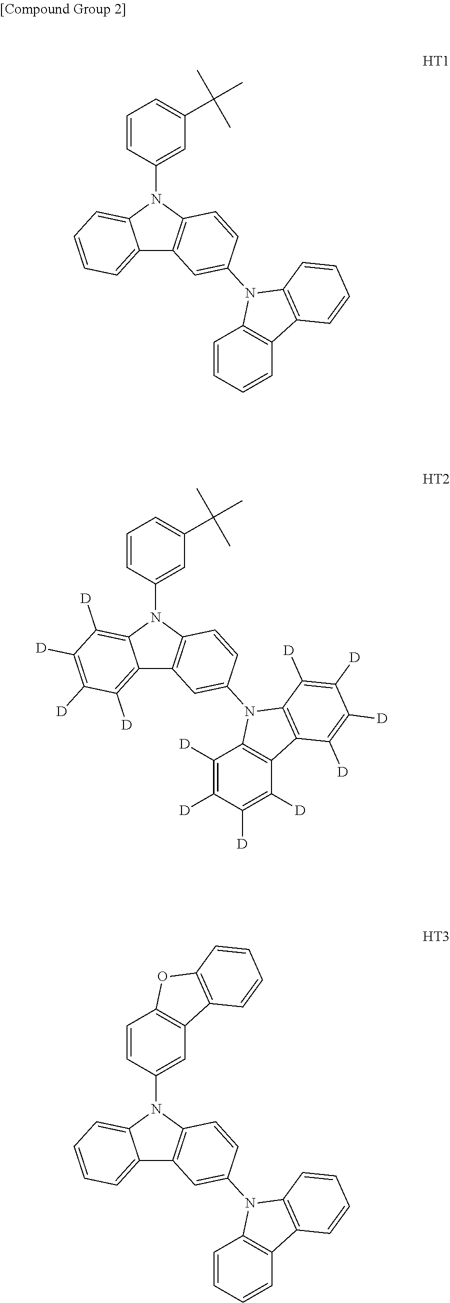 [SMILES: CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12]

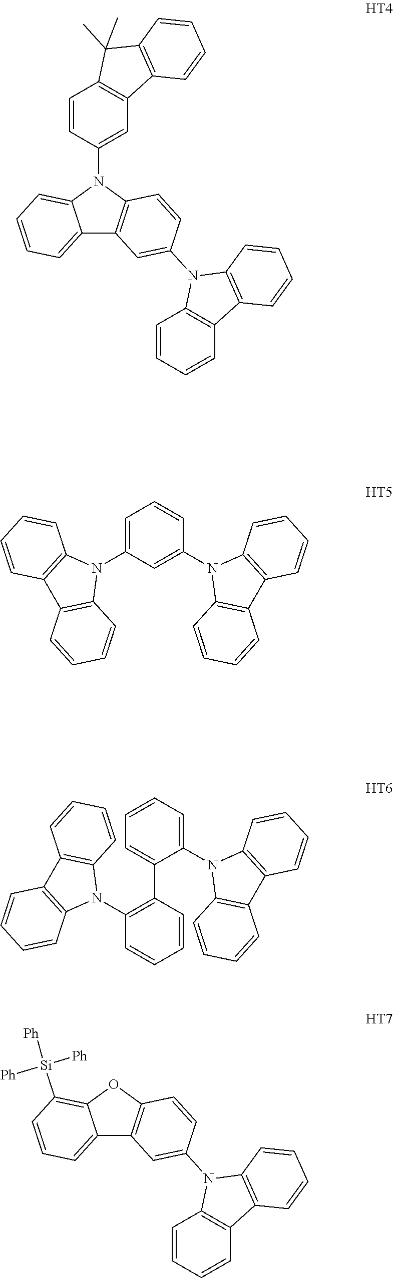 [SMILES: CC1(C)c2ccccc2-c2cc(-n3c4ccccc4c4cc(-n5c6ccccc6c6ccccc65)ccc43)ccc21 ; c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc([Si](c2ccccc2)(c2ccccc2)c2cccc3c2oc2ccc(-n4c5ccccc5c5ccccc54)cc23)cc1]

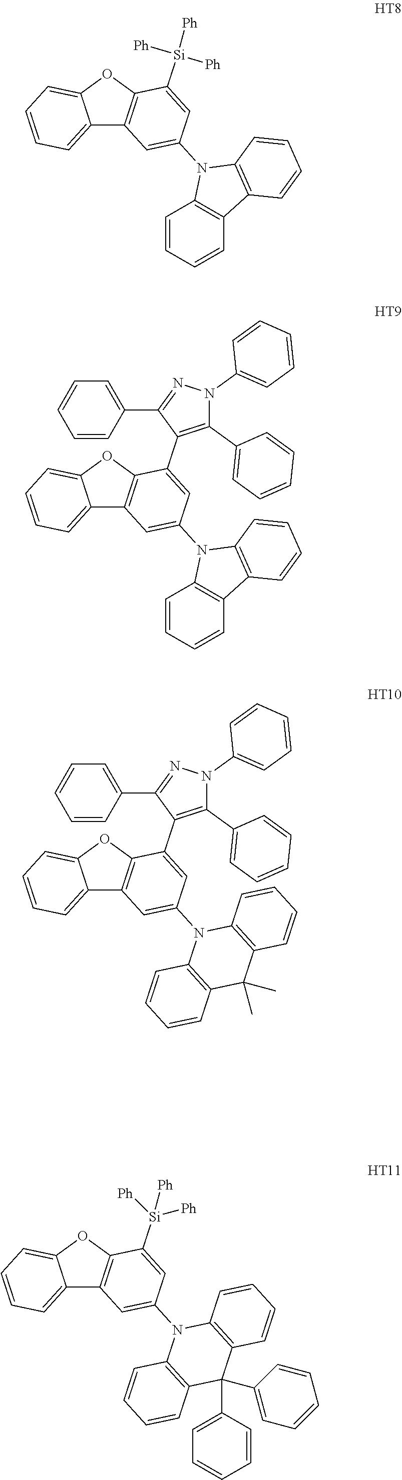 [SMILES: c1ccc([Si](c2ccccc2)(c2ccccc2)c2cc(-n3c4ccccc4c4ccccc43)cc3c2oc2ccccc23)cc1 ; c1ccc(-c2nn(-c3ccccc3)c(-c3ccccc3)c2-c2cc(-n3c4ccccc4c4ccccc43)cc3c2oc2ccccc23)cc1 ; CC1(C)c2ccccc2N(c2cc(-c3c(-c4ccccc4)nn(-c4ccccc4)c3-c3ccccc3)c3oc4ccccc4c3c2)c2ccccc21 ; c1ccc(C2(c3ccccc3)c3ccccc3N(c3cc([Si](c4ccccc4)(c4ccccc4)c4ccccc4)c4oc5ccccc5c4c3)c3ccccc32)cc1]

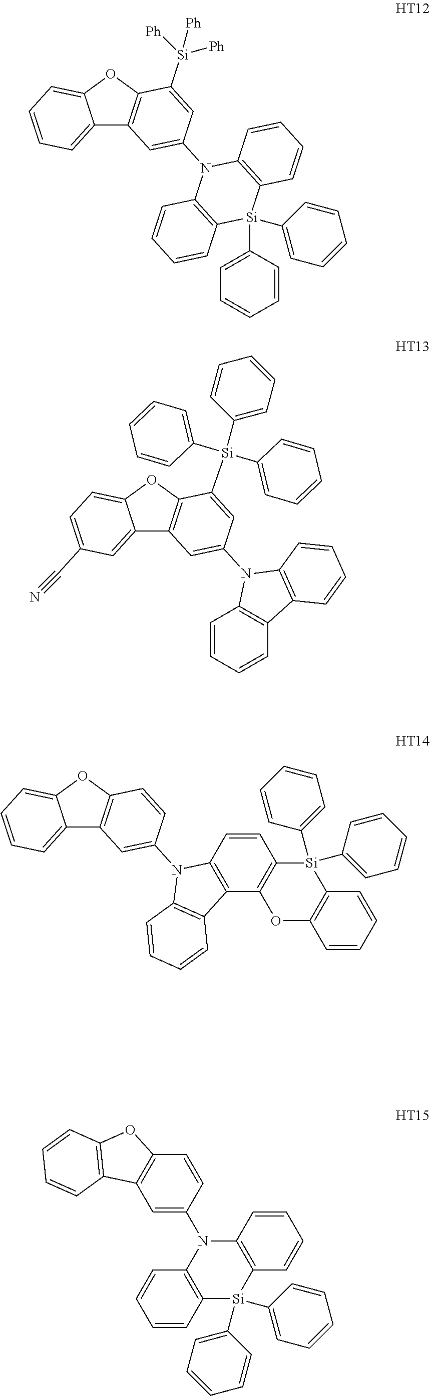

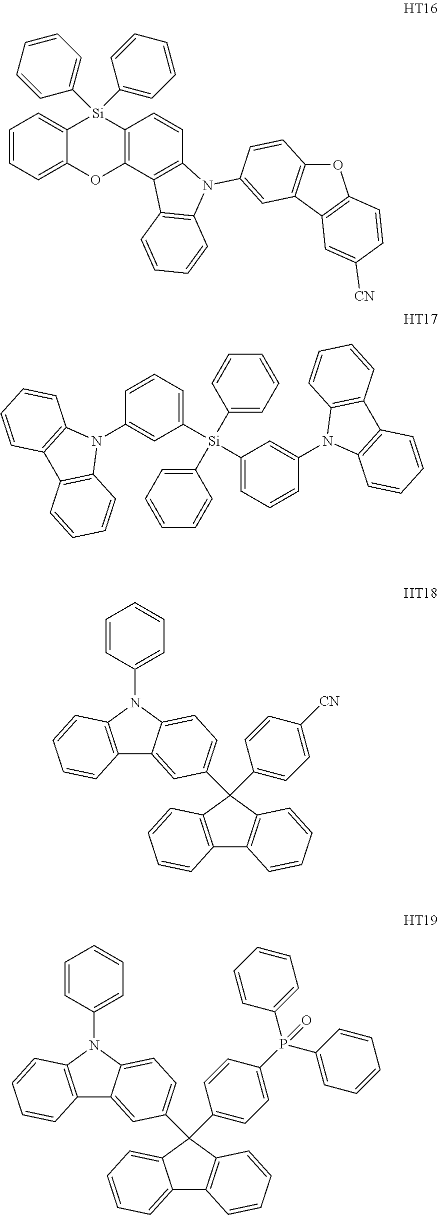 [SMILES: N#Cc1ccc2oc3ccc(-n4c5ccccc5c5c6c(ccc54)[Si](c4ccccc4)(c4ccccc4)c4ccccc4O6)cc3c2c1 ; c1ccc([Si](c2ccccc2)(c2cccc(-n3c4ccccc4c4ccccc43)c2)c2cccc(-n3c4ccccc4c4ccccc43)c2)cc1 ; N#Cc1ccc(C2(c3ccc4c(c3)c3ccccc3n4-c3ccccc3)c3ccccc3-c3ccccc32)cc1 ; O=P(c1ccccc1)(c1ccccc1)c1ccc(C2(c3ccc4c(c3)c3ccccc3n4-c3ccccc3)c3ccccc3-c3ccccc32)cc1]

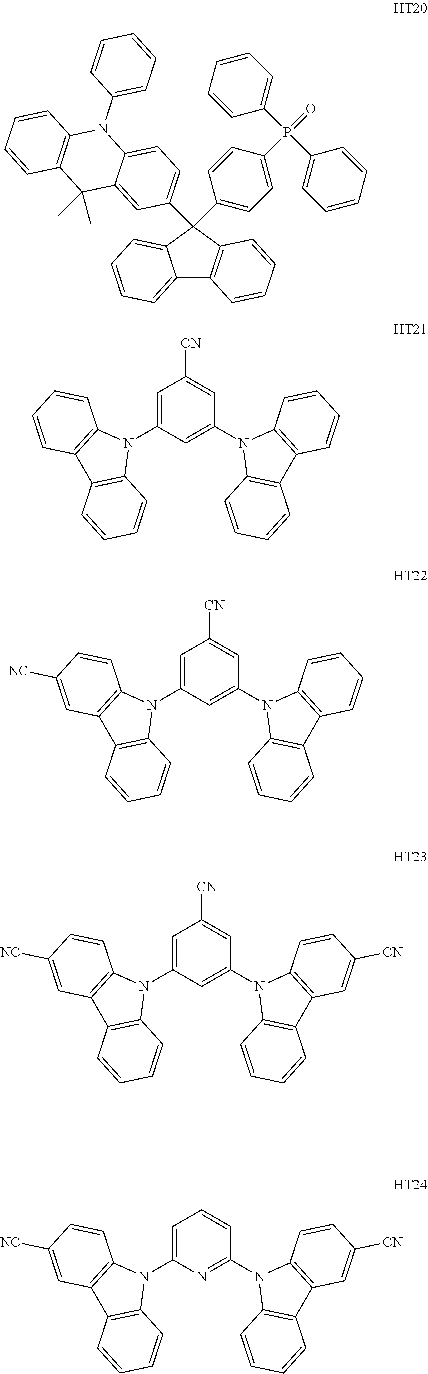 [SMILES: CC1(C)c2ccccc2N(c2ccccc2)c2ccc(C3(c4ccc(P(=O)(c5ccccc5)c5ccccc5)cc4)c4ccccc4-c4ccccc43)cc21 ; N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1 ; N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1]

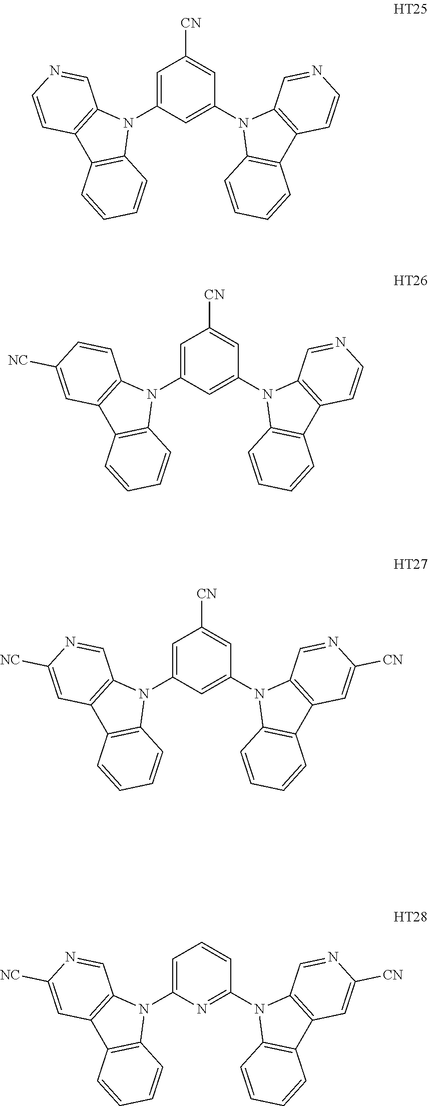 [SMILES: N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1 ; N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1]

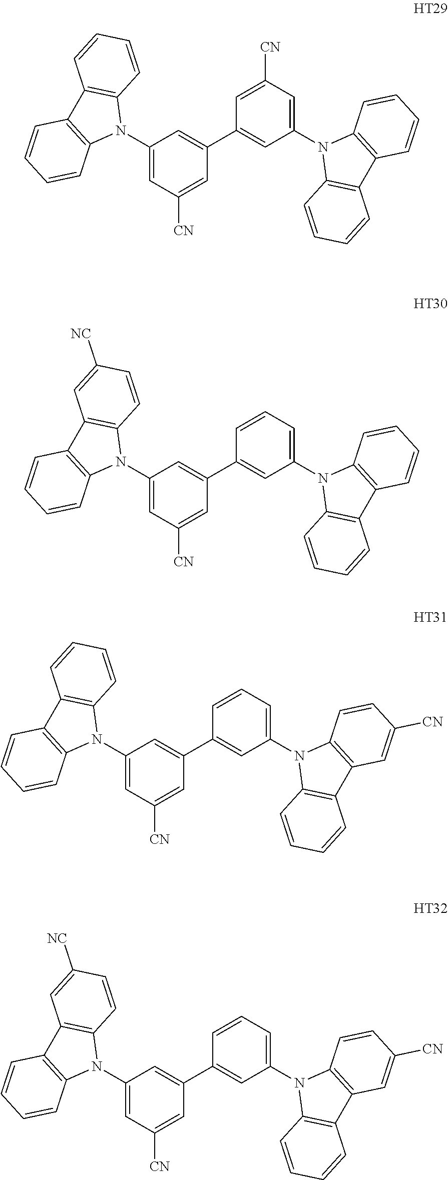 [SMILES: N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1 ; N#Cc1cc(-c2cccc(-n3c4ccccc4c4cc(C#N)ccc43)c2)cc(-n2c3ccccc3c3cc(C#N)ccc32)c1]

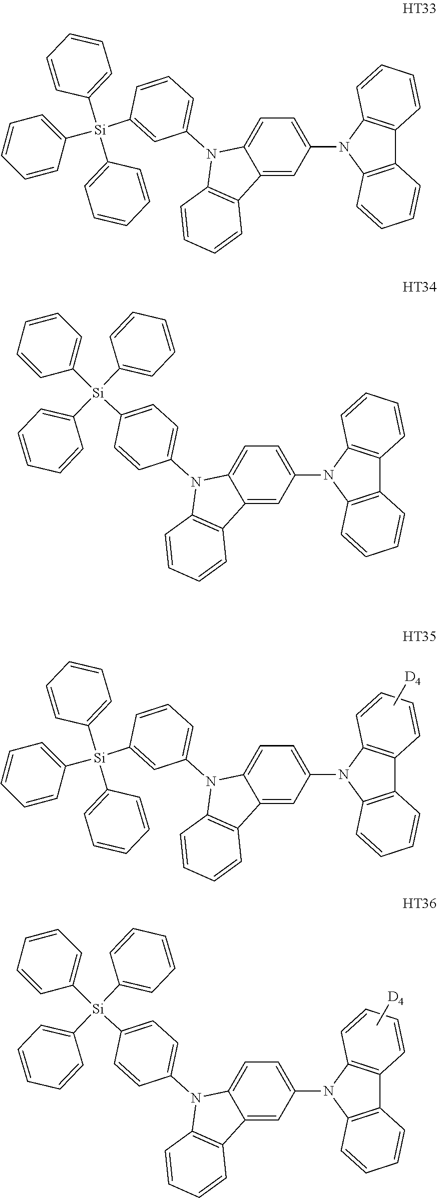

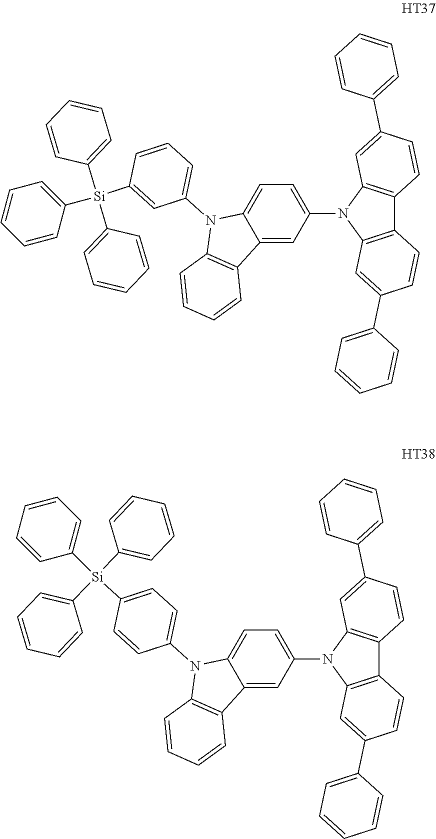 [SMILES: c1ccc(-c2ccc3c4ccc(-c5ccccc5)cc4n(-c4ccc5c(c4)c4ccccc4n5-c4cccc([Si](c5ccccc5)(c5ccccc5)c5ccccc5)c4)c3c2)cc1 ; c1ccc(-c2ccc3c4ccc(-c5ccccc5)cc4n(-c4ccc5c(c4)c4ccccc4n5-c4ccc([Si](c5ccccc5)(c5ccccc5)c5ccccc5)cc4)c3c2)cc1]

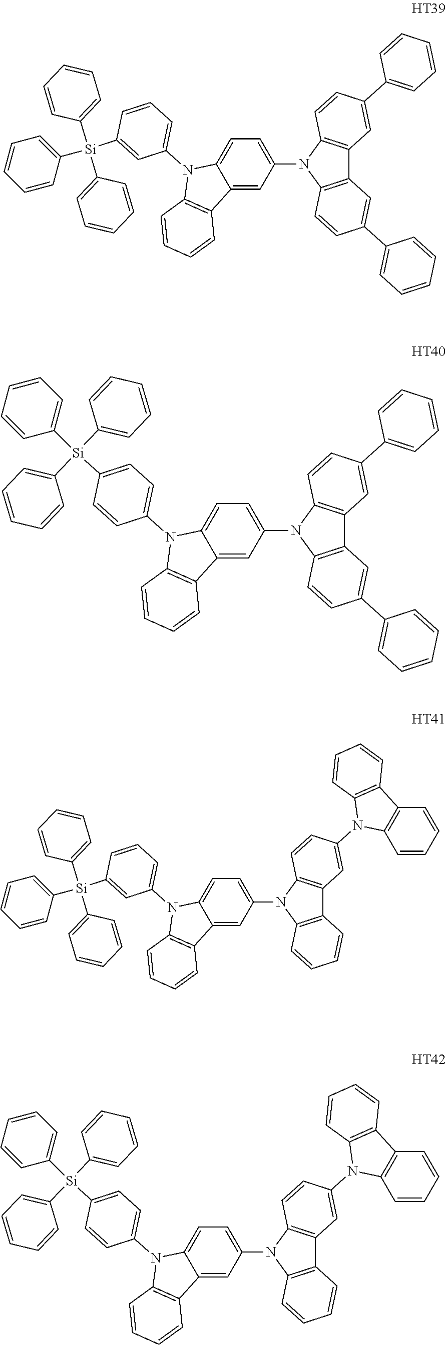 [SMILES: c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1 ; c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc([Si](c2ccccc2)(c2ccccc2)c2ccc(-n3c4ccccc4c4cc(-n5c6ccccc6c6cc(-n7c8ccccc8c8ccccc87)ccc65)ccc43)cc2)cc1]

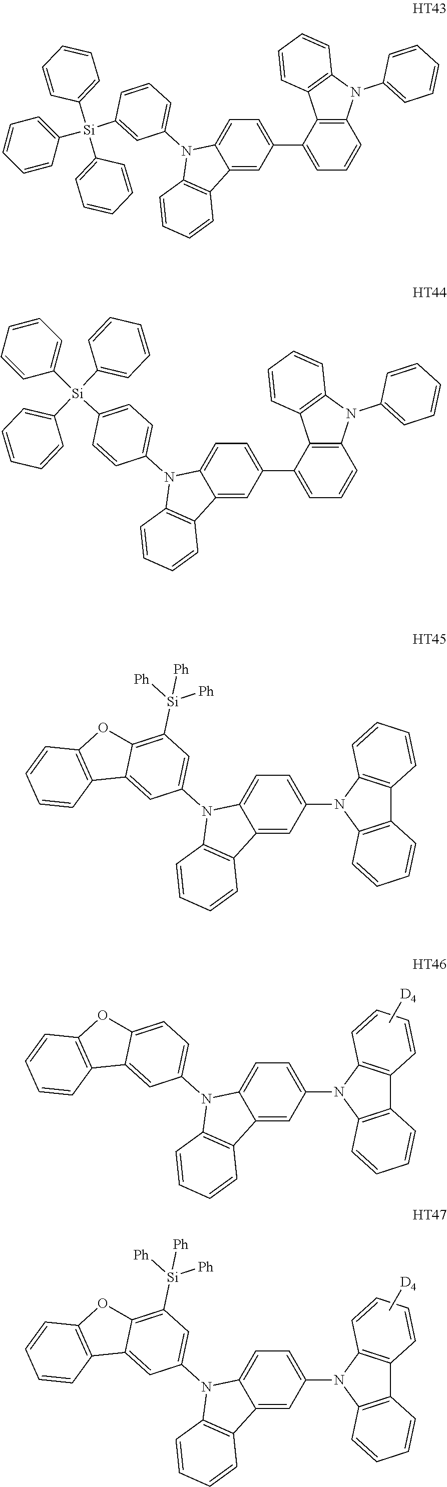

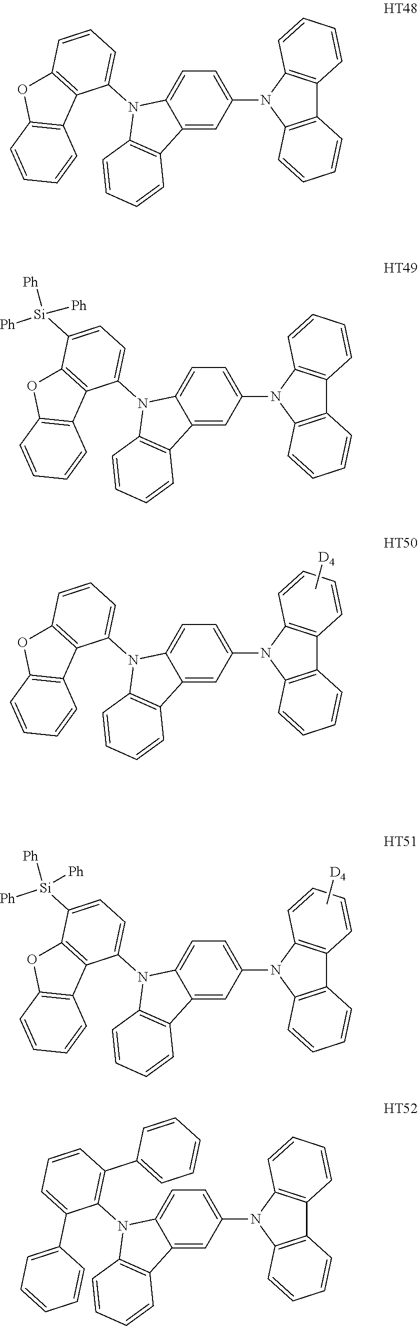

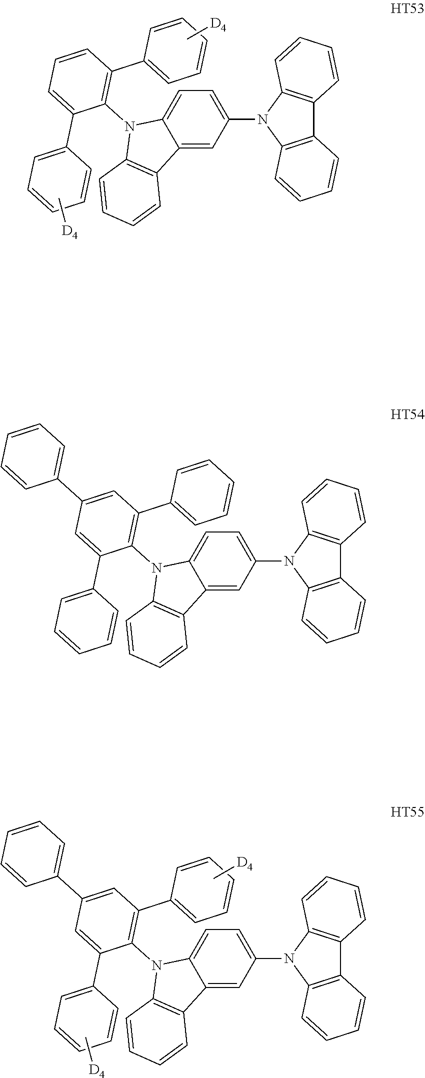

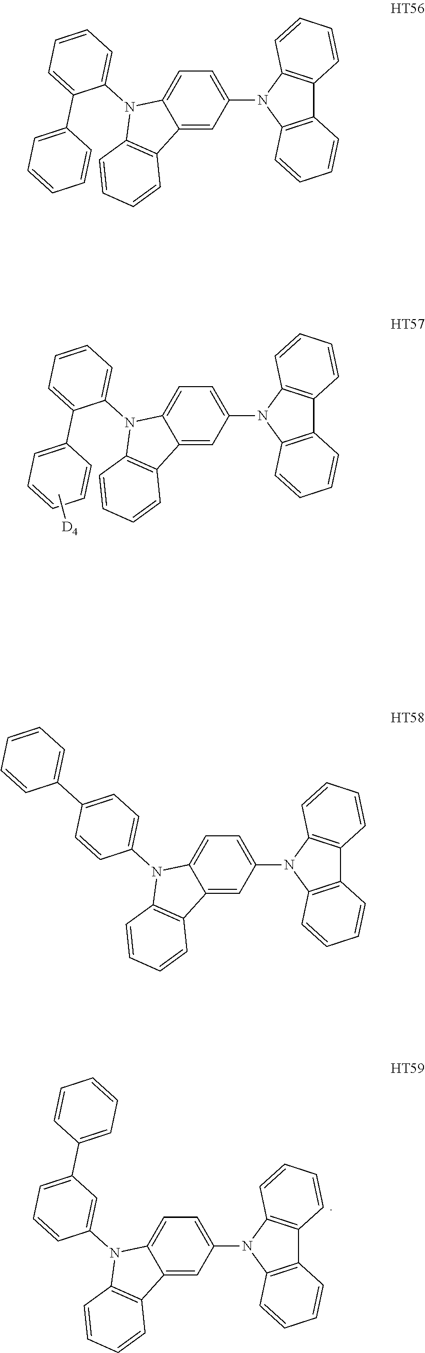

In the example compounds in Compound Group 2, “D” refers to deuterium, and “Ph” may refer to a substituted or unsubstituted phenyl group. For example, in the example compounds in Compound Group 2, “Ph” may be an unsubstituted phenyl group.

In one or more embodiments, the emission layer EML may include a third compound represented by Formula ET-1. For example, in one or more embodiments, the third compound may be utilized as an electron transport host material in the emission layer EML.

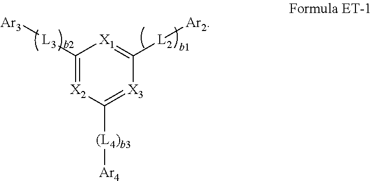

In Formula ET-1, at least one selected from among X₁ to X₃ may be N, and the remainder may be CR₅₆. For example, in some embodiments, at least one selected from among X₁ to X₃ may be N, and the remainder two may each independently be CR₅₆. In these embodiments, the third compound represented by Formula ET-1 may include a pyridine moiety. In some embodiments, at least two selected from among X₁ to X₃ may be N, and the remainder may be CR₅₆. In these embodiments, the third compound represented by Formula ET-1 may include a pyrimidine moiety. In some embodiments, X₁ to X₃ may be all N. In these embodiments, the third compound represented by Formula ET-1 may include a triazine moiety.

In Formula ET-1, R₅₆ may be hydrogen, deuterium, a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 60 ring-forming carbon atoms.

In Formula ET-1, b1 to b3 may each independently be an integer of 0 to 10.

In Formula ET-1, Ar₂ to Ar₄ may each independently be hydrogen, deuterium, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. For example, in some embodiments, Ar₂ to Ar₄ may be substituted or unsubstituted phenyl groups or substituted or unsubstituted carbazole groups.

In Formula ET-1, L₂ to L₄ may each independently be a direct linkage, a substituted or unsubstituted arylene group of 6 to 30 ring-forming carbon atoms, or a substituted or unsubstituted heteroarylene group of 2 to 30 ring-forming carbon atoms. In some embodiments, when each of b1 to b3 is an integer of 2 or more, L₂(s) to L₄(s) may each independently be a substituted or unsubstituted arylene group of 6 to 30 ring-forming carbon atoms, or a substituted or unsubstituted heteroarylene group of 2 to 30 ring-forming carbon atoms.

In one or more embodiments, the third compound may be represented by any one selected from among compounds in Compound Group 3. The light emitting device ED of an embodiment may include any one selected from among the compounds in Compound Group 3.

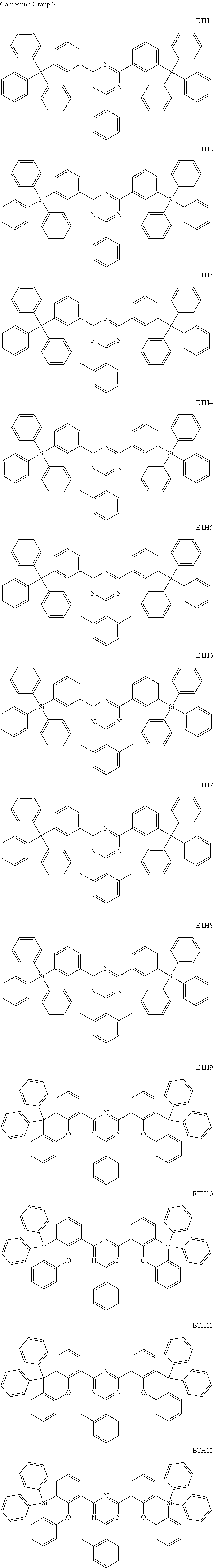

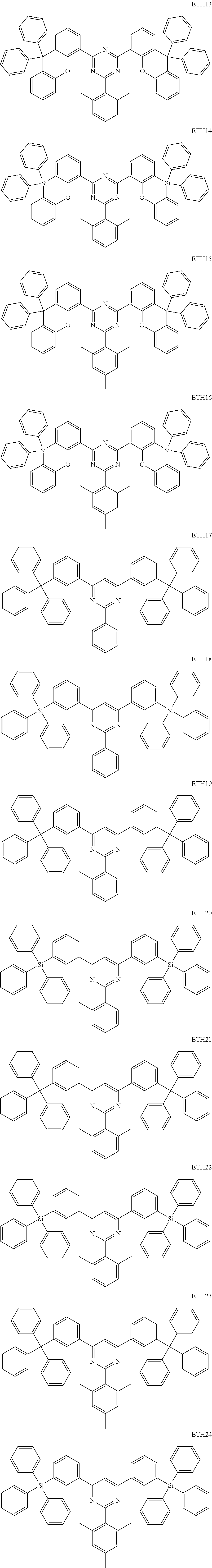

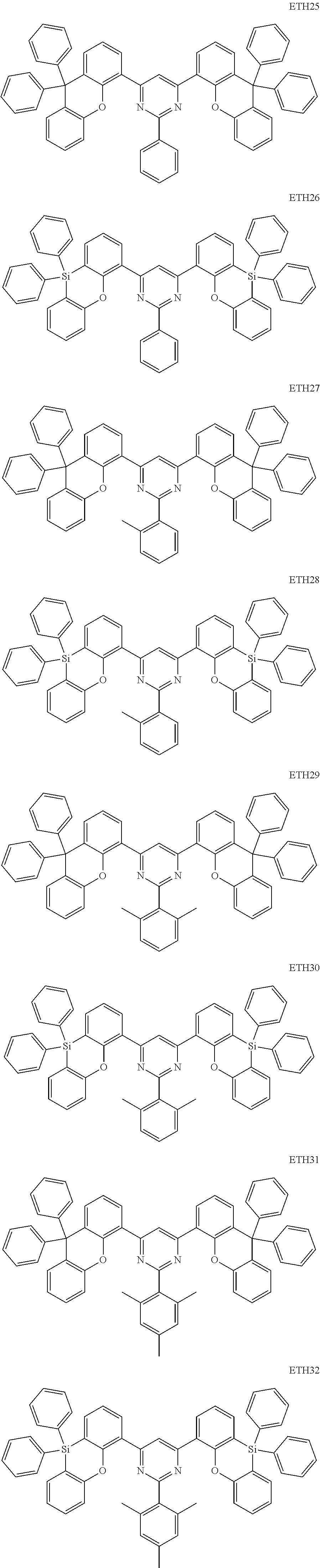

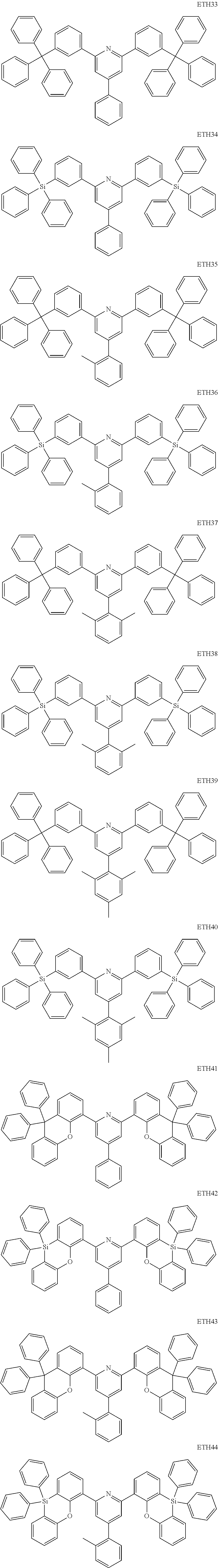

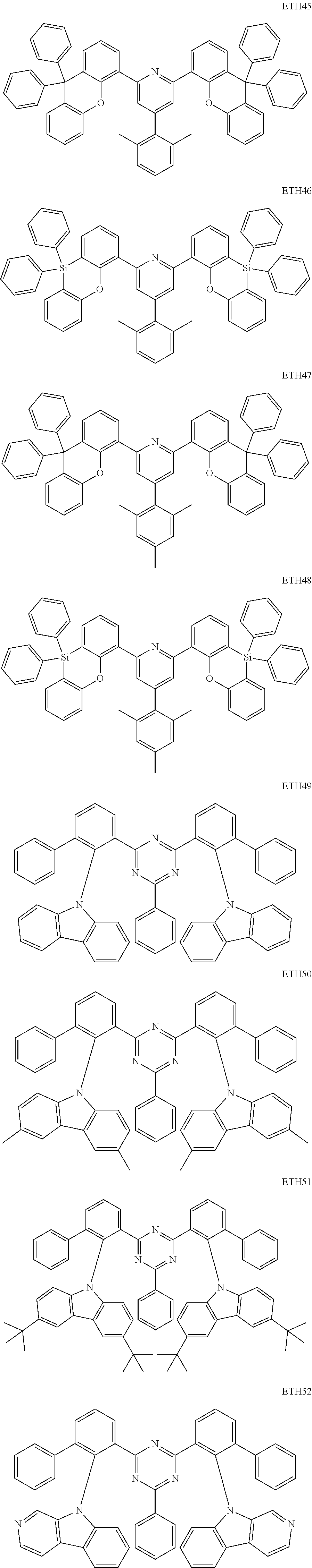

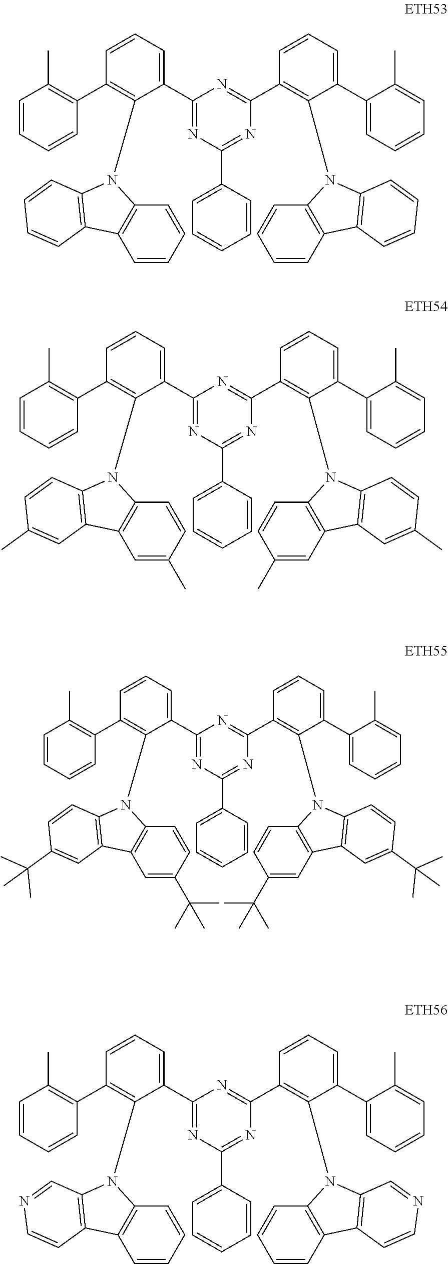

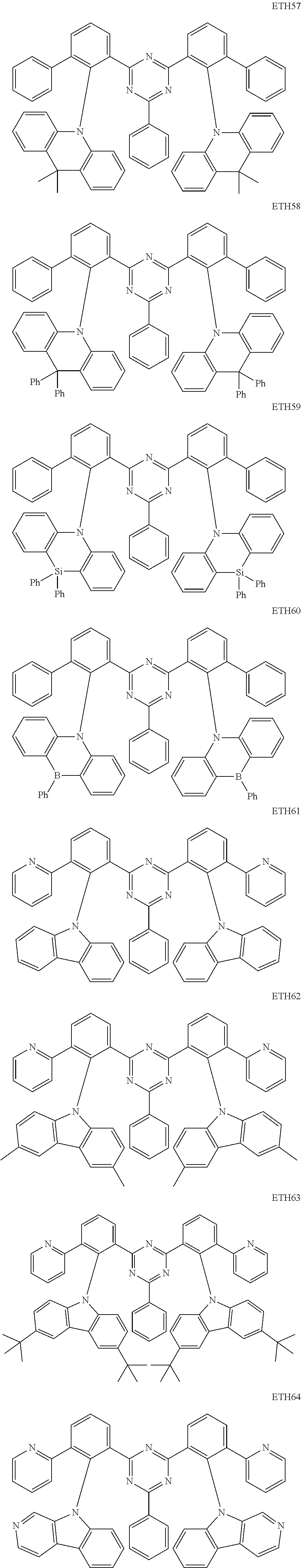

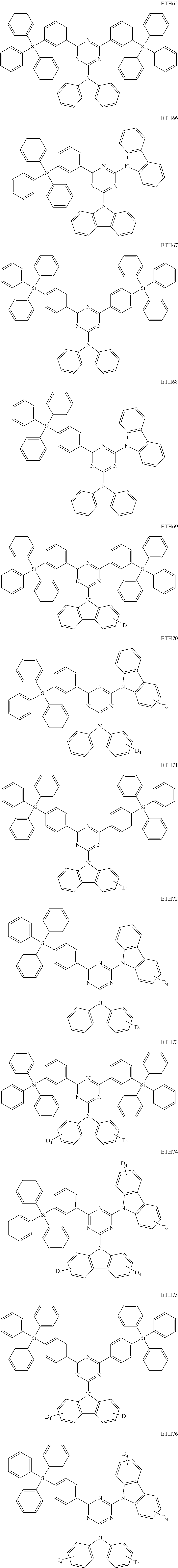

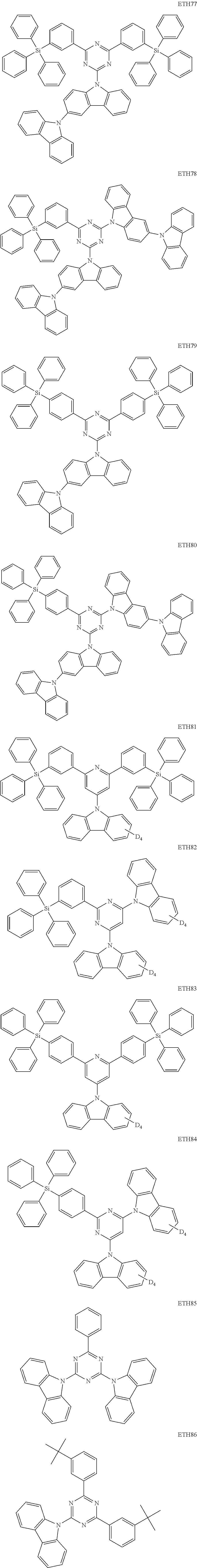

In the example compounds in Compound Group 3, “D” refers to deuterium, and “Ph” refers to an unsubstituted phenyl group.

In one or more embodiments, the emission layer EML may include the second compound and the third compound, and the second compound and the third compound may form exciplex. In the emission layer EML, exciplex may be formed by a hole transport host and an electron transport host. In this case, the triplet energy of the exciplex formed by the hole transport host and the electron transport host may correspond to a difference between the lowest unoccupied molecular orbital (LUMO) energy level of the electron transport host and the highest occupied molecular orbital (HOMO) energy level of the hole transport host.

For example, in one or more embodiments, the absolute value of the triplet energy level (T1) of the exciplex formed by a hole transport host and an electron transport host may be about 2.4 eV to about 3.0 eV. In some embodiments, the triplet energy of the exciplex may be a smaller value than the energy gap of each host material. The exciplex may have a triplet energy of about 3.0 eV or less, that is the energy gap between the hole transport host and the electron transport host.

In one or more embodiments, the emission layer EML may include a fourth compound in addition to the first compound to the third compound. The fourth compound may be utilized as a phosphorescence sensitizer of the emission layer EML. Because energy may transfer from the fourth compound to the first compound, light emission may arise.

For example, in one or more embodiments, the emission layer EML may include an organometallic complex including platinum (Pt) as a central metal atom and ligands bonded to the central metal atom, as the fourth compound. In the light emitting device ED of an embodiment, the emission layer EML may include a compound represented by Formula D-1 as the fourth compound.

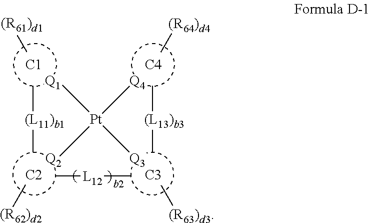

In Formula D-1, Q₁ to Q₄ may each independently be C or N.

In Formula D-1, C1 to C4 may each independently be a substituted or unsubstituted hydrocarbon ring of 5 to 30 ring-forming carbon atoms, or a substituted or unsubstituted heterocycle of 2 to 30 ring-forming carbon atoms.

In Formula D-1, L₁₁ to L₁₃ may each independently be a direct linkage,

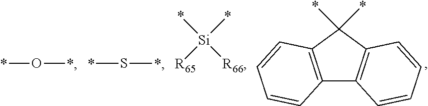

a substituted or unsubstituted alkylene group of 1 to 20 carbon atoms, a substituted or unsubstituted arylene group of 6 to 30 ring-forming carbon atoms, or a substituted or unsubstituted heteroarylene group of 2 to 30 ring-forming carbon atoms. In L₁₁ to L₁₃, “-*” refers to a part connected with C1 to C4.

In Formula D-1, b1 to b3 may each independently be 0 or 1. When b1 is 0, C1 and C2 may be unconnected. When b2 is 0, C2 and C3 may be unconnected. When b3 is 0, C3 and C4 may be unconnected.

In Formula D-1, R₆₁ to R₆₆ may each independently be hydrogen, deuterium, a halogen, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms. In some embodiments, each of R₆₁ to R₆₆ may be combined with an adjacent group to form a ring. In some embodiments, R₆₁ to R₆₆ may each independently be a substituted or unsubstituted methyl group, or a substituted or unsubstituted t-butyl group.

In Formula D-1, d1 to d4 may each independently be an integer of 0 to 4. In Formula D-1, when d1 to d4 (e.g., each independently) are 0, the fourth compound may be unsubstituted with corresponding R₆₁ to R₆₄. An embodiment in which d1 to d4 are (e.g., each independently) 4, and R₆₁ to R₆₄ are hydrogen, may be the same as an embodiment in which d1 to d4 are all 0. When d1 to d4 are integers of 2 or more (e.g., are each 2 or more), each of multiple R₆₁(s) to R₆₄(s) may be all the same, or at least one selected from among multiple R₆₁(s) to R₆₄(s) may be different.

In Formula D-1, C1 to C4 may each independently be a substituted or unsubstituted hydrocarbon ring or a substituted or unsubstituted heterocycle, represented by any one selected from among C-1 to C-4.

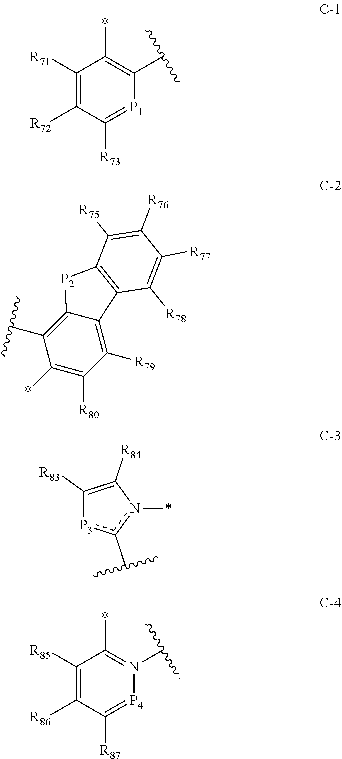

In C-1 to C-4, P₁ may be C—* or CR₇₄, P₂ may be N—* or NR₈₁, P₃ may be N—* or NR₈₂, and P₄ may be C—* or CR₈₈. R₇₁ to R₈₈ may each independently be a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring.

In C-1 to C-4,

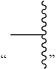

is a part connected with a central metal atom of Pt, and “-*” corresponds to a part connected with an adjacent ring group (C1 to C4) or linker (L₁₁ to L₁₃).

The emission layer EML of an embodiment may include the first compound that is a fused polycyclic compound of the present disclosure, and at least one selected from among the second to fourth compounds. For example, in some embodiments, the emission layer EML may include the first compound, the second compound and the third compound. In the emission layer EML, the second compound and the third compound may form exciplex, and via the exciplex, energy transfer to the first compound may arise, and light emission may arise.

In one or more embodiments, the emission layer EML may include the first compound, the second compound, the third compound, and the fourth compound. In the emission layer EML, the second compound and the third compound may form exciplex, and via the exciplex, energy transfer to the fourth compound and the first compound may arise, and light emission may arise. In some embodiments, the fourth compound may be a sensitizer. In the light emitting device ED of an embodiment, the fourth compound included in the emission layer EML may act as a sensitizer and may play the role of transferring energy from a host to the first compound that is a light-emitting dopant. For example, in some embodiments, the fourth compound that plays the role of an auxiliary dopant may accelerate energy transfer to the first compound that is a light emitting dopant and increase the light emitting ratio of the first compound. Accordingly, the emission efficiency of the emission layer EML of an embodiment may be improved. In some embodiments, when the energy transfer to the first compound increases, excitons formed in the emission layer EML may not be accumulated but rapidly emit light, and the deterioration of a device may be reduced. As a result, the lifetime of the light emitting device ED of an embodiment may increase.

The light emitting device ED of an embodiment may include all of the first compound, the second compound, the third compound, and the fourth compound, and the emission layer EML may include the combination of two host materials and two dopant materials. In the light emitting device ED of an embodiment, the emission layer EML may include the second compound and the third compound, which are two different hosts, the first compound which emits delayed fluorescence, and the fourth compound including an organometallic complex, concurrently (e.g., simultaneously), and may show excellent or suitable emission efficiency properties.

In one or more embodiments, the fourth compound represented by Formula D-1 may be represented by at least one selected from among compounds represented in Compound Group 4. In some embodiments, the emission layer EML may include at least one selected from among the compounds represented in Compound Group 4 as a sensitizer material.

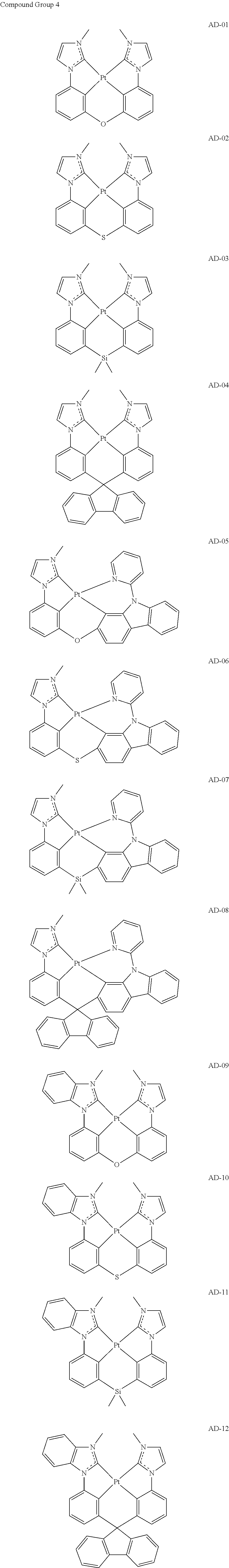

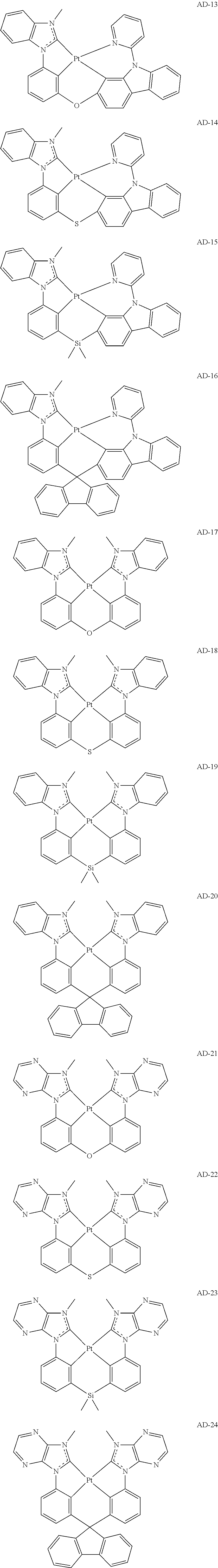

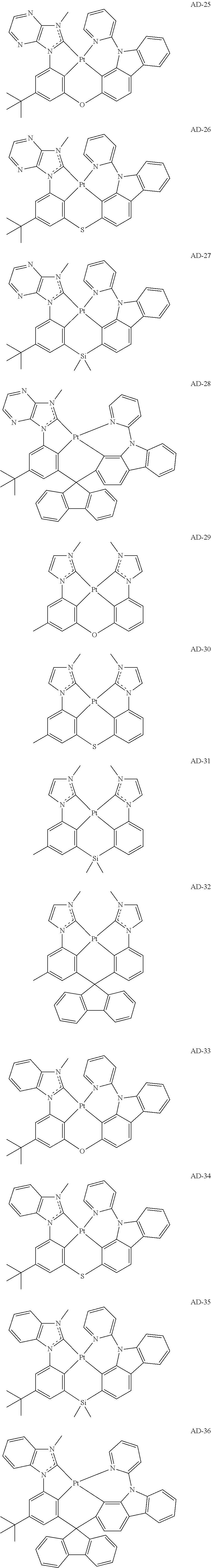

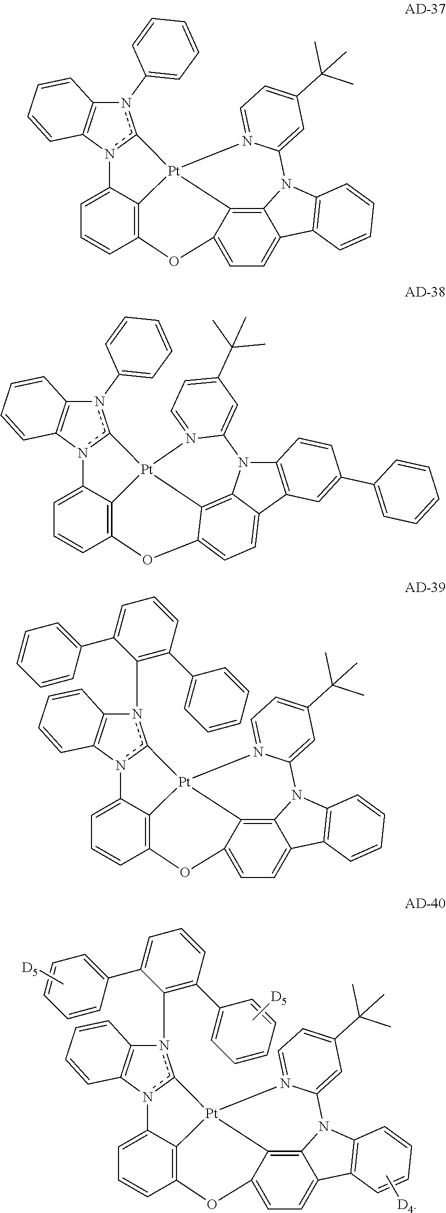

In the example compounds in Compound Group 4, “D” refers to deuterium.

In one or more embodiments, the light emitting device ED of an embodiment may include multiple emission layers. Multiple emission layers may be stacked in order and provided, and for example, a light emitting device ED including multiple emission layers may be to emit white light (e.g., combined white light). The light emitting device including multiple emission layers may be a light emitting device of a tandem structure. When the light emitting device ED includes multiple emission layers, at least one emission layer EML may include the first compound represented by Formula 1 of an embodiment. In some embodiments, when the light emitting device ED includes multiple emission layers, at least one emission layer EML may include all of the first compound, the second compound, the third compound, and the fourth compound as described above.

In the light emitting device ED of an embodiment, when the emission layer EML includes all of the first compound, the second compound, and the third compound, the amount of the first compound may be about 0.1 wt % to about 5 wt % based on the total weight of the first compound, the second compound, and the third compound. However, embodiments of the present disclosure are not limited thereto. When the amount of the first compound satisfies the above-described ratio, energy transfer from the second compound and the third compound to the first compound may increase, and accordingly, the emission efficiency and device lifetime may increase.

In the emission layer EML, the total amount of the second compound and the third compound may be the remaining amount excluding the amount of the first compound. For example, in one or more embodiments, the total amount of the second compound and the third compound may be about 65 wt % to about 95 wt % based on the total weight of the first compound, the second compound, and the third compound.

In the total amount of the second compound and the third compound, the weight ratio of the second compound and the third compound may be about 3:7 to about 7:3.

When the total amount of the second compound and the third compound satisfies the above-described ratio, charge balance properties in the emission layer EML may be improved, and emission efficiency and device lifetime may be improved and/or increased. When the total amount of the second compound and the third compound deviates from the above-described ratio range, charge balance in the emission layer EML may be broken, emission efficiency may be degraded and/or decreased, and the device may be easily deteriorated.

In one or more embodiments, When the emission layer EML includes the fourth compound, the amount of the fourth compound may be about 10 wt % to 30 wt % based on the total weight of the first compound, the second compound, the third compound, and the fourth compound in the emission layer EML. However, embodiments of the present disclosure are not limited thereto. When the amount of the fourth compound satisfies the above-described amount, energy transfer from a host to the first compound that is a light emitting dopant may increase, and emission ratio may be improved. Accordingly, the emission efficiency of the emission layer EML may be improved. When the amount ratio of the first compound, the second compound, the third compound, and the fourth compound, included in the emission layer EML satisfies the above-described amount ratio, excellent or suitable emission efficiency and long lifetime of the light emitting device may be achieved.

In the light emitting device ED of one or more embodiments, the emission layer EML may further include at least one of anthracene derivatives, pyrene derivatives, fluoranthene derivatives, chrysene derivatives, dihydrobenzanthracene derivatives, or triphenylene derivatives. For example, in one or more embodiments, the emission layer EML may include one or more anthracene derivatives and/or one or more pyrene derivatives.

In the light emitting devices ED of one or more embodiments, shown in FIG. 3 to FIG. 6, the emission layer EML may further include suitable hosts and dopants in addition to the above-described host and dopant. For example, in some embodiments, the emission layer EML may include a compound represented by Formula E-1. The compound represented by Formula E-1 may be utilized as a fluorescence host material.

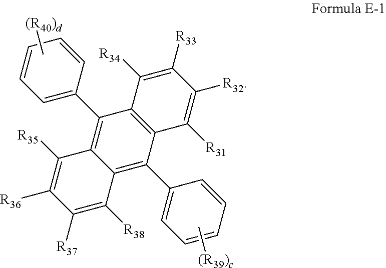

In Formula E-1, R₃₁ to R₄₀ may each independently be hydrogen, deuterium, a halogen, a substituted or unsubstituted silyl group, a substituted or unsubstituted thiol group, a substituted or unsubstituted oxy group, a substituted or unsubstituted alkyl group of 1 to 10 carbon atoms, a substituted or unsubstituted alkenyl group of 2 to 10 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring. In some embodiments, R₃₁ to R₄₀ may be combined with an adjacent group to form a saturated hydrocarbon ring, an unsaturated hydrocarbon ring, a saturated heterocycle, or an unsaturated heterocycle.

In Formula E-1, “c” and “d” may each independently be an integer of 0 to 5.

The compound represented by Formula E-1 may be any one selected from among Compound E1 to Compound E19.

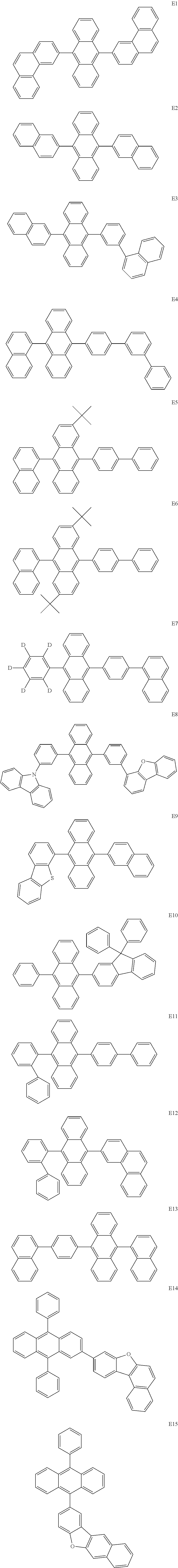

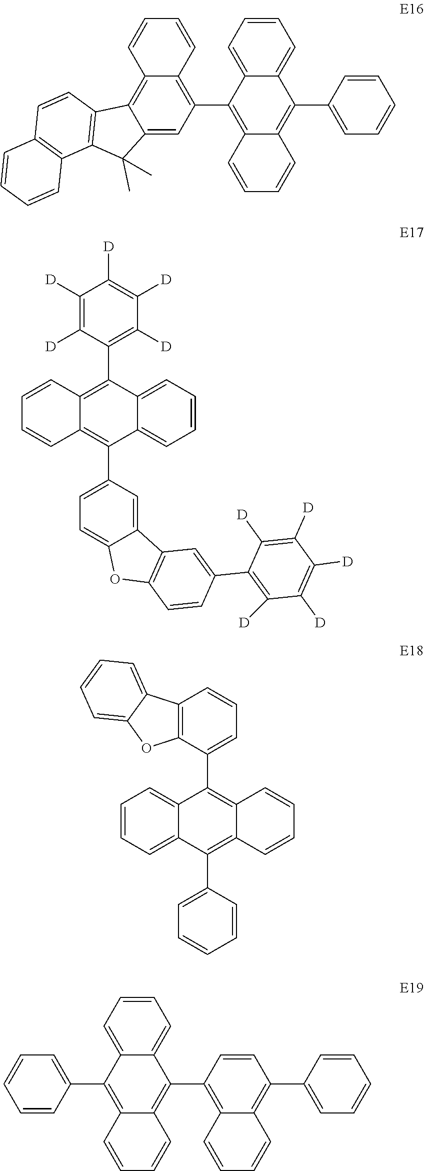

In one or more embodiments, the emission layer EML may include a compound represented by Formula E-2a or Formula E-2b. The compound represented by Formula E-2a or Formula E-2b may be utilized as a phosphorescence host material.

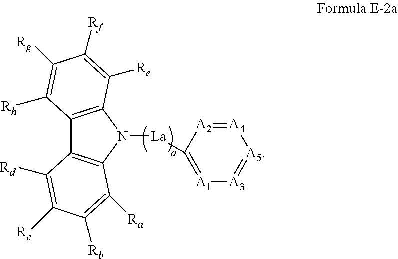

In Formula E-2a, “a” may be an integer of 0 to 10, La may be a direct linkage, a substituted or unsubstituted arylene group of 6 to 30 ring-forming carbon atoms, or a substituted or unsubstituted heteroarylene group of 2 to 30 ring-forming carbon atoms. In some embodiments, when “a” is an integer of 2 or more, multiple La(s) may each independently be a substituted or unsubstituted arylene group of 6 to 30 ring-forming carbon atoms, or a substituted or unsubstituted heteroarylene group of 2 to 30 ring-forming carbon atoms.

In some embodiments, in Formula E-2a, A₁ to A₅ may each independently be N or CRI. Rₐ to Rᵢ may each independently be hydrogen, deuterium, a substituted or unsubstituted amine group, a substituted or unsubstituted thiol group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, and/or may be combined with an adjacent group to form a ring. In some embodiments, Rₐ to Rᵢ may be combined with an adjacent group to form a hydrocarbon ring or a heterocycle including N, O, S, etc. as a ring-forming atom.

In some embodiments, in Formula E-2a, two or three selected from A₁ to A₅ may be N, and the remainder may be CRI.

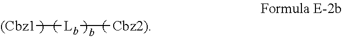

In Formula E-2b, Cbz1 and Cbz2 may each independently be an unsubstituted carbazole group, or a carbazole group substituted with an aryl group of 6 to 30 ring-forming carbon atoms. L_{b} may be a direct linkage, a substituted or unsubstituted arylene group of 6 to 30 ring-forming carbon atoms, or a substituted or unsubstituted heteroarylene group of 2 to 30 ring-forming carbon atoms. “b” is an integer of 0 to 10, and when “b” is an integer of 2 or more, multiple L_{b}(s) may each independently be a substituted or unsubstituted arylene group of 6 to 30 ring-forming carbon atoms, or a substituted or unsubstituted heteroarylene group of 2 to 30 ring-forming carbon atoms.

The compound represented by Formula E-2a or Formula E-2b may be any one selected from among compounds in Compound Group E-2. However, the compounds shown in Compound Group E-2 are only examples, and the compound represented by Formula E-2a or Formula E-2b is not limited to the compounds represented in Compound Group E-2.

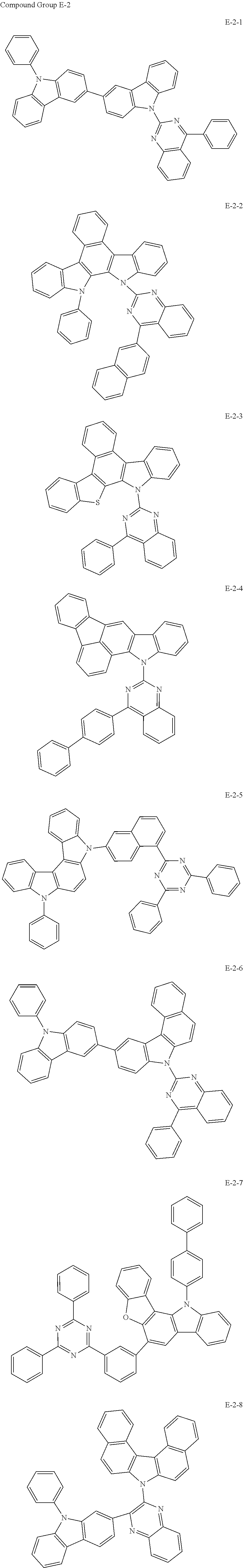

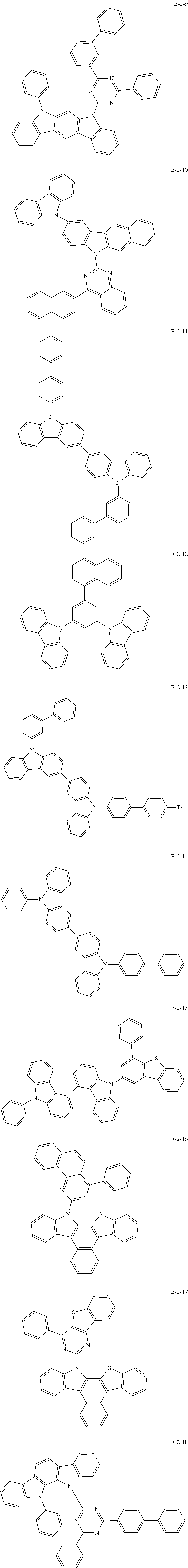

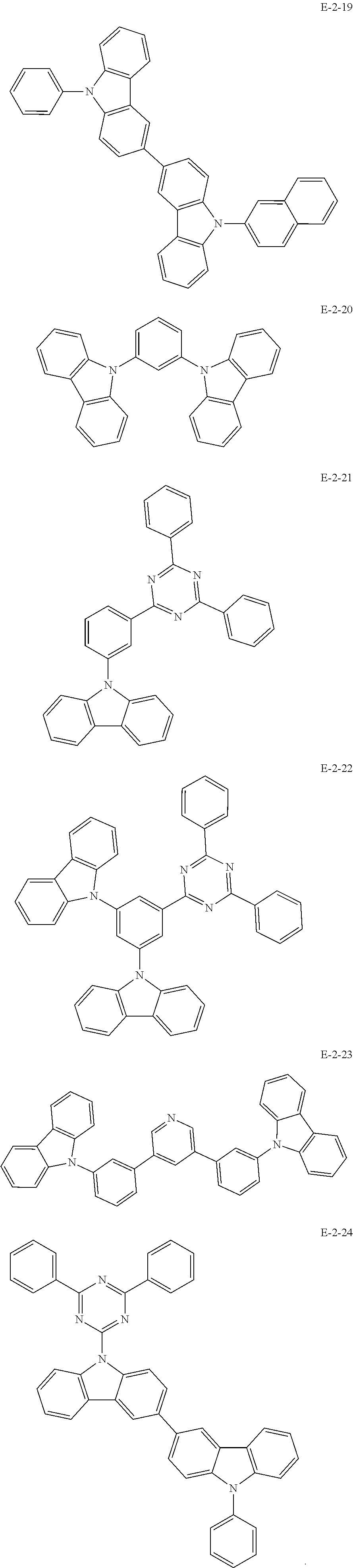 [SMILES: c1ccc(-n2c3ccccc3c3cc(-c4ccc5c(c4)c4ccccc4n5-c4ccc5ccccc5c4)ccc32)cc1 ; c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

In one or more embodiments, the emission layer EML may further include a material well-suitable in the art as a host material. For example, the emission layer EML may include as a host material, at least one of bis (4-(9H-carbazol-9-yl) phenyl) diphenylsilane (BCPDS), (4-(1-(4-(diphenylamino) phenyl) cyclohexyl) phenyl) diphenyl-phosphine oxide (POPCPA), bis[2-(diphenylphosphino)phenyl] ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), or 1,3,5-tris(1-phenyl-1H-benzo[d]imidazole-2-yl)benzene (TPBi). However, embodiments of the present disclosure are not limited thereto. For example, tris(8-hydroxyquinolinato)aluminum (Alq₃), 9,10-di(naphthalen-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetra siloxane (DPSiO₄), etc. may be utilized as the host material.

In one or more embodiments, the emission layer EML may include a compound represented by Formula M-a. The compound represented by Formula M-a may be utilized as a phosphorescence dopant material.

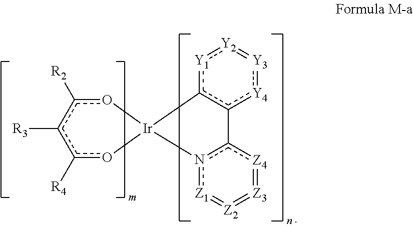

In Formula M-a, Y₁ to Y₄, and Z₁ to Z₄ may each independently be CR₁ or N, and R₁ to R₄ may each independently be hydrogen, deuterium, a substituted or unsubstituted amine group, a substituted or unsubstituted thiol group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, and/or may be combined with an adjacent group to form a ring. In Formula M-a, “m” is 0 or 1, and “n” is 2 or 3. In Formula M-a, when “m” is 0, “n” is 3, and when “m” is 1, “n” is 2.

The compound represented by Formula M-a may be utilized as a phosphorescence dopant.

The compound represented by Formula M-a may be any one selected from among Compounds M-a1 to M-a25. However, Compounds M-a1 to M-a25 are mere examples, and the compound represented by Formula M-a is not limited to the compounds represented by Compounds M-a1 to M-a25.

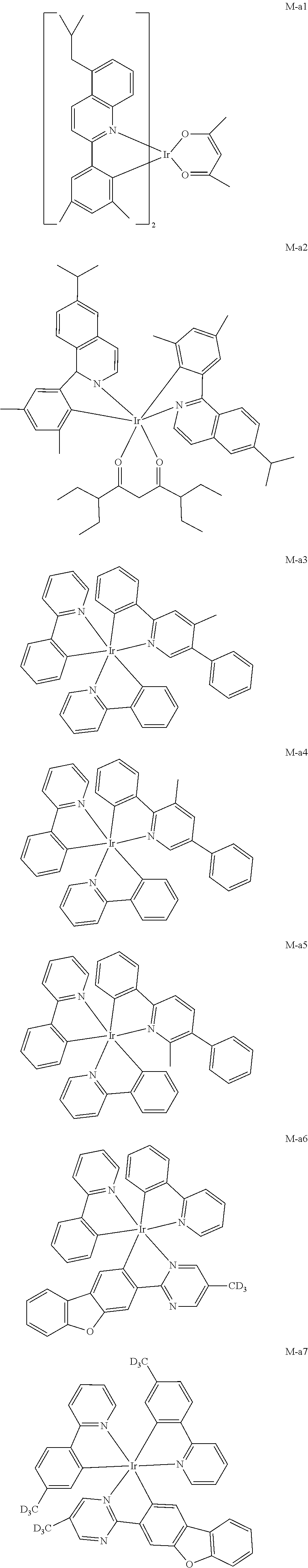

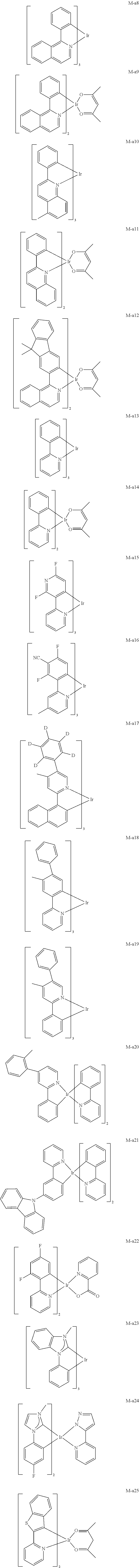

In one or more embodiments, the emission layer EML may further include a compound represented by any one selected from among Formula F-a to Formula F-c. The compounds represented by Formula F-a to Formula F-c may be utilized as fluorescence dopant materials.

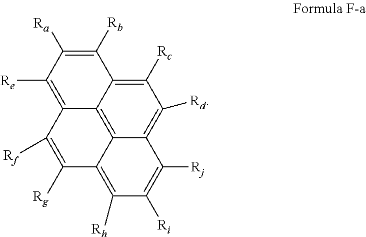

In Formula F-a, two selected from Rₐ to Rⱼ may each independently be substituted with *—NAr₁Ar₂. The remainder not substituted with *—NAr₁Ar₂ among Rₐ to Rⱼ may each independently be hydrogen, deuterium, a halogen, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In *—NAr₁Ar₂, Ar₁ and Ar₂ may each independently be a substituted or unsubstituted aryl group of 6 to 30 ring-forming carbon atoms, or a substituted or unsubstituted heteroaryl group of 2 to 30 ring-forming carbon atoms. For example, in some embodiments, at least one selected from among Ar₁ and Ar₂ may be a heteroaryl group including O or S as a ring-forming atom.

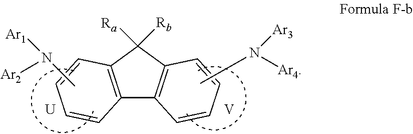

In Formula F-b, Rₐ and R_{b} may each independently be hydrogen, deuterium, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, and/or may be combined with an adjacent group to form a ring. Ar₁ to Ar₄ may each independently be a substituted or unsubstituted aryl group of 6 to 30 ring-forming carbon atoms, or a substituted or unsubstituted heteroaryl group of 2 to 30 ring-forming carbon atoms.

In Formula F-b, U and V may each independently be a substituted or unsubstituted hydrocarbon ring of 5 to 30 ring-forming carbon atoms, or a substituted or unsubstituted heterocycle of 2 to 30 ring-forming carbon atoms. In some embodiments, at least one selected from among Ar₁ to Ar₄ may be a heteroaryl group including O or S as a ring-forming atom.

In Formula F-b, the number of rings represented by U and V may each independently be 0 or 1. For example, in Formula F-b, when the number of U or V is 1, one ring forms a fused ring at the designated part by U or V, and when the number of U or V is 0, a ring is not present at the designated part by U or V. For example, when the number of U is 0, and the number of V is 1, or when the number of U is 1, and the number of V is 0, a fused ring having the fluorene core of Formula F-b may be a ring compound with four rings. In some embodiments, when the number of both (e.g., simultaneously) U and V is 0, the fused ring of Formula F-b may be a ring compound with three rings. In some embodiments, when the number of both (e.g., simultaneously) U and V is 1, a fused ring having the fluorene core of Formula F-b may be a ring compound with five rings.

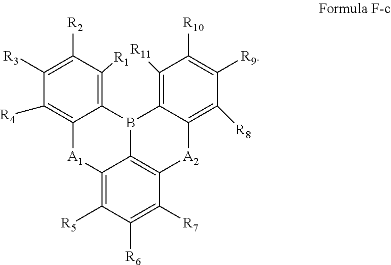

In Formula F-c, A₁ and A₂ may each independently be O, S, Se, or NRₘ, and Rₘ may be hydrogen, deuterium, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. R₁ to R₁₁ may each independently be hydrogen, deuterium, a halogen, a cyano group, a substituted or unsubstituted amine group, a substituted or unsubstituted boryl group, a substituted or unsubstituted oxy group, a substituted or unsubstituted thiol group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring.

In Formula F-c, A₁ and A₂ may each independently be combined with the substituents of an adjacent ring to form a fused ring. For example, when A₁ and A₂ may each independently be NRₘ, A₁ may be combined with R₄ or R₅ to form a ring. In some embodiments, A₂ may be combined with R₇ or R₈ to form a ring.

In one or more embodiments, the emission layer EML may include as a suitable dopant material, one or more selected from styryl derivatives (for example, 1,4-bis[2-(3-N-ethylcarbazoryl)vinyl]benzene (BCzVB), 4-(di-p-tolylamino)-4′-[(di-p-tolylamino)styryl]stilbene (DPAVB), N-(4-((E)-2-(6-((E)-4-(diphenylamino)styryl)naphthalen-2-yl)vinyl)phenyl)-N-phenylbenzenamine (N-BDAVBi), and 4,4′-bis[2-(4-(N,N-diphenylamino)phenyl)vinyl]biphenyl (DPAVBi)), perylene and the derivatives thereof (for example, 2,5,8,11-tetra-t-butylperylene (TBP)), pyrene and the derivatives thereof (for example, 1,1-dipyrene, 1,4-dipyrenylbenzene, and 1,4-bis(N,N-diphenylamino)pyrene), etc.

In one or more embodiments, the emission layer EML may include a suitable phosphorescence dopant material. For example, the phosphorescence dopant may utilize a metal complex including iridium (Ir), platinum (Pt), osmium (Os), gold (Au), titanium (Ti), zirconium (Zr), hafnium (Hf), europium (Eu), terbium (Tb), or thulium (Tm). For example, iridium(III) bis(4,6-difluorophenylpyridinato-N,C2′)picolinate (Firpic), bis(2,4-difluorophenylpyridinato)-tetrakis(1-pyrazolyl)borate iridium(III) (Fir6), or platinum octaethyl porphyrin (PtOEP) may be utilized as the phosphorescence dopant material. However, embodiments of the present disclosure are not limited thereto.

In one or more embodiments, the emission layer may include quantum dots.

In the present disclosure, the quantum dot refers to a crystal of a semiconductor compound. The quantum dot may be to emit light having one or more suitable emission wavelengths depending on the size of crystal. The quantum dot may be to emit light having one or more suitable emission wavelengths as the elemental ratio in the quantum dot compound is adjusted.

The quantum dot may have a diameter of, for example, about 1 nm to about 10 nm.

The quantum dot may be synthesized by a wet chemical process, a metal organic chemical vapor deposition process, a molecular beam epitaxy process, a similar process thereto, and/or the like.

The wet chemical process is a method in which a precursor material of the quantum dot is mixed with an organic solvent to grow quantum dot particle crystals. When the crystals grow, the organic solvent naturally may act as a dispersant coordinated on the surface of the quantum dot crystals and control the growth of the crystals. Thus, the wet chemical process may control the growth of quantum dot particles through a process which is more easily performed than vapor deposition methods, such as metal organic chemical vapor deposition (MOCVD) or molecular beam epitaxy (MBE), and which is performed at low costs.

In one or more embodiments, the emission layer EML may include a quantum dot material. In one or more embodiments, the quantum dot material may have a core/shell structure. The core of the quantum dot may be selected from a II-VI group compound, a III-VI group compound, a I-III-VI group compound, a III-V group compound, a III-II-V group compound, a IV-VI group compound, a IV group element, a IV group compound, and combinations thereof.

The II-VI group compound may be selected from the group consisting of: a binary compound selected from the group consisting of CdSe, CdTe, CdS, ZnS, ZnSe, ZnTe, ZnO, HgS, HgSe, HgTe, MgSe, MgS, and mixtures thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and mixtures thereof; and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, and mixtures thereof.

The III-VI group compound may include a binary compound such as In₂S₃ and/or In₂Se₃, a ternary compound such as InGaS₃ and/or InGaSe₃, or one or more combinations thereof.

The I-III-VI group compound may be selected from a ternary compound selected from the group consisting of AgInS, AgInS₂, CuInS, CuInS₂, AgGaS₂, CuGaS₂, CuGaO₂, AgGaO₂, AgAlO₂ and mixtures thereof, and/or a quaternary compound such as AgInGaS₂ and/or CuInGaS₂.

The III-V group compound may be selected from the group consisting of a binary compound selected from the group consisting of GaN, GaP, GaAs, GaSb, AlN, AlP, AIAs, AISb, InN, InP, InAs, InSb, and mixtures thereof, a ternary compound selected from the group consisting of GaNP, GaNAs, GaNSb, GaPAs, GaPSb, AlNP, AlNAs, AlNSb, AIPAs, AIPSb, InGaP, InAIP, InNP, InNAs, InNSb, InPAs, InPSb, and mixtures thereof, and a quaternary compound selected from the group consisting of GaAINP, GaAINAs, GaAINSb, GaAIPAs, GaAIPSb, GaInNP, GaInNAs, GalnNSb, GaInPAs, GalnPSb, InAINP, InAINAs, InAINSb, InAIPAs, InAIPSb, and mixtures thereof. In some embodiments, the III-V group compound may further include a II group metal. For example, InZnP, etc. may be selected as a III-II-V group compound.

The IV-VI group compound may be selected from the group consisting of a binary compound selected from the group consisting of SnS, SnSe, SnTe, PbS, PbSe, PbTe, and mixtures thereof, a ternary compound selected from the group consisting of SnSeS, SnSeTe, SnSTe, PbSeS, PbSeTe, PbSTe, SnPbS, SnPbSe, SnPbTe, and mixtures thereof, and a quaternary compound selected from the group consisting of SnPbSSe, SnPbSeTe, SnPbSTe, and mixtures thereof. The IV group element may be selected from the group consisting of Si, Ge, and a mixture thereof. The IV group compound may be a binary compound selected from the group consisting of SiC, SiGe, and a mixture thereof.

In one or more embodiments, constituting elements of the binary compound, the ternary compound, or the quaternary compound may be present at substantially uniform concentration in a particle or may be present at a partially different concentration distribution within the same particle. In some embodiments, a core/shell structure in which one quantum dot wraps another quantum dot may be desirable. The interface of the core and the shell may have a concentration gradient in which the concentration of an element present in the shell is decreased toward the center.

In some embodiments, the quantum dot may have the above-described core-shell structure including a core including a nanocrystal and a shell wrapping the core. The shell of the quantum dot may play the role of a protection layer for preventing or reducing the chemical deformation of the core to maintain semiconductor properties and/or a charging layer for imparting the quantum dot with electrophoretic properties. The shell may have a single layer or a multilayer. Examples of the shell of the quantum dot may include a metal or non-metal oxide, a semiconductor compound, or combinations thereof.

For example, the metal or non-metal oxide for the shell may include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, and/or NiO, and/or a ternary compound such as MgAl₂O₄, CoFe₂O₄, NiFe₂O₄, and/or CoMn₂O₄, but embodiments of the present disclosure are not limited thereto.

Also, the semiconductor compound suitable as a shell may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AISb, etc., but embodiments of the present disclosure are not limited thereto.

The quantum dot may have a full width of half maximum (FWHM) of emission spectrum of about 45 nm or less, about 40 nm or less, or, about 30 nm or less. Within this range, the color purity or color reproducibility of the light emitting device may be improved. In some embodiments, light emitted via such quantum dots is emitted in all directions, and light view angle properties may be improved.

In some embodiments, the shape of the quantum dot may be generally utilized shapes in the art, without specific limitation. In one or more embodiments, the shape of substantially spherical, pyramidal, multi-arm, or cubic nanoparticle, nanotube, nanowire, nanofiber, nanoplate particle, etc. may be utilized.

The quantum dot may control the color of light emitted according to the particle size, and accordingly, the quantum dot may have one or more suitable emission colors such as blue, red, and green.

In the light emitting devices ED of one or more embodiments, as shown in FIG. 3 to FIG. 6, the electron transport region ETR may be provided on the emission layer EML. The electron transport region ETR may include at least one of an electron blocking layer HBL, an electron transport layer ETL or an electron injection layer EIL. However, embodiments of the present disclosure are not limited thereto.

The electron transport region ETR may have a single layer formed utilizing a single material, a single layer formed utilizing multiple different materials, or a multilayer structure having multiple layers formed utilizing multiple different materials.

For example, in some embodiments, the electron transport region ETR may have a single layer structure of an electron injection layer EIL or an electron transport layer ETL, or a single layer structure formed utilizing an electron injection material and an electron transport material. Further, in some embodiments, the electron transport region ETR may have a single layer structure formed utilizing multiple different materials, or a structure stacked from the emission layer EML of electron transport layer ETL/electron injection layer EIL, or hole blocking layer HBL/electron transport layer ETL/electron injection layer EIL, without limitation. A thickness of the electron transport region ETR may be, for example, from about 1,000 Å to about 1,500 Å.

The electron transport region ETR may be formed utilizing one or more suitable methods such as a vacuum deposition method, a spin coating method, a casting method, a Langmuir-Blodgett (LB) method, an inkjet printing method, a laser printing method, and/or a laser induced thermal imaging (LITI) method.

In one or more embodiments, the electron transport region ETR may include a compound represented by Formula ET-2.

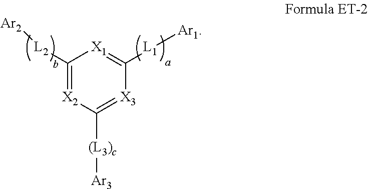

In Formula ET-2, at least one selected from among X₁ to X₃ may be N, and the remainder are CRₐ. Rₐ may be hydrogen, deuterium, a substituted or unsubstituted alkyl of 1 to 20 carbon atoms, a substituted or unsubstituted aryl group of 6 to 30 ring-forming carbon atoms, or a substituted or unsubstituted heteroaryl group of 2 to 30 ring-forming carbon atoms. Ar₁ to Ar₃ may each independently be hydrogen, deuterium, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In Formula ET-2, “a” to “c” may each independently be an integer of 0 to 10. In Formula ET-2, L₁ to L₃ may each independently be a direct linkage, a substituted or unsubstituted arylene group of 6 to 30 ring-forming carbon atoms, or a substituted or unsubstituted heteroarylene group of 2 to 30 ring-forming carbon atoms. In some embodiments, when “a” to “c” are integers of 2 or more, L₁(s) to L₃(s) may each independently be a substituted or unsubstituted arylene group of 6 to 30 ring-forming carbon atoms, or a substituted or unsubstituted heteroarylene group of 2 to 30 ring-forming carbon atoms.

In one or more embodiments, the electron transport region ETR may include an anthracene-based compound. However, embodiments of the present disclosure are not limited thereto, and, in some embodiments, the electron transport region ETR may include, for example, at least one selected from among tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzimidazolyl-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(biphenyl-4-yl)-4-phenyl-5-tert-butylphenyl-1,2,4-triazole (TAZ), 4-(naphthalen-1-yl)-3,5-diphenyl-4H-1,2,4-triazole (NTAZ), 2-(biphenyl-4-yl)-5-(4-tert-butylphenyl)-1,3,4-oxadiazole (tBu-PBD), bis(2-methyl-8-quinolinolato-N1,O8)-(1,1′-biphenyl-4-olato)aluminum (BAIq), berylliumbis(benzoquinolin-10-olate) (Bebq₂), 9,10-di(naphthalen-2-yl)anthracene (ADN), 1,3-bis[3,5-di(pyridin-3-yl)phenyl]benzene (BmPyPhB), and mixtures thereof, without limitation.

In one or more embodiments, the electron transport region ETR may include at least one selected from among Compounds ET1 to ET36.

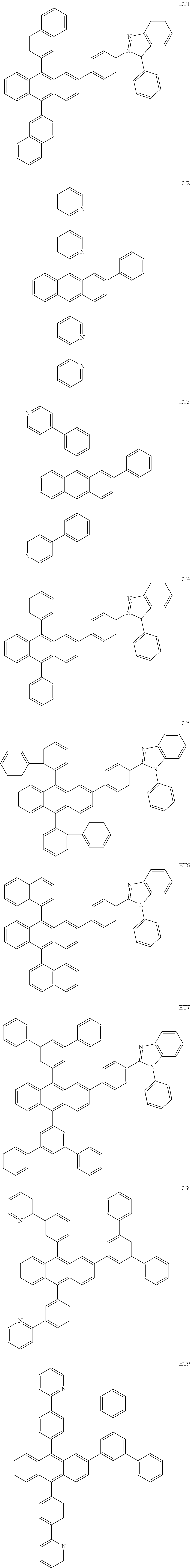

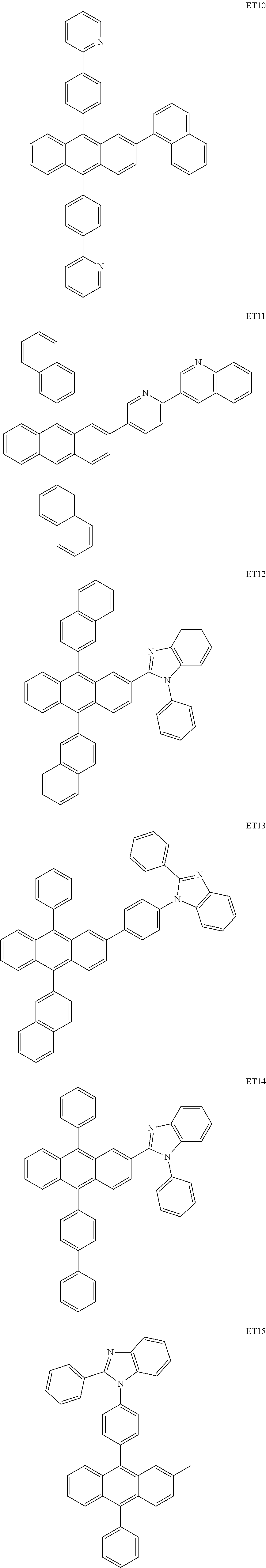 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1 ; c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1]

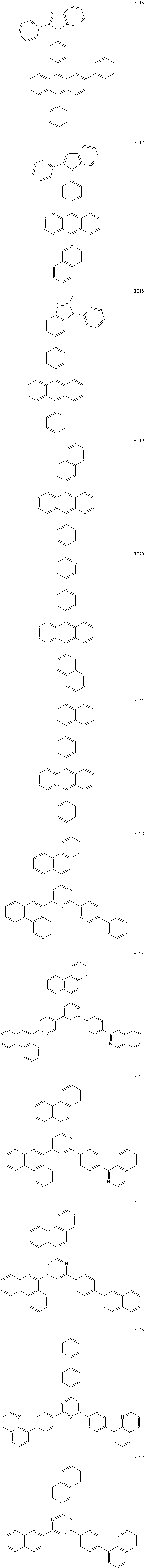

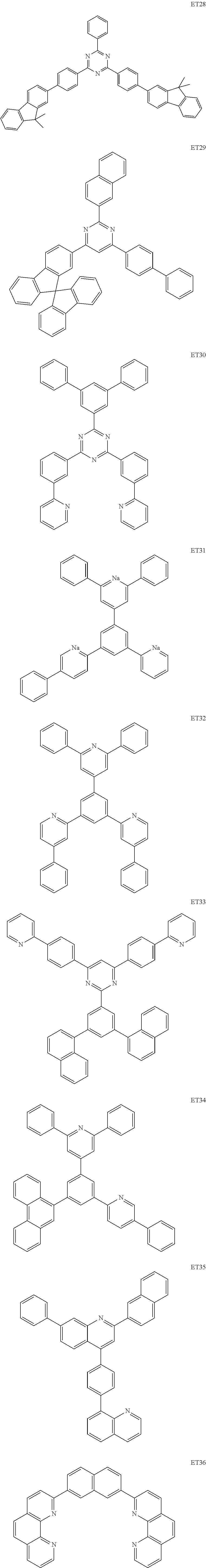

In some embodiments, the electron transport region ETR may include a metal halide such as LiF, NaCl, CsF, RbCI, RbI, CuI, and/or KI, a lanthanide metal such as Yb, or a co-depositing material of the metal halide and the lanthanide metal. For example, in some embodiments, the electron transport region ETR may include KILYb, RbI—Yb, LiF:Yb, etc., as the co-depositing material. In some embodiments, the electron transport region ETR may utilize a metal oxide such as Li₂O and/or BaO, or 8-hydroxy-lithium quinolate (Liq). However, embodiments of the present disclosure are not limited thereto. In some embodiments, the electron transport region ETR also may be formed utilizing a mixture material of an electron transport material and an insulating organo metal salt. The organo metal salt may be a material having an energy band gap of about 4 eV or more. For example, the organo metal salt may include, for example, metal acetates, metal benzoates, metal acetoacetates, metal acetylacetonates, and/or metal stearates.

In one or more embodiments, the electron transport region ETR may include at least one of 2,9-dimethyl-4,7-diphenyl-1,10-phenanthroline (BCP), diphenyl(4-(triphenylsilyl)phenyl)phosphine oxide (TSPO1), or 4,7-diphenyl-1,10-phenanthroline (Bphen) in addition to the aforementioned materials. However, embodiments of the present disclosure are not limited thereto.

The electron transport region ETR may include the compounds of the electron transport region in at least one selected from among an electron injection layer EIL, an electron transport layer ETL, and a hole blocking layer HBL.

When the electron transport region ETR includes an electron transport layer ETL, a thickness of the electron transport layer ETL may be from about 100 Å to about 1,000 Å, for example, from about 150 Å to about 500 Å. When the thickness of the electron transport layer ETL satisfies the above-described range, satisfactory electron transport properties may be obtained without a substantial increase in driving voltage. When the electron transport region ETR includes an electron injection layer EIL, a thickness of the electron injection layer EIL may be from about 1 Å to about 100 Å, or from about 3 Å to about 90 Å. When the thickness of the electron injection layer EIL satisfies the above described range, satisfactory electron injection properties may be obtained without inducing a substantial increase in driving voltage.

The second electrode EL2 may be provided on the electron transport region ETR. The second electrode EL2 may be a common electrode. The second electrode EL2 may be a cathode or an anode, but embodiments of the present disclosure are not limited thereto. For example, when the first electrode EL1 is an anode, the second cathode EL2 may be a cathode, and when the first electrode EL1 is a cathode, the second electrode EL2 may be an anode.

The second electrode EL2 may be a transmissive electrode, a transflective electrode, or a reflective electrode. When the second electrode EL2 is the transmissive electrode, the second electrode EL2 may include a transparent metal oxide, for example, ITO, IZO, ZnO, ITZO, etc.

When the second electrode EL2 is the transflective electrode or the reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, compounds thereof, or mixtures thereof (for example, AgMg, AgYb, or MgYb). In some embodiments, the second electrode EL2 may have a multilayered structure including a reflective layer or a transflective layer formed utilizing one or more selected from the above-described materials and a transparent conductive layer formed utilizing ITO, IZO, ZnO, ITZO, etc. For example, the second electrode EL2 may include one or more selected from the aforementioned metal materials, combinations of two or more metal materials selected from the aforementioned metal materials, or oxides of the aforementioned metal materials.

In some embodiments, the second electrode EL2 may be connected with an auxiliary electrode. When the second electrode EL2 is connected with the auxiliary electrode, the resistance of the second electrode EL2 may decrease.

In one or more embodiments, on the second electrode EL2 in the light emitting device ED, a capping layer CPL may be further disposed. The capping layer CPL may include a multilayer or a single layer.

In one or more embodiments, the capping layer CPL may be an organic layer or an inorganic layer. For example, in some embodiments, when the capping layer CPL includes an inorganic material, the inorganic material may include an alkali metal compound such as LiF, an alkaline earth metal compound such as MgF₂, SiON, SiNₓ, SiO_{y}, etc.

For example, in some embodiments, when the capping layer CPL includes an organic material, the organic material may include 2,2′-dimethyl-N,N′-di-[(1-naphthyl)-N,N′-diphenyl]-1,1′-biphenyl-4,4′-diamine(α-NPD), NPB, TPD, m-MTDATA, Alq₃, CuPc, N4,N4,N4′,N4′-tetra(biphenyl-4-yl) biphenyl-4,4′-diamine (TPD15), 4,4′,4″-tris(carbazol-9-yl) triphenylamine (TCTA), etc., or may include an epoxy resin, and/or acrylate such as methacrylate. In some embodiments, the capping layer CPL may include at least one selected from among Compounds P1 to P5, but embodiments of the present disclosure are not limited thereto.

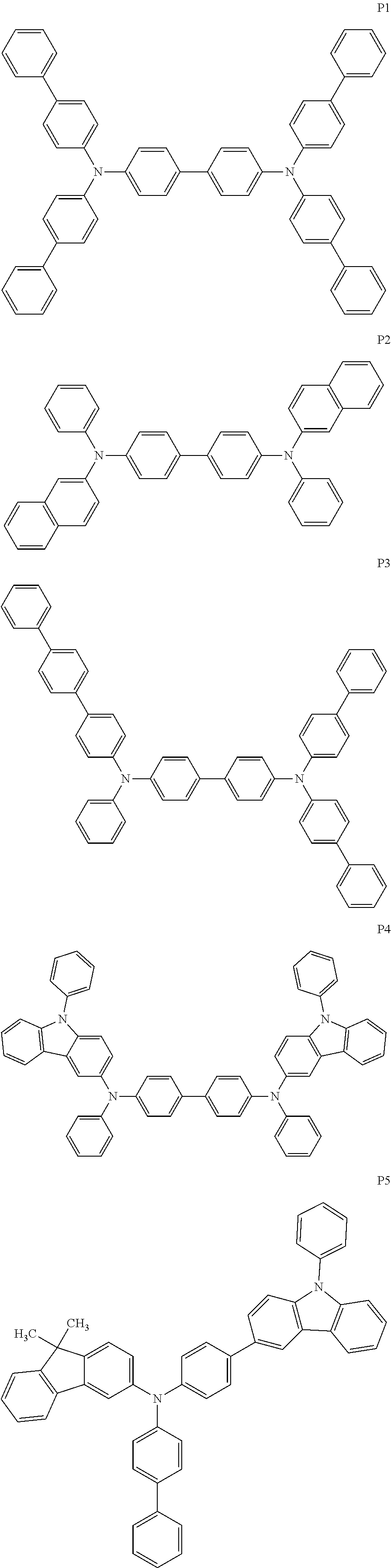

In some embodiments, the refractive index of the capping layer CPL may be about 1.6 or more. For example, in some embodiments, the refractive index of the capping layer CPL with respect to light in a wavelength range of about 550 nm to about 660 nm may be about 1.6 or more.

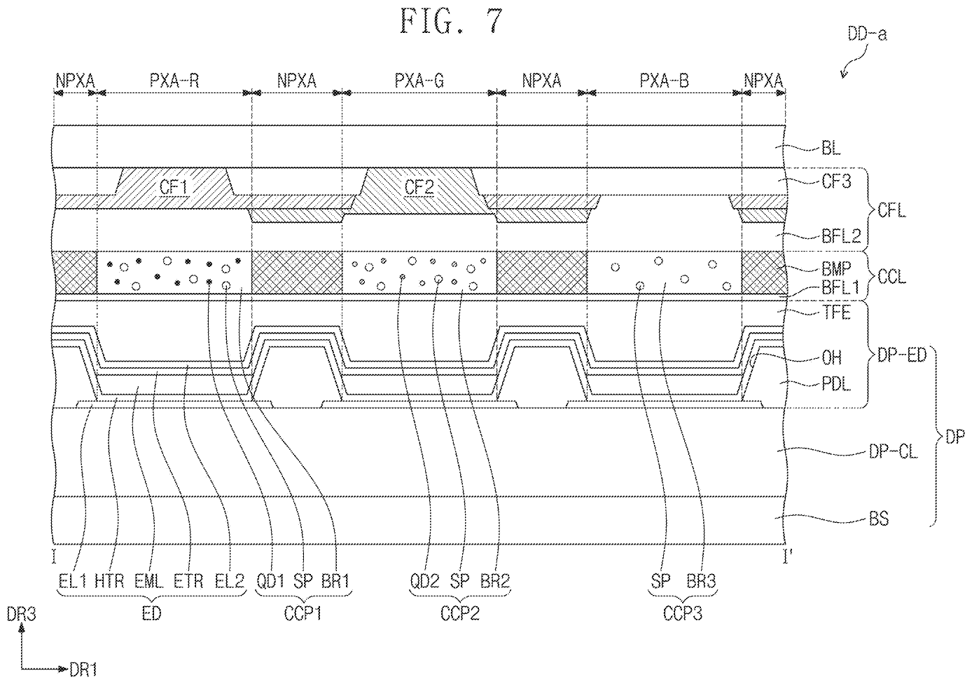

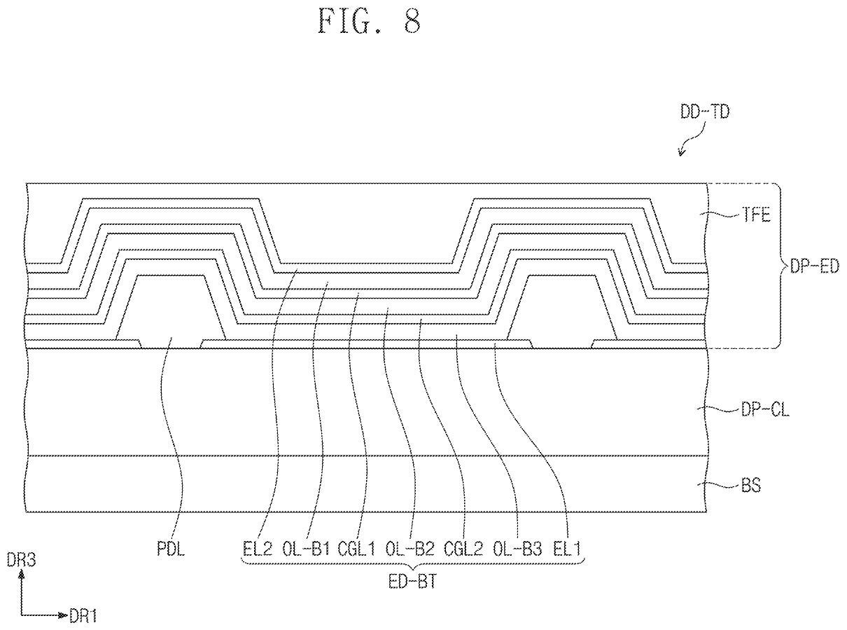

FIG. 7 to FIG. 10 are cross-sectional views on display apparatuses according to one or more embodiments of the present disclosure. In the explanation on the display apparatuses of embodiments by referring to FIG. 7 to FIG. 10, the overlapping parts with the explanation on FIG. 1 to FIG. 6 will not be explained/described again for conciseness, and only different features will be explained chiefly and mainly.

Referring to FIG. 7, the display apparatus DD-a according to one or more embodiments may include a display panel DP including a display device layer DP-ED, a light controlling layer CCL disposed on the display panel DP, and a color filter layer CFL. In one or more embodiments shown in FIG. 7, the display panel DP may include a base layer BS, a circuit layer DP-CL provided on the base layer BS, and a display device layer DP-ED, and the display device layer DP-ED may include a light emitting device ED.

The light emitting device ED may include a first electrode EL1, a hole transport region HTR on the first electrode EL1, an emission layer EML on the hole transport region HTR, an electron transport region ETR on the emission layer EML, and a second electrode EL2 on the electron transport region ETR. In one or more embodiments, the same structures as the light emitting devices of FIG. 3 to FIG. 6 may be applied to the structure of the light emitting device ED shown in FIG. 7.

The emission layer EML of the light emitting device ED included in the display device DD-a according to one or more embodiments may include the above-described fused polycyclic compound of an embodiment.

Referring to FIG. 7, the emission layer EML may be disposed in an opening part OH defined in a pixel definition layer PDL. For example, the emission layer EML divided by the pixel definition layer PDL and correspondingly provided to each of luminous areas PXA-R, PXA-G and PXA-B may be to emit light in substantially the same wavelength region. In the display apparatus DD-a of one or more embodiments, the emission layer EML may be to emit blue light. In some embodiments, the emission layer EML may be provided as a common layer for all luminous areas PXA-R, PXA-G and PXA-B.

The light controlling layer CCL may be disposed on the display panel DP. The light controlling layer CCL may include a light converter. The light converter may be a quantum dot and/or a phosphor. The light converter may transform the wavelength of light provided and then emit. For example, the light controlling layer CCL may be a layer including a quantum dot or a layer including a phosphor.

The light controlling layer CCL may include multiple light controlling parts CCP1, CCP2, and CCP3. The light controlling parts CCP1, CCP2 and CCP3 may be separated and apart from one another.

Referring to FIG. 7, a partition pattern BMP may be disposed between the separated light controlling parts CCP1, CCP2, and CCP3, but embodiments of the present disclosure are not limited thereto. In FIG. 7, the partition pattern BMP is shown not to be overlapped with the light controlling parts CCP1, CCP2, and CCP3, but, in some embodiments, at least a portion of the edges of the light controlling parts CCP1, CCP2, and CCP3 may be overlapped with the partition pattern BMP.

The light controlling layer CCL may include a first light controlling part CCP1 including a first quantum dot QD1 converting first color light provided from the light emitting device ED into second color light, a second light controlling part CCP2 including a second quantum dot QD2 converting the first color light into third color light, and a third light controlling part CCP3 transmitting the first color light. In one or more embodiments, the first light controlling part CCP1 may provide red light which is the second color light, and the second light controlling part CCP2 may provide green light which is the third color light. The third color controlling part CCP3 may be to transmit and provide blue light which is the first color light provided from the light emitting device ED. For example, the first quantum dot QD1 may be a red quantum dot to emit red light, and the second quantum dot QD2 may be a green quantum dot to emit green light. On the quantum dots QD1 and QD2, the same content as those described above may be applied.

In some embodiments, the light controlling layer CCL may further include a scatterer SP. The first light controlling part CCP1 may include the first quantum dot QD1 and the scatterer SP, the second light controlling part CCP2 may include the second quantum dot QD2 and the scatterer SP, and the third light controlling part CCP3 may not include a (e.g., may exclude any) quantum dot but include the scatterer SP.

The scatterer SP may be an inorganic particle. For example, the scatterer SP may include at least one selected from among TiO₂, ZnO, Al₂O₃, SiO₂, and hollow silica. In one or more embodiments, the scatterer SP may include at least one selected from among TiO₂, ZnO, Al₂O₃, SiO₂, and hollow silica, or may be a mixture of two or more materials selected from among TiO₂, ZnO, Al₂O₃, SiO₂, and hollow silica.

The first light controlling part CCP1, the second light controlling part CCP2, and the third light controlling part CCP3 may respectively include base resins BR1, BR2, and BR3 dispersing the quantum dots QD1 and QD2 and the scatterer SP. In one or more embodiments, the first light controlling part CCP1 may include the first quantum dot QD1 and the scatterer SP dispersed in a first base resin BR1, the second light controlling part CCP2 may include the second quantum dot QD2 and the scatterer SP dispersed in a second base resin BR2, and the third light controlling part CCP3 may include the scatterer particle SP dispersed in a third base resin BR3.

The base resins BR1, BR2, and BR3 are mediums in which the quantum dots QD1 and QD2 and the scatterer SP are dispersed, and may be composed of one or more suitable resin compositions which may be generally referred to as a binder. For example, the base resins BR1, BR2, and BR3 may each independently be acrylic resins, urethane-based resins, silicone-based resins, epoxy-based resins, etc. The base resins BR1, BR2, and BR3 may be transparent resins. In one or more embodiments, the first base resin BR1, the second base resin BR2, and the third base resin BR3 may be the same or different from each other.

In one or more embodiments, the light controlling layer CCL may include a barrier layer BFL1. The barrier layer BFL1 may play the role of blocking the penetration of moisture and/or oxygen (hereinafter, will be referred to as “humidity/oxygen”). The barrier layer BFL1 may block or reduce the exposure of the light controlling parts CCP1, CCP2, and CCP3 to humidity/oxygen. In some embodiments, the barrier layer BFL1 may cover the light controlling parts CCP1, CCP2, and CCP3. In some embodiments, a color filter layer CFL, which will be explained later, may include a barrier layer BFL2 disposed on the light controlling parts CCP1, CCP2 and CCP3.

The barrier layers BFL1 and BFL2 may include at least one inorganic layer. For example, in some embodiments, the barrier layers BFL1 and BFL2 may be formed by including an inorganic material. For example, the barrier layers BFL1 and BFL2 may be formed by including silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, or a metal thin film securing light transmittance. In some embodiments, the barrier layers BFL1 and BFL2 may further include an organic layer. The barrier layers BFL1 and BFL2 may be composed of a single layer or multiple layers.

In one or more embodiments, in the display apparatus DD-a, the color filter layer CFL may be disposed on the light controlling layer CCL. For example, the color filter layer CFL may be disposed directly on the light controlling layer CCL. In these embodiments, the barrier layer BFL2 may not be provided.

The color filter layer CFL may include filters CF1, CF2, and CF3. Each of the first to third filters CF1, CF2, and CF3 may be disposed corresponding to a red luminous area PXA-R, a green luminous area PXA-G, and a blue luminous area PXA-B, respectively.

The color filter layer CFL may include a first filter CF1 transmitting the second color light, a second filter CF2 transmitting the third color light, and a third filter CF3 transmitting the first color light. For example, in some embodiments, the first filter CF1 may be a red filter, the second filter CF2 may be a green filter, and the third filter CF3 may be a blue filter. Each of the filters CF1, CF2 and CF3 may include a polymer photosensitive resin and a pigment and/or dye. The first filter CF1 may include a red pigment and/or dye, the second filter CF2 may include a green pigment and/or dye, and the third filter CF3 may include a blue pigment and/or dye.

However, embodiments of the present disclosure are not limited thereto, and the third filter CF3 may not include (e.g., may exclude) the pigment and/or dye (e.g., not include any pigment or dye). The third filter CF3 may include a polymer photosensitive resin and not include a pigment and/or dye. The third filter CF3 may be transparent. The third filter CF3 may be formed utilizing a transparent photosensitive resin.

In some embodiments, the first filter CF1 and the second filter CF2 may be yellow filters. The first filter CF1 and the second filter CF2 may be provided in one body without distinction.

In one or more embodiments, the color filter layer CFL may further include a light blocking part. The light blocking part may be a black matrix. The light blocking part may be formed by including an organic light blocking material and/or an inorganic light blocking material including a black pigment and/or black dye. The light blocking part may prevent or reduce light leakage phenomenon and divide the boundaries among adjacent filters CF1, CF2, and CF3.

On the color filter layer CFL, a base substrate BL may be disposed/provided. The base substrate BL may be a member providing a base surface on which the color filter layer CFL, the light controlling layer CCL, etc. are disposed. The base substrate BL may be a glass substrate, a metal substrate, a plastic substrate, etc. However, embodiments of the present disclosure are not limited thereto, and the base substrate BL may be an inorganic layer, an organic layer, or a composite material layer. In some embodiments, the base substrate BL may not be provided.

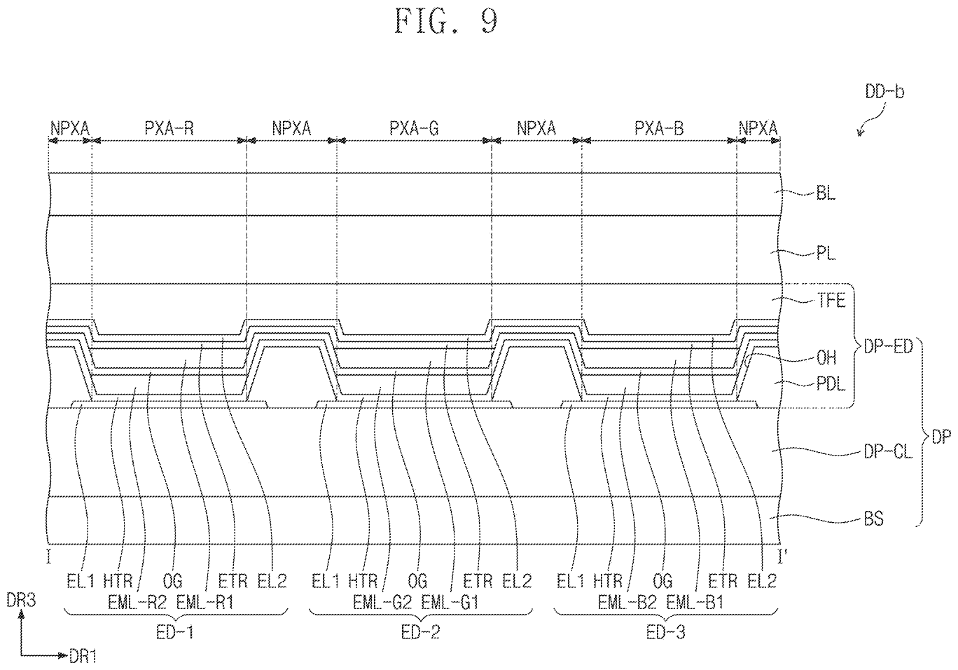

FIG. 8 is a cross-sectional view showing a portion of a display apparatus according to one or more embodiments. In a display apparatus DD-TD, a light emitting device ED-BT may include multiple light emitting structures OL-B1, OL-B2, and OL-B3. The light emitting device ED-BT may include oppositely disposed first electrode EL1 and second electrode EL2, and the multiple light emitting structures OL-B1, OL-B2, and OL-B3 stacked in order in a thickness direction and provided between the first electrode EL1 and the second electrode EL2. Each of the light emitting structures OL-B1, OL-B2, and OL-B3 may include an emission layer EML (FIG. 7), and a hole transport region HTR and an electron transport region ETR disposed with the emission layer EML (FIG. 7) therebetween.

For example, in some embodiments, the light emitting device ED-BT included in the display apparatus DD-TD may be a light emitting device of a tandem structure including multiple emission layers.

In one or more embodiments shown in FIG. 8, light emitted from the light emitting structures OL-B1, OL-B2, and OL-B3 may be all blue light. However, embodiments of the present disclosure are not limited thereto, and the wavelength regions of light emitted from the light emitting structures OL-B1, OL-B2, and OL-B3 may be different from each other. For example, in one or more embodiments, the light emitting device ED-BT including the multiple light emitting structures OL-B1, OL-B2, and OL-B3 emitting light in different wavelength regions may be to emit white light (e.g., combined white light).

Between neighboring light emitting structures OL-B1, OL-B2, and OL-B3, charge generating layers CGL1 and CGL2 may be disposed. The charge generating layers CGL1 and CGL2 may include a p-type or kind charge (e.g., P-charge) generating layer and/or an n-type or kind charge (e.g., N-charge) generating layer.

At least one selected from among the light emitting structures OL-B1, OL-B2, and OL-B3 included in the display device DD-TD of one or more embodiments may contain the above-described fused polycyclic compound of one or more embodiments. For example, in one or more embodiments, at least one selected from among the plurality of emission layers included in the light emitting device ED-BT may include the fused polycyclic compound of an embodiment.

In at least one selected from among the light emitting structures OL-B1, OL-B2, and OL-B3, included in the display apparatus DD-TD of an embodiment, the fused polycyclic compound of an embodiment may be included. For example, in one or more embodiments, at least one selected from among multiple emission layers included in the light emitting device ED-BT may include the fused polycyclic compound of an embodiment.

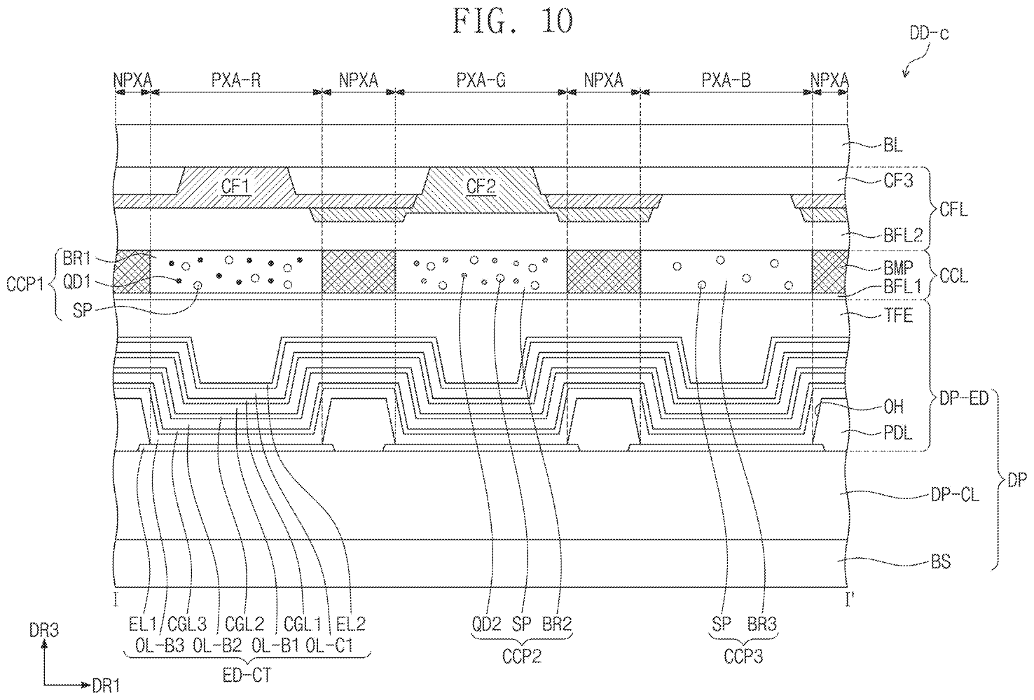

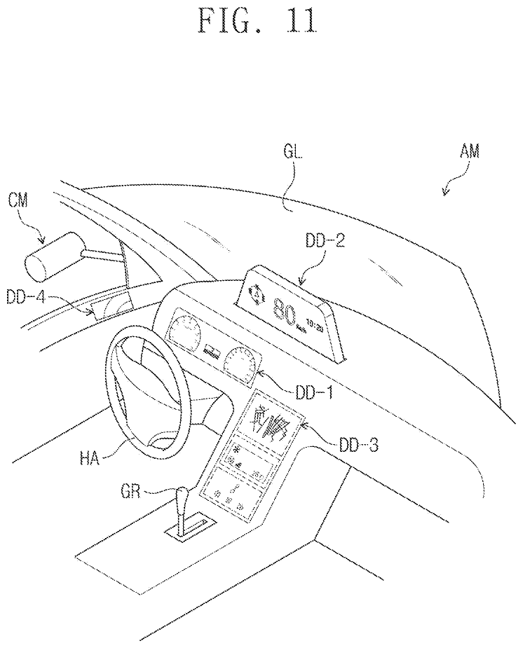

FIG. 9 is a cross-sectional view showing a display apparatus according to one or more embodiments of the present disclosure. FIG. 10 is a cross-sectional view showing a display apparatus according to one or more embodiments of the present disclosure.

Referring to FIG. 9, a display apparatus DD-b according to one or more embodiments may include light emitting devices ED-1, ED-2, and ED-3, each formed by stacking two emission layers. Compared to the display apparatus DD shown in FIG. 2, the display apparatus DD-b shown in FIG. 9 is different in that first to third light emitting devices ED-1, ED-2, and ED-3 each include two emission layers stacked in a thickness direction. In each of the first to third light emitting devices ED-1, ED-2, and ED-3, the two emission layers may be to emit light in substantially the same wavelength region.

In one or more embodiments, the first light emitting device ED-1 may include a first red emission layer EML-R1 and a second red emission layer EML-R₂. The second light emitting device ED-2 may include a first green emission layer EML-G1 and a second green emission layer EML-G2. In addition, the third light emitting device ED-3 may include a first blue emission layer EML-B1 and a second blue emission layer EML-B2. Between the first red emission layer EML-R1 and the second red emission layer EML-R₂, between the first green emission layer EML-G1 and the second green emission layer EML-G2, and between the first blue emission layer EML-B1 and the second blue emission layer EML-B2, an emission auxiliary part OG may be disposed.

The emission auxiliary part OG may include a single layer or a multilayer. The emission auxiliary part OG may include a charge generating layer. In one or more embodiments, the emission auxiliary part OG may include an electron transport region, a charge generating layer, and a hole transport region stacked in order (e.g., in the stated order). The emission auxiliary part OG may be provided as a common layer in all of the first to third light emitting devices ED-1, ED-2, and ED-3. However, embodiments of the present disclosure are not limited thereto, and the emission auxiliary part OG may be patterned and provided in an opening part OH defined in a pixel definition layer PDL.

The first red emission layer EML-R1, the first green emission layer EML-G1, and the first blue emission layer EML-B1 may be disposed between the electron transport region ETR and the emission auxiliary part OG. The second red emission layer EML-R2, the second green emission layer EML-G2, and the second blue emission layer EML-B2 may be disposed between the emission auxiliary part OG and the hole transport region HTR.

For example, in one or more embodiments, the first light emitting device ED-1 may include a first electrode EL1, a hole transport region HTR, a second red emission layer EML-R2, an emission auxiliary part OG, a first red emission layer EML-R₁, an electron transport region ETR, and a second electrode EL2, stacked in order (e.g., in the stated order). The second light emitting device ED-2 may include a first electrode EL1, a hole transport region HTR, a second green emission layer EML-G2, an emission auxiliary part OG, a first green emission layer EML-G1, an electron transport region ETR, and a second electrode EL2, stacked in order (e.g., in the stated order). The third light emitting device ED-3 may include a first electrode EL1, a hole transport region HTR, a second blue emission layer EML-B2, an emission auxiliary part OG, a first blue emission layer EML-B1, an electron transport region ETR, and a second electrode EL2, stacked in order (e.g., in the stated order).

In some embodiments, an optical auxiliary layer PL may be disposed on a display device layer DP-ED. The optical auxiliary layer PL may include a polarization layer. The optical auxiliary layer PL may be disposed on a display panel DP and may control reflected light at the display panel DP by external light. In some embodiments, the optical auxiliary layer PL may not be provided in the display apparatus.

In one or more embodiments, at least one emission layer included in the display device DD-b illustrated in FIG. 9 may include the above-described fused polycyclic compound of an embodiment. For example, in some embodiments, at least one of the first blue emission layer EML-B1 or the second blue emission layer EML-B2 may include the fused polycyclic compound of an embodiment.

Different from FIG. 8 and FIG. 9, a display apparatus DD-c in FIG. 10 is shown to include four light emitting structures OL-B1, OL-B2, OL-B3, and OL-C1. A light emitting device ED-CT may include oppositely disposed first electrode EL1 and second electrode EL2, and first to fourth light emitting structures OL-B1, OL-B2, OL-B3, and OL-C1 stacked in a thickness direction between the first electrode EL1 and the second electrode EL2. Between the first to fourth light emitting structures OL-B1, OL-B2, OL-B3, and OL-C1, charge generating layers CGL1, CGL2, and CGL3 may be disposed. Among the four light emitting structures, the first to third light emitting structures OL-B1, OL-B2, and OL-B3 may be to emit blue light, and the fourth light emitting structure OL-C1 may be to emit green light. However, embodiment of the present disclosure are not limited thereto, and the first to fourth light emitting structures OL-B1, OL-B2, OL-B3, and OL-C1 may be to emit different wavelengths of light.

Charge generating layers CGL1, CGL2, and CGL3 disposed among neighboring light emitting structures OL-B1, OL-B2, OL-B3, and OL-C1 may include a p-type or kind charge (e.g., P-charge) generating layer and/or an n-type or kind charge (e.g., N-charge) generating layer.

At least one selected from among the light emitting structures OL-B1, OL-B2, OL-B3, and OL-C1 included in the display device DD-c of one or more embodiments may contain the above-described fused polycyclic compound of an embodiment. For example, in some embodiments, at least one selected from among the first to third light emitting structures OL-B1, OL-B2, and OL-B3 may include the above-described fused polycyclic compound of an embodiment.

The light emitting device ED according to an embodiment of the present disclosure may include the above-described polycyclic compound represented by Formula 1 of an embodiment in at least one functional layer disposed between the first electrode EL1 and the second electrode EL2, thereby exhibiting excellent or suitable luminous efficiency and improved service life characteristics. For example, the polycyclic compound according to an embodiment may be included in the emission layer EML of the light emitting device ED of an embodiment, and the light emitting device of an embodiment may exhibit a long service life characteristic.

In one or more embodiments, an electronic apparatus may include a display apparatus including multiple light emitting devices and a control part controlling the display apparatus. The electronic apparatus of an embodiment may be an apparatus activated according to electrical signals. The electronic apparatus may include display apparatuses of one or more embodiments. For example, the electronic apparatus may include at least one selected from televisions, monitors, large-size display apparatuses such as outside billboards, personal computers, laptop computers, personal digital terminals, display apparatuses for automobiles, game consoles, portable electronic devices, and medium- and small-size display apparatuses such as cameras.

FIG. 11 is a diagram showing an automobile AM in which first to fourth display apparatuses DD-1, DD-2, DD-3, and DD-4 are disposed. At least one selected from among the first to fourth display apparatuses DD-1, DD-2, DD-3, and DD-4 may include substantially the same configurations of the display apparatuses DD, DD-TD, DD-a, DD-b, and/or DD-c, explained referring to FIGS. 1, 2, and 7 to 10.

In FIG. 11, a vehicle is shown as an automobile AM, but this is a mere example. The first to fourth display apparatuses DD-1, DD-2, DD-3, and DD-4 may be disposed on other transport apparatuses such as bicycles, motorcycles, trains, ships, and airplanes. In some embodiments, at least one selected from among the first to fourth display apparatuses DD-1, DD-2, DD-3, and DD-4 including substantially the same configurations of the display apparatuses DD, DD-TD, DD-a, DD-b and/or DD-c may be introduced in personal computers, laptop computers, personal digital terminals, game consoles, portable electronic devices, televisions, monitors, external billboards, and/or the like. These are mere examples, and the display apparatus may be introduced in other electronic devices as long as not deviated from the present disclosure.

In one or more embodiments, at least one selected from among the first to fourth display devices DD-1, DD-2, DD-3, and DD-4 may include the light emitting device ED of an embodiment as described with reference to FIGS. 3 to 6. The light emitting device ED of an embodiment may include the fused polycyclic compound of an embodiment. In one or more embodiments, at least one selected from among the first to fourth display devices DD-1, DD-2, DD-3, and DD-4 may include the light emitting device ED including the fused polycyclic compound of an embodiment, thereby improving a display service life.

Referring to FIG. 11, an automobile AM may include a steering wheel HA for the operation of the automobile AM and a gear GR. In addition, the automobile AM may include a front window GL disposed to face a driver.

A first display apparatus DD-1 may be disposed in a first region overlapping with the steering wheel HA. For example, the first display apparatus DD-1 may be a digital cluster displaying first information of the automobile AM. The first information may include a first graduation showing the travel speed of the automobile AM, a second graduation showing the number of revolution of an engine (i.e., revolutions per minute (RPM)), and images showing a fuel state. The first graduation and second graduation may be represented by digital images.

A second display apparatus DD-2 may be disposed in a second region facing a driver seat and overlapping with the front window GL. The driver seat may be a seat where the steering wheel HA faces. For example, the second display apparatus DD-2 may be a head up display (HUD) showing second information of the automobile AM. The second display apparatus DD-2 may be optically clear. The second information may include digital numbers showing the travel speed of the automobile AM and may further include information including the current time. In some embodiments, the second information of the second display apparatus DD-2 may be projected and displayed on the front window GL.

A third display apparatus DD-3 may be disposed in a third region adjacent to the gear GR. For example, the third display apparatus DD-3 may be a center information display (CID) for the automobile, disposed between a driver seat and a passenger seat and showing third information. The passenger seat may be a seat separated from the driver seat with the gear GR therebetween. The third information may include information on road conditions (for example, navigation information), on playing music or radio, on playing a dynamic image (or image), on the temperature in the automobile AM, and/or the like.

A fourth display apparatus DD-4 may be disposed in a fourth region separated from the steering wheel HA and the gear GR and adjacent to a side of the automobile AM. For example, the fourth display apparatus DD-4 may be a digital wing mirror displaying fourth information. The fourth display apparatus DD-4 may display external images of the automobile AM, taken by a camera module CM disposed at the outside of the automobile AM. The fourth information may include external images of the automobile AM.

The above-described first to fourth information is mere examples, and the first to fourth display apparatuses DD-1, DD-2, DD-3, and DD-4 may further display information on the inside and outside of the automobile. The first to fourth information may include different information from each other. However, embodiments of the present disclosure are not limited thereto, for example, in some embodiments, a portion of the first to fourth information may include the same information.

Hereinafter, with reference to Examples and Comparative Examples, a fused polycyclic according to one or more embodiments of the present disclosure and a luminescence device (e.g., a light emitting device) of an embodiment of the present disclosure will be described in more detail. In addition, Examples described are only illustrations to assist the understanding of the present disclosure, and the scope of the present disclosure is not limited thereto.

### EXAMPLES

### 1. Synthesis of Fused Polycyclic Compound

First, a synthetic method of a fused polycyclic compound according to one or more embodiments will be described in more detail by illustrating synthetic methods of Compounds F-12, H-11, B-13, D-12, and J-1. In addition, the synthetic methods of the fused polycyclic compounds as described herein are only examples, and the synthetic method of the fused polycyclic compound according to one or more embodiments of the present disclosure is not limited to the following examples.

### (1) Synthesis of Compound F-12

### Synthesis of Intermediate F-12a

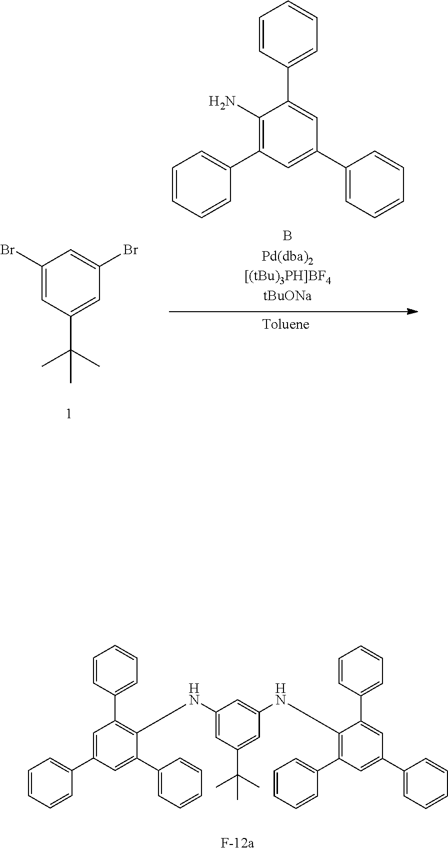

To a three-necked flask, Intermediate A (150 mmol), Intermediate B (300 mmol), tBuONa (450 mmol), tris(dibenzylideneacetone)dipalladium(0) (Pd(dba)₂) (15 mmol), and [(tBu)₃PH]BF₄ (30 mmol) were added to perform argon (Ar) substitution, 1,000 mL of toluene was then added thereto, and the resultant mixture was stirred at about 100° C. for about 5 hours. Water was added to the reaction system, and an organic layer was extracted by utilizing toluene, and then was dried over magnesium sulfate to distill the solvent off. The crude product was purified by silica gel column chromatography (a mixed solvent of hexane/toluene as an eluent) and recrystallization (a mixed solvent of ethanol/toluene) to obtain white solids (129 mmol, yield 86%). The obtained purified product was confirmed to have a molecular weight of 621 through fast atom bombardment mass spectrometry FAB-MS measurement, and thus it was clearly confirmed to obtain Intermediate F-12a.

### Synthesis of Intermediate F-12b

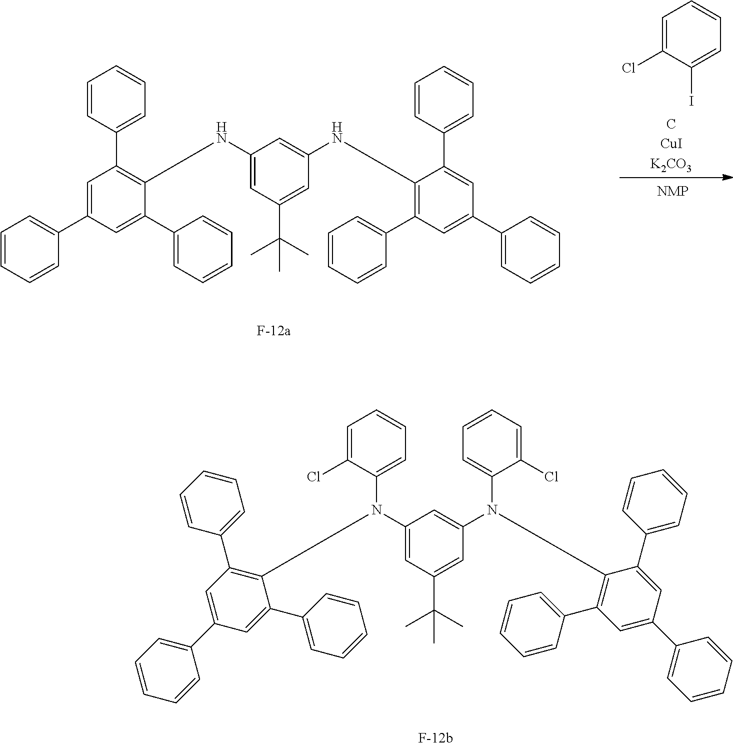 [SMILES: CC(C)(C)c1cc(Nc2c(-c3ccccc3)cc(-c3ccccc3)cc2-c2ccccc2)cc(Nc2c(-c3ccccc3)cc(-c3ccccc3)cc2-c2ccccc2)c1 ; Clc1ccccc1I ; CC(C)(C)c1cc(N(c2ccccc2Cl)c2c(-c3ccccc3)cc(-c3ccccc3)cc2-c2ccccc2)cc(N(c2ccccc2Cl)c2c(-c3ccccc3)cc(-c3ccccc3)cc2-c2ccccc2)c1]

To a three-necked flask, Intermediate F-12a (129 mmol), Intermediate C (1290 mmol), K₂CO₃ (645 mmol), and CuI (141 mmol) were added to perform Ar substitution, and then the mixture was dissolved by adding 50 mL of N-methyl-2-pyrrolidone (NMP), and the resultant mixture was stirred at about 200° C. for about 30 hours. Water was added to the reaction system, and an organic layer was extracted by utilizing toluene, and then was dried over magnesium sulfate to distill the solvent off. The obtained crude product was purified by silica gel column chromatography (a mixed solvent of hexane/toluene as an eluent) and recrystallization (a mixed solvent of ethanol/toluene) to obtain white solids (101 mmol, yield 78%). The obtained purified product was confirmed to have a molecular weight of 994 through FAB-MS measurement, and thus it was clearly confirmed to obtain Intermediate F-12b.

### Synthesis of Intermediate F-12c

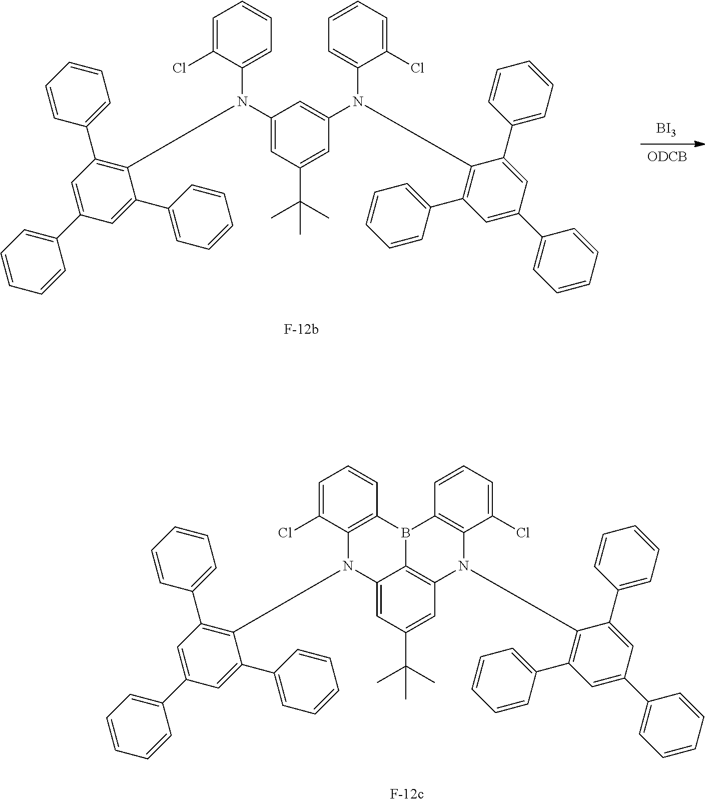 [SMILES: CC(C)(C)c1cc(N(c2ccccc2Cl)c2c(-c3ccccc3)cc(-c3ccccc3)cc2-c2ccccc2)cc(N(c2ccccc2Cl)c2c(-c3ccccc3)cc(-c3ccccc3)cc2-c2ccccc2)c1 ; "ODCB" ; "BI3" ; CC(C)(C)c1cc2c3c(c1)N(c1c(-c4ccccc4)cc(-c4ccccc4)cc1-c1ccccc1)c1c(Cl)cccc1B3c1cccc(Cl)c1N2c1c(-c2ccccc2)cc(-c2ccccc2)cc1-c1ccccc1]

To a three-necked flask, Intermediate F-12b (101 mmol) was added to perform Ar substitution, was then dissolved by adding 100 mL of 1,2-dichlorobenzene (ODCB), BI₃ (202 mmol) was then added thereto, and the resultant mixture was stirred at about 180° C. for about 10 hours. The reaction solution was subjected to dispersion washing with a large amount of acetonitrile, and then solids were recovered through filtration. The obtained crude product was purified by silica gel column chromatography (a mixed solvent of hexane/dichloromethane as an eluent) and recrystallization (a mixed solvent of ethanol/toluene) to obtain yellow solids (45 mmol, yield 45%). The obtained purified product was confirmed to have a molecular weight of 1002 through FAB-MS measurement, and thus it was clearly confirmed to obtain Intermediate F-12c.

### Synthesis of Intermediate F-12d

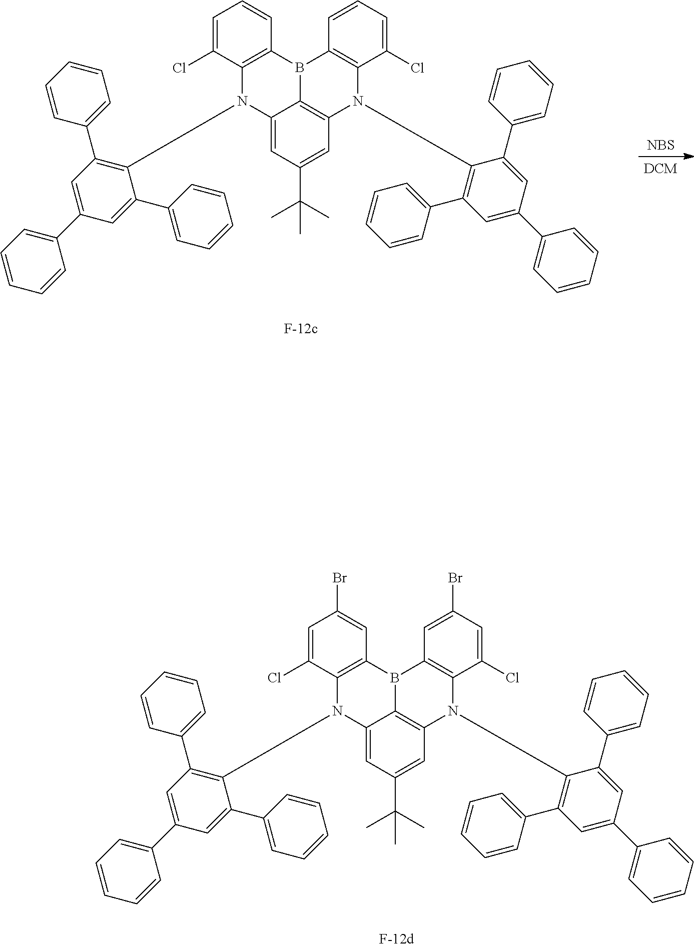 [SMILES: CC(C)(C)c1cc2c3c(c1)N(c1c(-c4ccccc4)cc(-c4ccccc4)cc1-c1ccccc1)c1c(Cl)cccc1B3c1cccc(Cl)c1N2c1c(-c2ccccc2)cc(-c2ccccc2)cc1-c1ccccc1 ; "NBS" ; CC(C)(C)c1cc2c3c(c1)N(c1c(-c4ccccc4)cc(-c4ccccc4)cc1-c1ccccc1)c1c(Cl)cc(Br)cc1B3c1cc(Br)cc(Cl)c1N2c1c(-c2ccccc2)cc(-c2ccccc2)cc1-c1ccccc1]

To a three-necked flask, Intermediate F-12c (45 mmol) and n-bromosuccinimide (NBS) (100 mmol) were added to perform Ar substitution, 10 mL of dichloromethane (DCM) was then added thereto, and the resultant mixture was stirred at room temperature for about 1 hour. Water was added to the reaction system, and an organic layer was extracted by utilizing DCM, and then was dried over magnesium sulfate to distill the solvent off. The obtained crude product was purified by silica gel column chromatography (a mixed solvent of hexane/toluene as an eluent) and recrystallization (a mixed solvent of ethanol/toluene) to obtain yellow solids (40 mmol, yield 89%). The obtained purified product was confirmed to have a molecular weight of 1160 through FAB-MS measurement, and thus it was clearly confirmed to obtain Intermediate F-12d.

### Synthesis of Intermediate F-12e

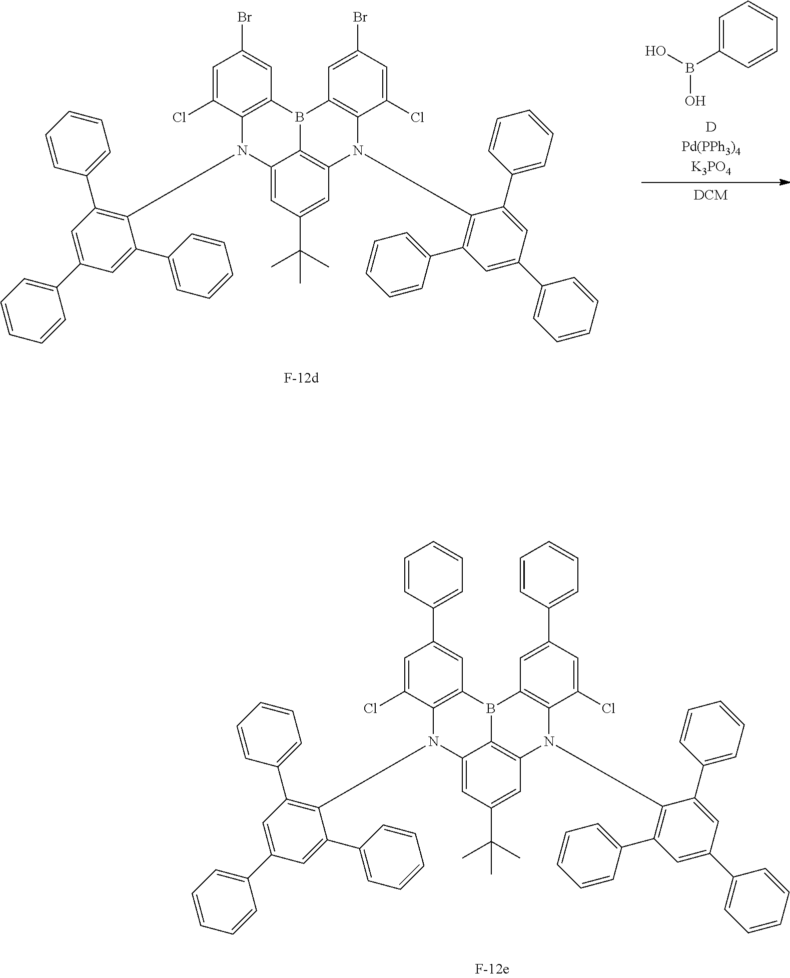 [SMILES: CC(C)(C)c1cc2c3c(c1)N(c1c(-c4ccccc4)cc(-c4ccccc4)cc1-c1ccccc1)c1c(Cl)cc(Br)cc1B3c1cc(Br)cc(Cl)c1N2c1c(-c2ccccc2)cc(-c2ccccc2)cc1-c1ccccc1 ; OB(O)c1ccccc1 ; CC(C)(C)c1cc2c3c(c1)N(c1c(-c4ccccc4)cc(-c4ccccc4)cc1-c1ccccc1)c1c(Cl)cc(-c4ccccc4)cc1B3c1cc(-c3ccccc3)cc(Cl)c1N2c1c(-c2ccccc2)cc(-c2ccccc2)cc1-c1ccccc1]

To a three-necked flask, Intermediate F-12d (40 mmol), Intermediate D (90 mmol), K₃PO₄ (160 mmol), and Pd(PPh₃)₄ (4 mmol) were added to perform Ar substitution, 60 mL of toluene was then added thereto, and the resultant mixture was stirred at about 60° C. for about 24 hours. Water was added to the reaction system, and an organic layer was extracted by utilizing toluene, and then was dried over magnesium sulfate to distill the solvent off. The obtained crude product was purified by silica gel column chromatography (a mixed solvent of hexane/toluene as an eluent) and recrystallization (a mixed solvent of ethanol/toluene) to obtain yellow solids (37 mmol, yield 93%). The obtained purified product was confirmed to have a molecular weight of 1154 through FAB-MS measurement, and thus it was clearly confirmed to obtain Intermediate F-12e.

### Synthesis of Compound L F-12

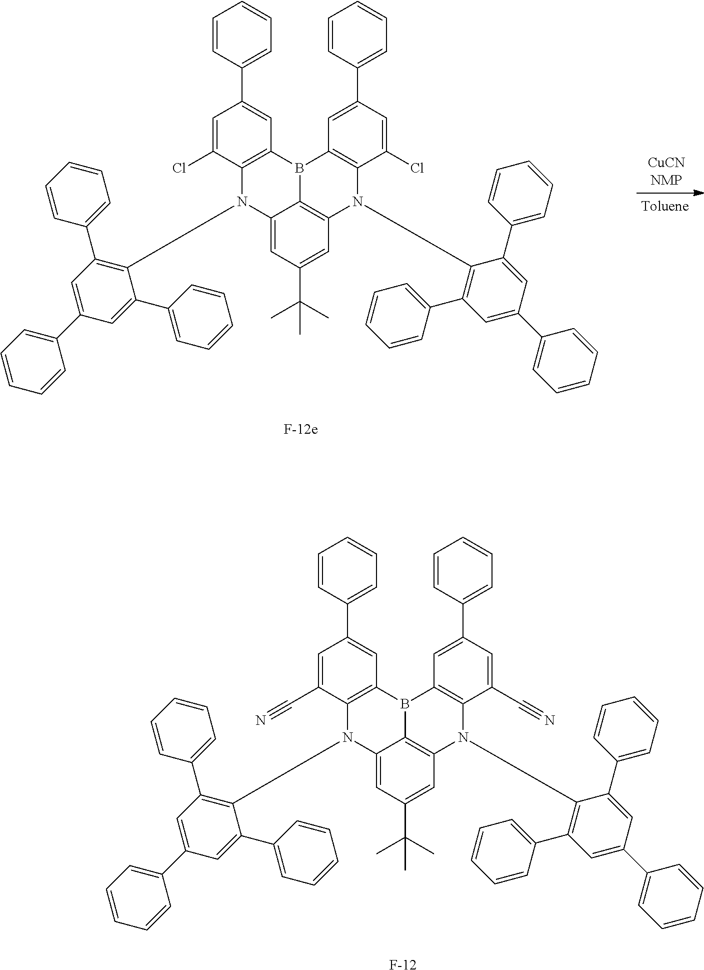

To a three-necked flask, Intermediate F-12e (37 mmol) and CuCN (93 mmol) were added to perform Ar substitution, 370 mL of NMP was then added thereto, and the resultant mixture was stirred at about 150° C. for about 80 hours. Water was added to the reaction system, and an organic layer was extracted by utilizing toluene, and then was dried over magnesium sulfate to distill the solvent off. The obtained crude product was purified by silica gel column chromatography (a mixed solvent of hexane/toluene as an eluent) and recrystallization (a mixed solvent of ethanol/toluene) to obtain yellow solids (13 mmol, yield 34%). The obtained purified product was confirmed to have a molecular weight of 1135 through FAB-MS measurement, and thus it was clearly confirmed to obtain Compound F-12.

### (2) Synthesis of Compound H-11

### Synthesis of Intermediate H-11a

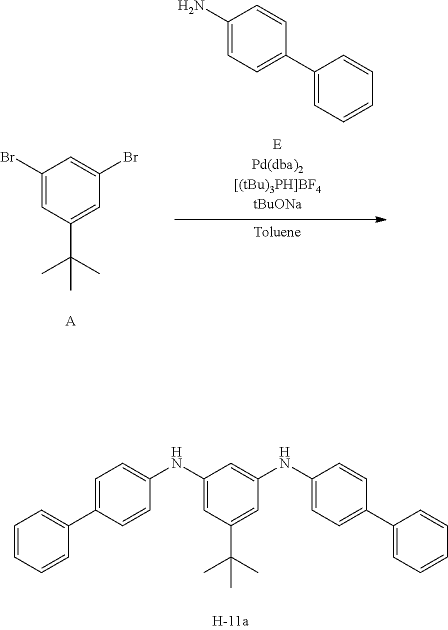

To a three-necked flask, Intermediate A (150 mmol), Intermediate E (300 mmol), tBuONa (450 mmol), Pd(dba)₂ (15 mmol), and [(tBu)₃PH]BF₄ (30 mmol) were added to perform Ar substitution, 1,000 mL of toluene was then added thereto, and the resultant mixture was stirred at about 80° C. for about 2 hours. Water was added to the reaction system, and an organic layer was extracted by utilizing toluene, and then was dried over magnesium sulfate to distill the solvent off. The obtained crude product was purified by silica gel column chromatography (a mixed solvent of hexane/toluene as an eluent) and recrystallization (a mixed solvent of ethanol/toluene) to obtain white solids (144 mmol, yield 96%). The obtained purified product was confirmed to have a molecular weight of 469 through FAB-MS measurement, and thus it was clearly confirmed to obtain Intermediate H-11a.

### Synthesis of Intermediate H-11b

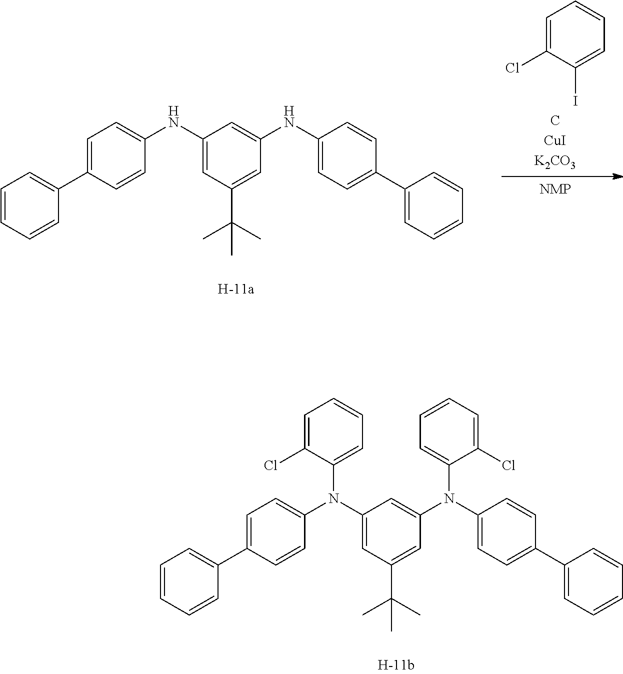 [SMILES: Clc1ccccc1I ; CC(C)(C)c1cc(Nc2ccc(-c3ccccc3)cc2)cc(Nc2ccc(-c3ccccc3)cc2)c1 ; CC(C)(C)c1cc(N(c2ccc(-c3ccccc3)cc2)c2ccccc2Cl)cc(N(c2ccc(-c3ccccc3)cc2)c2ccccc2Cl)c1]

To a three-necked flask, Intermediate H-11a (144 mmol), Intermediate C (1440 mmol), K₂CO₃ (720 mmol), and CuI (288 mmol) were added to perform Ar substitution, and then the mixture was dissolved by adding 50 mL of NMP, and the resultant mixture was stirred at about 190° C. for about 24 hours. Water was added to the reaction system, and an organic layer was extracted by utilizing toluene, and then was dried over magnesium sulfate to distill the solvent off. The obtained crude product was purified by silica gel column chromatography (a mixed solvent of hexane/toluene as an eluent) and recrystallization (a mixed solvent of ethanol/toluene) to obtain white solids (115 mmol, yield 80%). The obtained purified product was confirmed to have a molecular weight of 690 through FAB-MS measurement, and thus it was clearly confirmed to obtain Intermediate H-11 b.

### Synthesis of Intermediate H-11c

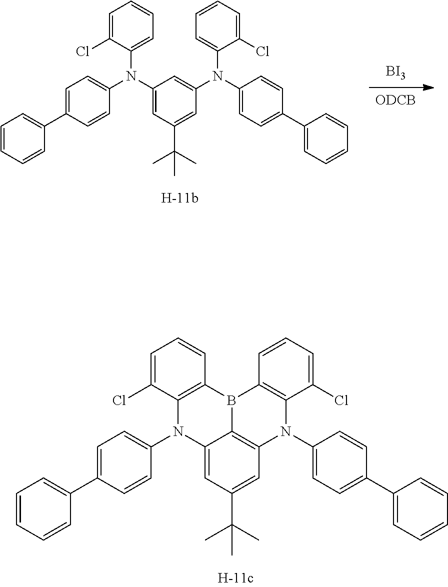

To a three-necked flask, Intermediate H-11b (115 mmol) was added to perform Ar substitution, was then dissolved by adding 50 mL of ODCB, BI₃ (230 mmol) was then added thereto, and the resultant mixture was stirred at about 180° C. for about 24 hours. The reaction solution was subjected to dispersion washing with a large amount of acetonitrile, and then solids were recovered through filtration. The obtained crude product was purified by silica gel column chromatography (a mixed solvent of hexane/dichloromethane as an eluent) and recrystallization (a mixed solvent of ethanol/toluene) to obtain yellow solids (57 mmol, yield 50%). The obtained purified product was confirmed to have a molecular weight of 698 through FAB-MS measurement, and thus it was clearly confirmed to obtain Intermediate H-11c.

### Synthesis of Intermediate H-11d

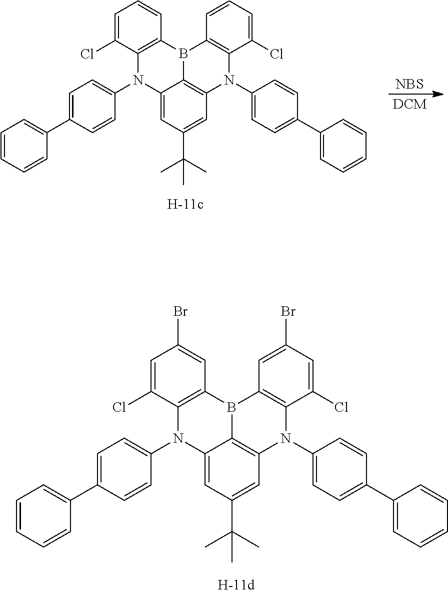

To a three-necked flask, Intermediate H-11c (57 mmol) and NBS (143 mmol) were added to perform Ar substitution, 20 mL of DCM was then added thereto, and the resultant mixture was stirred at room temperature for about 1 hour. Water was added to the reaction system, and an organic layer was extracted by utilizing DCM, and then was dried over magnesium sulfate to distill the solvent off. The obtained crude product was purified by silica gel column chromatography (a mixed solvent of hexane/toluene as an eluent) and recrystallization (a mixed solvent of ethanol/toluene) to obtain yellow solids (43 mmol, yield 75%). The obtained purified product was confirmed to have a molecular weight of 855 through FAB-MS measurement, and thus it was clearly confirmed to obtain Intermediate H-11d.

### Synthesis of Intermediate H-11e

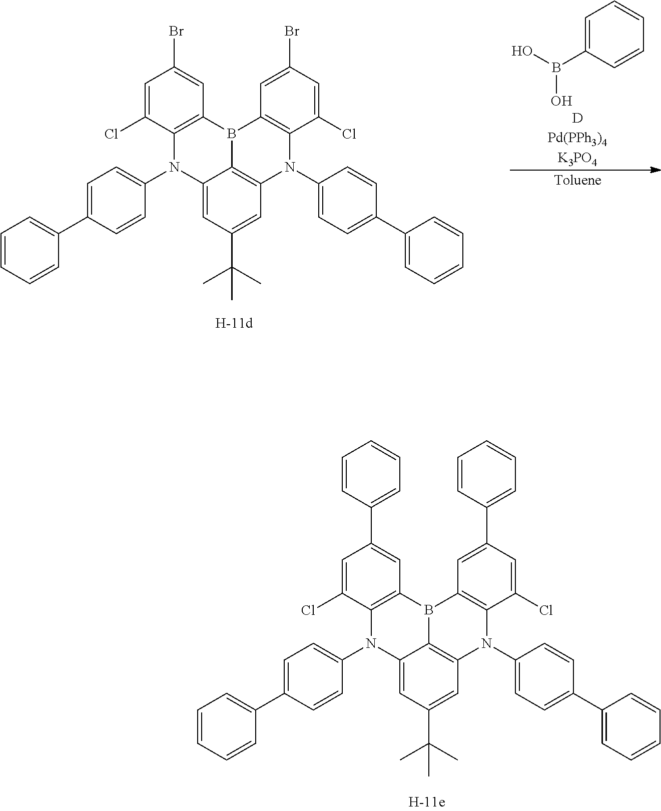 [SMILES: CC(C)(C)c1cc2c3c(c1)N(c1ccc(-c4ccccc4)cc1)c1c(Cl)cc(Br)cc1B3c1cc(Br)cc(Cl)c1N2c1ccc(-c2ccccc2)cc1 ; OB(O)c1ccccc1 ; "Toluene" ; CC(C)(C)c1cc2c3c(c1)N(c1ccc(-c4ccccc4)cc1)c1c(Cl)cc(-c4ccccc4)cc1B3c1cc(-c3ccccc3)cc(Cl)c1N2c1ccc(-c2ccccc2)cc1 ; "DPd(PPh3)4K3PO4"]

To a three-necked flask, Intermediate H-11d (43 mmol), Intermediate D (86 mmol), K₃PO₄ (172 mmol), and Pd(PPh₃)₄ (5 mmol) were added to perform Ar substitution, 100 mL of toluene was then added thereto, and the resultant mixture was stirred at about 80° C. for about 8 hours. Water was added to the reaction system, and an organic layer was extracted by utilizing toluene, and then was dried over magnesium sulfate to distill the solvent off. The obtained crude product was purified by silica gel column chromatography (a mixed solvent of hexane/toluene as an eluent) and recrystallization (a mixed solvent of ethanol/toluene) to obtain yellow solids (35 mmol, yield 81%). The obtained purified product was confirmed to have a molecular weight of 850 through FAB-MS measurement, and thus it was clearly confirmed to obtain Intermediate H-11e.

### Synthesis of Compound H-11

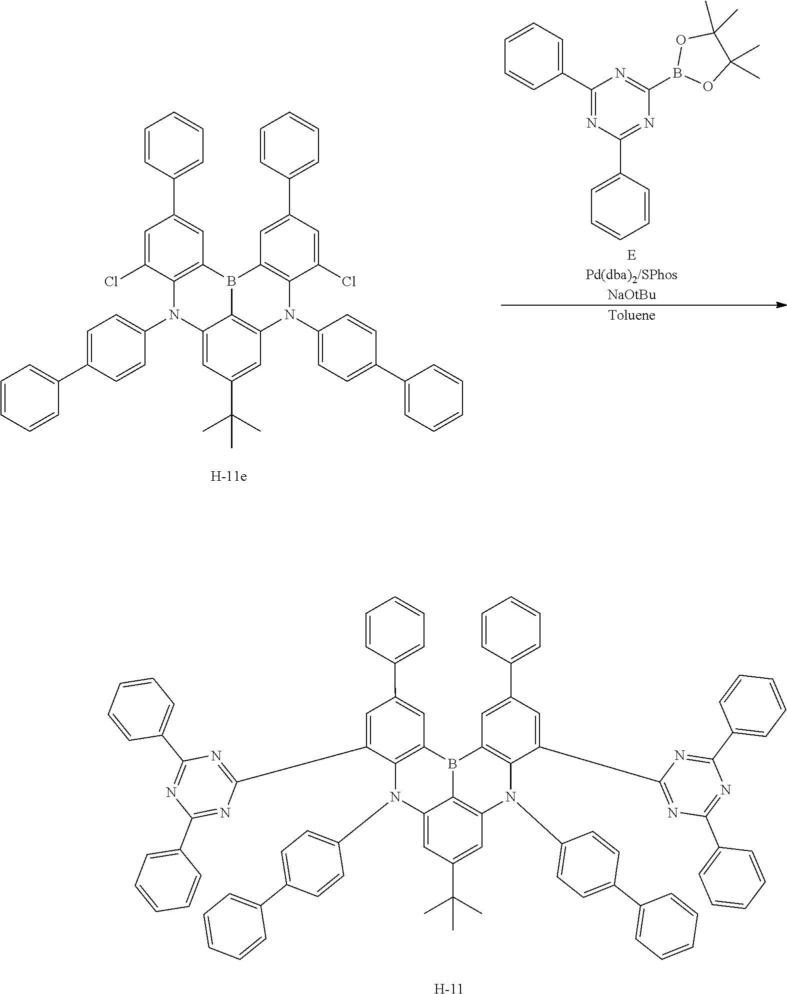

To a three-necked flask, Intermediate H-11e (35 mmol), Intermediate E (105 mmol), Pd(dba)₂ (4 mmol), 2-dicyclohexylphosphino-2′,6′-dimethoxybiphenyl (SPhos) (8 mmol), and NaOtBu (105 mmol) were added to perform Ar substitution, 350 mL of toluene was then added thereto, and the resultant mixture was stirred at about 120° C. for about 12 hours. Water was added to the reaction system, and an organic layer was extracted by utilizing toluene, and then was dried over magnesium sulfate to distill the solvent off. The obtained crude product was purified by silica gel column chromatography (a mixed solvent of hexane/toluene as an eluent) and recrystallization (a mixed solvent of ethanol/toluene) to obtain yellow solids (21 mmol, yield 60%). The obtained purified product was confirmed to have a molecular weight of 1243 through FAB-MS measurement, and thus it was clearly confirmed to obtain Compound H-11.

### (3) Synthesis of Compound B-13

### Synthesis of Intermediate B-13a

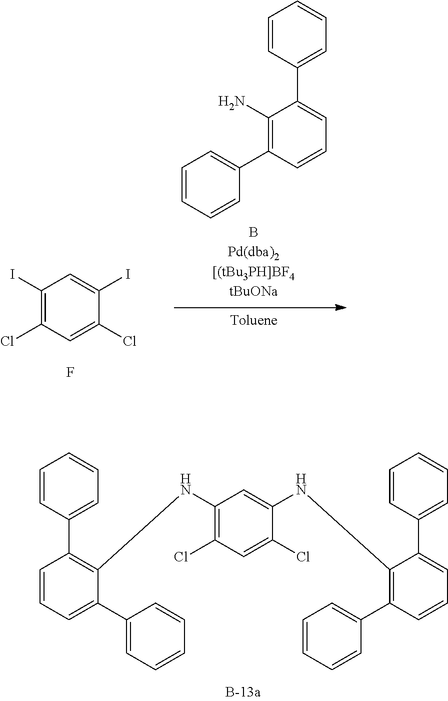

To a three-necked flask, Intermediate F (150 mmol), Intermediate B (300 mmol), tBuONa (450 mmol), Pd(dba)₂ (15 mmol), and [(tBu)₃PH]BF₄ (30 mmol) were added to perform Ar substitution, 1,000 mL of toluene was then added thereto, and the resultant mixture was stirred at about 50° C. for about 6 hours, Water was added to the reaction system, and an organic layer was extracted by utilizing toluene, and then was dried over magnesium sulfate to distill the solvent off. The obtained crude product was purified by silica gel column chromatography (a mixed solvent of hexane/toluene as an eluent) and recrystallization (a mixed solvent of ethanol/toluene) to obtain white solids (132 mmol, yield 88%). The obtained purified product was confirmed to have a molecular weight of 634 through FAB-MS measurement, and thus it was clearly confirmed to obtain Intermediate B-13a.

### Synthesis of Intermediate B-13b

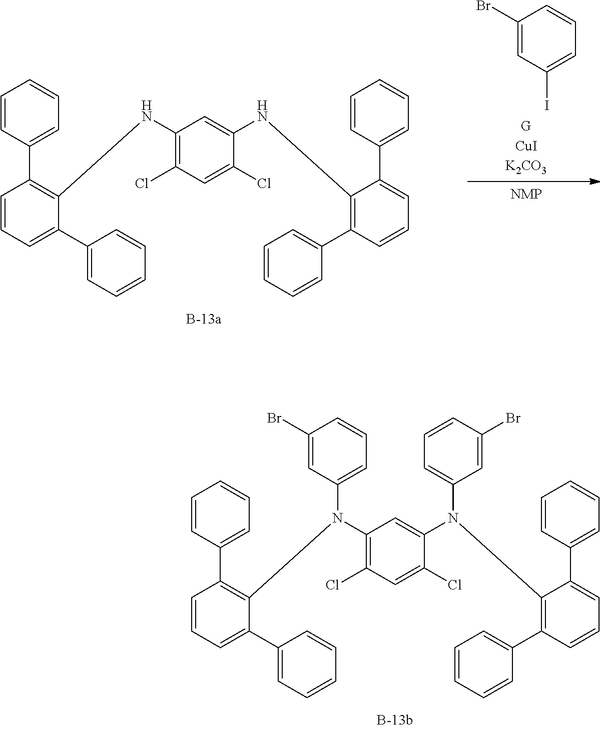 [SMILES: Clc1cc(Cl)c(Nc2c(-c3ccccc3)cccc2-c2ccccc2)cc1Nc1c(-c2ccccc2)cccc1-c1ccccc1 ; Brc1cccc(I)c1 ; Clc1cc(Cl)c(N(c2cccc(Br)c2)c2c(-c3ccccc3)cccc2-c2ccccc2)cc1N(c1cccc(Br)c1)c1c(-c2ccccc2)cccc1-c1ccccc1]

To a three-necked flask, Intermediate B-13a (132 mmol), Intermediate G (1320 mmol), K₂CO₃ (924 mmol), and CuI (264 mmol) were added to perform Ar substitution, and then the mixture was dissolved by adding 50 mL of NMP, and the resultant mixture was stirred at about 190° C. for about 66 hours. Water was added to the reaction system, and an organic layer was extracted by utilizing toluene, and then was dried over magnesium sulfate to distill the solvent off. The obtained crude product was purified by silica gel column chromatography (a mixed solvent of hexane/toluene as an eluent) and recrystallization (a mixed solvent of ethanol/toluene) to obtain white solids (106 mmol, yield 80%). The obtained purified product was confirmed to have a molecular weight of 944 through FAB-MS measurement, and thus it was clearly confirmed to obtain Intermediate B-13b.

### Synthesis of Intermediate B-13c

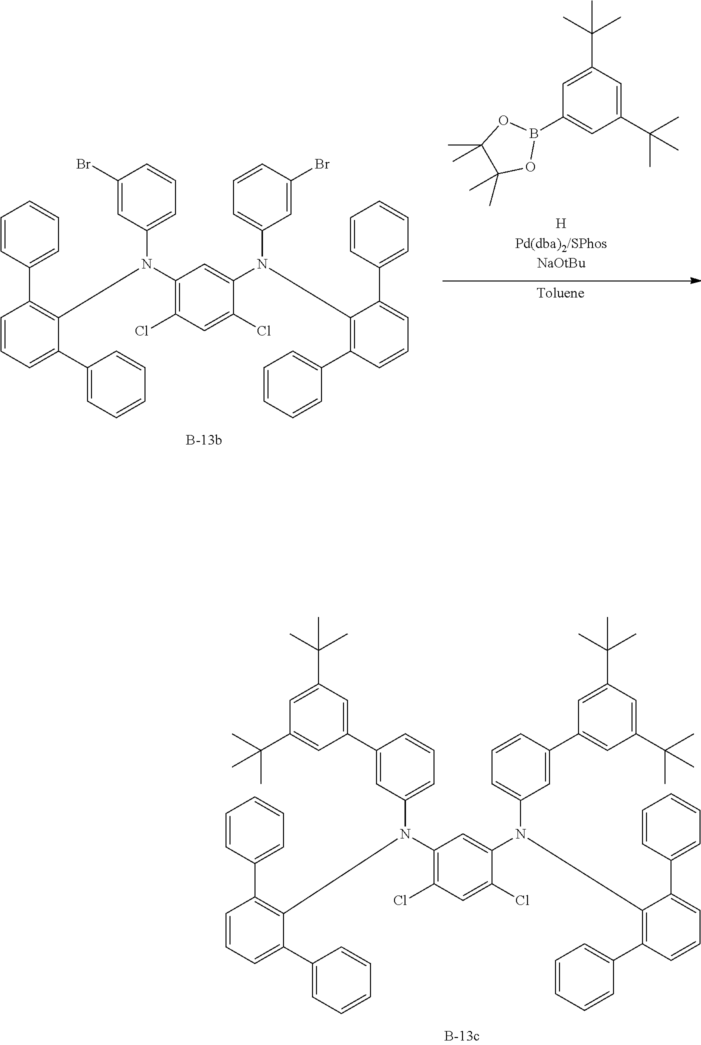 [SMILES: Clc1cc(Cl)c(N(c2cccc(Br)c2)c2c(-c3ccccc3)cccc2-c2ccccc2)cc1N(c1cccc(Br)c1)c1c(-c2ccccc2)cccc1-c1ccccc1 ; CC(C)(C)c1cc(B2OC(C)(C)C(C)(C)O2)cc(C(C)(C)C)c1 ; CC(C)(C)c1cc(-c2cccc(N(c3cc(N(c4cccc(-c5cc(C(C)(C)C)cc(C(C)(C)C)c5)c4)c4c(-c5ccccc5)cccc4-c4ccccc4)c(Cl)cc3Cl)c3c(-c4ccccc4)cccc3-c3ccccc3)c2)cc(C(C)(C)C)c1]

To a three-necked flask, Intermediate B-13b (106 mmol), Intermediate H (332 mmol), Pd(dba)₂ (20 mmol), SPhos (40 mmol), and NaOtBu (332 mmol) were added to perform Ar substitution, 300 mL of toluene was then added thereto, and the resultant mixture was stirred at about 80° C. for about 12 hours. Water was added to the reaction system, and an organic layer was extracted by utilizing toluene, and then was dried over magnesium sulfate to distill the solvent off. The obtained crude product was purified by silica gel column chromatography (a mixed solvent of hexane/toluene as an eluent) and recrystallization (a mixed solvent of ethanol/toluene) to obtain white solids (79 mmol, yield 75%). The obtained purified product was confirmed to have a molecular weight of 1162 through FAB-MS measurement, and thus it was clearly confirmed to obtain Intermediate B-13c.

### Synthesis of Intermediate B-13d

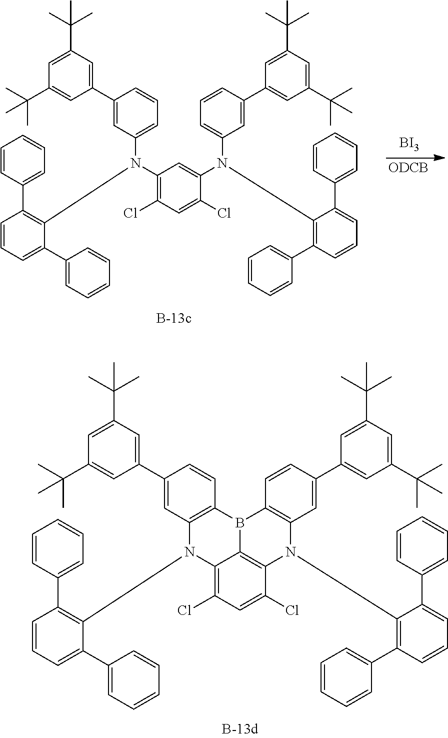

To a three-necked flask, Intermediate B-13c (79 mmol) was added to perform Ar substitution, was then dissolved by adding 30 mL of ODCB, BI₃ (632 mmol) was then added thereto, and the resultant mixture was stirred at about 160° C. for about 36 hours. The reaction solution was subjected to dispersion washing with a large amount of acetonitrile, and then solids were recovered through filtration. The obtained crude product was purified by silica gel column chromatography (a mixed solvent of hexane/dichloromethane as an eluent) and recrystallization (a mixed solvent of ethanol/toluene) to obtain yellow solids (25 mmol, yield 32%). The obtained purified product was confirmed to have a molecular weight of 1170 through FAB-MS measurement, and thus it was clearly confirmed to obtain Intermediate B-13d.

### Synthesis of Compound B-13

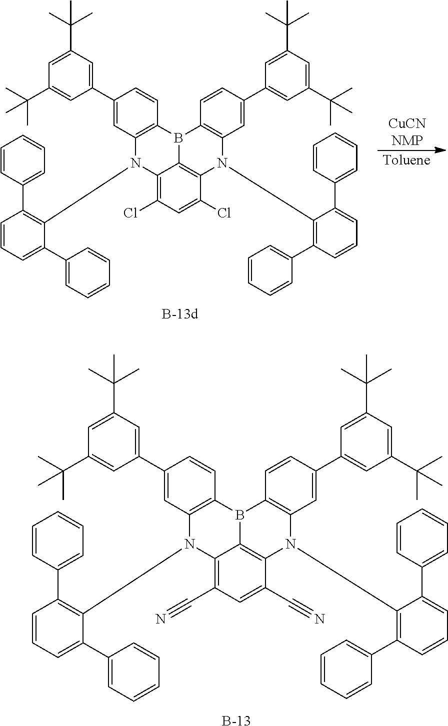

To a three-necked flask, Intermediate B-13d (25 mmol) and CuCN (75 mmol) were added to perform Ar substitution, 250 mL of NMP was then added thereto, and the resultant mixture was stirred at about 150° C. for about 50 hours. Water was added to the reaction system, and an organic layer was extracted by utilizing DCM, and then was dried over magnesium sulfate to distill the solvent off. The obtained crude product was purified by silica gel column chromatography (a mixed solvent of hexane/toluene as an eluent) and recrystallization (a mixed solvent of ethanol/toluene) to obtain yellow solids (16 mmol, yield 64%). The obtained purified product was confirmed to have a molecular weight of 1151 through FAB-MS measurement, and thus it was clearly confirmed to obtain Compound B-13.

### (4) Synthesis of Compound D-12

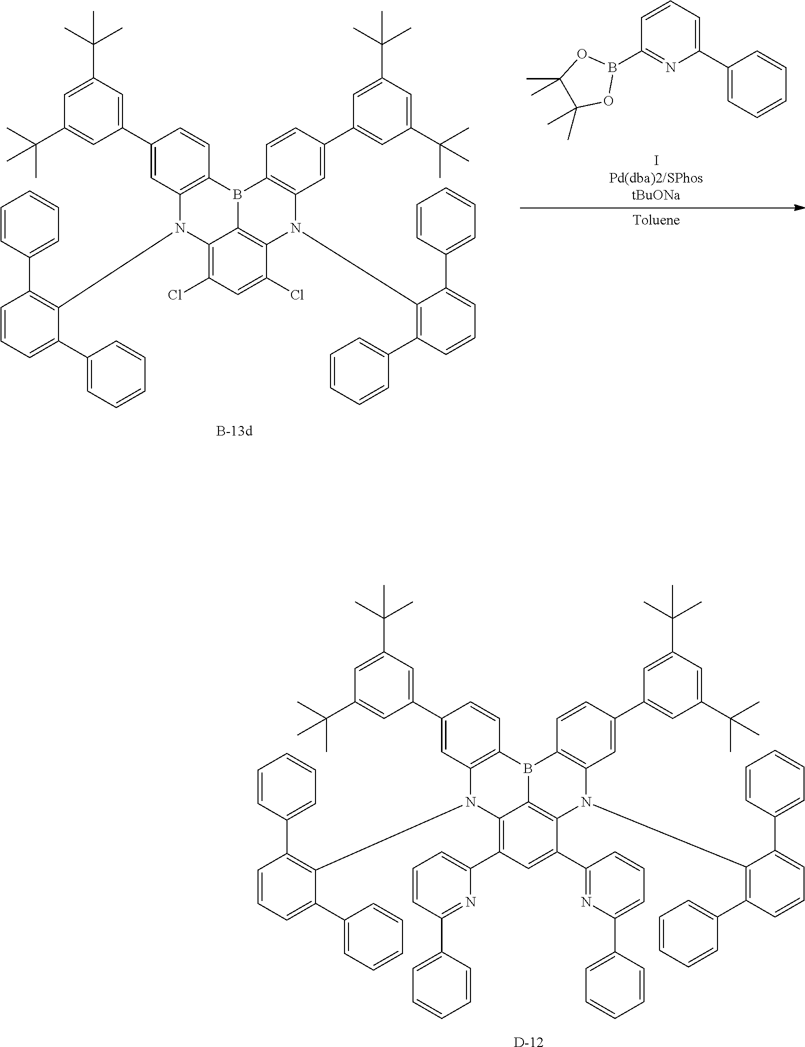

To a three-necked flask, Intermediate B-13d (25 mmol), Intermediate 1 (75 mmol), tBuONa (100 mmol), Pd(dba)₂ (5 mmol), and SPhos (10 mmol) were added to perform Ar substitution, 100 mL of toluene was then added thereto, and the resultant mixture was stirred at about 110° C. for about 8 hours. Water was added to the reaction system, and an organic layer was extracted by utilizing toluene, and then was dried over magnesium sulfate to distill the solvent off. The obtained crude product was purified by silica gel column chromatography (a mixed solvent of hexane/toluene as an eluent) and recrystallization (a mixed solvent of ethanol/toluene) to obtain yellow solids (20 mmol, yield 80%). The obtained purified product was confirmed to have a molecular weight of 1407 through FAB-MS measurement, and thus it was clearly confirmed to obtain Compound D-12.

### (5) Synthesis of Compound J-1

### Synthesis of Intermediate J-1a

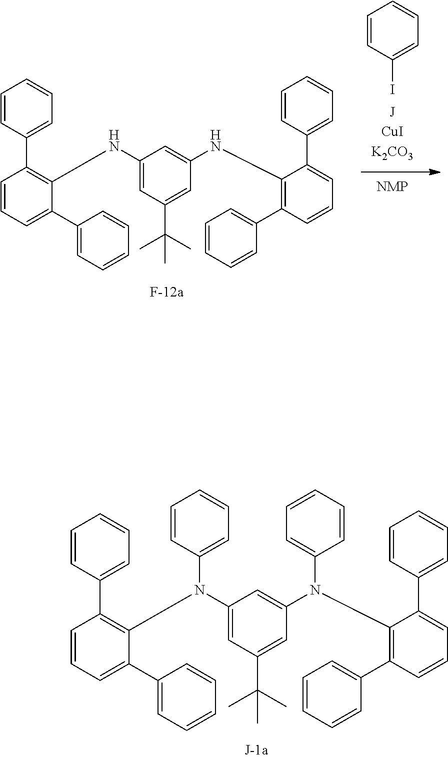 [SMILES: CC(C)(C)c1cc(Nc2c(-c3ccccc3)cccc2-c2ccccc2)cc(Nc2c(-c3ccccc3)cccc2-c2ccccc2)c1 ; Ic1ccccc1 ; CC(C)(C)c1cc(N(c2ccccc2)c2c(-c3ccccc3)cccc2-c2ccccc2)cc(N(c2ccccc2)c2c(-c3ccccc3)cccc2-c2ccccc2)c1]

To a three-necked flask, Intermediate F-12a (129 mmol), Intermediate J (1290 mmol), K₂CO₃ (645 mmol), and CuI (141 mmol) were added to perform Ar substitution, and then the mixture was dissolved by adding 50 mL of NMP, and the resultant mixture was stirred at about 200° C. for about 20 hours. Water was added to the reaction system, and an organic layer was extracted by utilizing toluene, and then was dried over magnesium sulfate to distill the solvent off. The obtained crude product was purified by silica gel column chromatography (a mixed solvent of hexane/toluene as an eluent) and recrystallization (a mixed solvent of ethanol/toluene) to obtain white solids (111 mmol, yield 86%). The obtained purified product was confirmed to have a molecular weight is 773 through FAB-MS measurement, and thus it was clearly confirmed to obtain Intermediate J-1a.

### Synthesis of Intermediate J-1 b

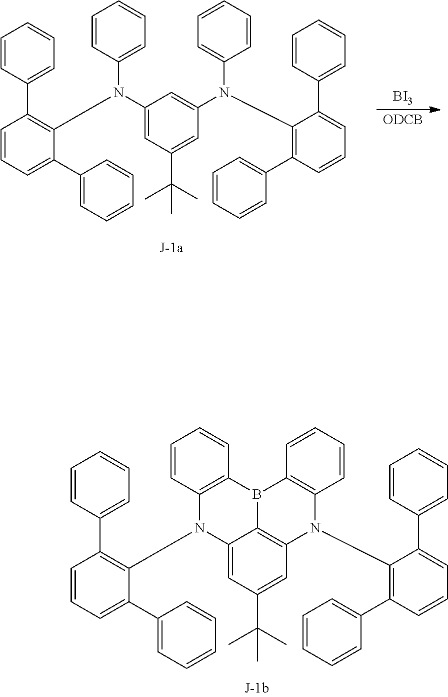

To a three-necked flask, Intermediate J-1a (111 mmol) was added to perform Ar substitution, was then dissolved by adding 110 mL of ODCB, BI₃ (222 mmol) was then added thereto, and the resultant mixture was stirred at about 180° C. for about 5 hours. The reaction solution was subjected to dispersion washing with a large amount of acetonitrile, and then solids were recovered through filtration. The obtained crude product was purified by silica gel column chromatography (a mixed solvent of hexane/dichloromethane as an eluent) and recrystallization (a mixed solvent of ethanol/toluene) to obtain yellow solids (34 mmol, yield 31%). The obtained purified product was confirmed to have a molecular weight of 781 through FAB-MS measurement, and thus it was clearly confirmed to obtain Intermediate J-1 b.

### Synthesis of Intermediate J-1c

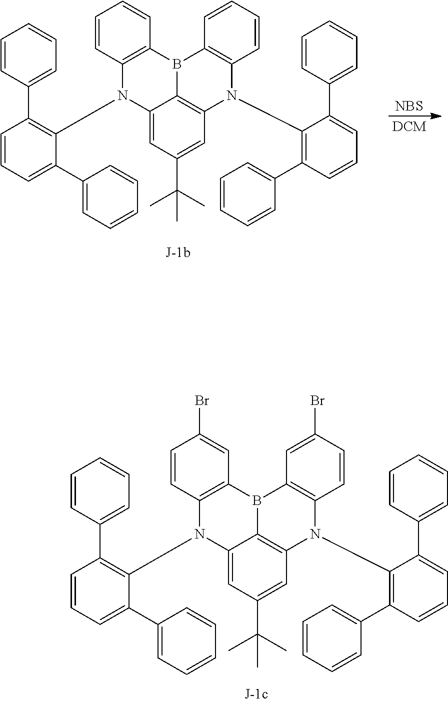

To a three-necked flask, Intermediate J-1b (34 mmol) and NBS (68 mmol) were added to perform Ar substitution, 20 mL of DCM was then added thereto, and the resultant mixture was stirred at room temperature for about 1 hour. Water was added to the reaction system, and an organic layer was extracted by utilizing DCM, and then was dried over magnesium sulfate to distill the solvent off. The obtained crude product was purified by silica gel column chromatography (a mixed solvent of hexane/toluene as an eluent) and recrystallization (a mixed solvent of ethanol/toluene) to obtain yellow solids (33 mmol, yield 97%). The obtained purified product was confirmed to have a molecular weight of 939 through FAB-MS measurement, and thus it was clearly confirmed to obtain Intermediate J-1c.

### Synthesis of Compound J-1

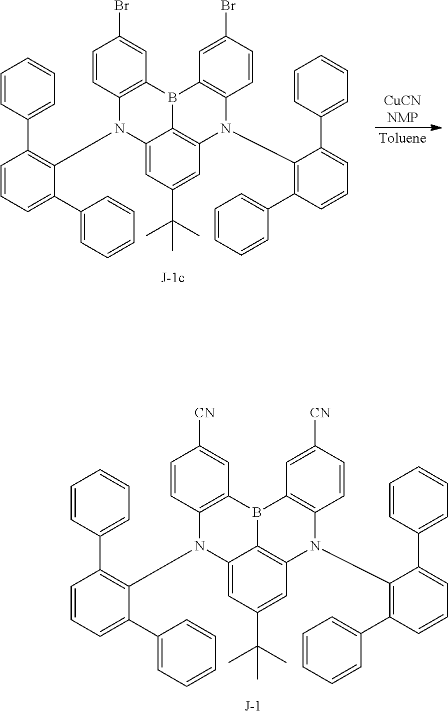

To a three-necked flask, Intermediate J-1c (33 mmol) and CuCN (99 mmol) were added to perform Ar substitution, 200 mL of NMP was then added thereto, and the resultant mixture was stirred at about 180° C. for about 5 hours. Water was added to the reaction system, and an organic layer was extracted by utilizing toluene, and then was dried over magnesium sulfate to distill the solvent off. The obtained crude product was purified by silica gel column chromatography (a mixed solvent of hexane/toluene as an eluent) and recrystallization (a mixed solvent of ethanol/toluene) to obtain yellow solids (16 mmol, yield 48%). The obtained purified product was confirmed to have a molecular weight of 831 through FAB-MS measurement, and thus it was clearly confirmed to obtain Compound J-1.

### 2. Manufacture and Evaluation of Light Emitting Elements

A light emitting element of an example including the fused polycyclic compound of an example in an emission layer of the light emitting element was manufactured as follows. Fused polycyclic compounds of Compounds F-12, H-11, B-13, D-12, and J-1, which are Example Compounds as described above, were respectively utilized as dopant materials for the emission layers to manufacture the light emitting elements of Examples 1 to 5. Comparative Examples 1 to 10 correspond to the light emitting elements manufactured by utilizing Comparative Example Compounds X-1 to X-10 as emission layer dopant materials, respectively.

### Example Compounds

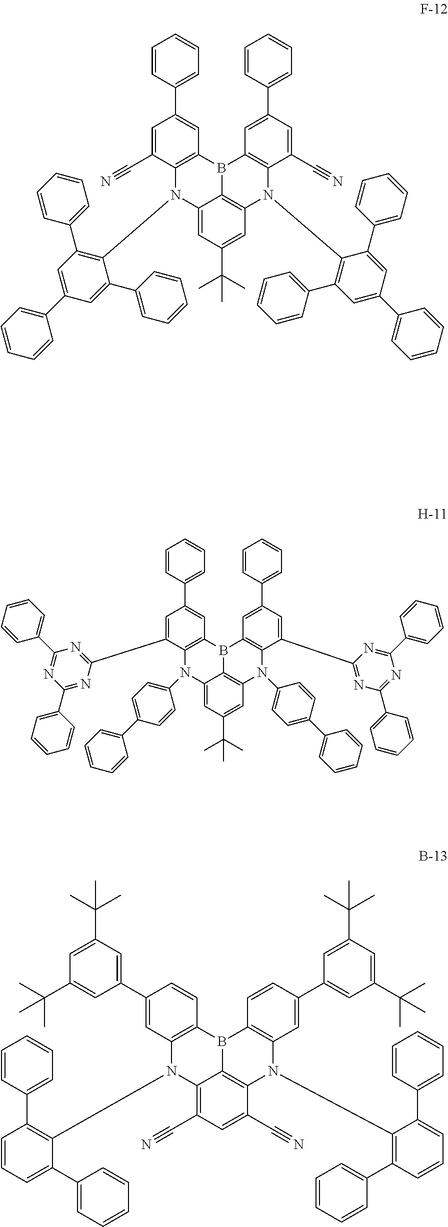 [SMILES: CC(C)(C)c1cc2c3c(c1)N(c1c(-c4ccccc4)cc(-c4ccccc4)cc1-c1ccccc1)c1c(C#N)cc(-c4ccccc4)cc1B3c1cc(-c3ccccc3)cc(C#N)c1N2c1c(-c2ccccc2)cc(-c2ccccc2)cc1-c1ccccc1 ; CC(C)(C)c1cc2c3c(c1)N(c1ccc(-c4ccccc4)cc1)c1c(cc(-c4ccccc4)cc1-c1nc(-c4ccccc4)nc(-c4ccccc4)n1)B3c1cc(-c3ccccc3)cc(-c3nc(-c4ccccc4)nc(-c4ccccc4)n3)c1N2c1ccc(-c2ccccc2)cc1 ; CC(C)(C)c1cc(-c2ccc3c(c2)N(c2c(-c4ccccc4)cccc2-c2ccccc2)c2c(C#N)cc(C#N)c4c2B3c2ccc(-c3cc(C(C)(C)C)cc(C(C)(C)C)c3)cc2N4c2c(-c3ccccc3)cccc2-c2ccccc2)cc(C(C)(C)C)c1]

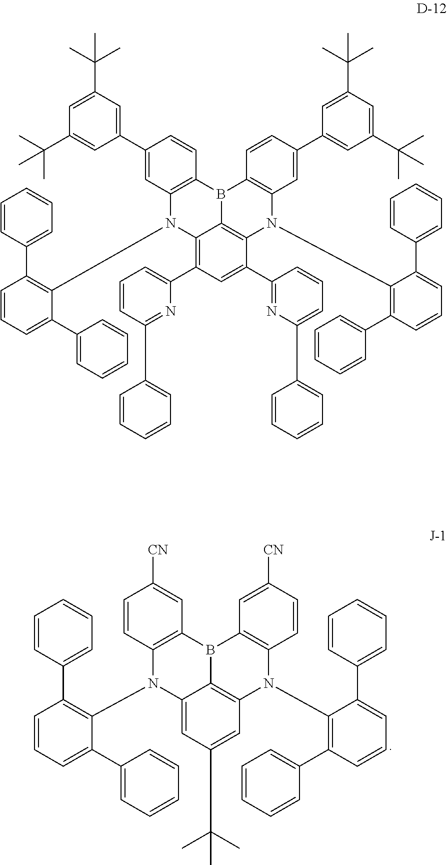 [SMILES: CC(C)(C)c1cc(-c2ccc3c(c2)N(c2c(-c4ccccc4)cccc2-c2ccccc2)c2c(-c4cccc(-c5ccccc5)n4)cc(-c4cccc(-c5ccccc5)n4)c4c2B3c2ccc(-c3cc(C(C)(C)C)cc(C(C)(C)C)c3)cc2N4c2c(-c3ccccc3)cccc2-c2ccccc2)cc(C(C)(C)C)c1 ; CC(C)(C)c1cc2c3c(c1)N(c1c(-c4ccccc4)cccc1-c1ccccc1)c1ccc(C#N)cc1B3c1cc(C#N)ccc1N2c1c(-c2ccccc2)cccc1-c1ccccc1]

### Comparative Example Compounds

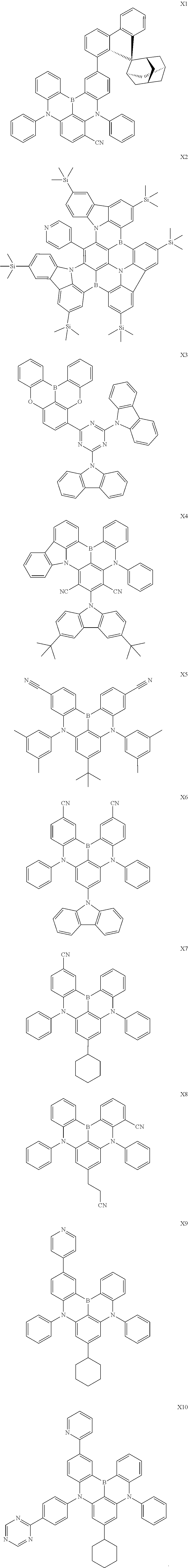

### Manufacture of Light Emitting Elements

ITO was utilized to form a 150 nm-thick first electrode, dipyrazino[2,3-f: 2′,3′-h]quinoxaline-2,3,6,7,10,11-hexacarbonitrile (HATCN) was utilized to form a 10 nm-thick hole injection layer on the first electrode, N,N-di(1-naphthyl)-N,N′-diphenyl-(1,1′-biphenyl)-4,4′-diamine (NPD) was utilized to form a 80 nm-thick hole transport layer on the hole injection layer, 1,3-bis(N-carbazolyl)benzene (mCP) was utilized to form a 5 nm-thick emission auxiliary layer on the hole transport layer, Example Compound or Comparative Example Compound was doped by 1% by weight to 3,3′-di(9H-carbazol-9-yl)-1,1′-biphenyl (mCBP) to form a 20 nm-thick emission layer on the emission auxiliary layer, 2,2′,2″-(1,3,5-benzinetriyl)-tris(1-phenyl-1-H-benzimidazole) (TPBi) was utilized to form a 30 nm-thick electron transport layer on the emission layer, LiF was utilized to form a 0.5 nm-thick electron injection layer on the electron transport layer, and Al was utilized to form a 300 nm-thick second electrode on the electron injection layer. Each layer was formed by a deposition method in a vacuum atmosphere.

Compounds utilized for manufacturing the light emitting elements of Examples and Comparative Examples are disclosed herein. The compounds below are other utilized materials, and commercial products were subjected to sublimation purification and utilized to manufacture the elements.

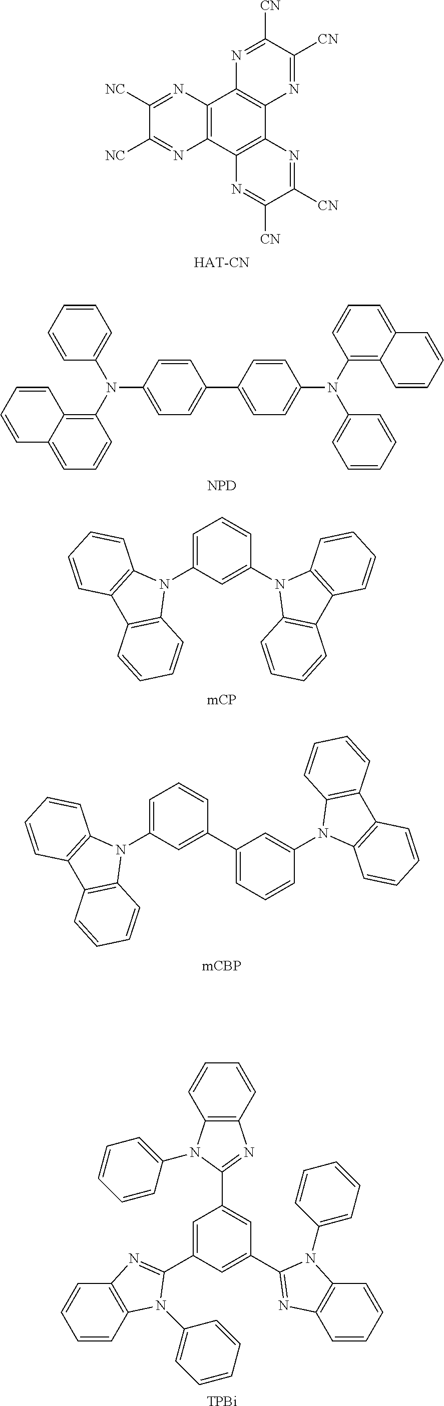

### Evaluation of Physical Properties of Example and Comparative Example Compounds

Physical properties of Compounds F-12, H-11, B-13, D-12, and J-1, which are Example Compounds, and Comparative Example Compounds X1 to X10, which are Comparative Example Compounds, are each evaluated and the results are listed in Table 1. In Table 1, the emission wavelength (λ_{film}) and fluorescence quantum yield in deposition films of Example Compounds and Comparative Example Compounds were each evaluated.

In the evaluation of emission properties, a 20 wt % dope film was formed on a quartz glass by depositing PPF as a matrix, and the fluorescence emission spectrum was measured utilizing a JASCO V-670 spectrometer. The fluorescence quantum yield was measured utilizing JASCOILF-835 integrating sphere system:

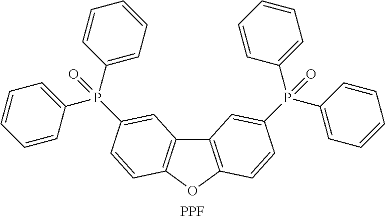

TABLE 1

| | λ_{film} | Fluorescence quantum |
|---|---|---|
| Compound | (nm) | yield (%) |
| Compound F-12 | 473 | 96 |
| Compound H-11 | 480 | 95 |
| Compound B-13 | 458 | 97 |
| Compound D-12 | 460 | 95 |
| Compound J-1 | 460 | 89 |
| Comparative Example Compound X1 | 457 | 87 |
| Comparative Example Compound X2 | 476 | 73 |
| Comparative Example Compound X3 | 452 | 88 |
| Comparative Example Compound X4 | 484 | 73 |
| Comparative Example Compound X5 | 475 | 76 |
| Comparative Example Compound X6 | 453 | 83 |
| Comparative Example Compound X7 | 457 | 79 |
| Comparative Example Compound X8 | 476 | 68 |
| Comparative Example Compound X9 | 463 | 76 |
| Comparative Example Compound X10 | 465 | 71 |

### Evaluation of Light Emitting Element Characteristics

Evaluation results of the light emitting elements of Examples 1 to 5 and Comparative Examples 1 to 10 are listed in Table 2. A maximum emission wavelength (λₘₐₓ), a maximum external quantum efficiency (EQEₘₐₓ), and a relative service life (LT50) in the manufactured light emitting elements are listed in comparison in Table 2.

The voltages and current densities of each of the organic electroluminescence elements were measured by utilizing SourceMeter (Keithley Instruments, Inc., 2400 series), and the brightness and external quantum efficiency were measured by utilizing an external quantum efficiency measurement apparatus, C9920-2-12 manufactured by Hamamatsu Photonics, Co., Japan. In addition, the relative service life is shown by evaluating a brightness half-life from an initial brightness of 100 cd/m². The relative service life is shown relatively on the basis of the result of Comparative Example 1.

TABLE 2

| | | λₘₐₓ | EQEₘₐₓ | LT50 |
|---|---|---|---|---|
| Division | Dopant | (nm) | (%) | (%) |
| Example 1 | Compound F-12 | 474 | 21 | 354 |
| Example 2 | Compound H-11 | 482 | 23 | 269 |
| Example 3 | Compound B-13 | 460 | 22 | 330 |
| Example 4 | Compound D-12 | 461 | 21 | 302 |
| Example 5 | Compound J-1 | 465 | 18 | 260 |
| Comparative | Comparative Example | 459 | 13 | 100 |
| Example 1 | Compound X1 | | | |
| Comparative | Comparative Example | 480 | 17 | 153 |
| Example 2 | Compound X2 | | | |
| Comparative | Comparative Example | 454 | 16 | 39 |
| Example 3 | Compound X3 | | | |
| Comparative | Comparative Example | 486 | 17 | 99 |
| Example 4 | Compound X4 | | | |
| Comparative | Comparative Example | 477 | 14 | 45 |
| Example 5 | Compound X5 | | | |
| Comparative | Comparative Example | 455 | 16 | 140 |
| Example 6 | Compound X6 | | | |
| Comparative | Comparative Example | 453 | 17 | 134 |
| Example 7 | Compound X7 | | | |
| Comparative | Comparative Example | 455 | 16 | 87 |
| Example 8 | Compound X8 | | | |
| Comparative | Comparative Example | 464 | 17 | 110 |
| Example 9 | Compound X9 | | | |
| Comparative | Comparative Example | 466 | 16 | 91 |
| Example 10 | Compound X10 | | | |

Referring to the results of Table 2, it may be confirmed that Examples of the light emitting elements, in which the fused polycyclic compounds according to examples of the present disclosure are each utilized as a luminescent material, have high efficiency and improved service life characteristics as compared with Comparative Examples. Example Compounds include the fused ring core in which the first to third aromatic rings are fused about the boron atom, the first heteroatom, and the second heteroatom, and include a structure in which the first substituent is introduced at a specific position, and thus may effectively protect the boron atom, thereby achieving high efficiency and long service life. Example Compounds may each have an increase in the luminous efficiency because the intermolecular interaction may be suppressed or reduced by the introduction of the first substituent, thereby controlling the formation of excimer or exciplex. In addition, Example Compounds each have an increase in the distance between adjacent molecules due to the large steric hindrance structure to thereby suppress or reduce the Dexter energy transfer, and thus may suppress or reduce the deterioration of service life caused by the increase of triplet concentration. In addition, Example Compounds each have a structure in which the first substituent is linked at the meta position with respect to the boron atom, and thus may strengthen the bond between the first substituent and the fused ring core, and suppress or reduce a high charge density localized at the nitrogen atom, thereby improving the stability of materials. Therefore, when Example Compounds are applied to the light emitting elements, high luminous efficiency and a long service life may be achieved.

The light emitting element of an embodiment includes the fused polycyclic compound of an embodiment as a light emitting dopant of a thermally activated delayed fluorescence (TADF) light emitting element, and thus may achieve long service life.

The light emitting element of an embodiment may exhibit improved element characteristics with high efficiency and a long service life.

The fused polycyclic compound of an embodiment may be included in an emission layer of a light emitting element to contribute to high efficiency and a long service life (long lifespan) of the light emitting element.

As utilized herein, the terms “substantially,” “about,” or similar terms are used as terms of approximation and not as terms of degree, and are intended to account for the inherent deviations in measured or calculated values that would be recognized by those of ordinary skill in the art. “About” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

In the present disclosure, when particles are spherical, “size” indicates a particle diameter or an average particle diameter, and when the particles are non-spherical, the “size” indicates a major axis length or an average major axis length. The diameter (or size) of the particles may be measured utilizing a scanning electron microscope or a particle size analyzer. As the particle size analyzer, for example, HORIBA, LA-950 laser particle size analyzer, may be utilized. When the size of the particles is measured utilizing a particle size analyzer, the average particle diameter (or size) is referred to as D50. D50 refers to the average diameter (or size) of particles whose cumulative volume corresponds to 50 vol % in the particle size distribution (e.g., cumulative distribution), and refers to the value of the particle size corresponding to 50% from the smallest particle when the total number of particles is 100% in the distribution curve accumulated in the order of the smallest particle size to the largest particle size.

The light-emitting device/element, the display device, the display apparatus, or any other relevant apparatuses/devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

Although the present disclosure has been described with reference to example embodiments of the present disclosure, it will be understood that the present disclosure should not be limited to these embodiments but one or more suitable changes and modifications can be made by those skilled in the art without departing from the spirit and scope of the present disclosure.

Accordingly, the technical scope of the present disclosure is not intended to be limited to the contents set forth in the detailed description of the present disclosure, but is intended to be defined by the appended claims and equivalents thereof.

What is claimed is:

1. A light emitting element, comprising:
a first electrode;
a second electrode on the first electrode; and
at least one functional layer between the first electrode and the second electrode and comprising a fused polycyclic compound represented by Formula 1: 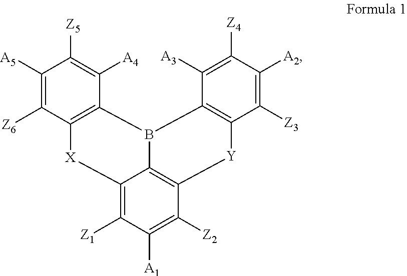
wherein, in Formula 1,
X and Y are each independently O, S, or a substituent represented by Formula 2,
A₁ is hydrogen, deuterium, a halogen, a cyano group, a nitro group, a substituted or unsubstituted amine group, an unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
A₂ to A₅ are each independently hydrogen, deuterium, a halogen, a cyano group, a nitro group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
Z₁ to Z₆ are each independently hydrogen, deuterium, a halogen, a cyano group, a nitro group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or a substituent represented by Formula 3,
at least one selected from among Z₁ to Z₆ is a cyano group, or a substituent represented by a Formula 3,
when each of X and Y is O, the case where each of Z₄ and Z₅ is hydrogen is excluded, and
the case where the fused polycyclic compound represented by Formula 1 comprises an adamantyl group is excluded, 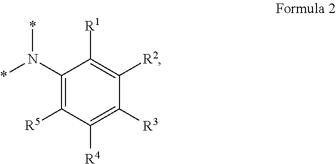
wherein, in Formula 2,
R₁ to R₅ are each independently hydrogen, deuterium, a halogen, a cyano group, a nitro group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
when each of R₁ to R₅ is a substituted or unsubstituted heteroaryl group having 2 to 30 ring-forming carbon atoms, the case where the heteroaryl group contains nitrogen as a ring-forming atom is excluded, and
wherein, in Formula 1, when any one selected from among Z₄ and Z₅ is a cyano group or a substituted or unsubstituted pyridine group, at least one selected from among R₁ to R₅ in Formula 2 is a substituted or unsubstituted aryl group having 6 to 30 ring-forming carbon atoms, or a substituted or unsubstituted heteroaryl group having 2 to 30 ring-forming carbon atoms, and
-* is a position linked to Formula 1, 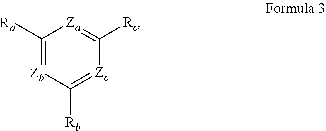
wherein, in Formula 3,
at least one selected from among Zₐ to Z_{c} is N, and the rest are CR_{d},
Rₐ to R_{d} are each independently hydrogen, deuterium, a halogen, a cyano group, a nitro group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and
at least one selected from among Rₐ to R_{d} is a position linked to Formula 1.

2. The light emitting element of claim 1, wherein the at least one functional layer comprises an emission layer, a hole transport region between the first electrode and the emission layer, and an electron transport region between the emission layer and the second electrode, and
wherein the emission layer comprises the fused polycyclic compound.

3. The light emitting element of claim 2, wherein the emission layer is to emit delayed fluorescence.

4. The light emitting element of claim 2, wherein the emission layer is to emit light having a luminescence center wavelength of about 430 nm to about 490 nm.

5. The light emitting element of claim 1, wherein the substituent represented by Formula 3 is represented by any one selected from among Formula 3-1-1 to Formula 3-1-7: 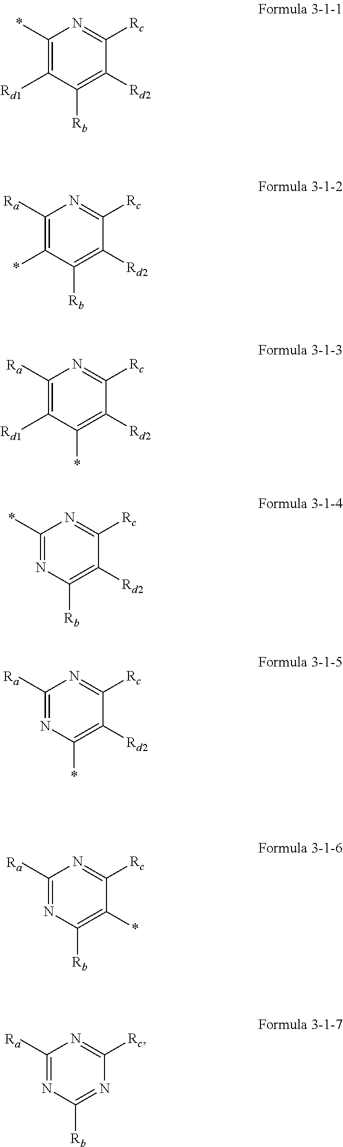
wherein, in Formula 3-1-1 to Formula 3-1-7,
R_{d1} and R_{d2} are each independently hydrogen, deuterium, a halogen, a cyano group, a nitro group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
-* is a position linked to Formula 1, and
Rₐ to R_{c} are each independently the same as defined in Formula 3.

6. The light emitting element of claim 1, wherein the substituent represented by Formula 3 is represented by any one selected from among Formula 3-2-1 to Formula 3-2-7: 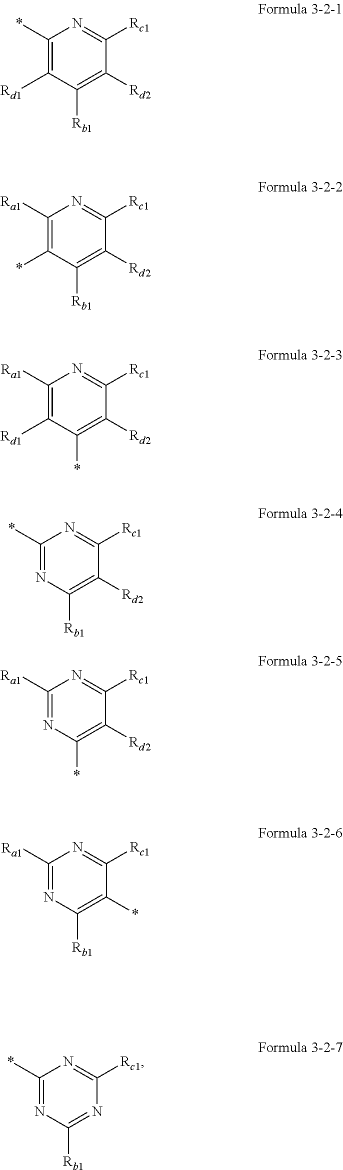
wherein, in Formula 3-2-1 to Formula 3-2-7,
Rₐ₁, R_{b1}, R_{c1}, R_{d1}, and R_{d2} are each independently hydrogen, deuterium, a halogen, a cyano group, a nitro group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
wherein, in Formula 3-2-1, Formula 3-2-4, and Formula 3-2-7,
at least one of R_{b1} or R_{c1} is a substituted or unsubstituted aryl group having 6 to 30 ring-forming carbon atoms,
wherein, in Formula 3-2-2 and Formula 3-2-6,
at least one of Rₐ₁, R_{b1}, or R_{c1} is a substituted or unsubstituted aryl group having 6 to 30 ring-forming carbon atoms,
wherein, in Formula 3-2-3 and Formula 3-2-5,
at least one of Rₐ₁ or R_{c1} is a substituted or unsubstituted aryl group having 6 to 30 ring-forming carbon atoms, and
wherein, ** is a position linked to Formula 1.

7. The light emitting element of claim 1, wherein the fused polycyclic compound represented by Formula 1 is represented by Formula 1-1-1 or Formula 1-1-2: 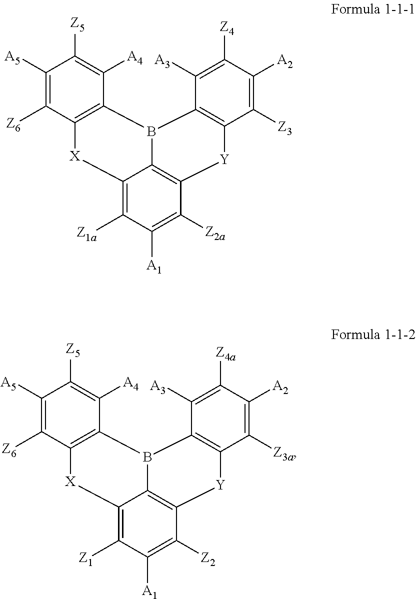
wherein, in Formula 1-1-1 and Formula 1-1-2,
Z₁ₐ to Z₄a are each independently hydrogen, deuterium, a halogen, a cyano group, a nitro group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or a substituent represented by Formula 3,
wherein, in Formula 1-1-1,
at least one of Z₁a or Z₂a is a cyano group, or a substituent represented by Formula 3,
wherein, in Formula 1-1-2,
at least one of Z₃ₐ or Z₄ₐ is a cyano group, or a substituent represented by Formula 3, and
wherein, X, Y, A₁ to A₅, and Z₁ to Z₆ are each independently the same as defined in Formula 1.

8. The light emitting element of claim 1, wherein the fused polycyclic compound represented by Formula 1 is represented by any one selected from among Formula 1-2-1 to Formula 1-2-3: 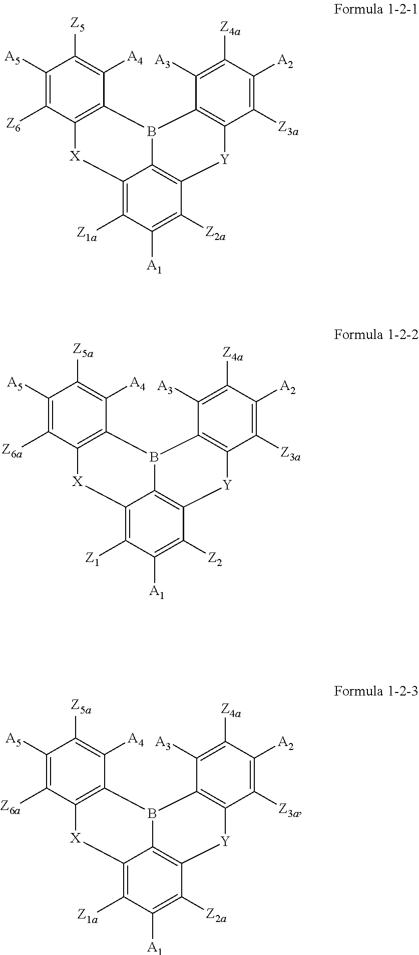
wherein, in Formula 1-2-1 to Formula 1-2-3,
Z₁ₐ to Z₆a are each independently hydrogen, deuterium, a halogen, a cyano group, a nitro group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or a substituent represented by Formula 3,
wherein, in Formula 1-2-1,
at least one of Z₁a or Z₂ₐ and at least one of Z₃ₐ or Z₄ₐ are each independently a cyano group or a substituent represented by Formula 3,
wherein, in Formula 1-2-2,
at least one of Z₃ₐ or Z₄ₐ and at least one of Z₅ₐ or Z₆ₐ are each independently a cyano group or a substituent represented by Formula 3,
wherein, in Formula 1-2-3,
at least one of Z₁a or Z₂ₐ, at least one of Z₃ₐ or Z₄ₐ, and at least one of Z₅ₐ or Z₆ₐ are each independently a cyano group or a substituent represented by Formula 3, and
wherein, X, Y, A₁ to A₅, and Z₁, Z₂, Z₅, and Z₆ are each independently the same as defined in Formula 1.

9. The light emitting element of claim 1, wherein the fused polycyclic compound represented by Formula 1 is represented by any one selected from among Formula 1-3-1 to Formula 1-3-4: 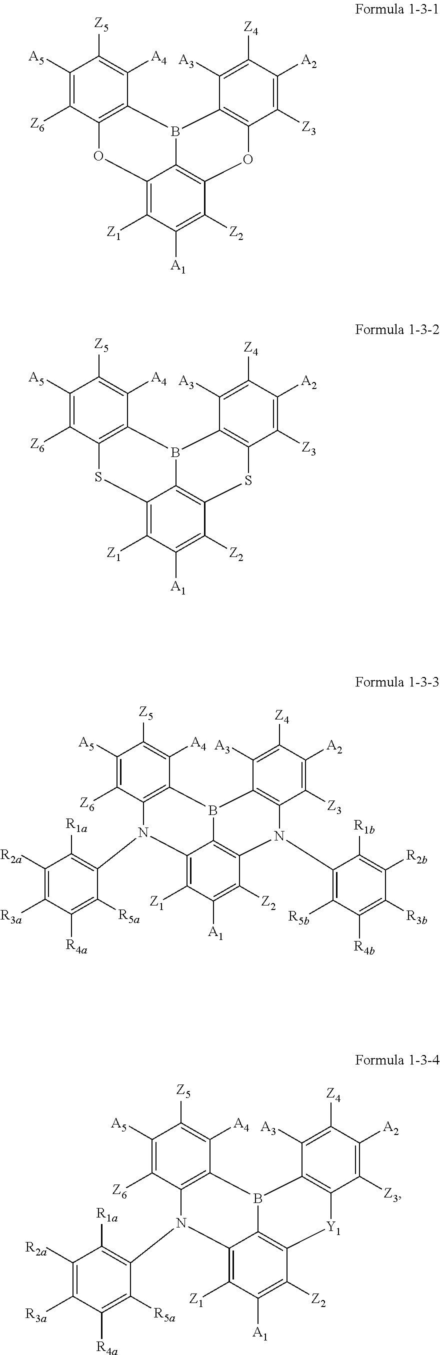
wherein, in Formula 1-3-1 to Formula 1-3-4,
Y₁ is O or S, and
R₁ₐ to R₅ₐ, and R_{1b} to R_{5b} are each independently hydrogen, deuterium, a halogen, a cyano group, a nitro group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
wherein, in Formula 1-3-3 and Formula 1-3-4,
when each of R₁ₐ to R₅ₐ and R_{1b} to R_{5b} is a substituted or unsubstituted heteroaryl group having 2 to 30 ring-forming carbon atoms, the case where the heteroaryl group contains nitrogen as a ring-forming atom is excluded,
wherein, in Formula 1-3-3,
when any one selected from among Z₄ and Z₅ is a cyano group or a substituted or unsubstituted pyridine group, at least one selected from among R₁ₐ to R₅ₐ and at least one selected from among R_{1b} to R_{5b} are each independently a substituted or unsubstituted aryl group having 6 to 30 ring-forming carbon atoms, or a substituted or unsubstituted heteroaryl group having 2 to 30 ring-forming carbon atoms,
wherein, in Formula 1-3-4,
when any one selected from among Z₄ and Z₅ is a cyano group or a substituted or unsubstituted pyridine group, at least one selected from among R₁ₐ to R₅ₐ is a substituted or unsubstituted aryl group having 6 to 30 ring-forming carbon atoms, or a substituted or unsubstituted heteroaryl group having 2 to 30 ring-forming carbon atoms, and
wherein, A₁ to A₅, and Z₁ to Z₆ are each independently the same as defined in Formula 1.

10. The light emitting element of claim 1, wherein the fused polycyclic compound represented by Formula 1 is represented by Formula 1-4: 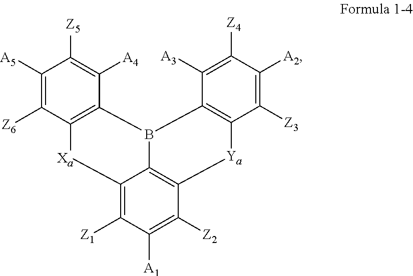
wherein, in Formula 1-4,
Xₐ and Yₐ are each independently represented by any one selected from among Formula 2-1 to Formula 2-7, and
when any one selected from among Z₄ and Z₅ is a cyano group or a substituted or unsubstituted pyridine group, Xₐ and Yₐ are each independently represented by any one among Formula 2-2 to Formula 2-7: 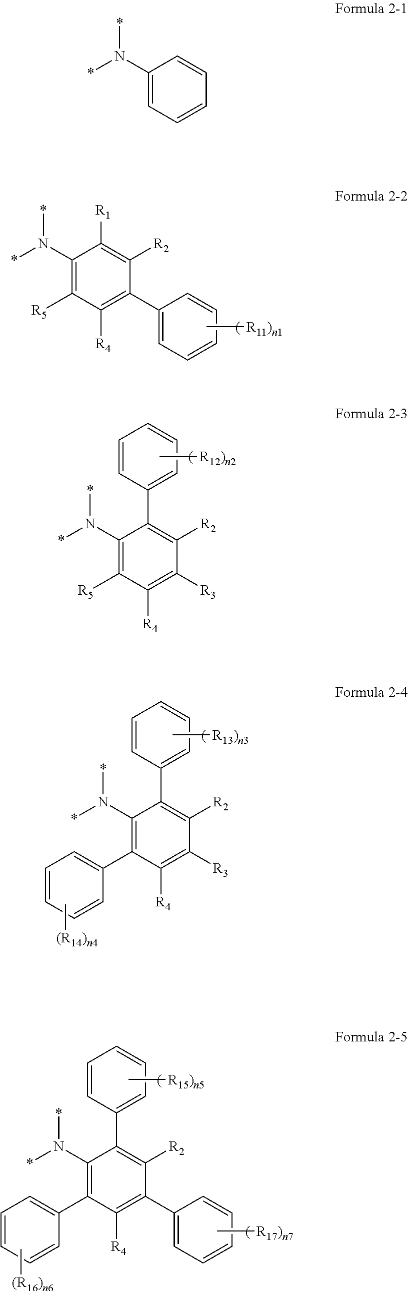 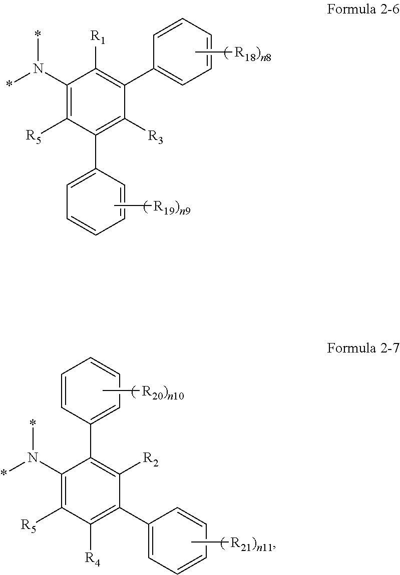
wherein, in Formula 2-1 to Formula 2-7,
R₁₁ to R₂₁ are each independently hydrogen, deuterium, a halogen, a cyano group, a nitro group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
n1 to n11 are each independently an integer of 0 to 5, and
R₁ to R₅ are each independently the same as defined in Formula 2, and
wherein, in Formula 1-4,
A₁ to A₅, and Z₁ to Z₆ are each independently the same as defined in Formula 1.

11. The light emitting element of claim 1, wherein the fused polycyclic compound represented by Formula 1 is represented by any one selected from among Formula 1-5-1 to Formula 1-5-7: 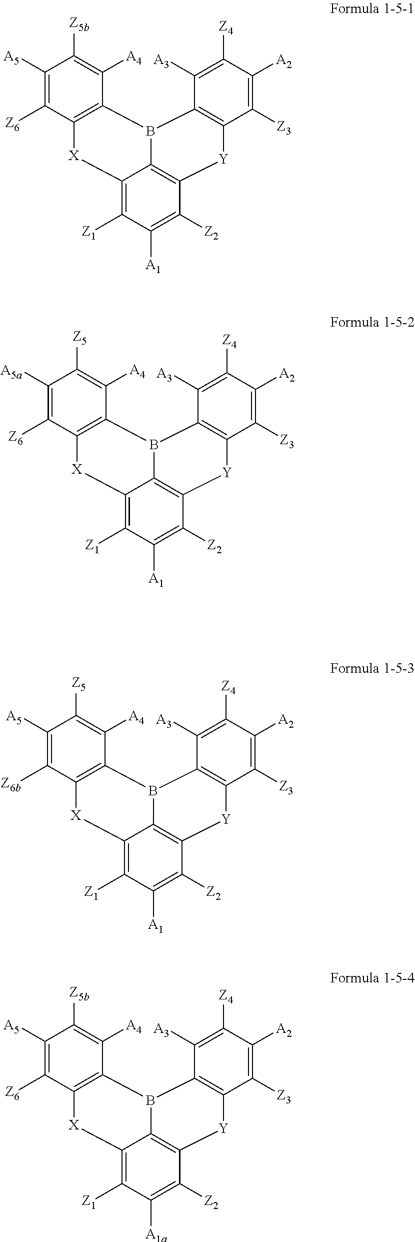 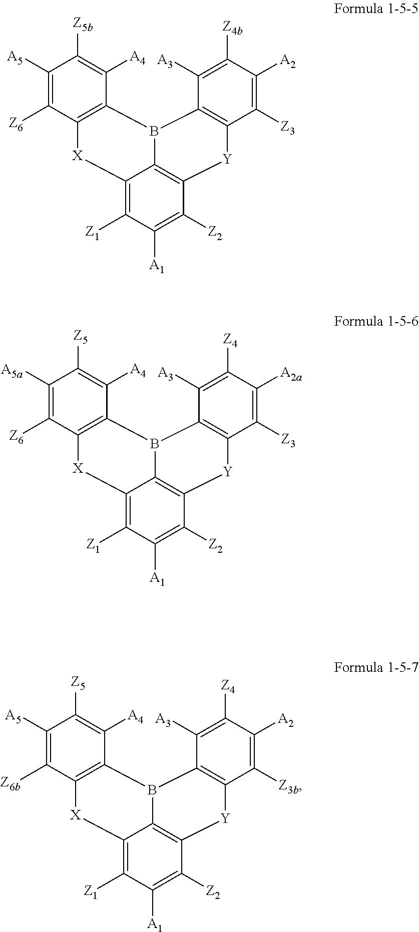
wherein, in Formula 1-5-1 to Formula 1-5-7,
Z_{3b} to Z_{6b}, A₂ₐ, and A₅ₐ are each independently a substituted or unsubstituted alkyl group having 1 to 10 carbon atoms, or represented by Formula A-1 or Formula A-2, and
A₁ₐ is an unsubstituted alkyl group having 1 to 10 carbon atoms, or represented by Formula A-1 or Formula A-2,
wherein, in Formula 1-5-1 and Formula 1-5-4,
at least one selected from among Z₁ to Z₄ and Z₆ is a cyano group, or a substituent represented by Formula 3,
wherein, in Formula 1-5-2 and Formula 1-5-6,
at least one selected from among Z₁ to Z₆ is a cyano group, or a substituent represented by Formula 3,
wherein, in Formula 1-5-3,
at least one selected from among Z₁ to Z₅ is a cyano group, or a substituent represented by Formula 3,
wherein, in Formula 1-5-5,
at least one selected from among Z₁ to Z₃ and Z₆ is a cyano group, or a substituent represented by Formula 3, and
wherein, in Formula 1-5-7,
at least one selected from among Z₁, Z₂, Z₄, and Z₅ is a cyano group, or a substituent represented by Formula 3, 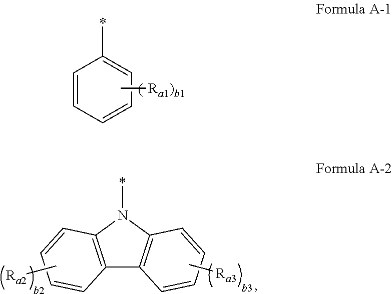
wherein, in Formula A-1 and Formula A-2,
Rₐ₁ to Rₐ₃ are each independently hydrogen, deuterium, a halogen, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
b1 is an integer of 0 to 5,
b2 and b3 are each independently an integer of 0 to 4, and
-* is a position linked to Formula 1-5-1 to Formula 1-5-7, and
wherein, in Formula 1-5-1 to Formula 1-5-7,
X, Y, A₁ to A₅, and Z₁ to Z₆ are each independently the same as defined in Formula 1.

12. The light emitting element of claim 1, wherein the fused polycyclic compound represented by Formula 1 is represented by any one selected from among Formula 1-6-1 to Formula 1-6-8: 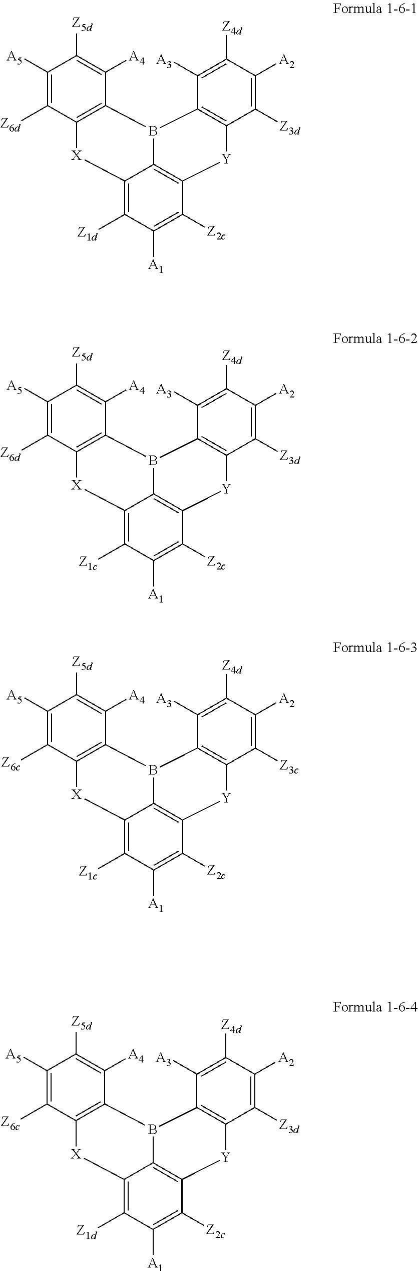 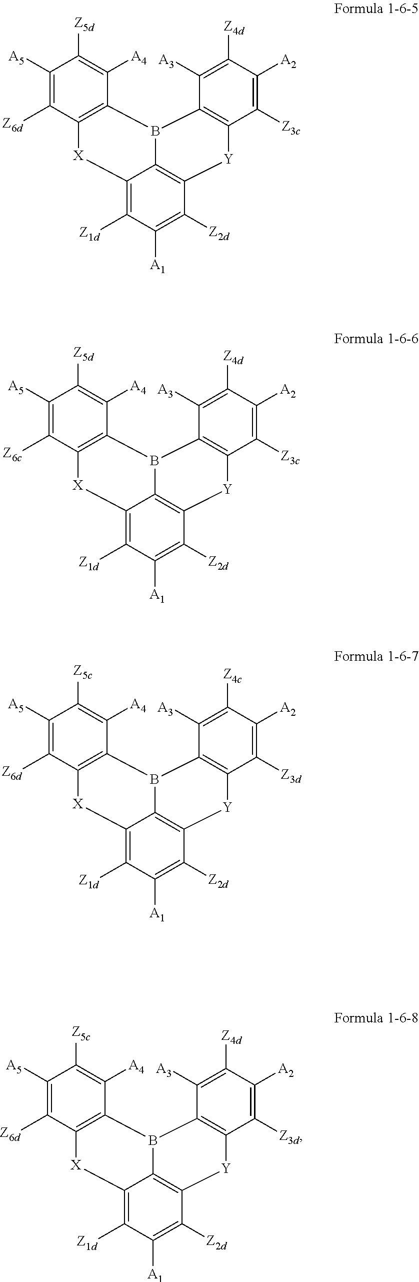
wherein, in Formula 1-6-1 to Formula 1-6-8,
Z_{1d} to Z_{6d} are each independently hydrogen, deuterium, a halogen, a cyano group, a nitro group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or a substituent represented by Formula 3,
Z_{1c} to Z_{6c} are each a cyano group, or a substituent represented by Formula 3, and
X, Y, and A₁ to A₅ are the same as defined in Formula 1.

13. The light emitting element of claim 1, wherein the fused polycyclic compound comprises at least one selected from among compounds in Compound Group 1:

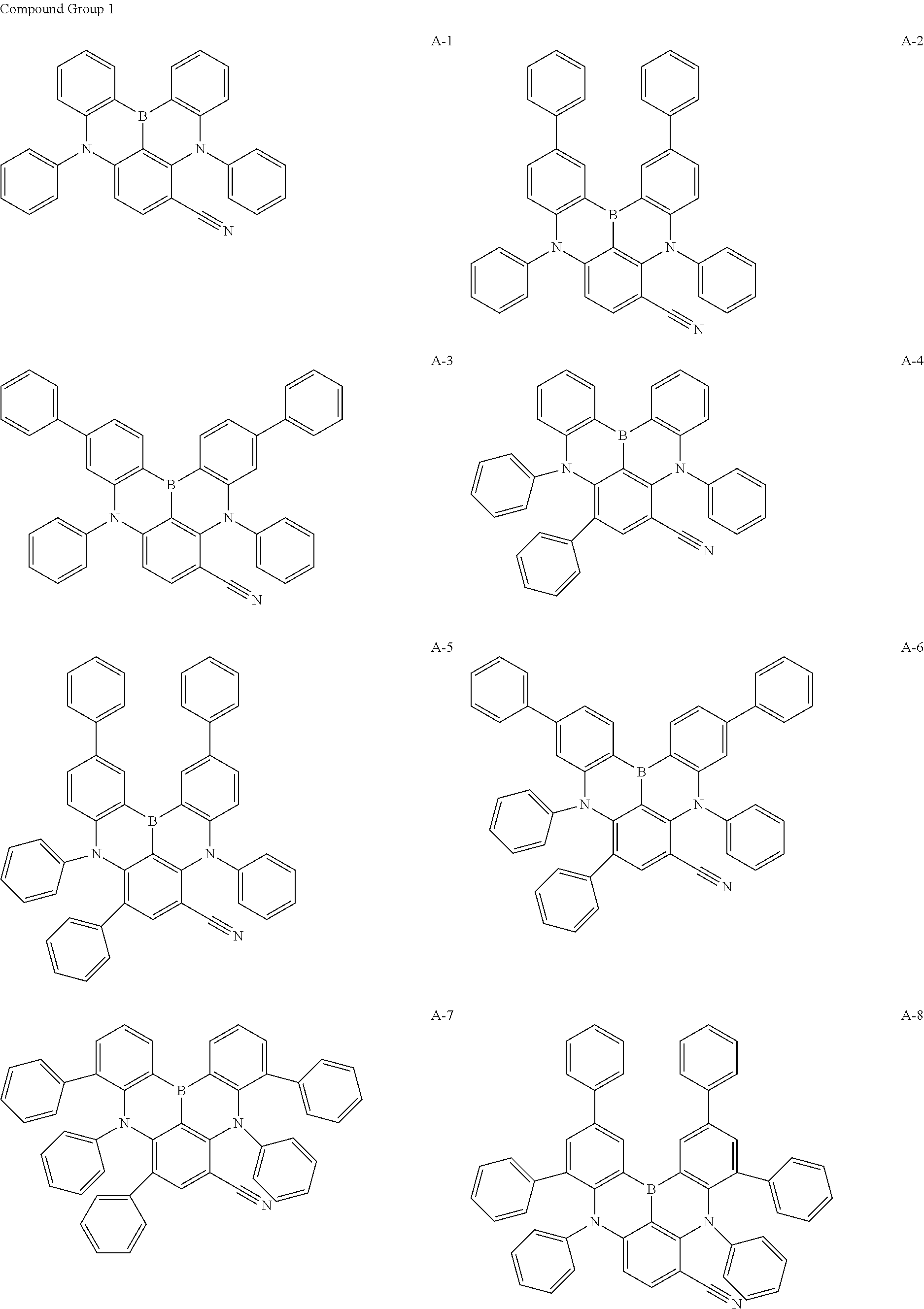

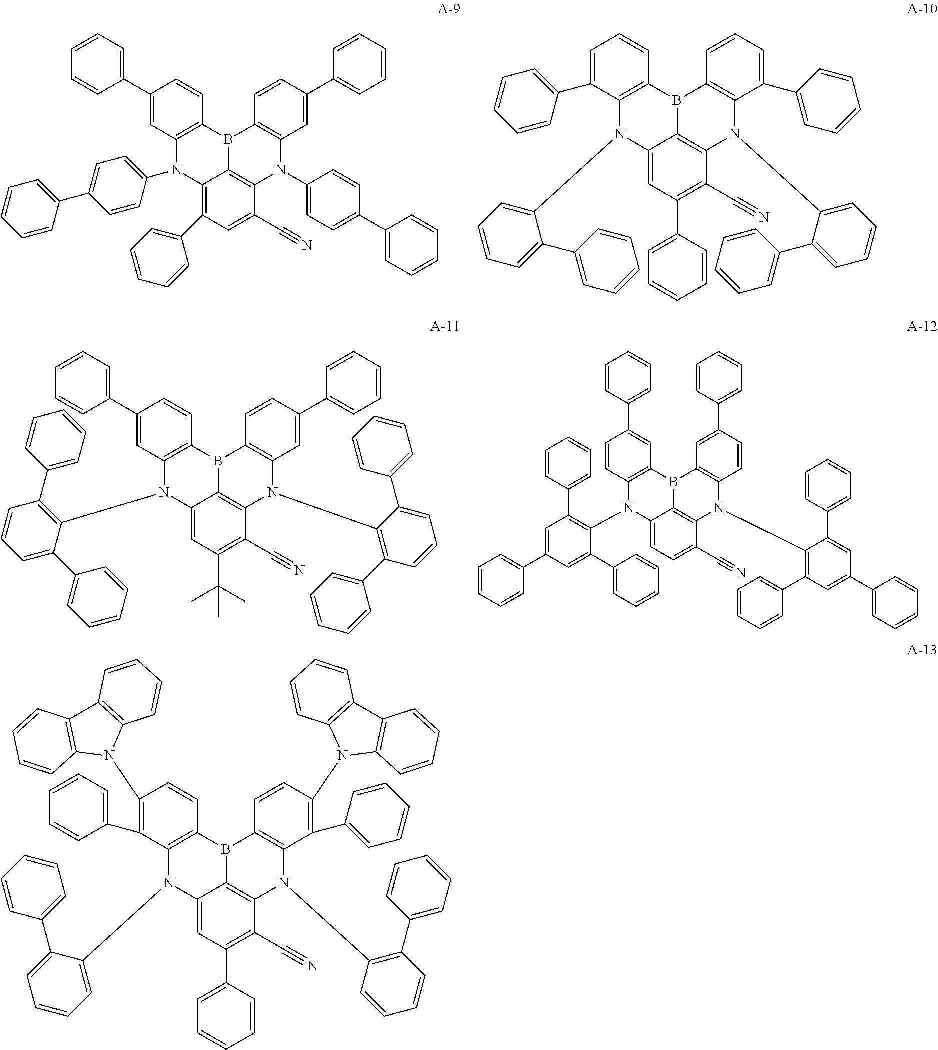

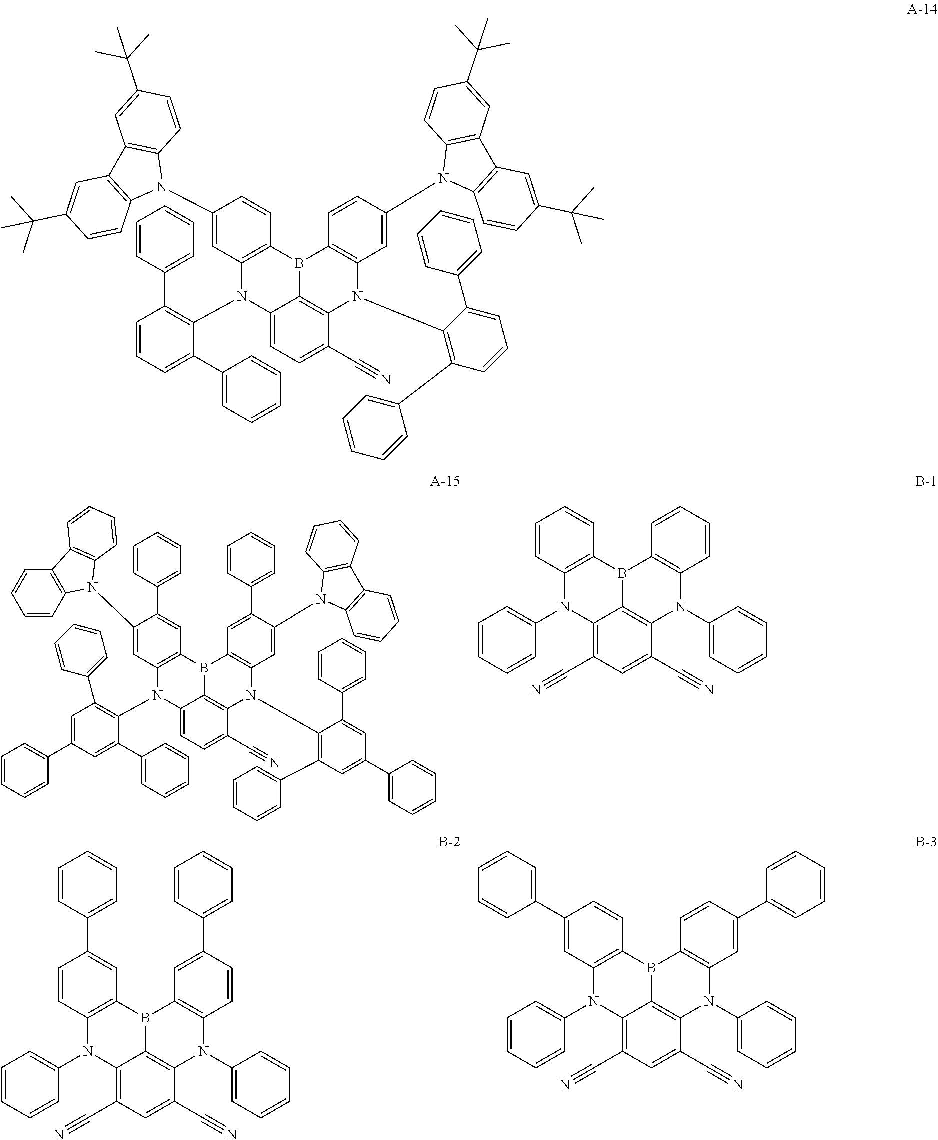

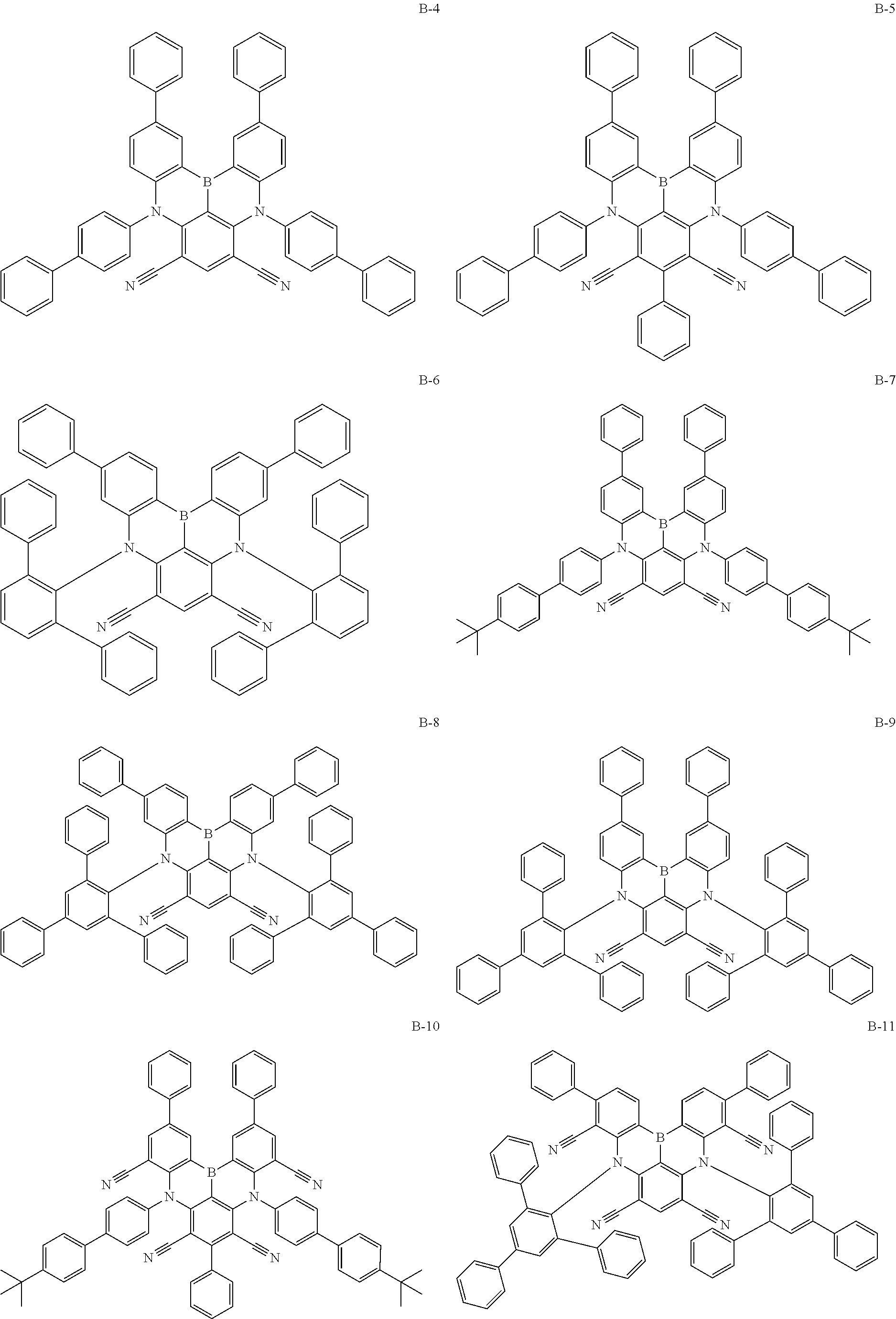

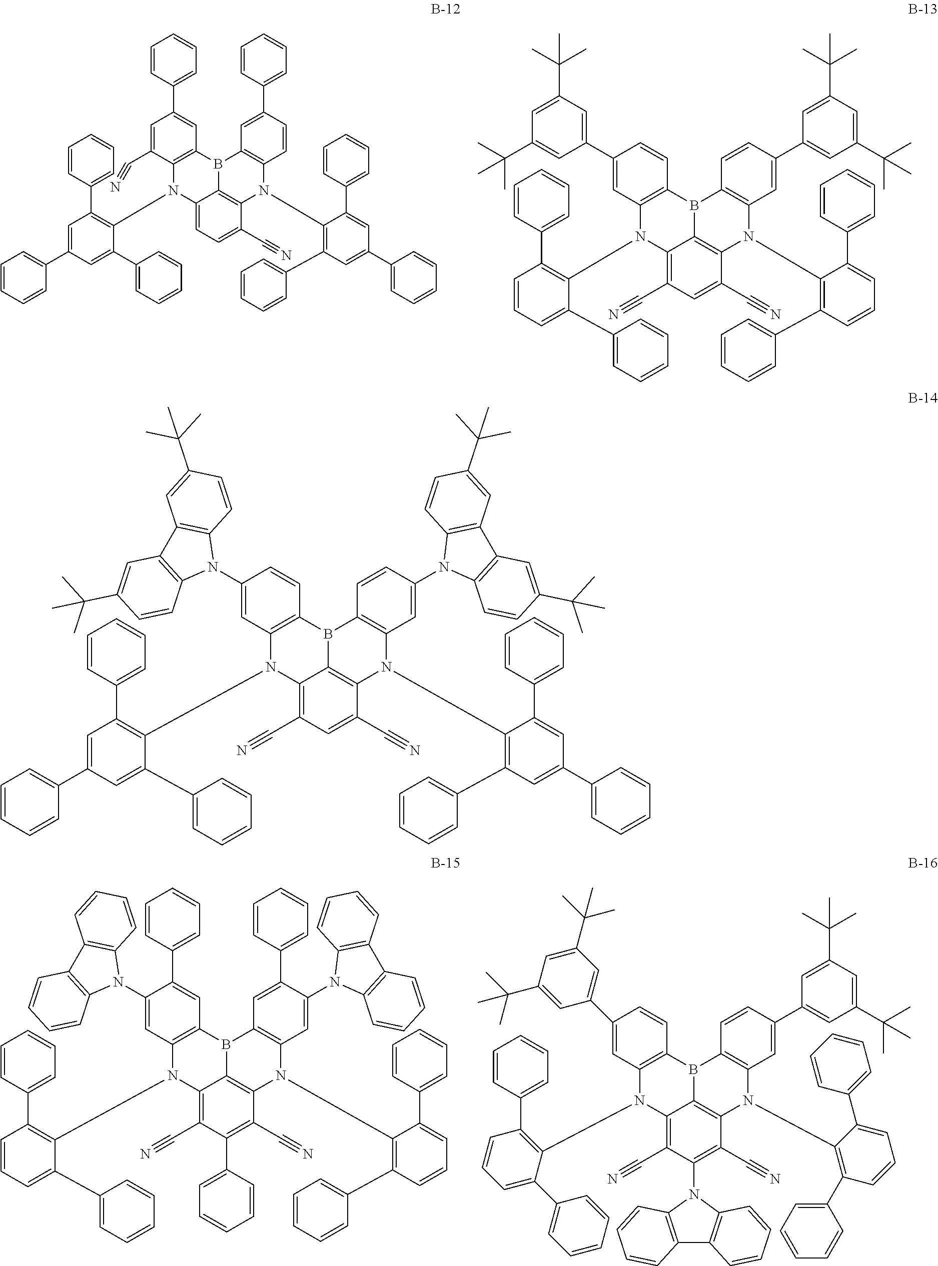

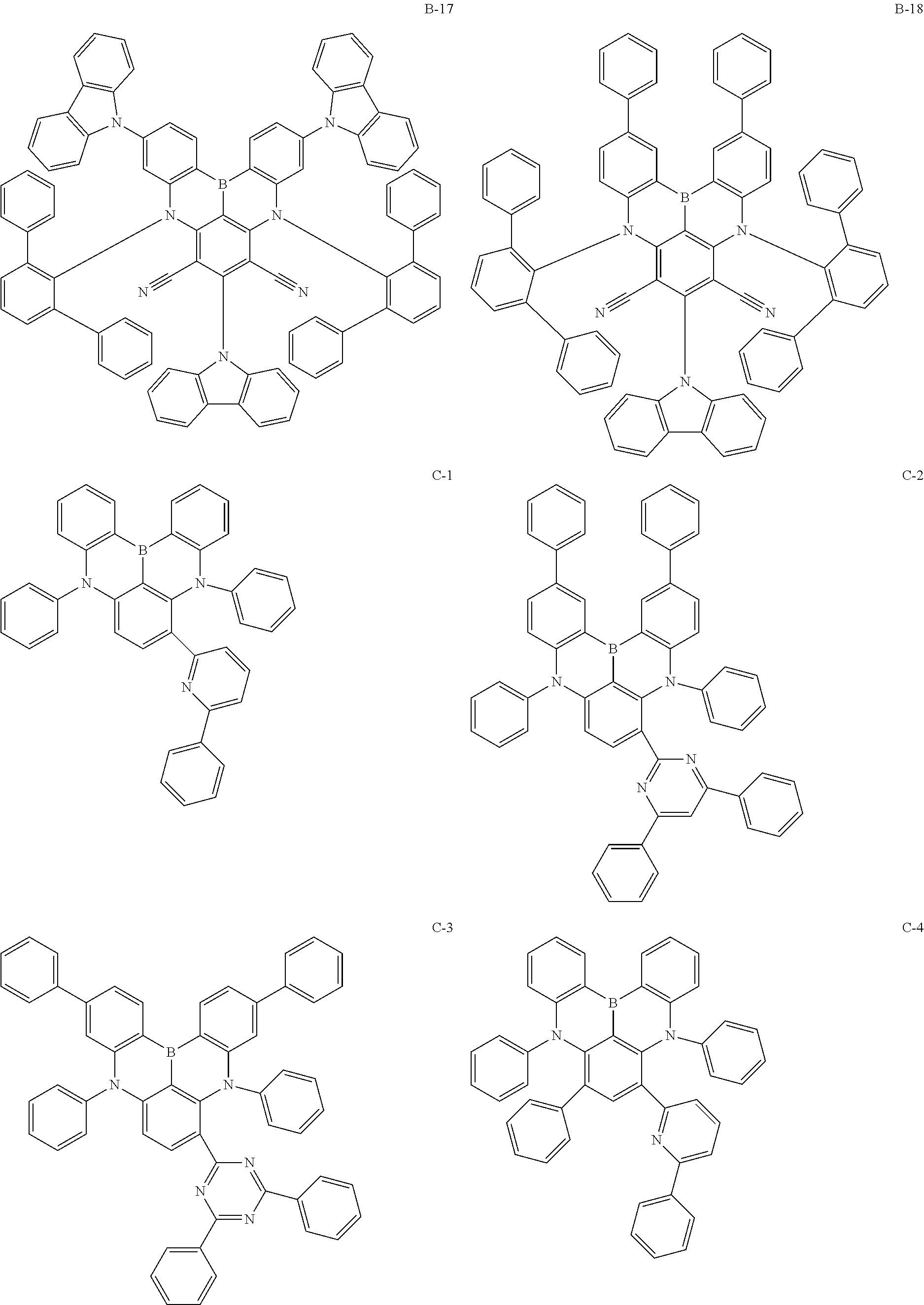

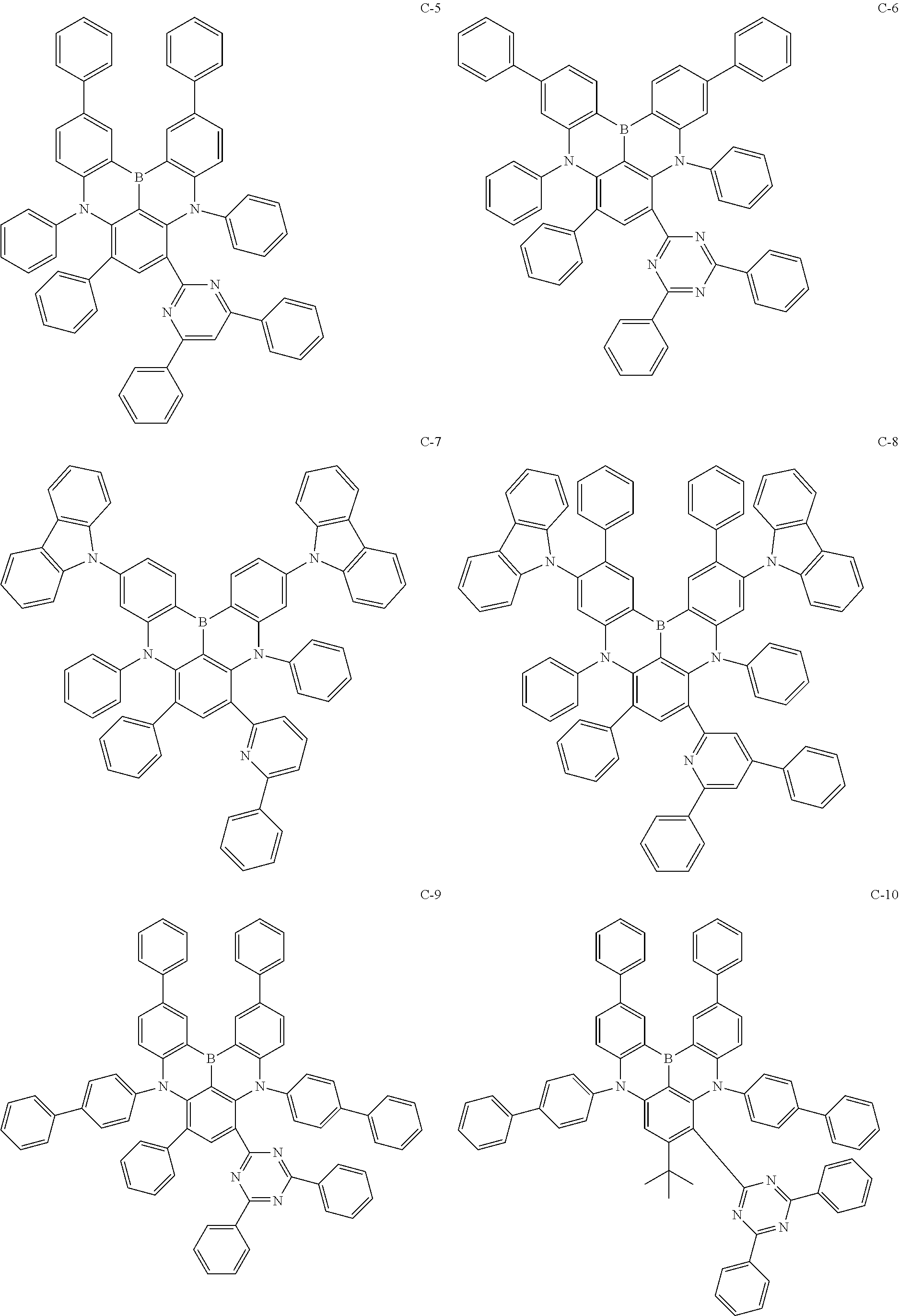

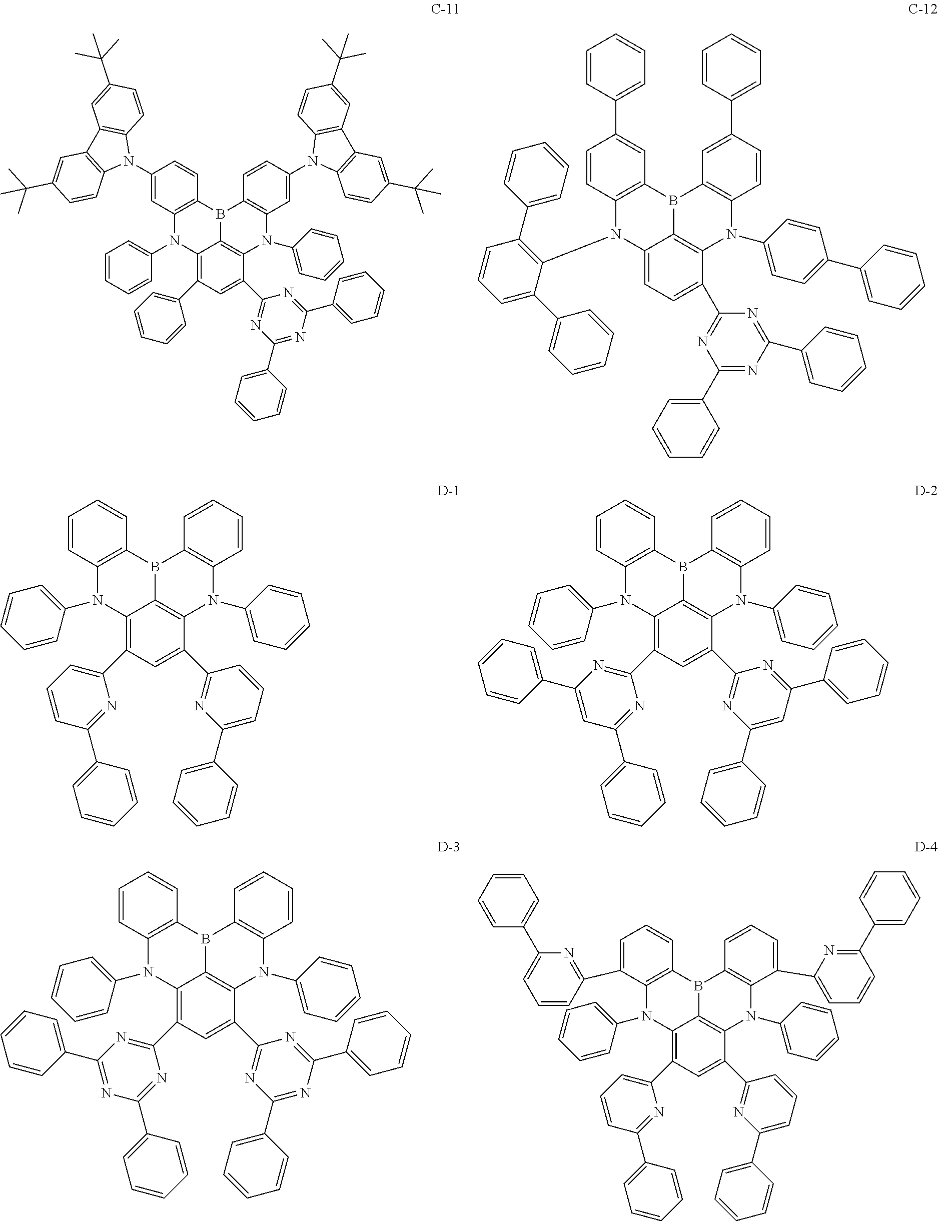

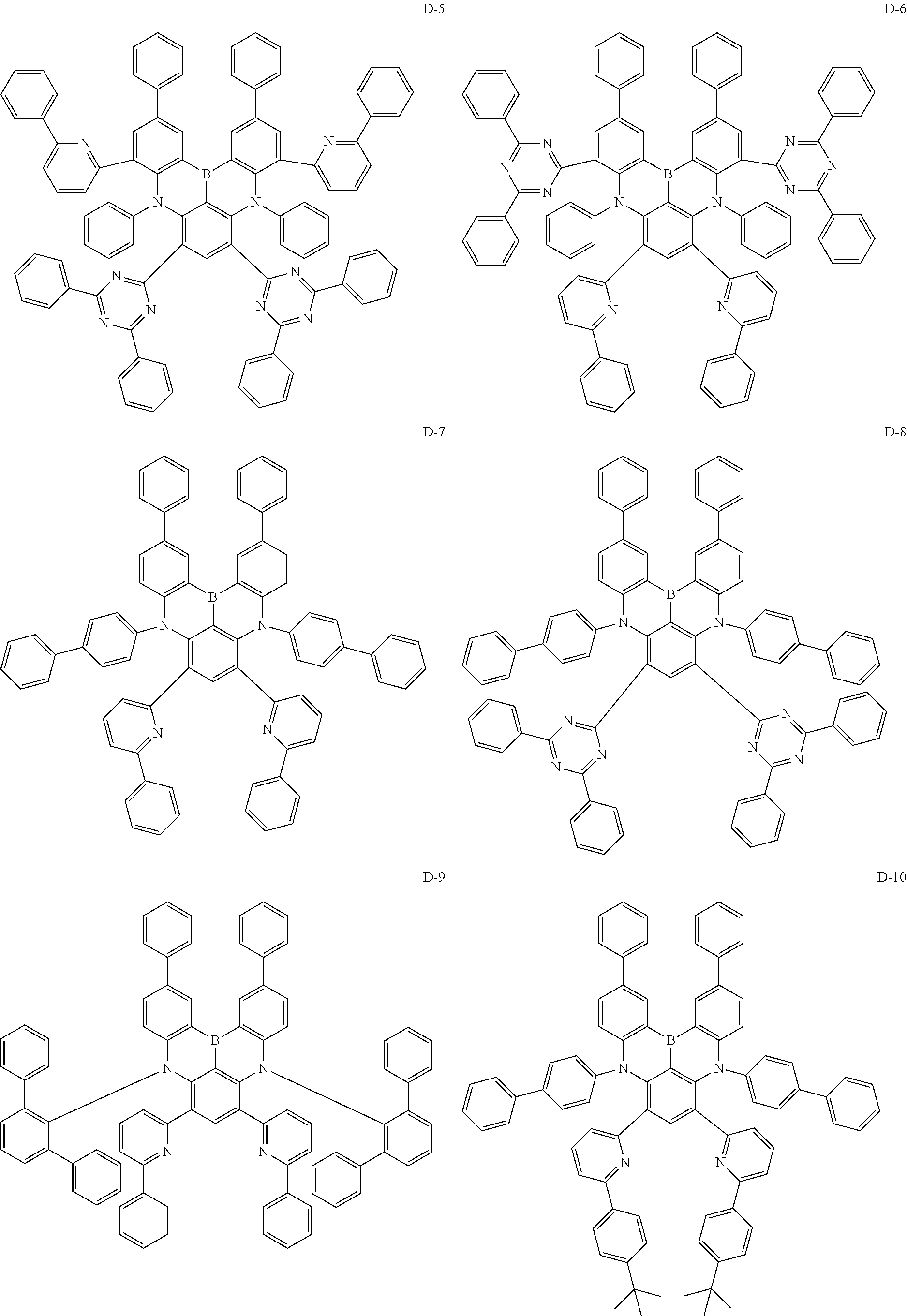

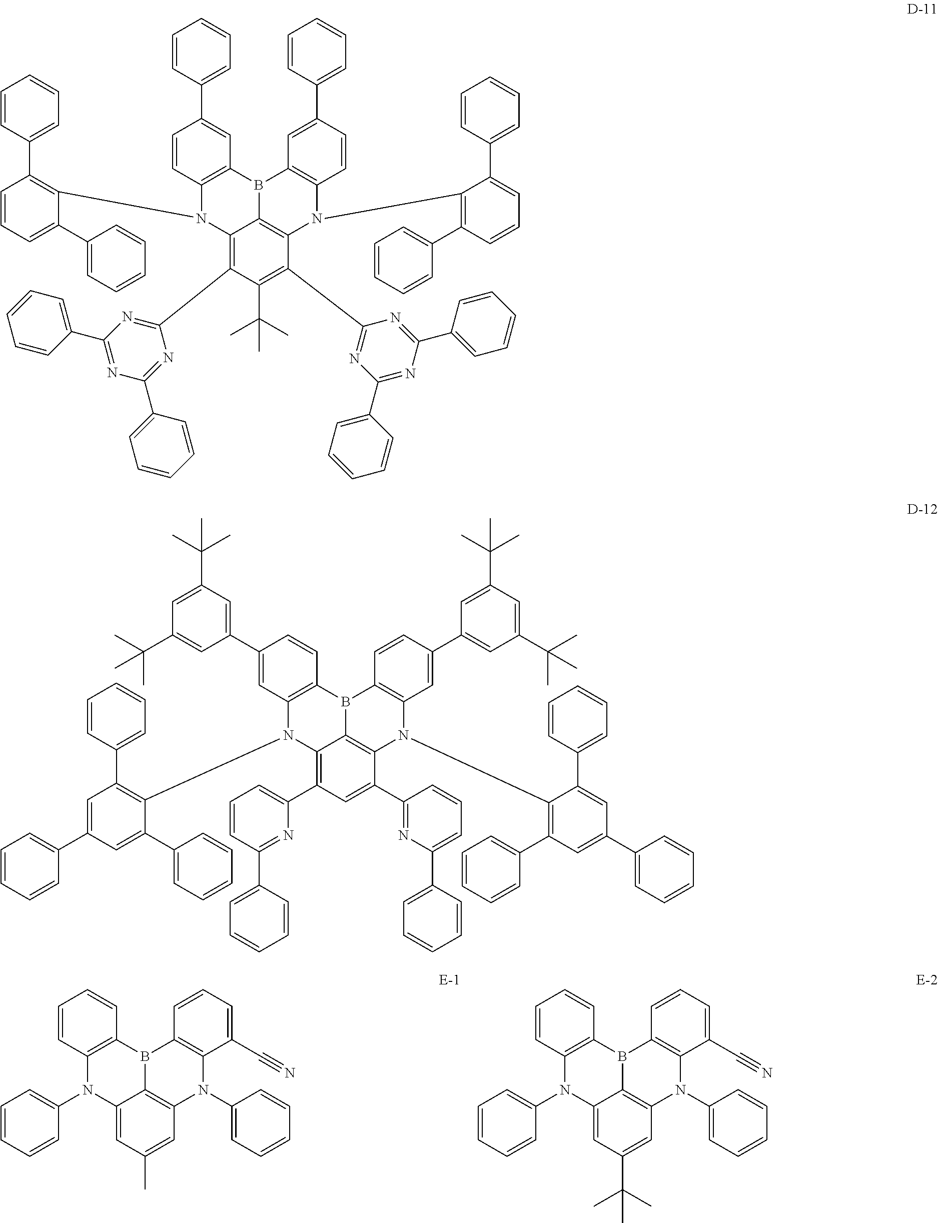

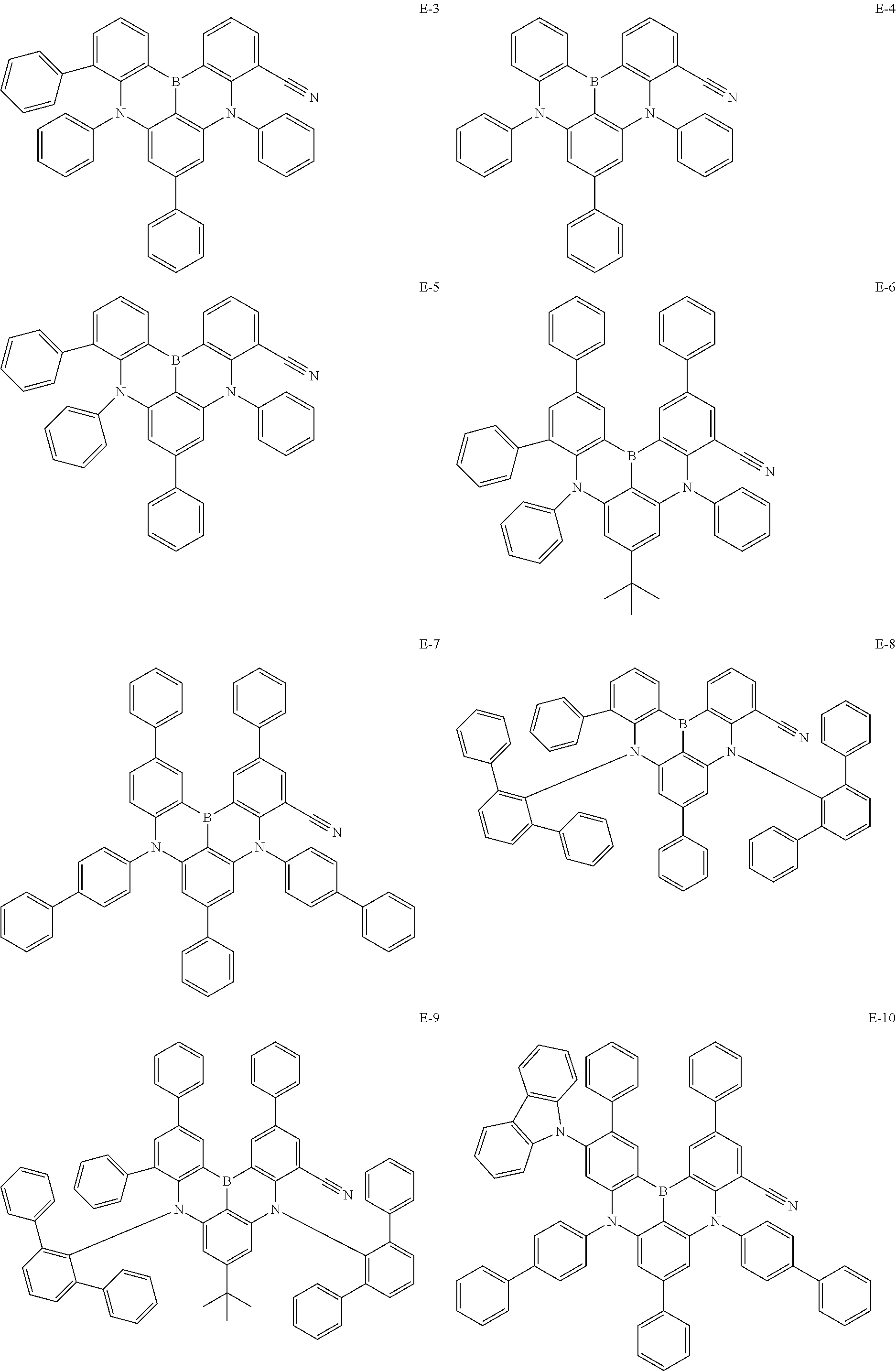

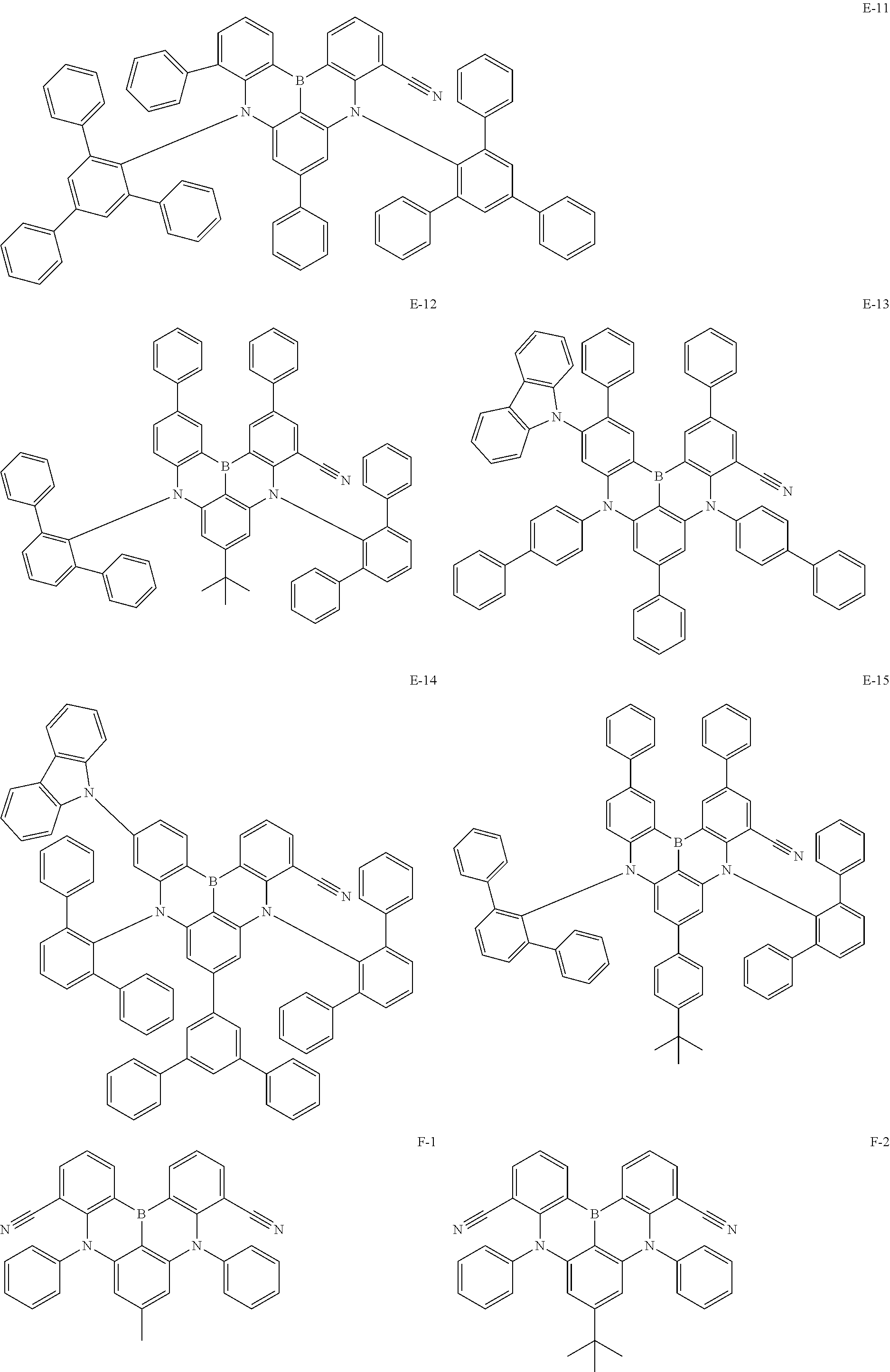

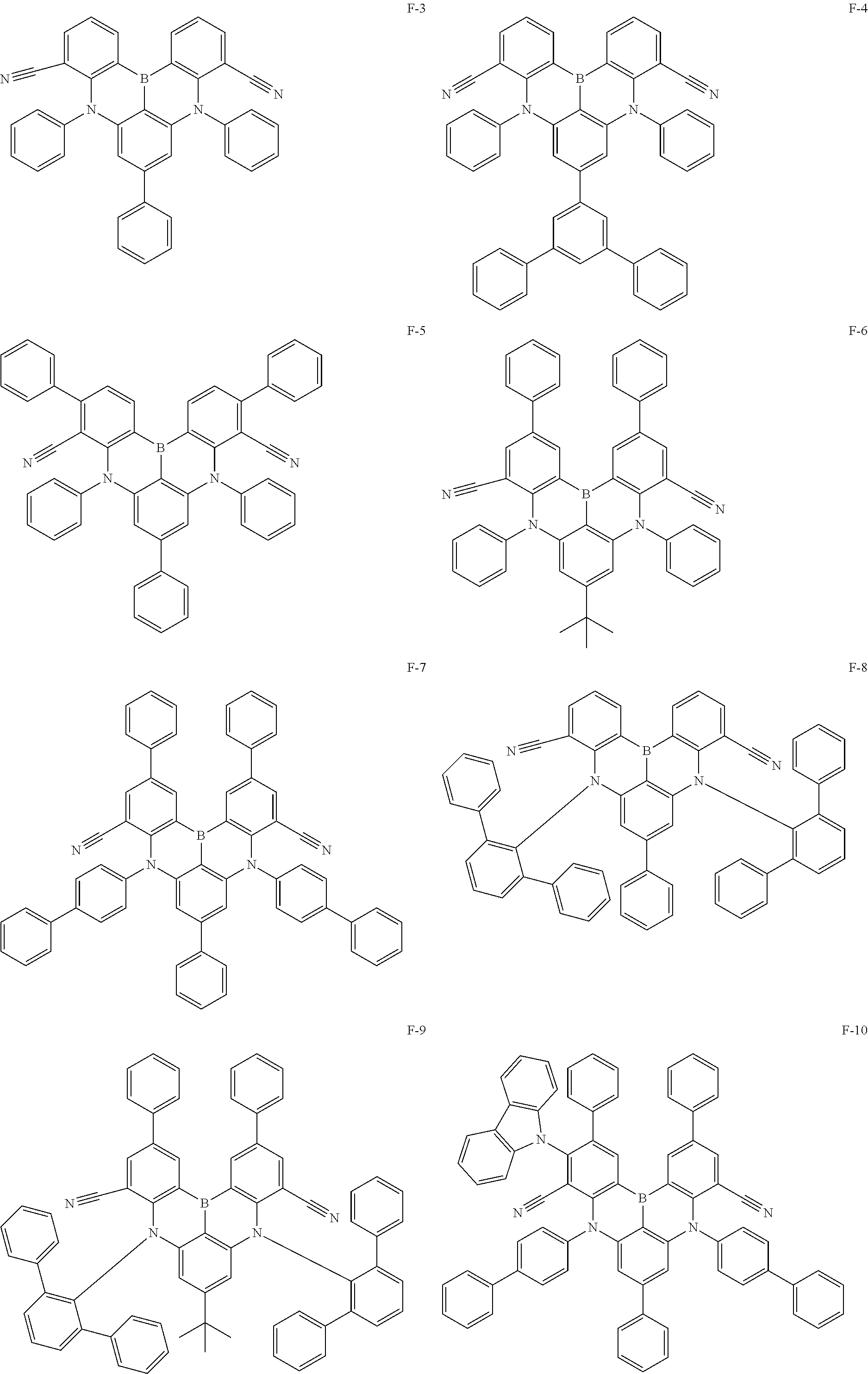

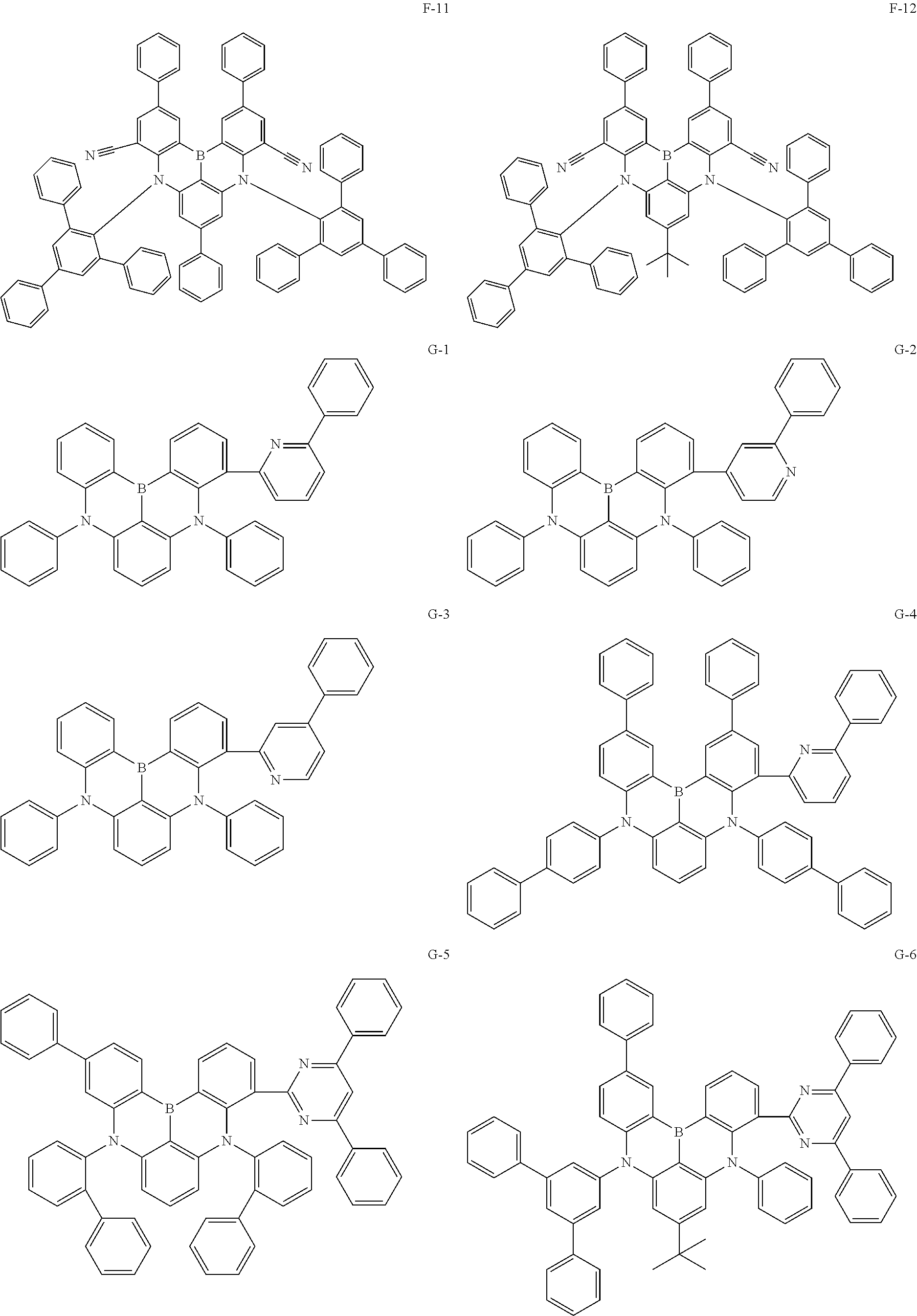

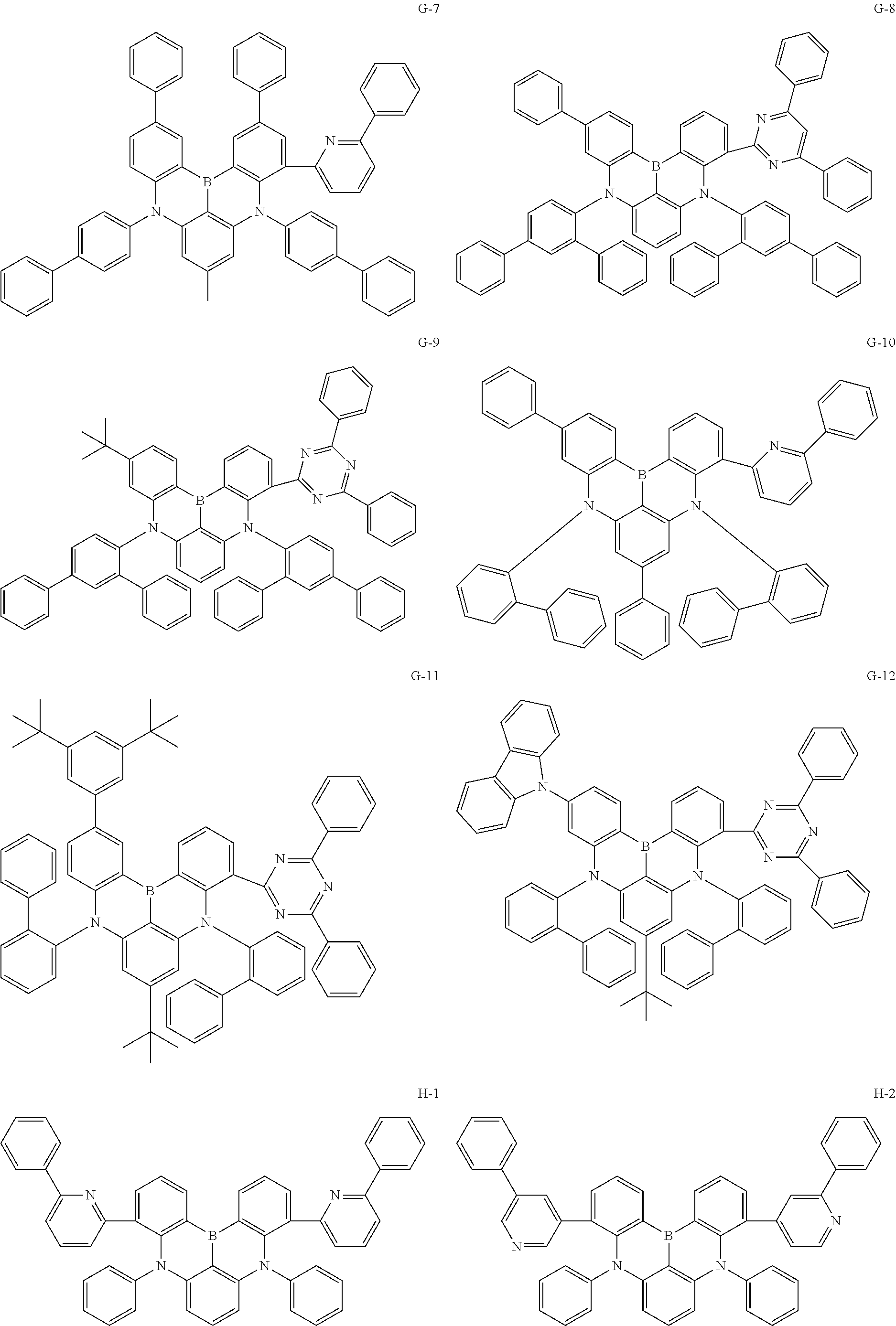

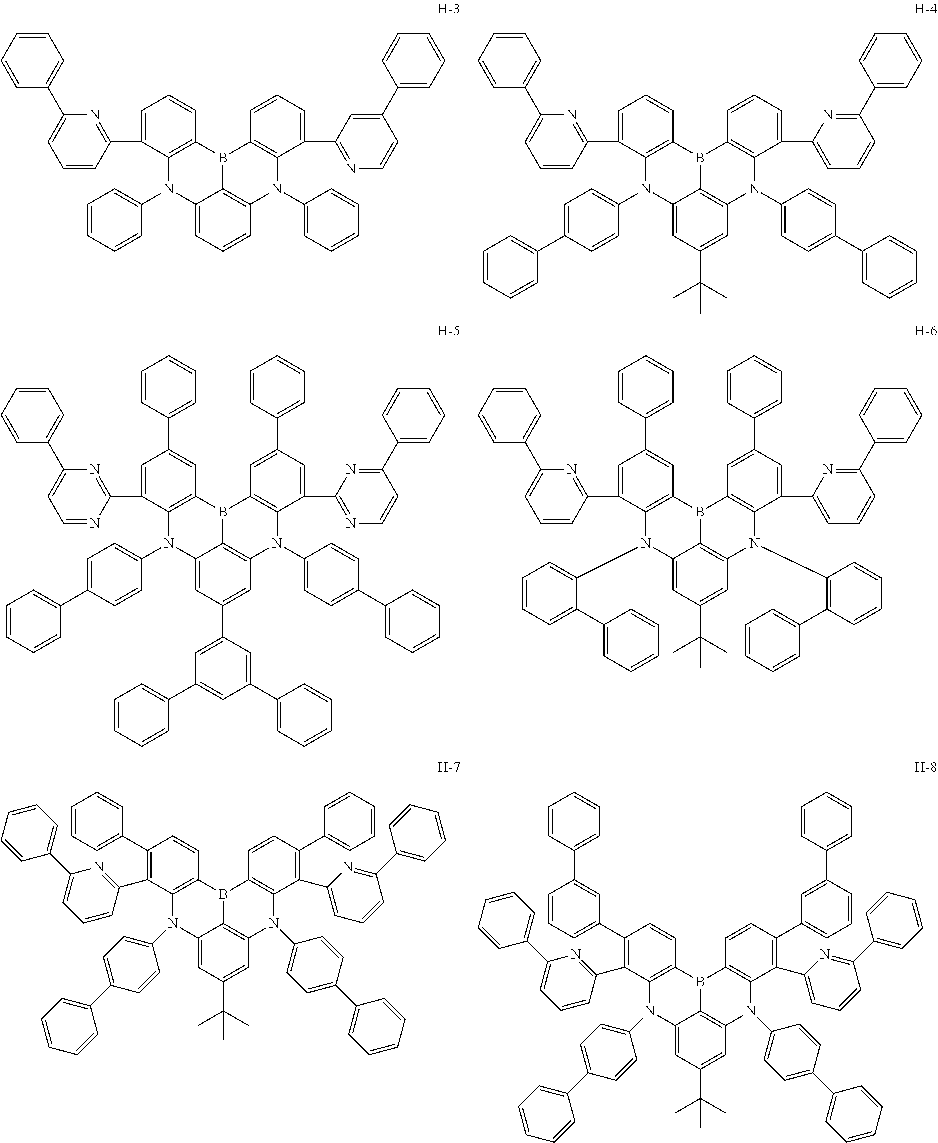

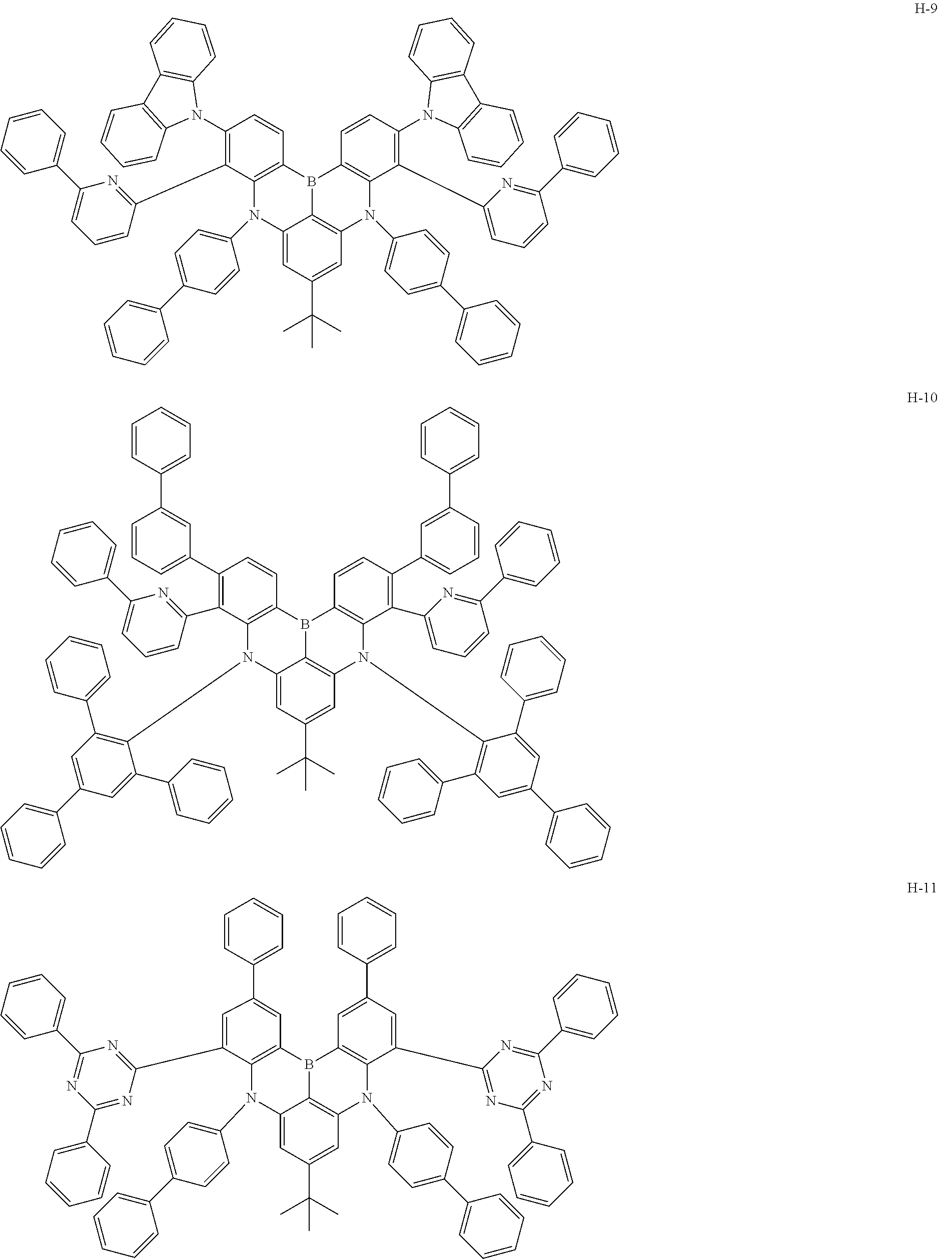

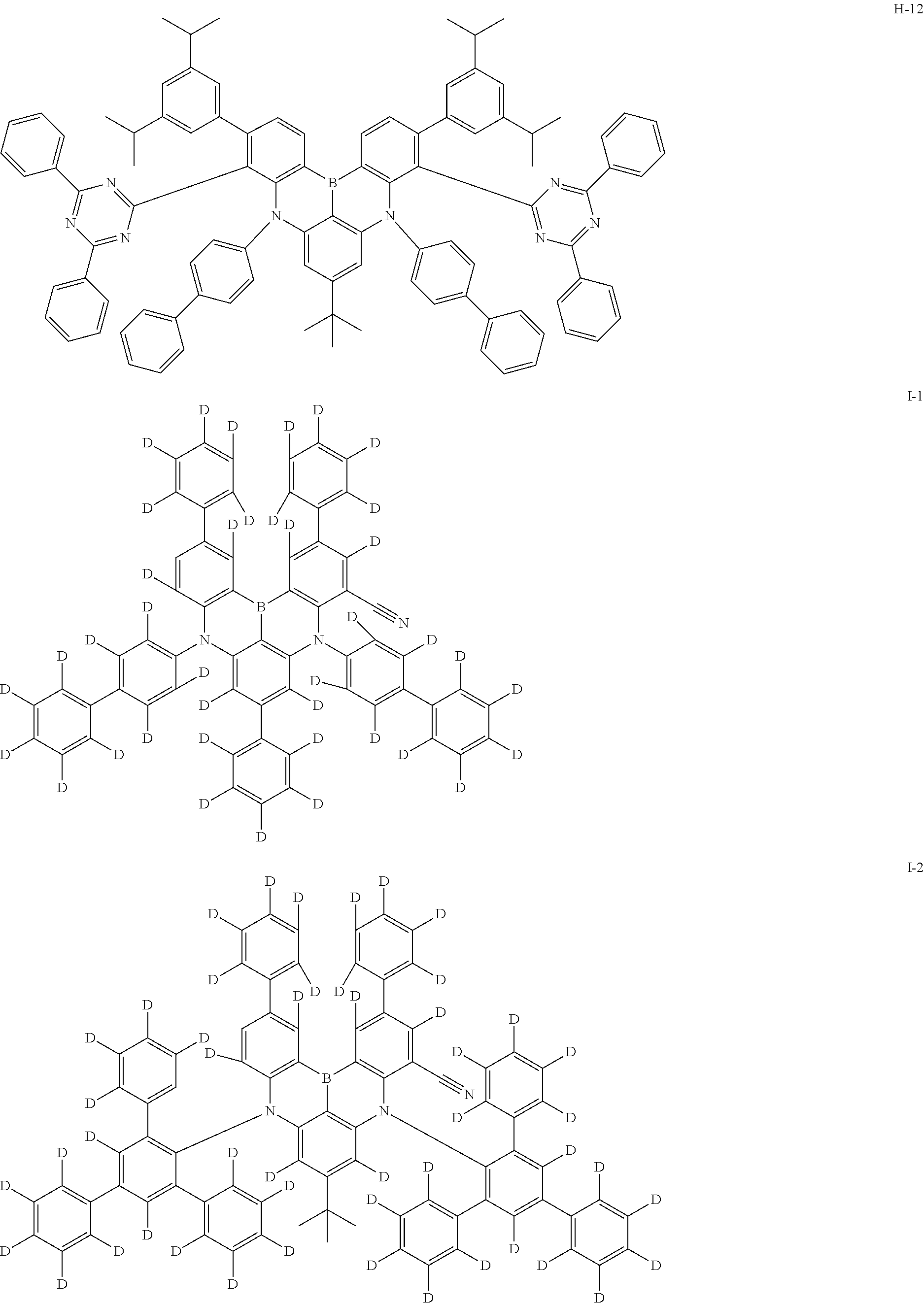

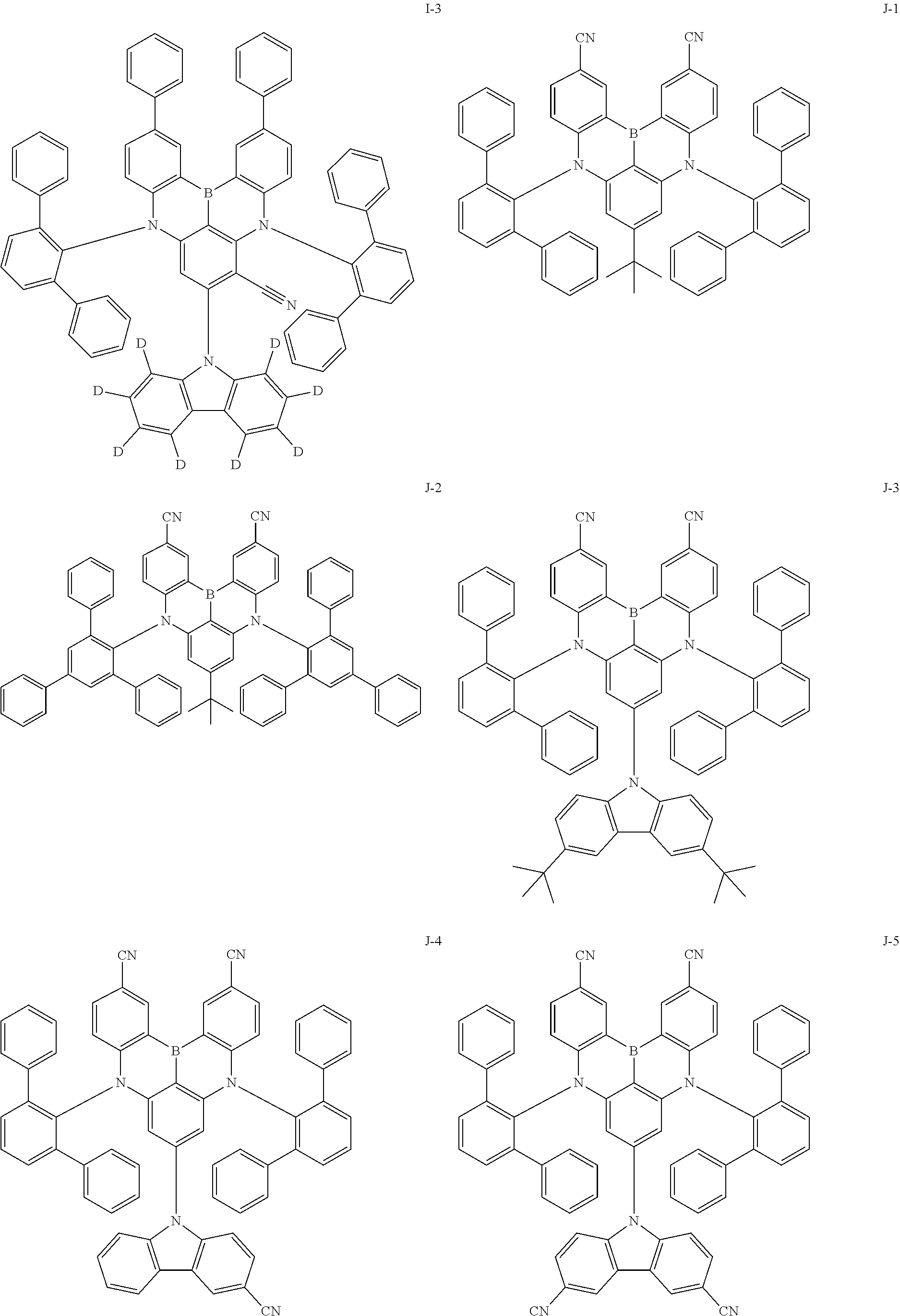

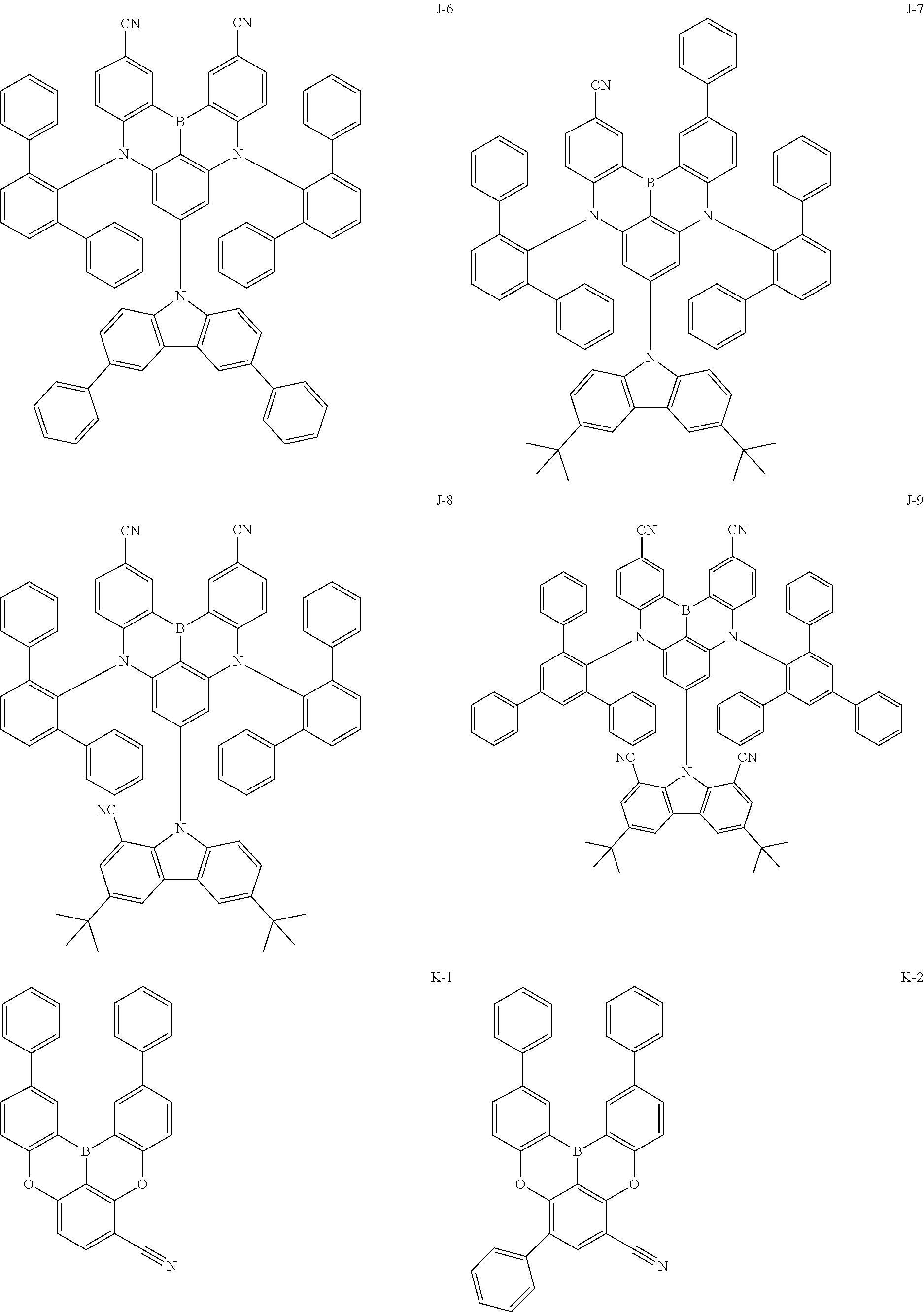

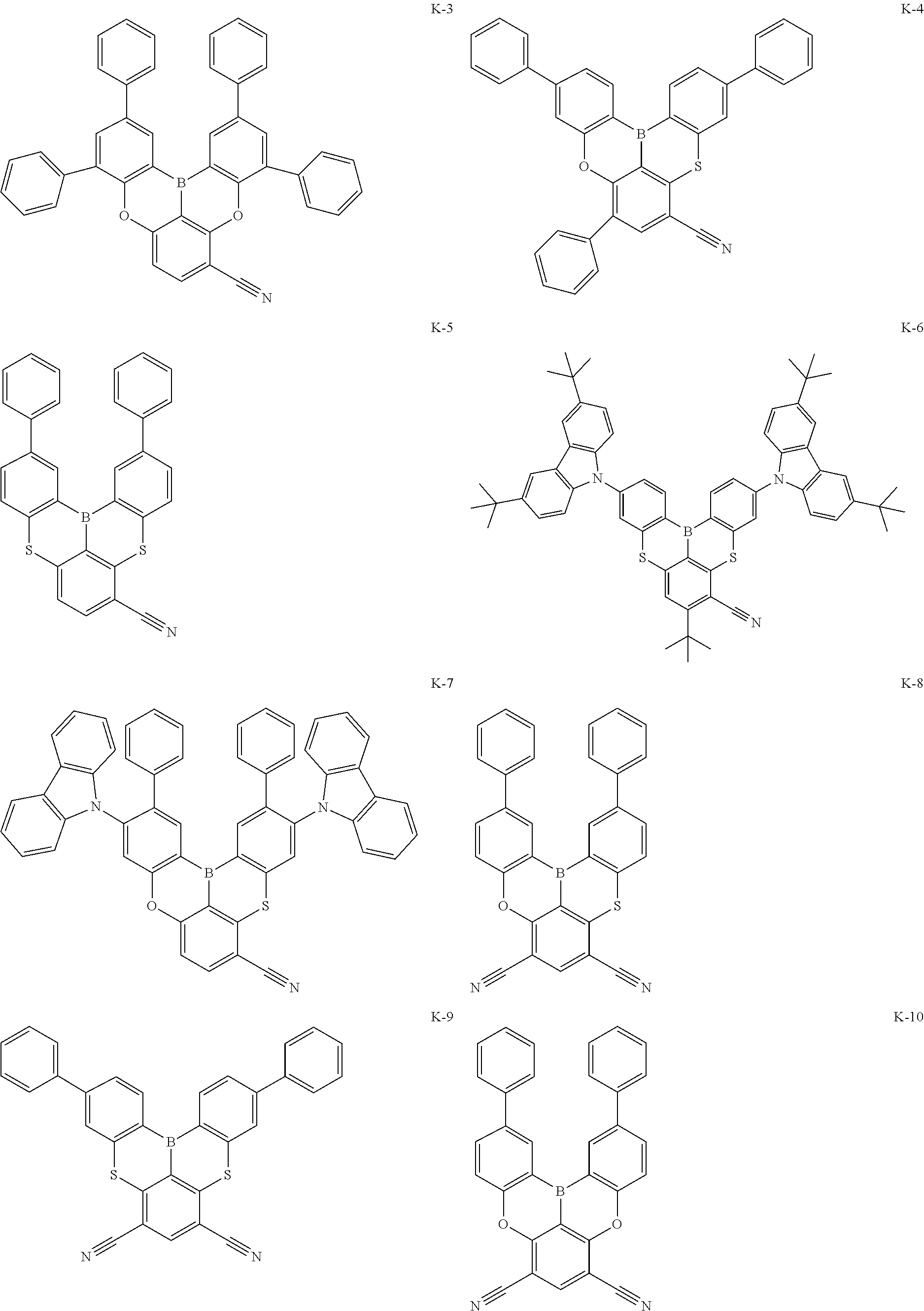

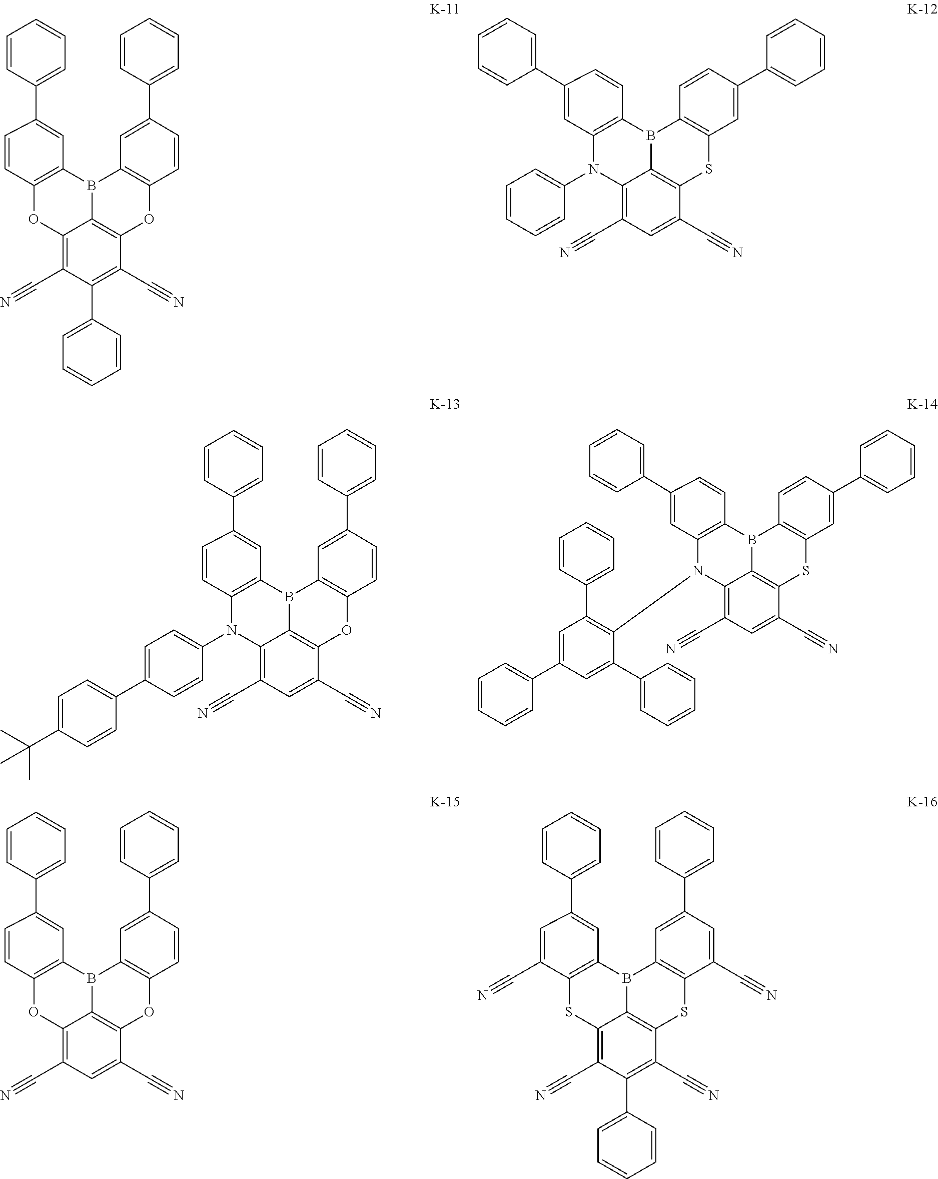

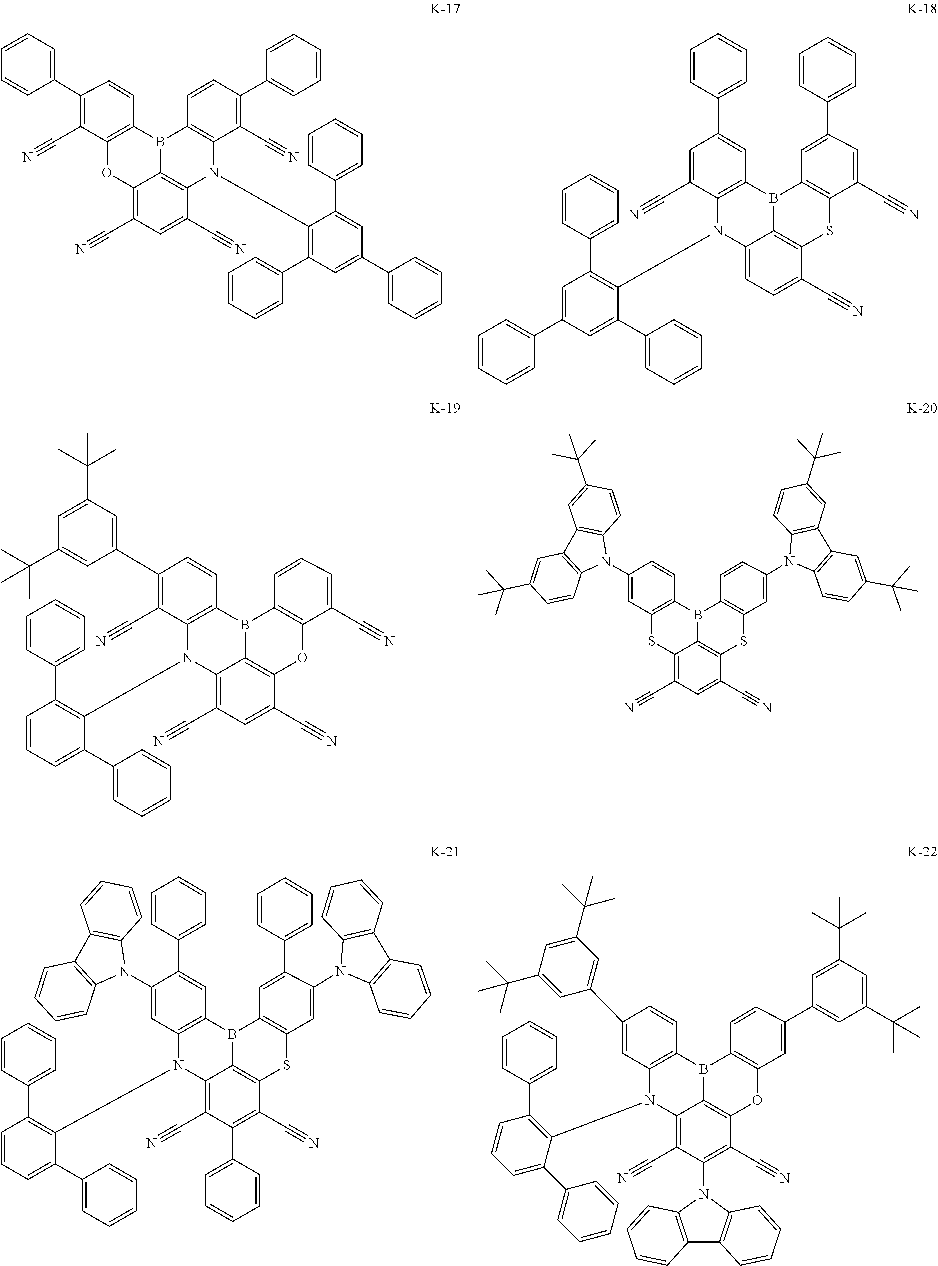

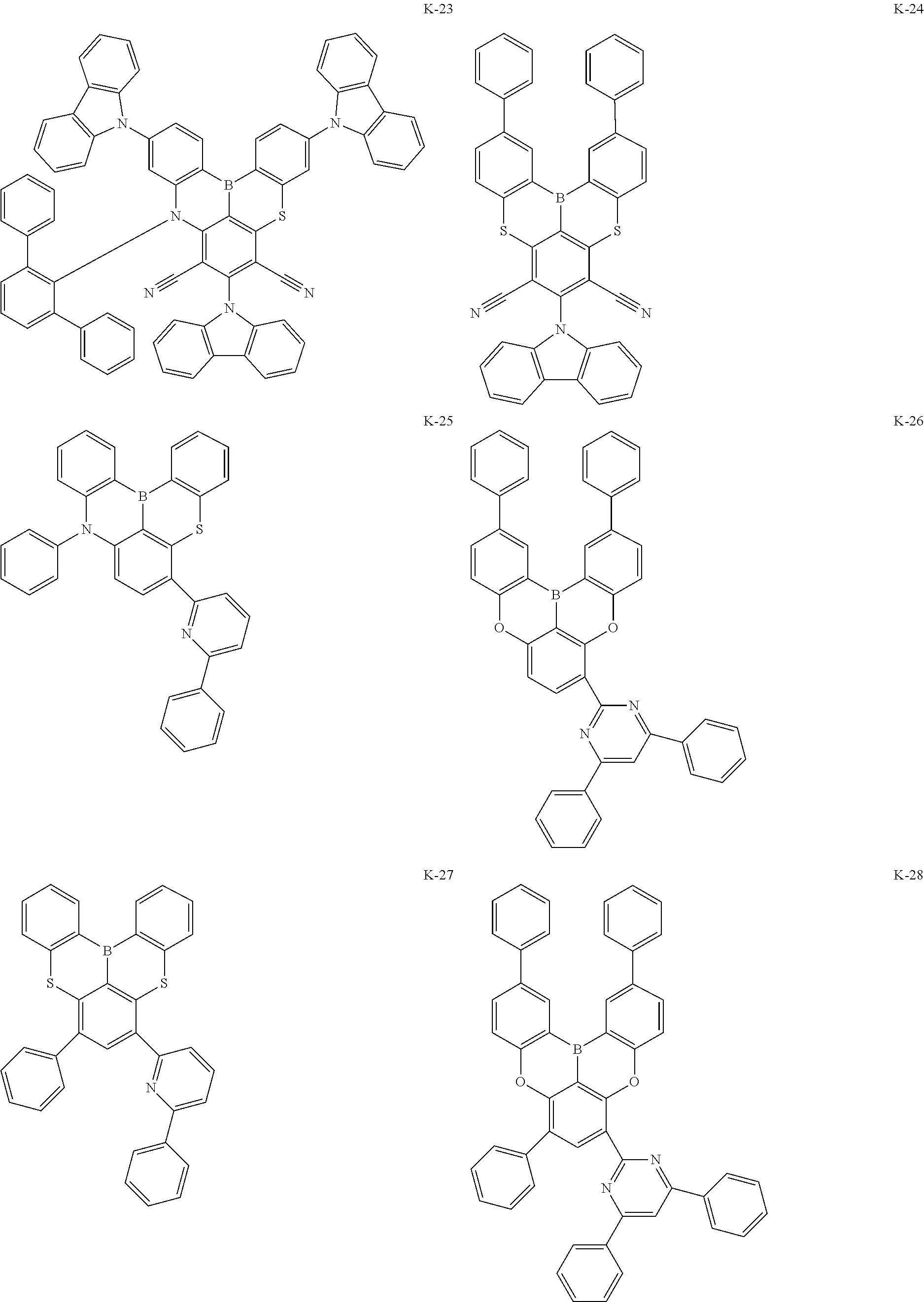

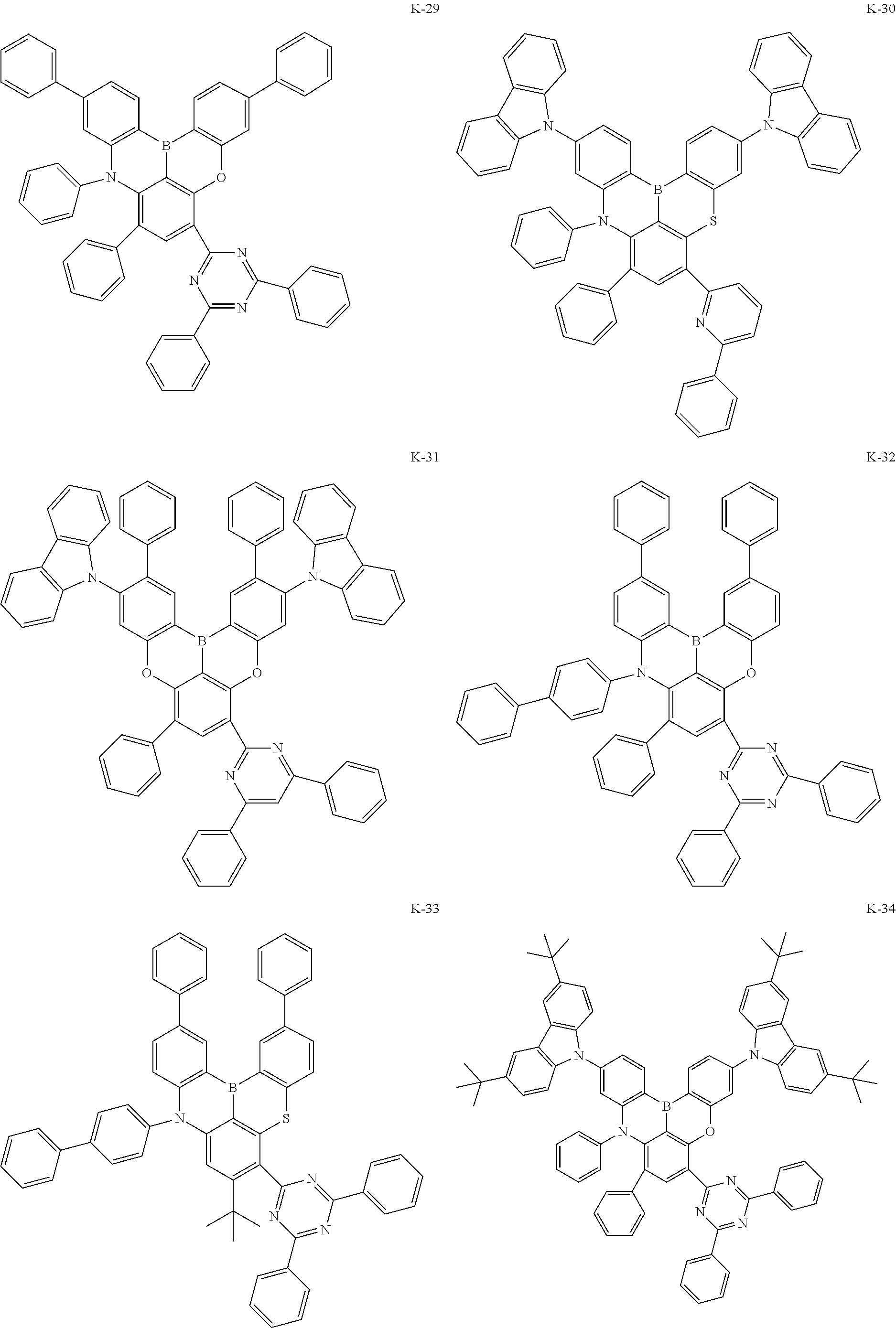

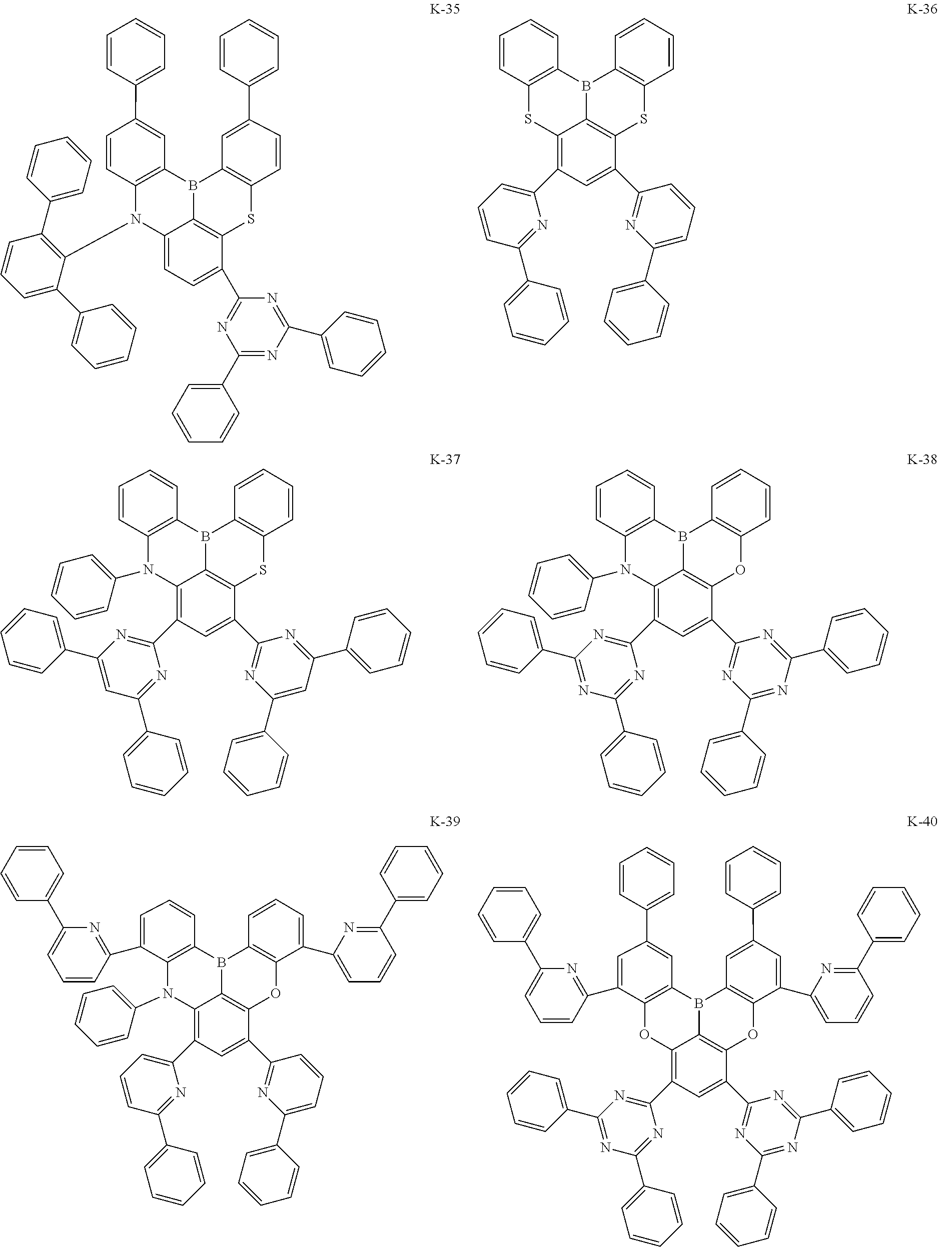

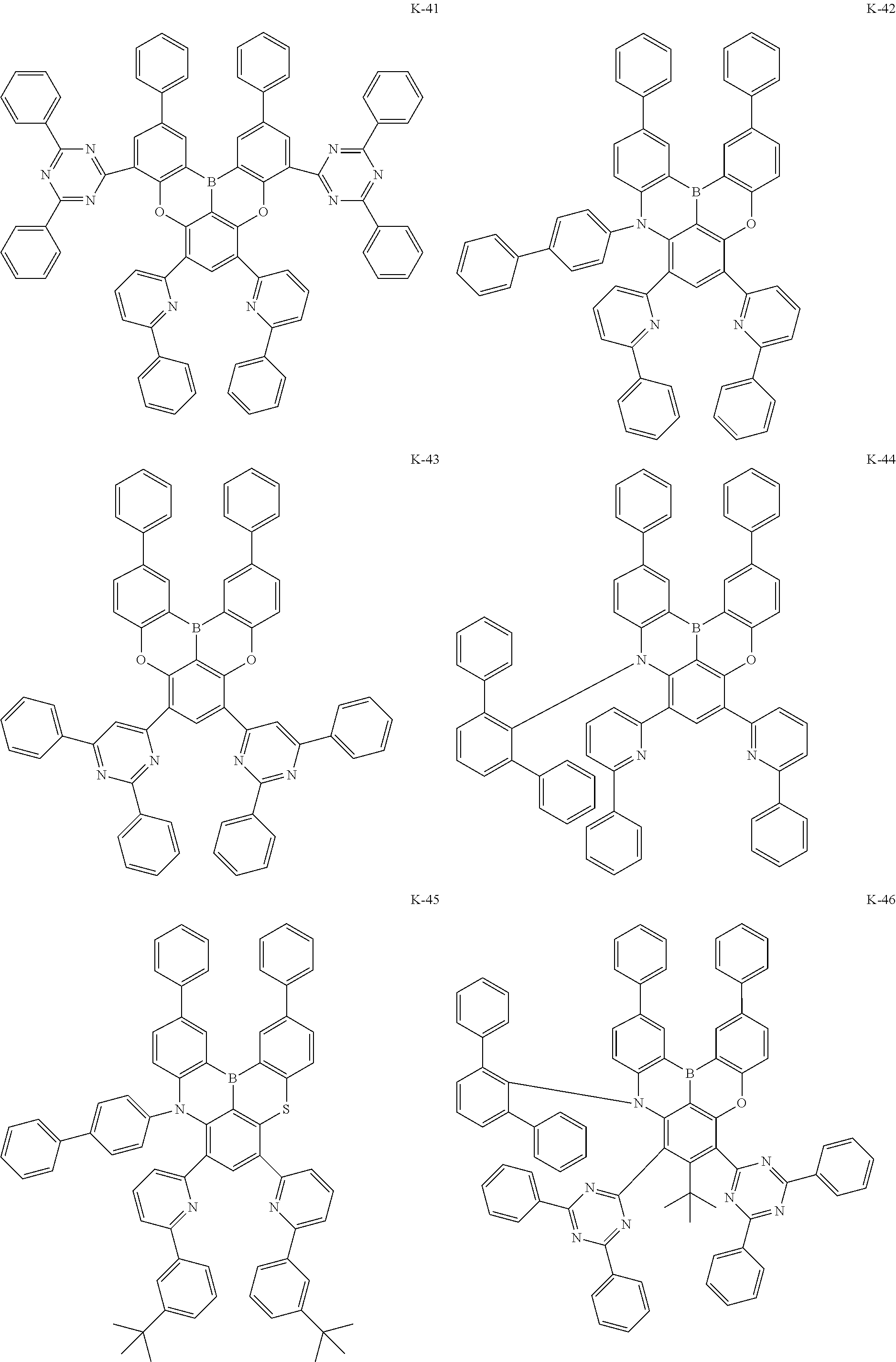

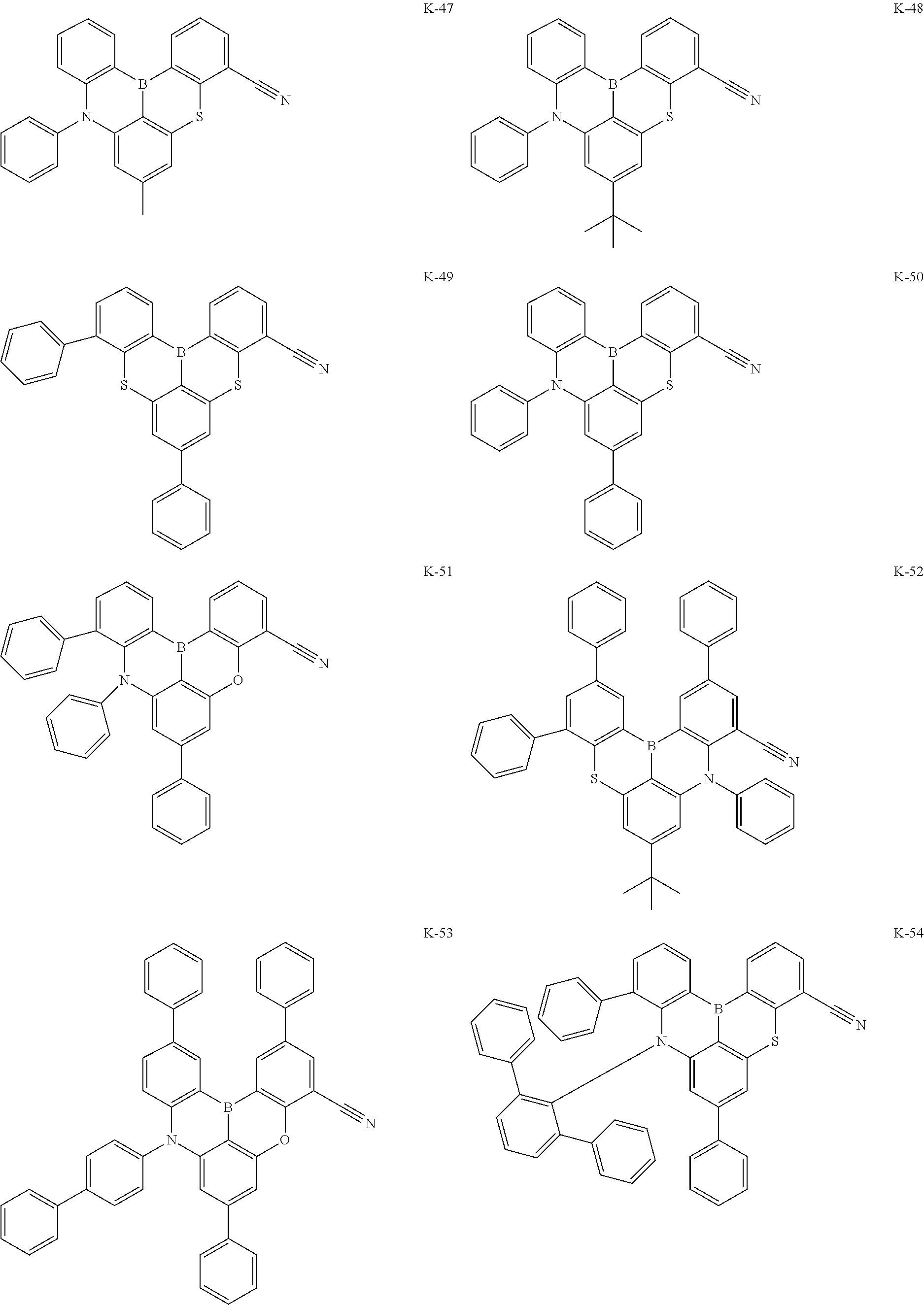

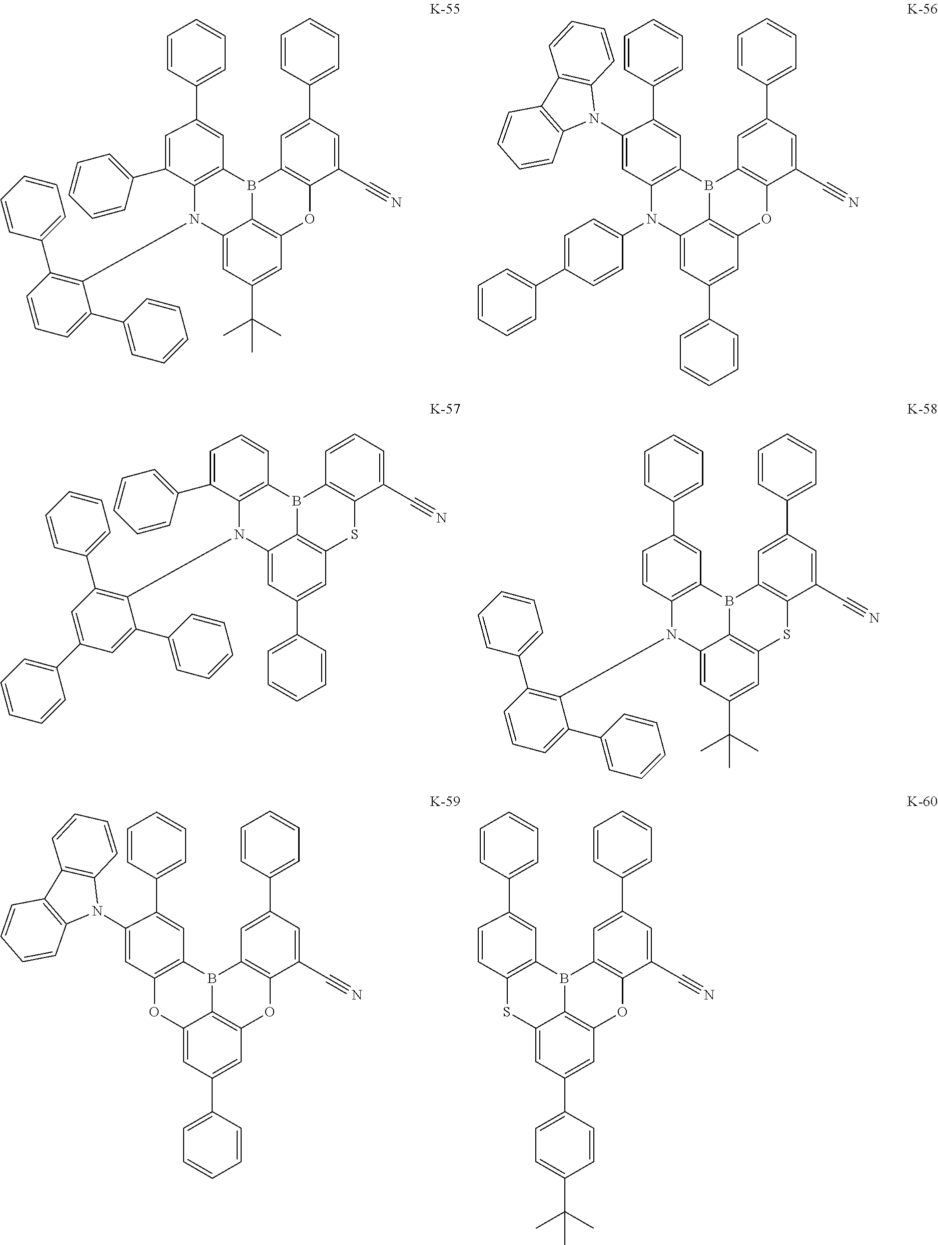

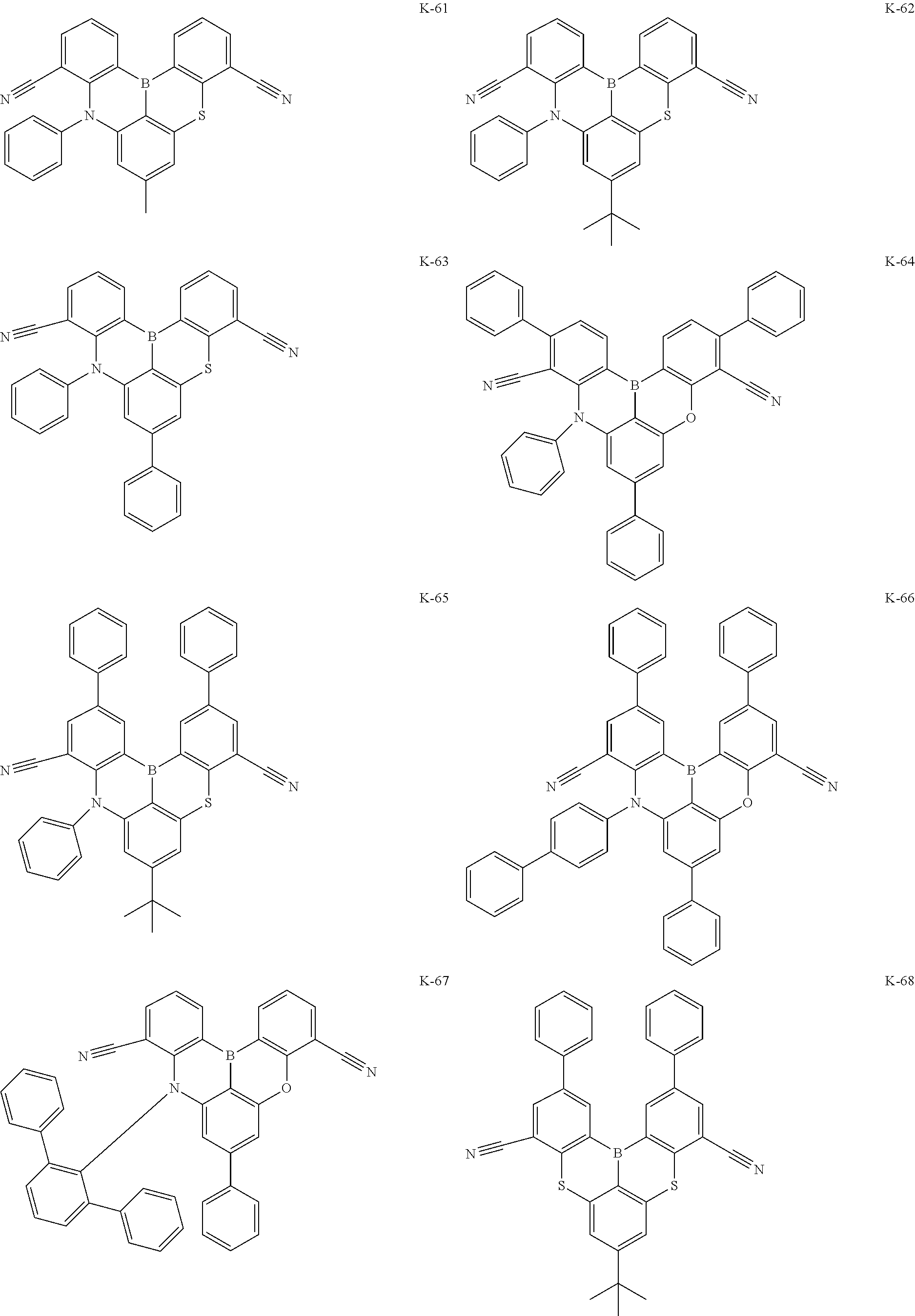

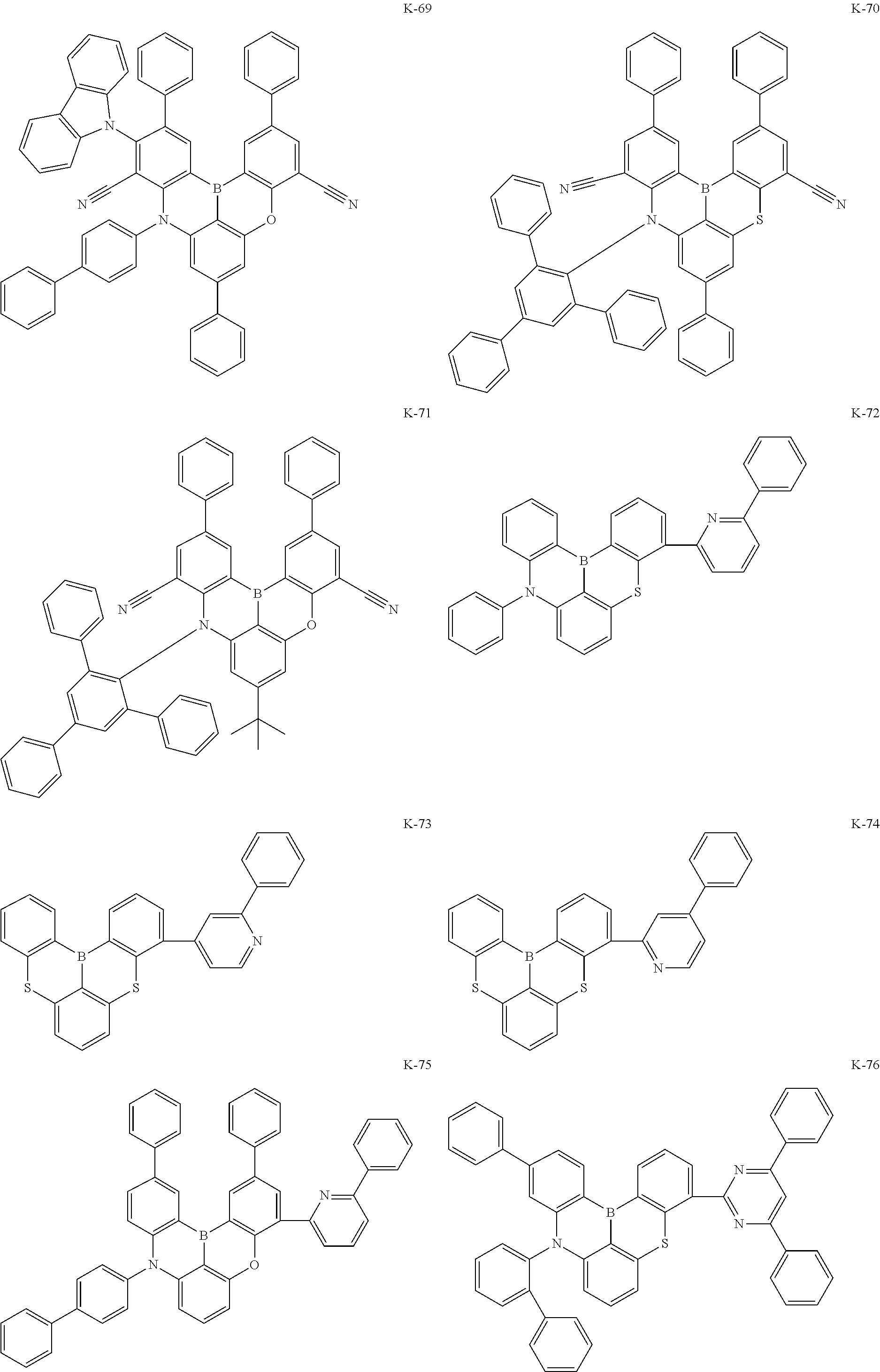

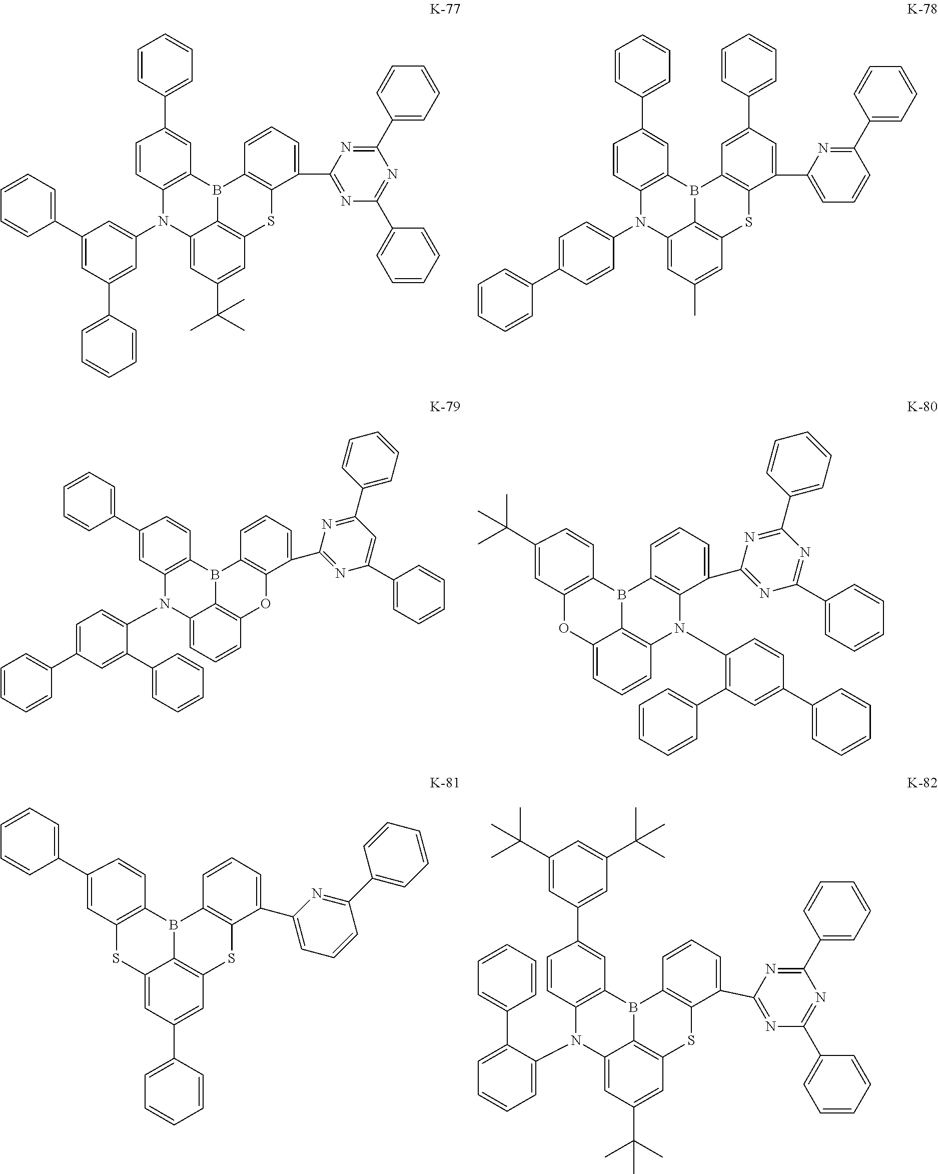

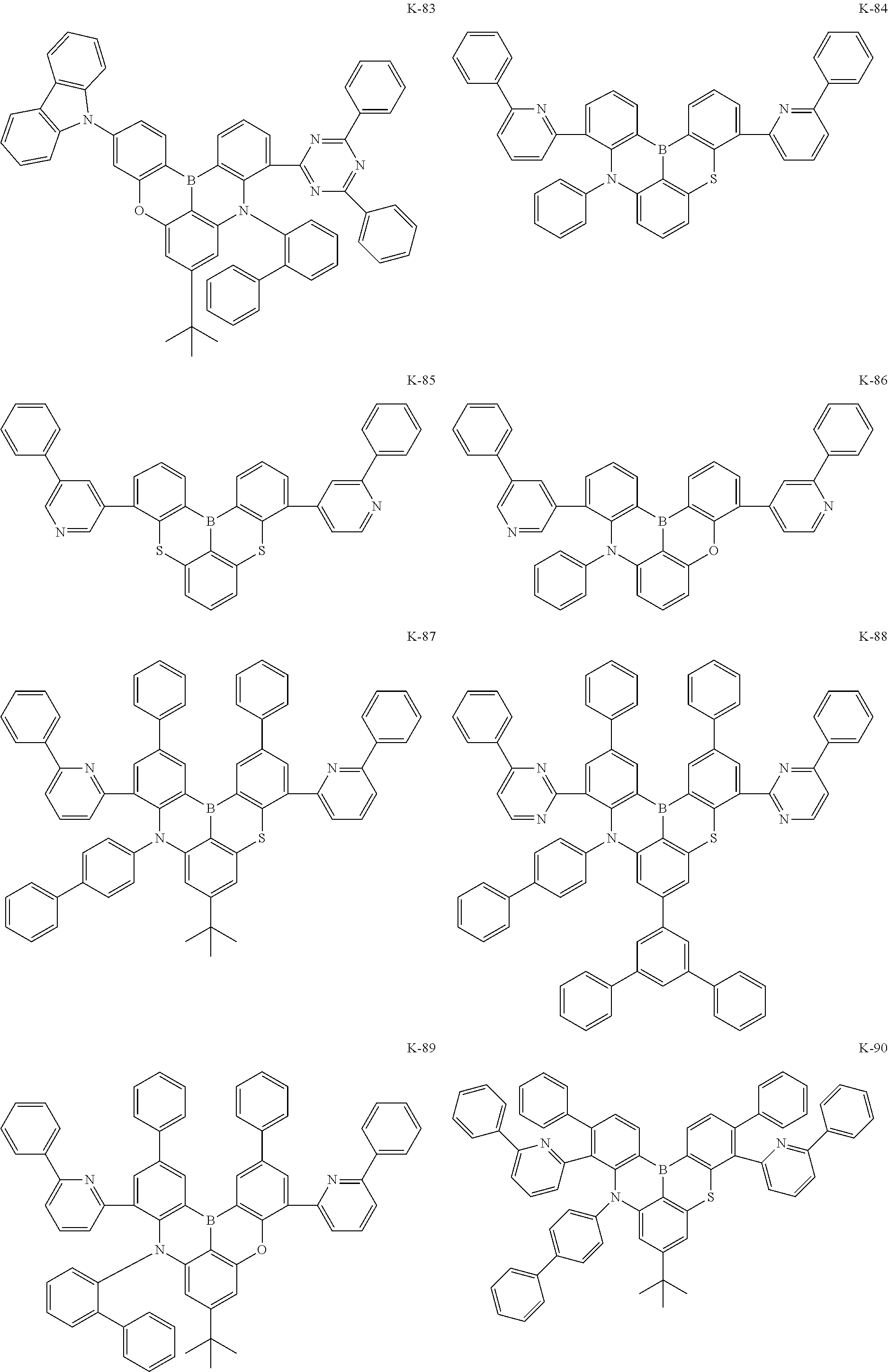

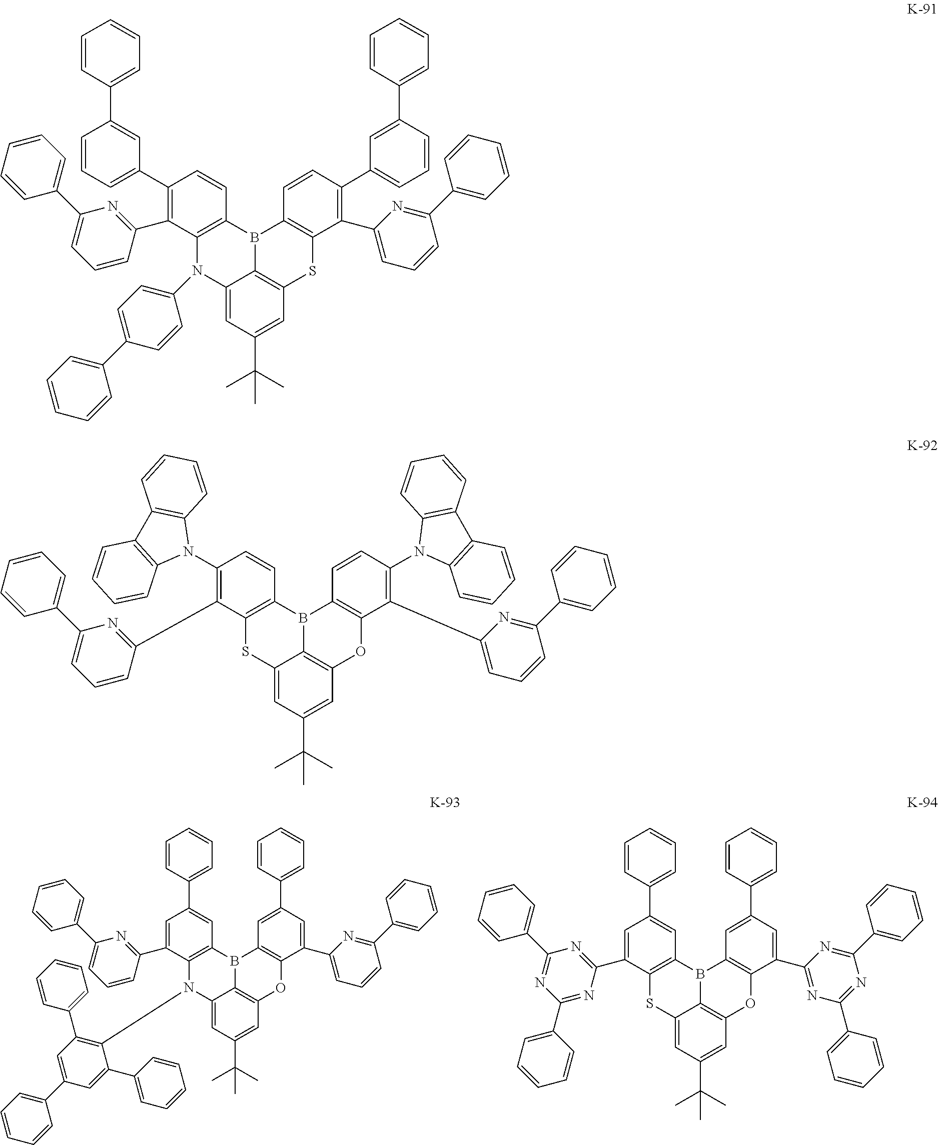

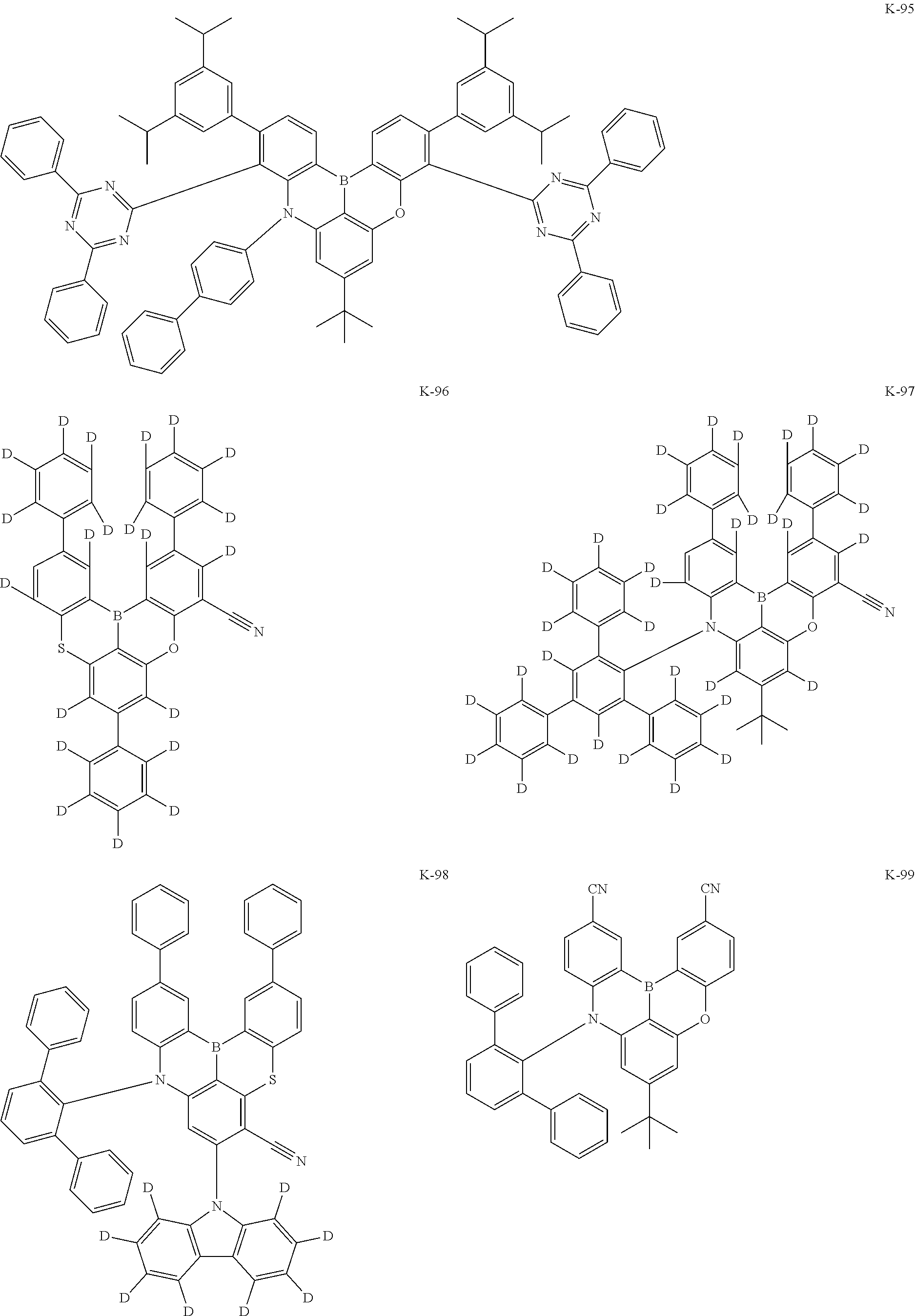

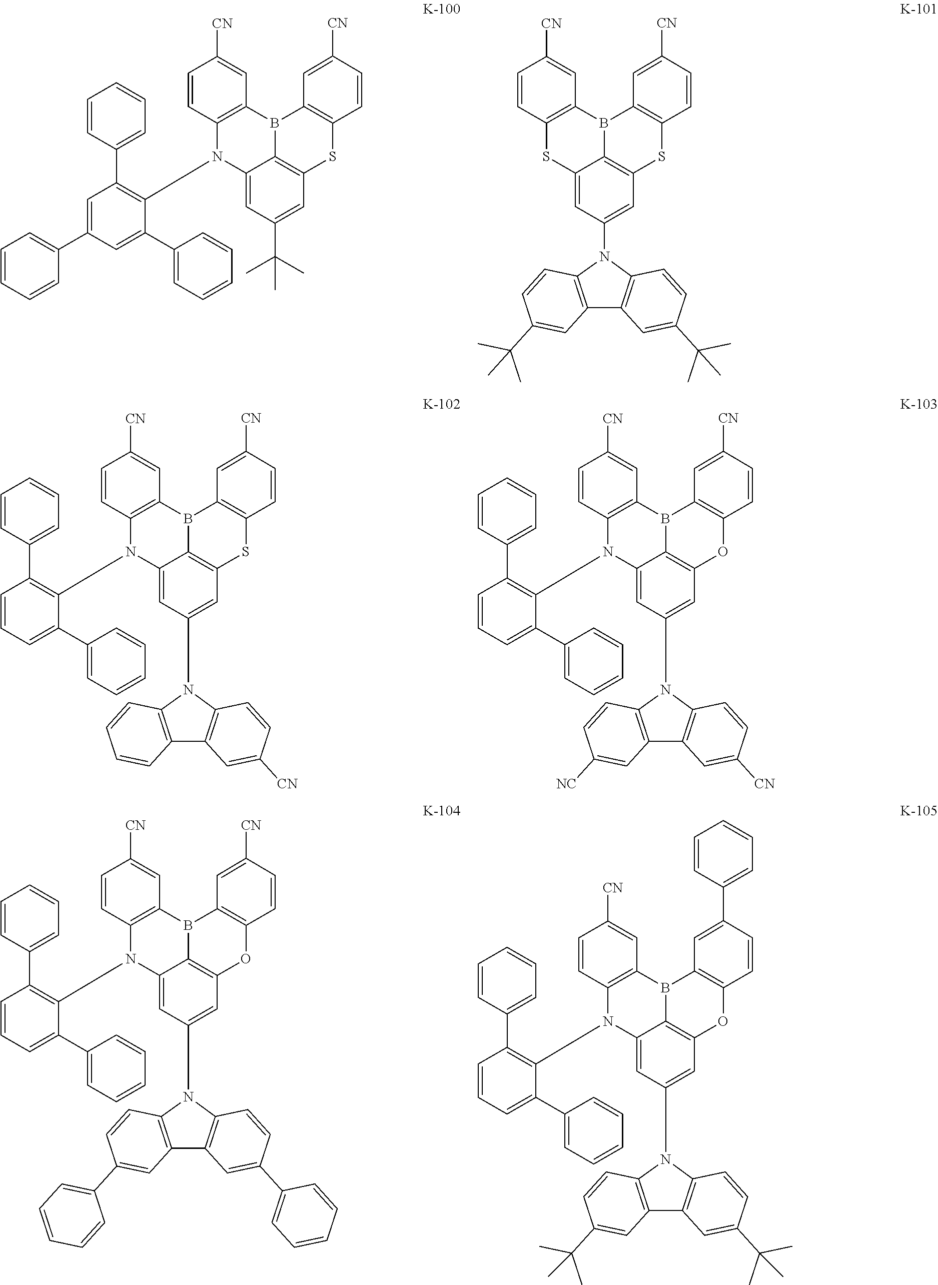

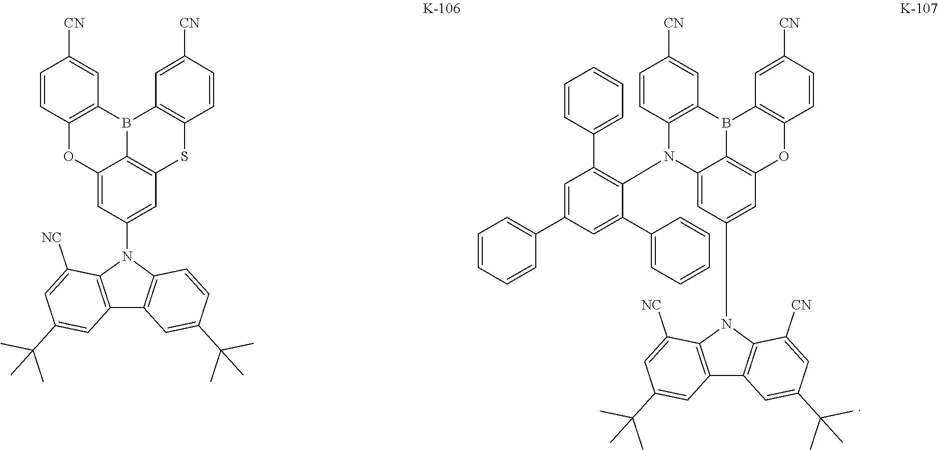 [SMILES: CC(C)(C)c1ccc2c(c1)c1cc(C(C)(C)C)cc(C#N)c1n2-c1cc2c3c(c1)Sc1ccc(C#N)cc1B3c1cc(C#N)ccc1O2 ; CC(C)(C)c1cc(C#N)c2c(c1)c1cc(C(C)(C)C)cc(C#N)c1n2-c1cc2c3c(c1)N(c1c(-c4ccccc4)cc(-c4ccccc4)cc1-c1ccccc1)c1ccc(C#N)cc1B3c1cc(C#N)ccc1O2]

14. A fused polycyclic compound represented by Formula 1: 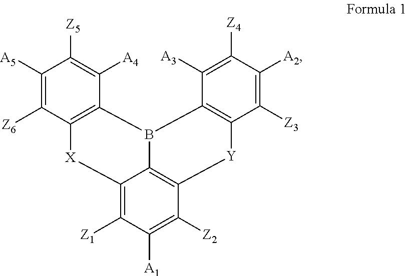
wherein, in Formula 1,
X and Y are each independently O, S, or a substituent represented by Formula 2,
A₁ is hydrogen, deuterium, a halogen, a cyano group, a nitro group, a substituted or unsubstituted amine group, an unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
A₂ to A₅ are each independently hydrogen, deuterium, a halogen, a cyano group, a nitro group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
Z₁ to Z₆ are each independently hydrogen, deuterium, a halogen, a cyano group, a nitro group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or a substituent represented by Formula 3,
at least one selected from among Z₁ to Z₆ is a cyano group, or a substituent represented by a Formula 3, and
the case where the fused polycyclic compound represented by Formula 1 comprises an adamantyl group is excluded, 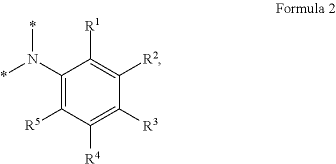
wherein, in Formula 2,
R₁ to R₅ are each independently hydrogen, deuterium, a halogen, a cyano group, a nitro group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and
when each of R₁ to R₅ is a substituted or unsubstituted heteroaryl group having 2 to 30 ring-forming carbon atoms, the case where the heteroaryl group contains nitrogen as a ring-forming atom is excluded,
wherein, in Formula 1, when any one selected from among Z₄ and Z₅ is a cyano group or a substituted or unsubstituted pyridine group, at least one selected from among R₁ to R₅ in Formula 2 is a substituted or unsubstituted aryl group having 6 to 30 ring-forming carbon atoms, or a substituted or unsubstituted heteroaryl group having 2 to 30 ring-forming carbon atoms,
wherein, ** is a position linked to Formula 1, 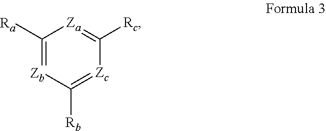
and
wherein, in Formula 3,
at least one selected from among Z₁ to Z₃ is N, and the rest are CR_{d},
Rₐ to R_{d} are each independently hydrogen, deuterium, a halogen, a cyano group, a nitro group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and
at least one selected from among Rₐ to R_{d} is a position linked to Formula 1.

15. The fused polycyclic compound of claim 14, wherein the substituent represented by Formula 3 is represented by any one selected from among Formula 3-1-1 to Formula 3-1-7: 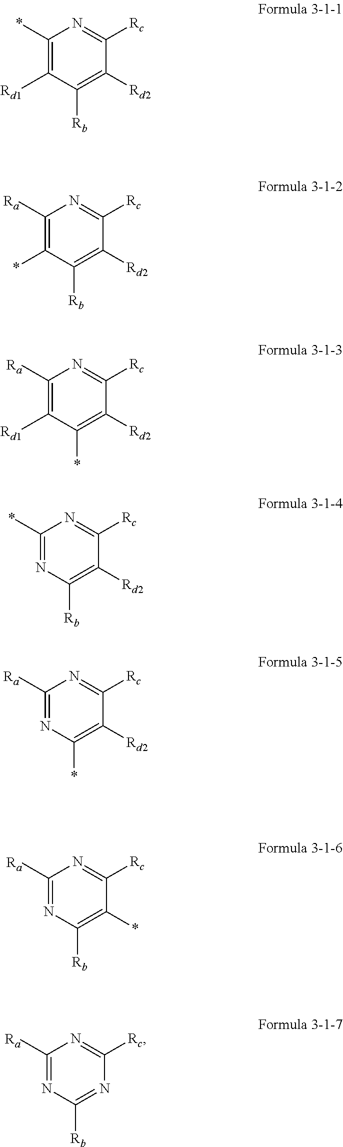
and
wherein, in Formula 3-1-1 to Formula 3-1-7,
R_{d1} and R_{d2} are each independently hydrogen, deuterium, a halogen, a cyano group, a nitro group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
-* is a position linked to Formula 1, and
Rₐ to R_{c} are each independently the same as defined in Formula 3.

16. The fused polycyclic compound of claim 14, wherein the fused polycyclic compound represented by Formula 1 is represented by Formula 1-1-1 or Formula 1-1-2: 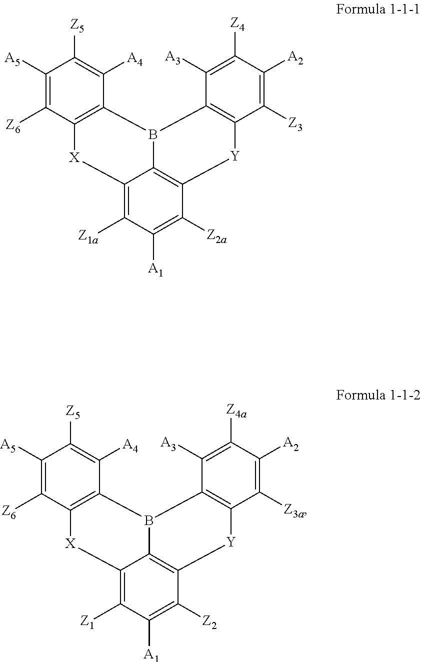
wherein, in Formula 1-1-1 and Formula 1-1-2,
Z₁ₐ to Z₄ₐ are each independently hydrogen, deuterium, a halogen, a cyano group, a nitro group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or a substituent represented by Formula 3,
wherein, in Formula 1-1-1,
at least one of Z₁ₐ or Z₂ₐ is a cyano group, or a substituent represented by Formula 3,
wherein, in Formula 1-1-2,
at least one of Z₃ₐ or Z₄ₐ is a cyano group, or a substituent represented by Formula 3, and
wherein, X, Y, A₁ to A₅, and Z₁ to Z₆ are each independently the same as defined in Formula 1.

17. The fused polycyclic compound of claim 14, wherein the fused polycyclic compound represented by Formula 1 is represented by any one selected from among Formula 1-2-1 to Formula 1-2-3: 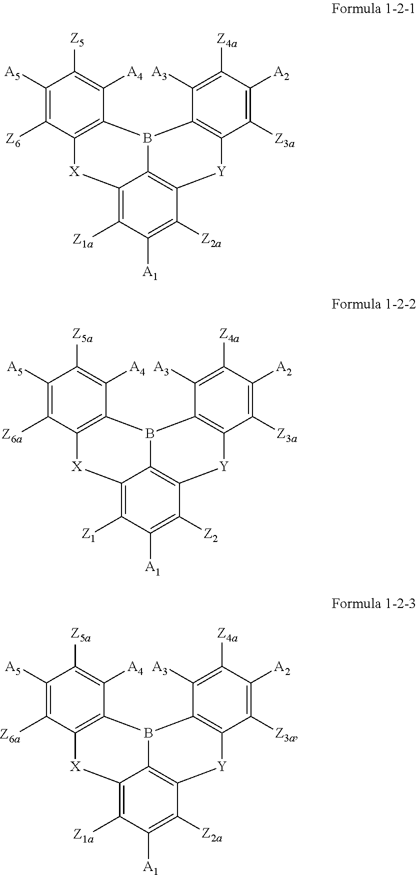
wherein, in Formula 1-2-1 to Formula 1-2-3,
Z₁ₐ to Z₆a are each independently hydrogen, deuterium, a halogen, a cyano group, a nitro group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or a substituent represented by Formula 3,
wherein, in Formula 1-2-1,
at least one of Z₁a or Z₂ₐ and at least one of Z₃ₐ or Z₄a are each independently a cyano group or a substituent represented by Formula 3,
wherein, in Formula 1-2-2,
at least one of Z₃ₐ or Z₄a and at least one of Z₅a or Z₆a are each independently a cyano group or a substituent represented by Formula 3,
wherein, in Formula 1-2-3,
at least one of Z₁a or Z₂ₐ, at least one of Z₃ₐ or Z₄ₐ, and at least one of Z₅a or Z₆a are each independently a cyano group or a substituted represented by Formula 3, and
wherein, X, Y, A₁ to A₅, and Z₁, Z₂, Z₅, and Ze are each independently the same as defined in Formula 1.

18. The fused polycyclic compound of claim 14, wherein the fused polycyclic compound represented by Formula 1 is represented by Formula 1-4: 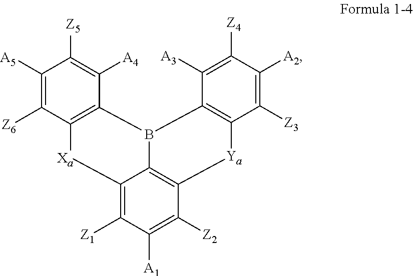
wherein, in Formula 4,
Xₐ and Yₐ are each independently represented by any one selected from among Formula 2-1 to Formula 2-7, and
when any one selected from among Z₄ and Z₅ is a cyano group or a substituted or unsubstituted pyridine group, Xₐ and Yₐ are each independently represented by any one selected from among Formula 2-2 to Formula 2-7: 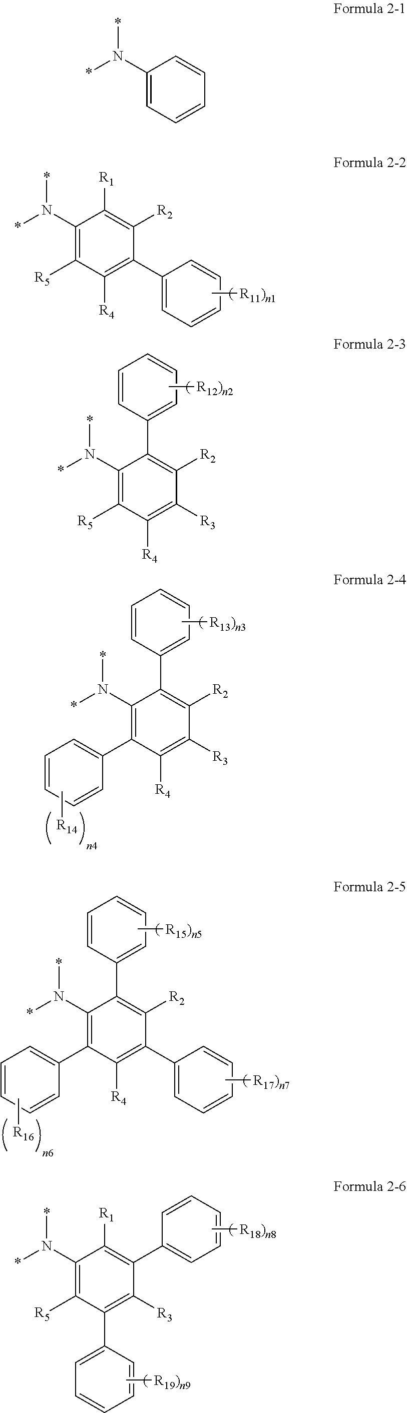 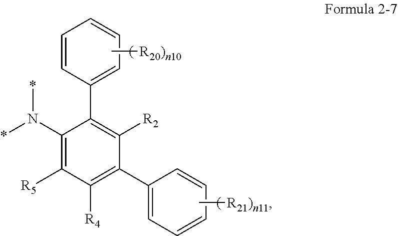
wherein, in Formula 2-1 to Formula 2-7,
R₁₁ to R₂₁ are each independently hydrogen, deuterium, a halogen, a cyano group, a nitro group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
n1 to n11 are each independently an integer of 0 to 5, and
R₁ to R₅ are each independently the same as defined in Formula 2, and
wherein, in Formula 1-4,
A₁ to A₅, and Z₁ to Z₆ are each independently the same as defined in Formula 1.

19. The fused polycyclic compound of claim 14, wherein the fused polycyclic compound represented by Formula 1 is represented by any one selected from among Formula 1-5-1 to Formula 1-5-7: 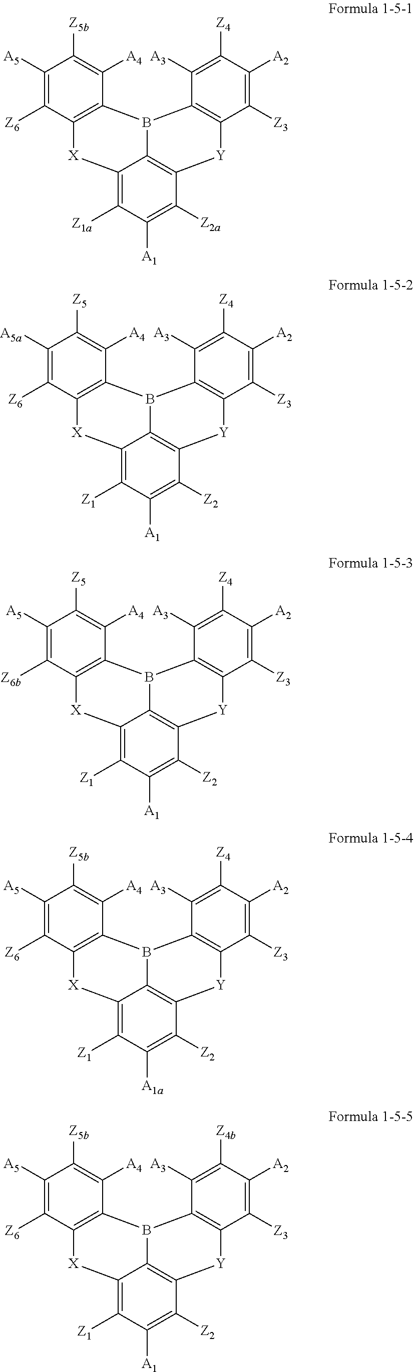 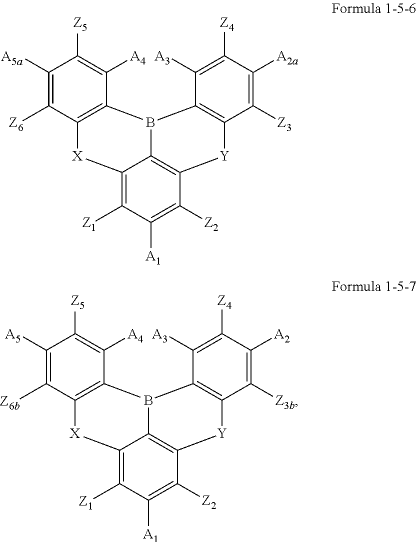
wherein, in Formula 1-5-1 to Formula 1-5-7,
Z_{3b} to Z_{6b}, A₂ₐ, and A₅ₐ are each independently a substituted or unsubstituted alkyl group having 1 to 10 carbon atoms, or represented by Formula A-1 or Formula A-2, and
A₁ₐ is an unsubstituted alkyl group having 1 to 10 carbon atoms, or represented by Formula A-1 or Formula A-2,
wherein, in Formula 1-5-1 and Formula 1-5-4,
at least one selected from among Z₁ to Z₄ and Z₆ is a cyano group, or a substituent represented by Formula 3,
wherein, in Formula 1-5-2 and Formula 1-5-6,
at least one selected from among Z₁ to Z₆ is a cyano group, or a substituent represented by Formula 3,
wherein, in Formula 1-5-3,
at least one selected from among Z₁ to Z₅ is a cyano group, or a substituent represented by Formula 3,
wherein, in Formula 1-5-5,
at least one selected from among Z₁ to Z₃ and Z₆ is a cyano group, or a substituent represented by Formula 3,
wherein, in Formula 1-5-7,
at least one selected from among Z₁, Z₂, Z₄, and Z₅ is a cyano group, or a substituent represented by Formula 3, 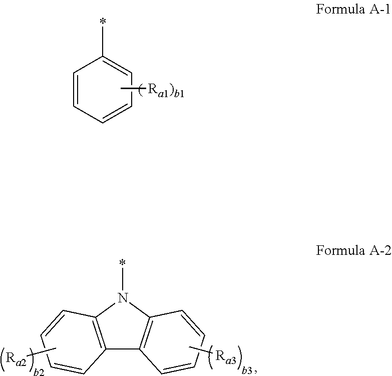
wherein, in Formula A-1 and Formula A-2,
Rₐ₁ to Rₐ₃ are each independently hydrogen, deuterium, a halogen, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
b1 is an integer of 0 to 5,
b2 and b3 are each independently an integer of 0 to 4, and
-* is a position linked to Formula 1-5-1 to Formula 1-5-7, and
wherein, in Formula 1-5-1 to Formula 1-5-7,
X, Y, A₁ to A₅, and Z₁ to Z₆ are each independently the same as defined in Formula 1.

20. The fused polycyclic compound of claim 14, wherein the fused polycyclic compound comprises at least one selected from among compounds in Compound Group 1: 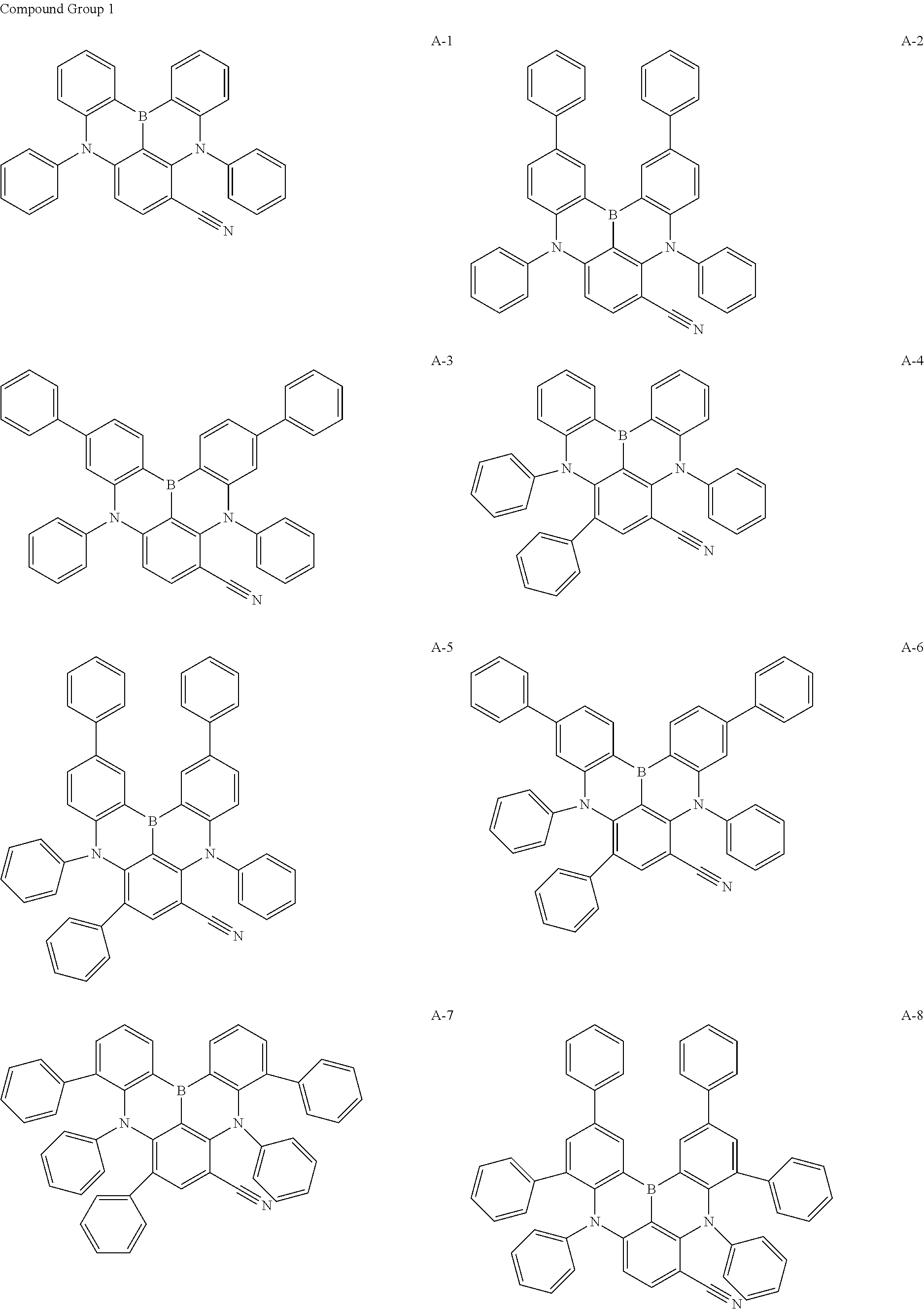 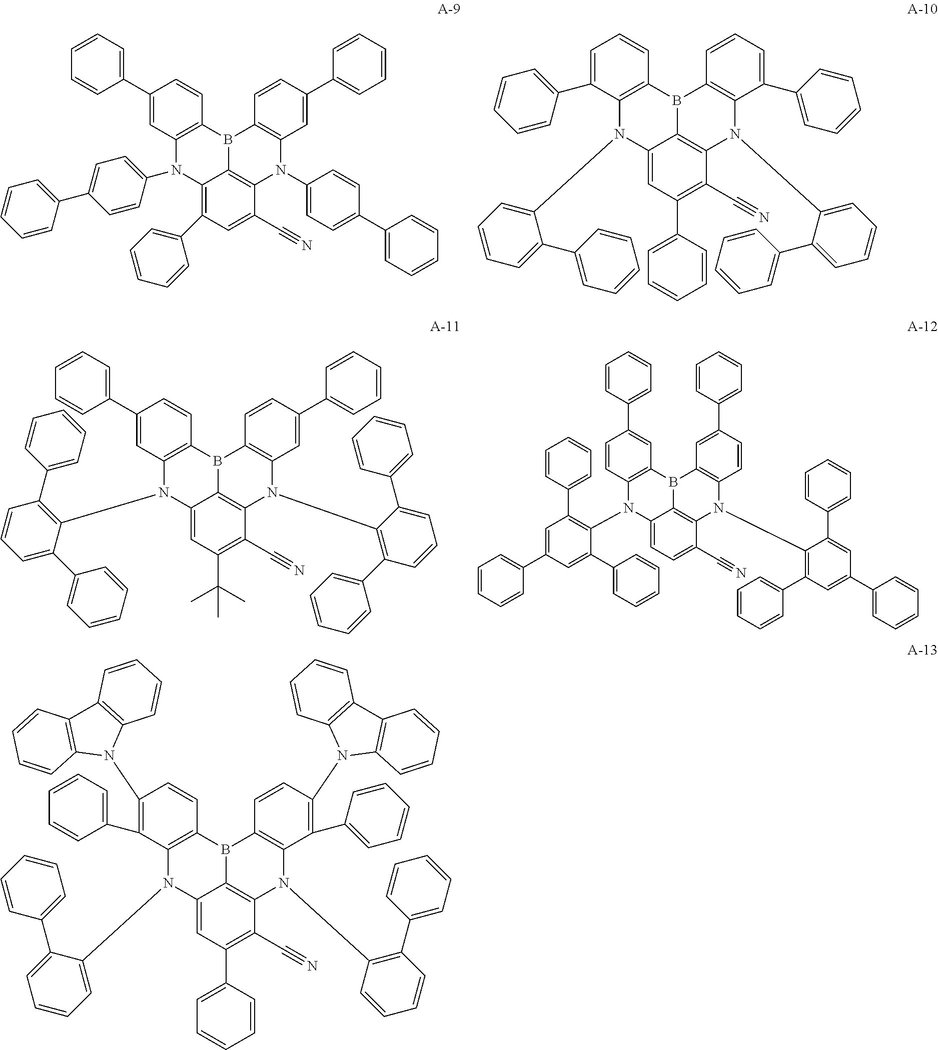 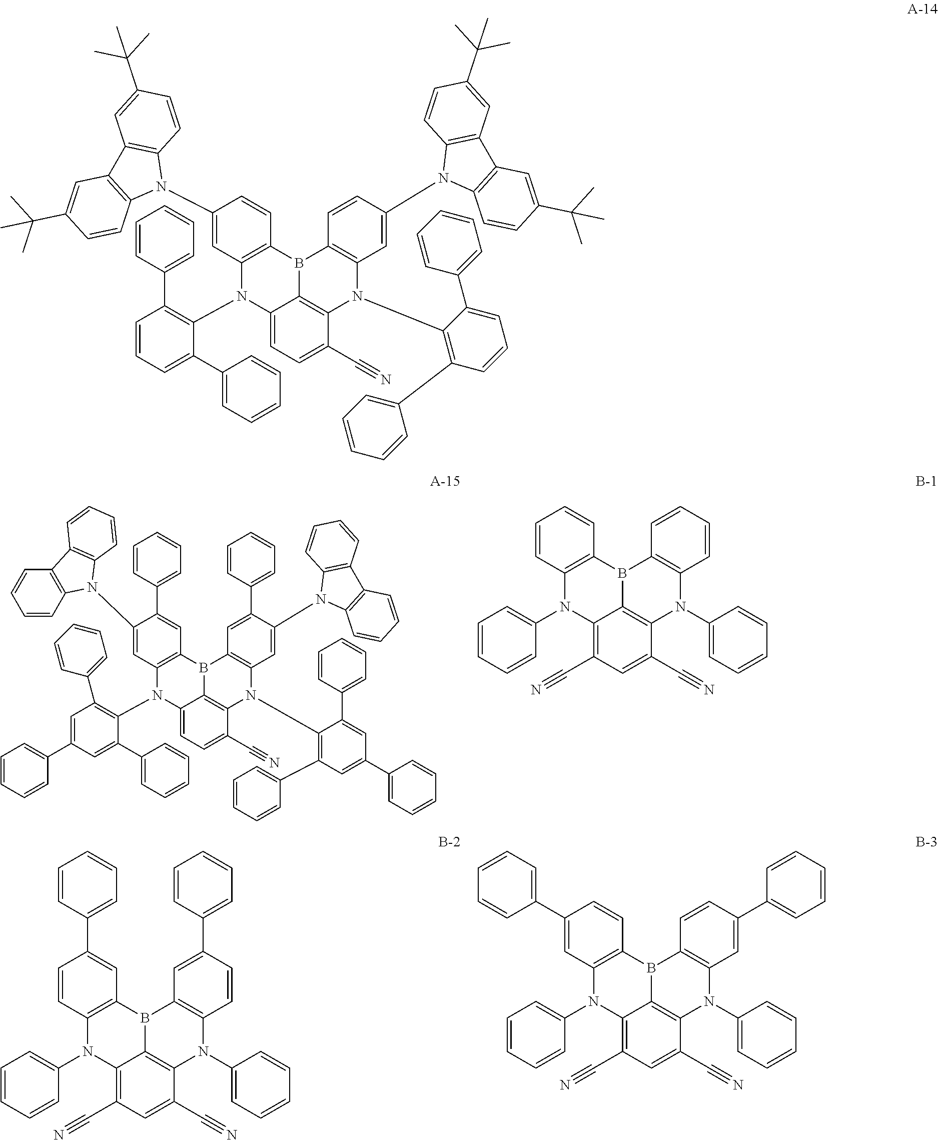 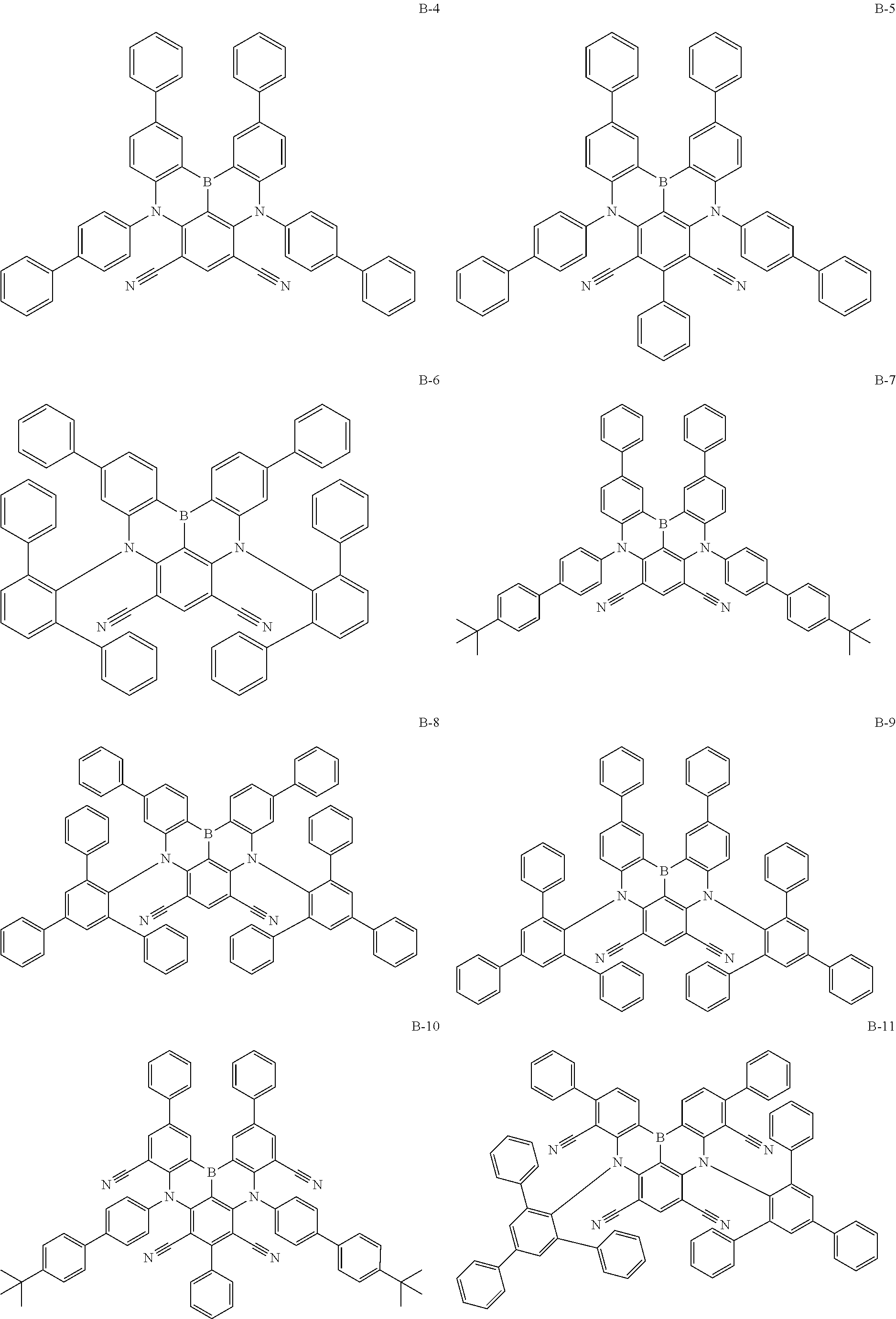 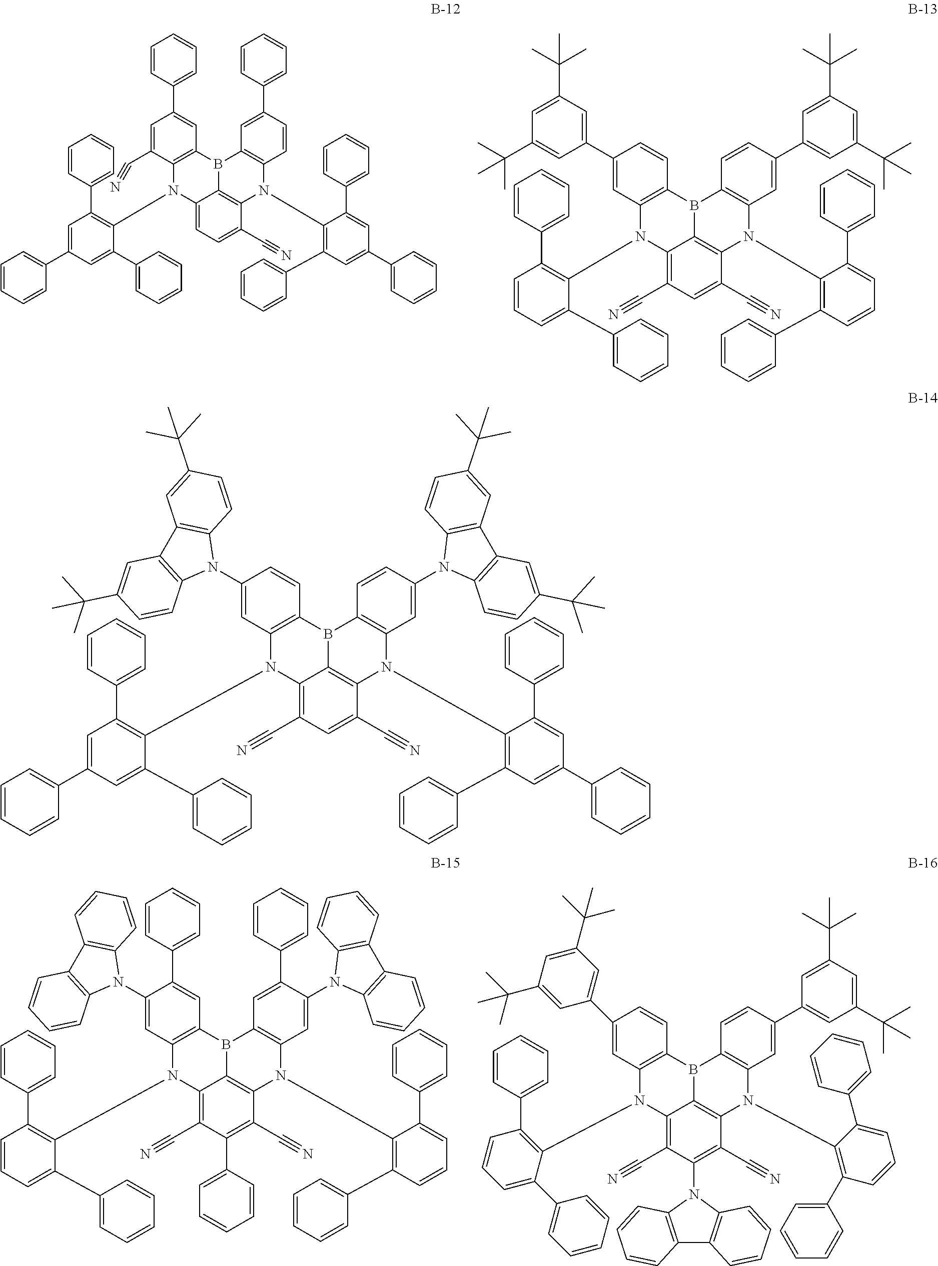 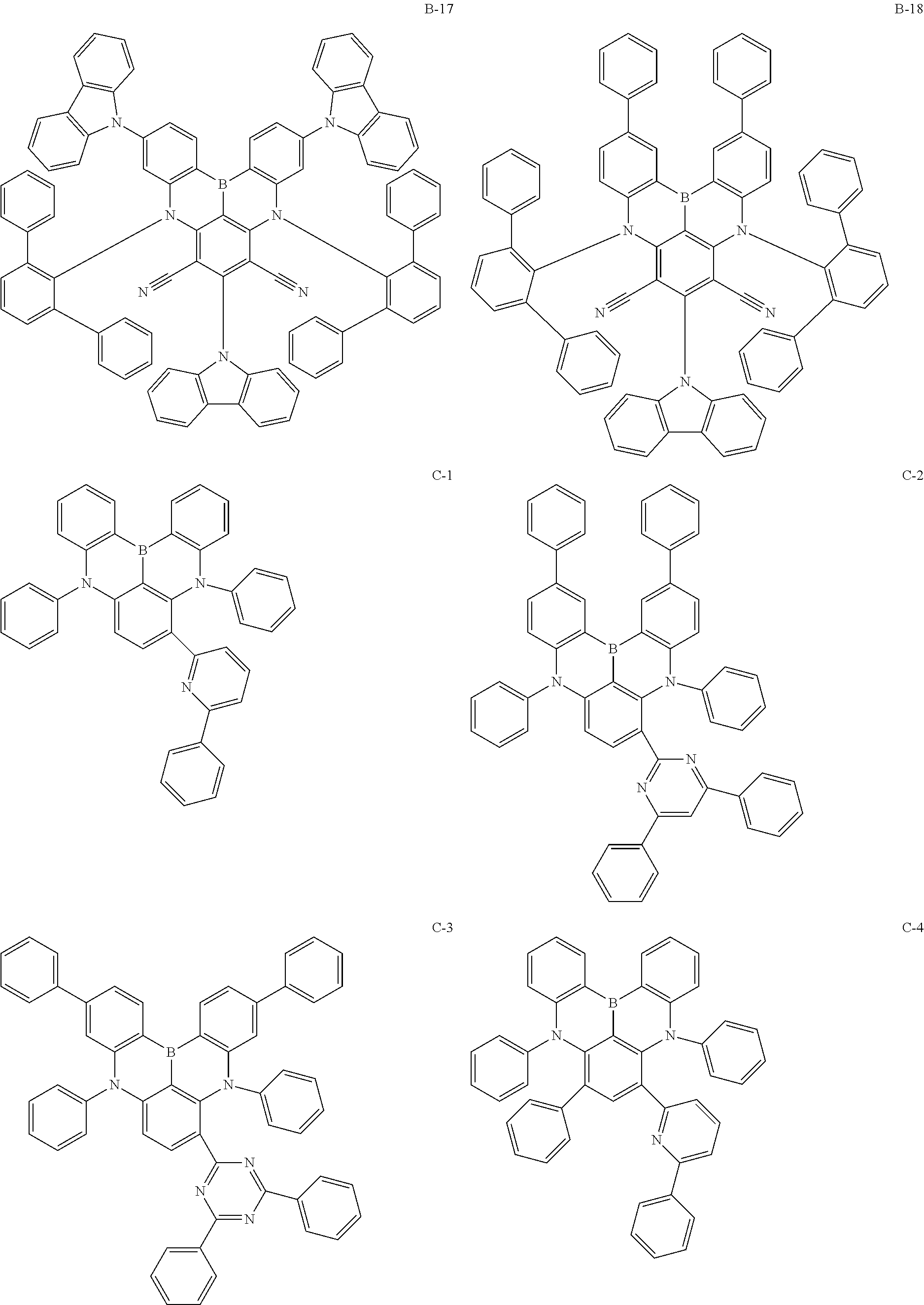 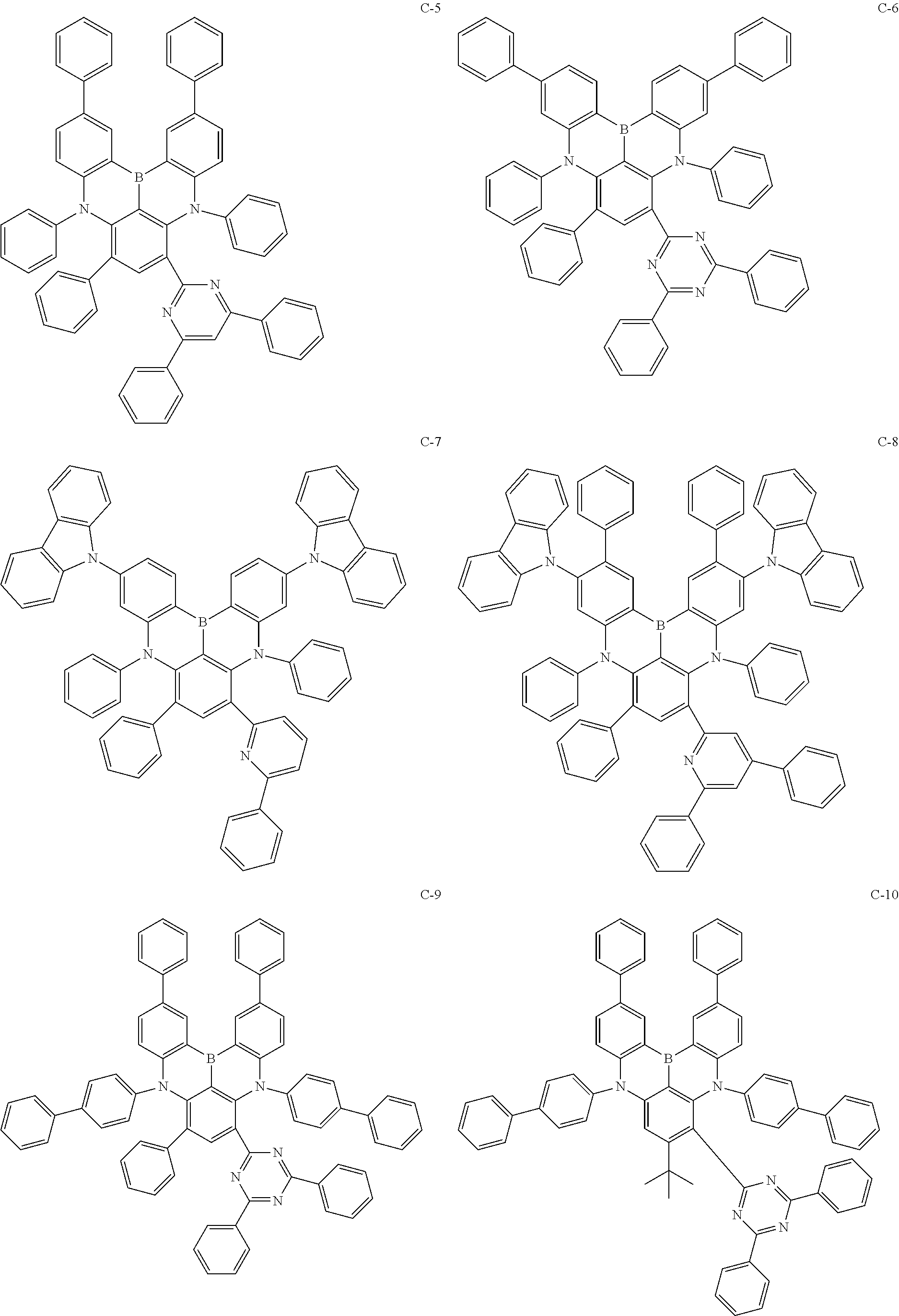 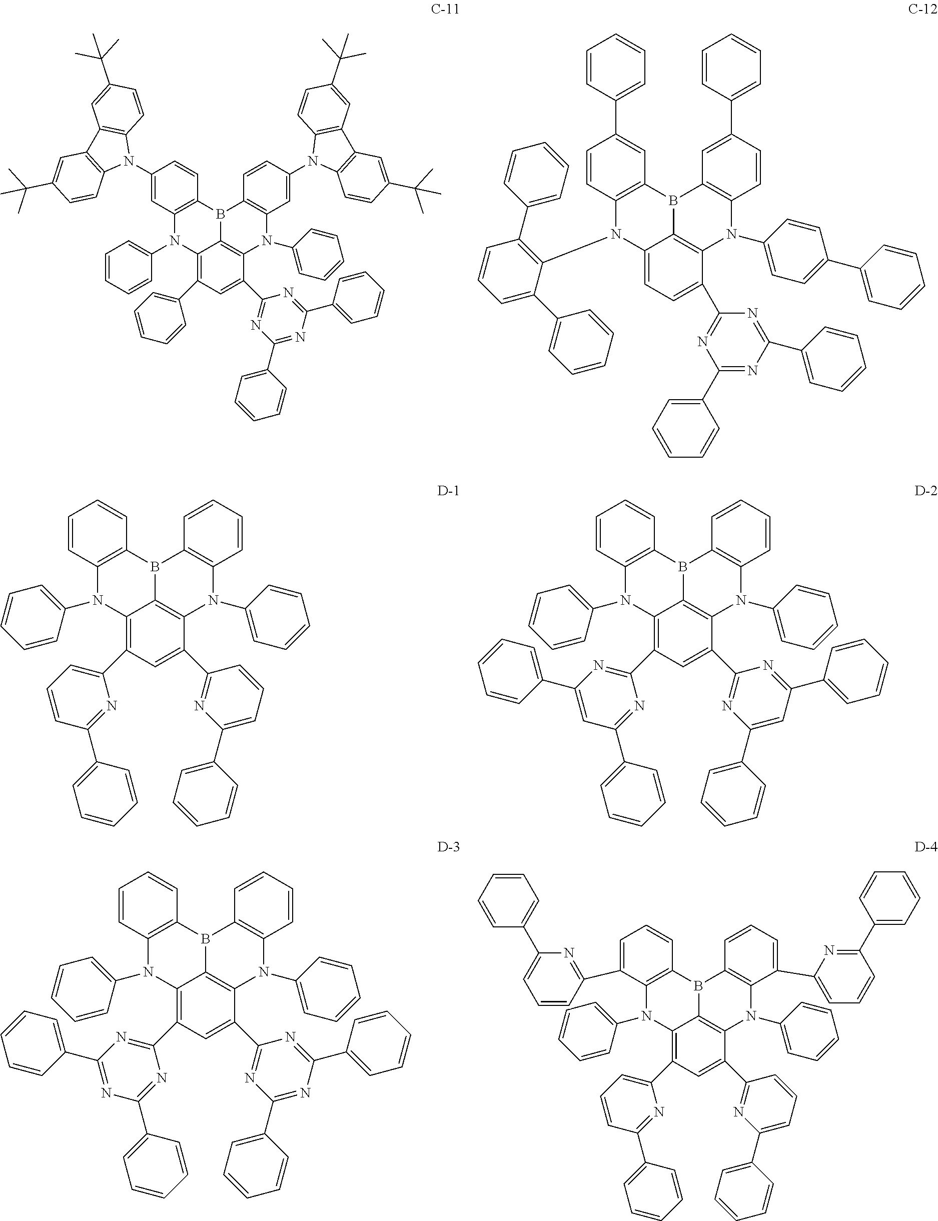 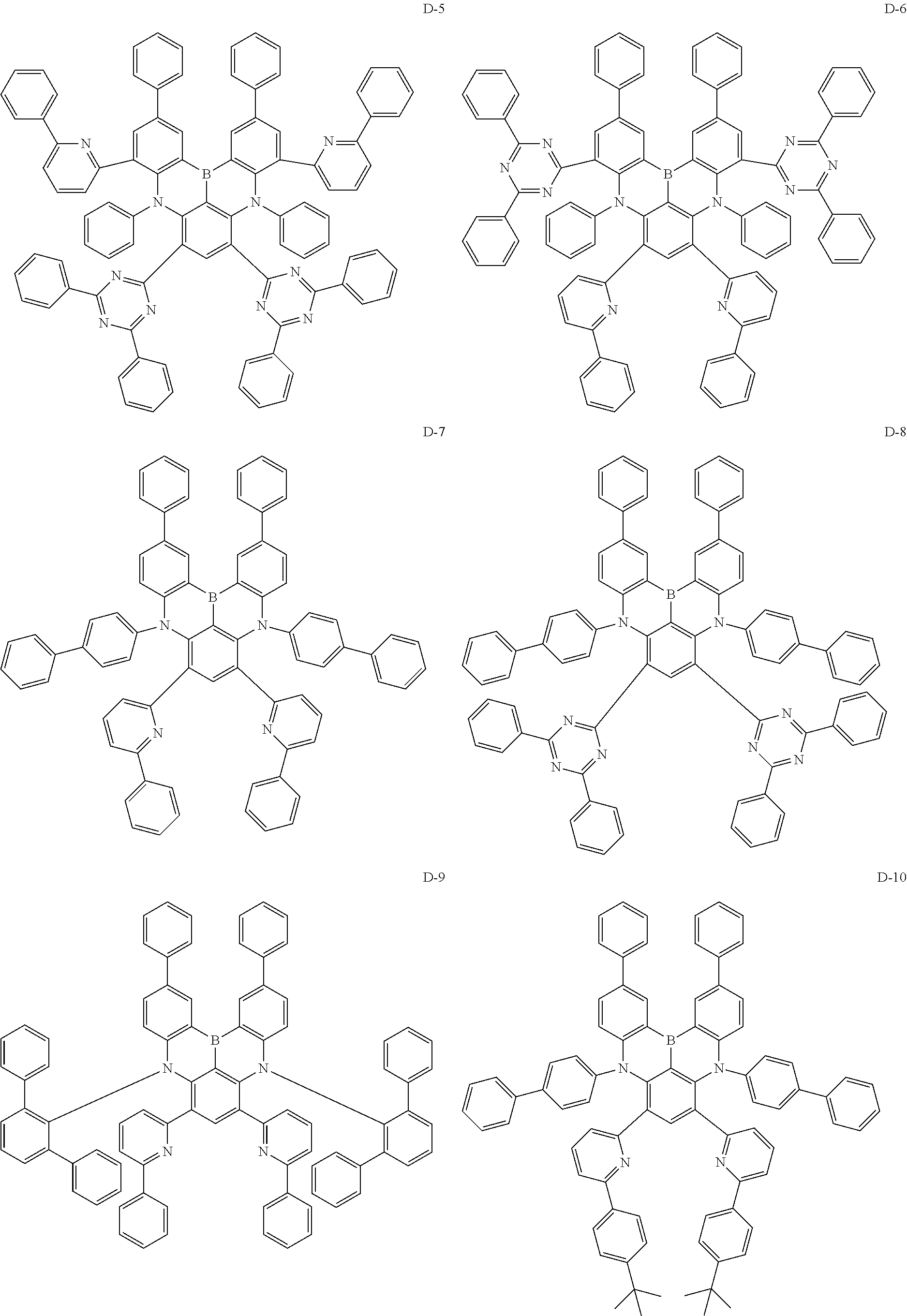 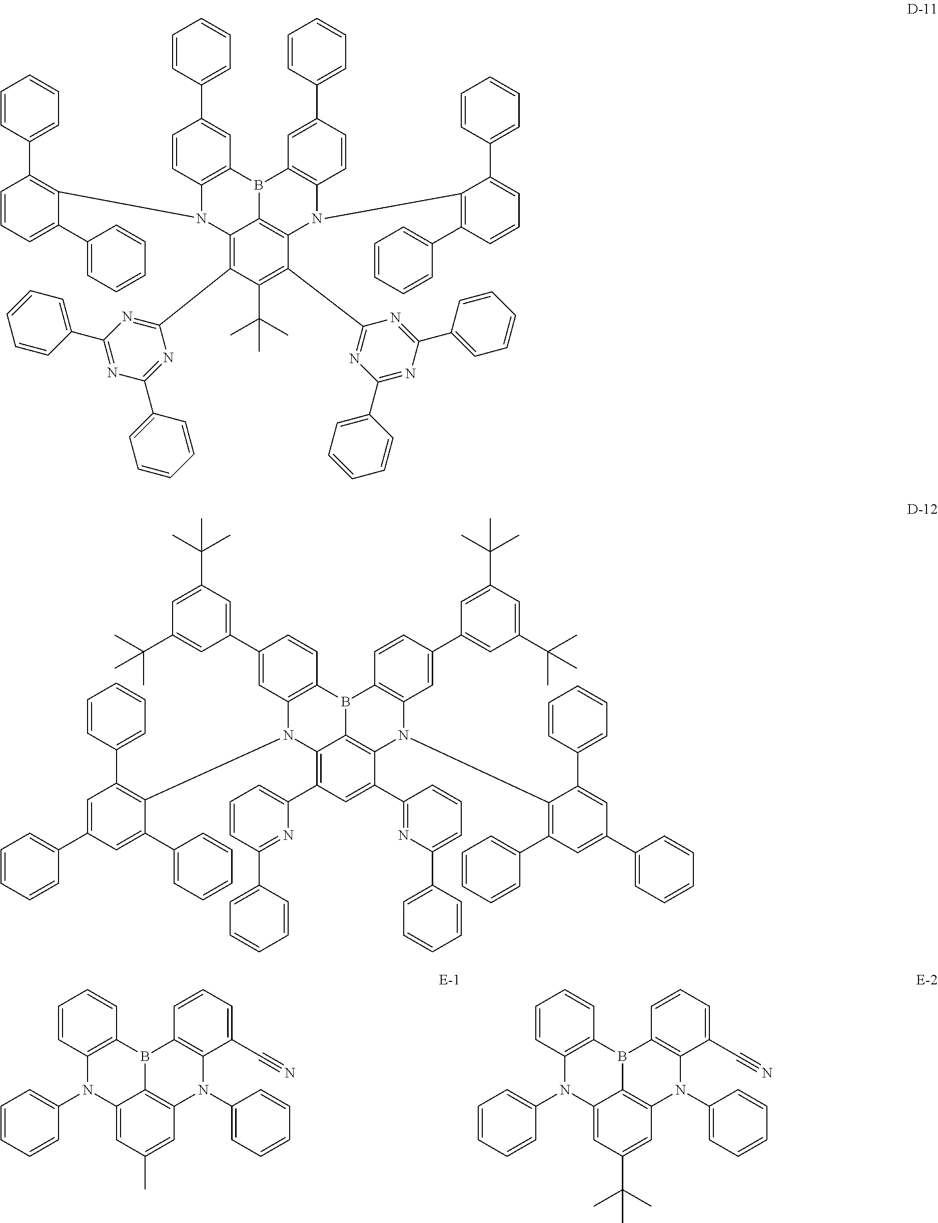 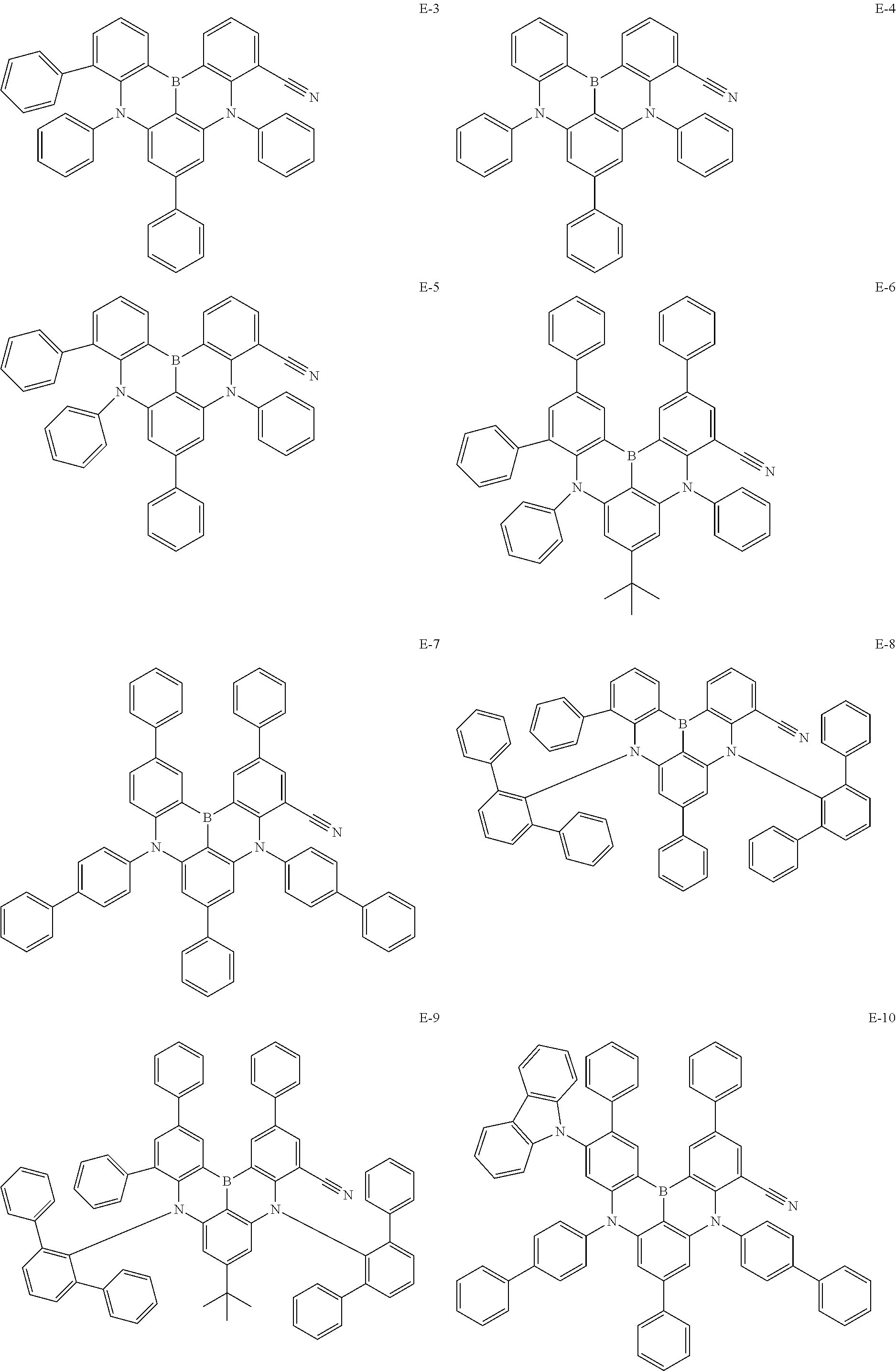 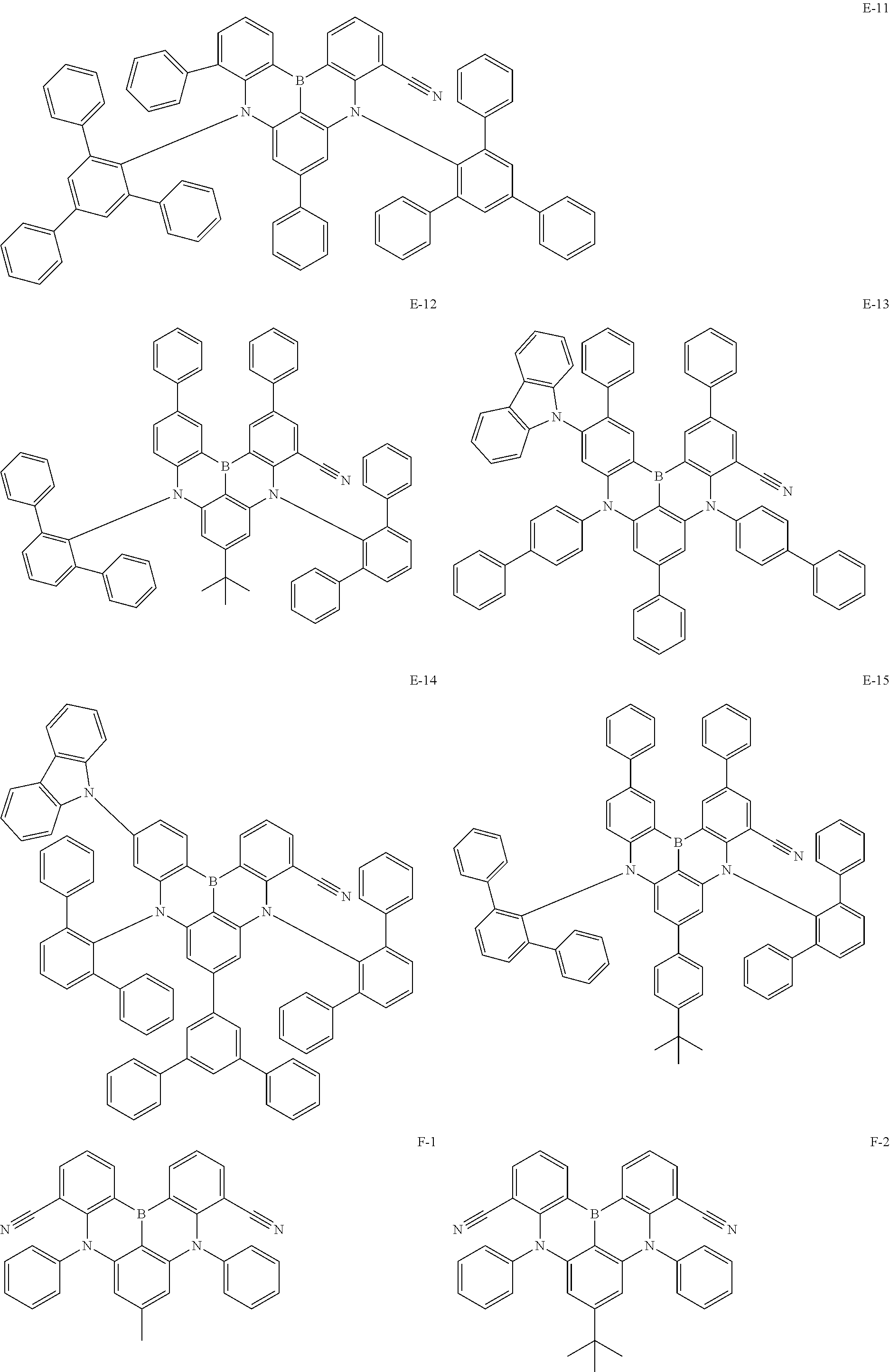 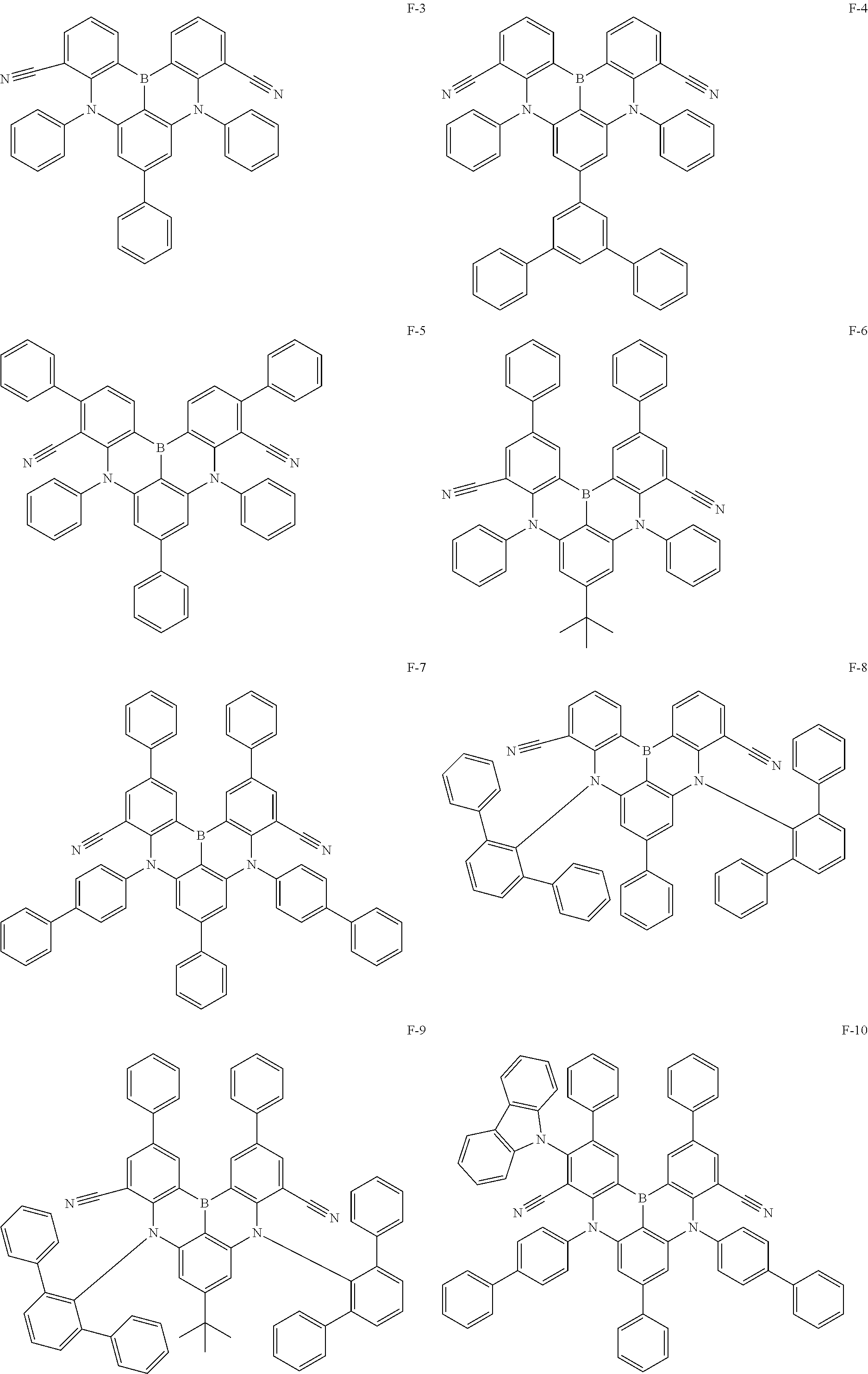 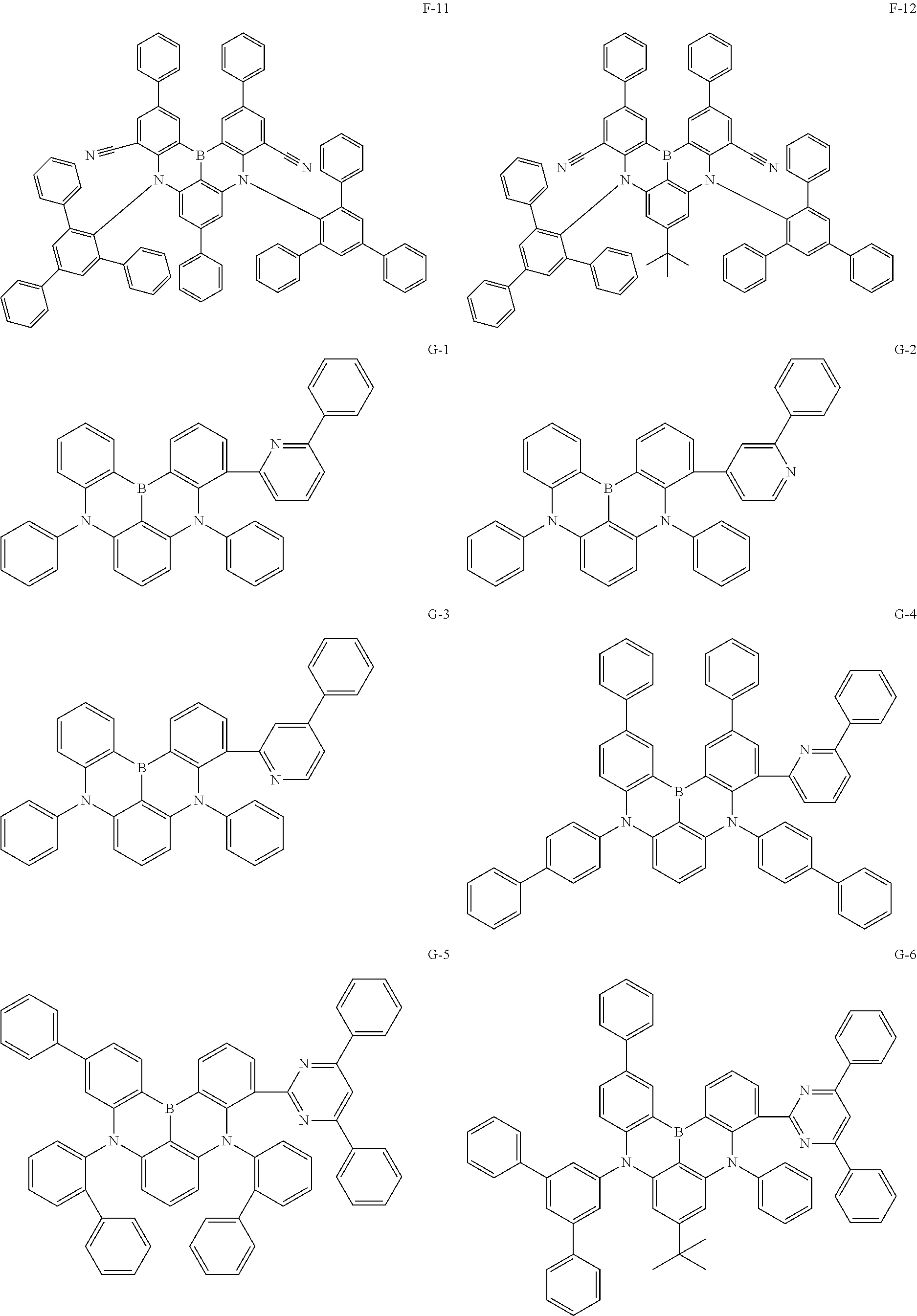 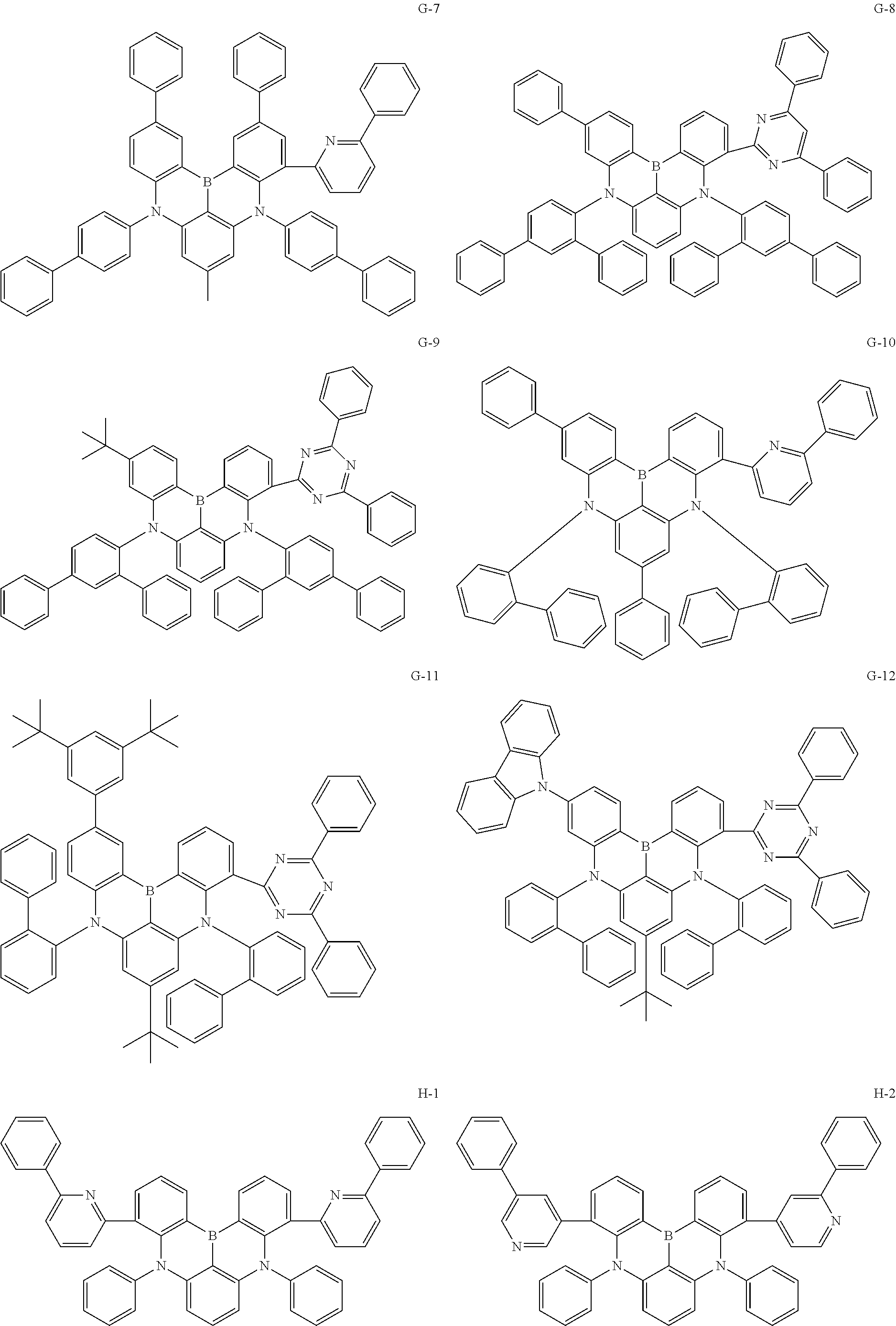 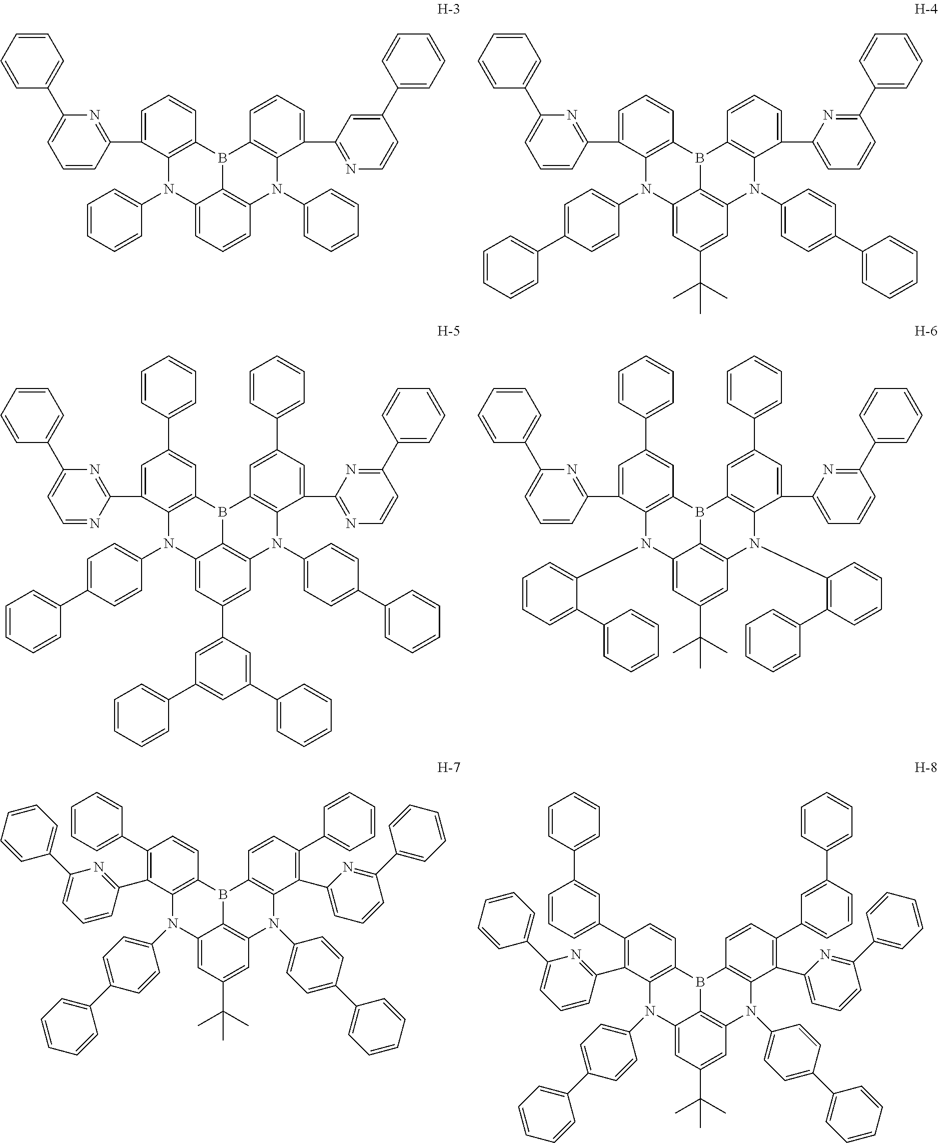 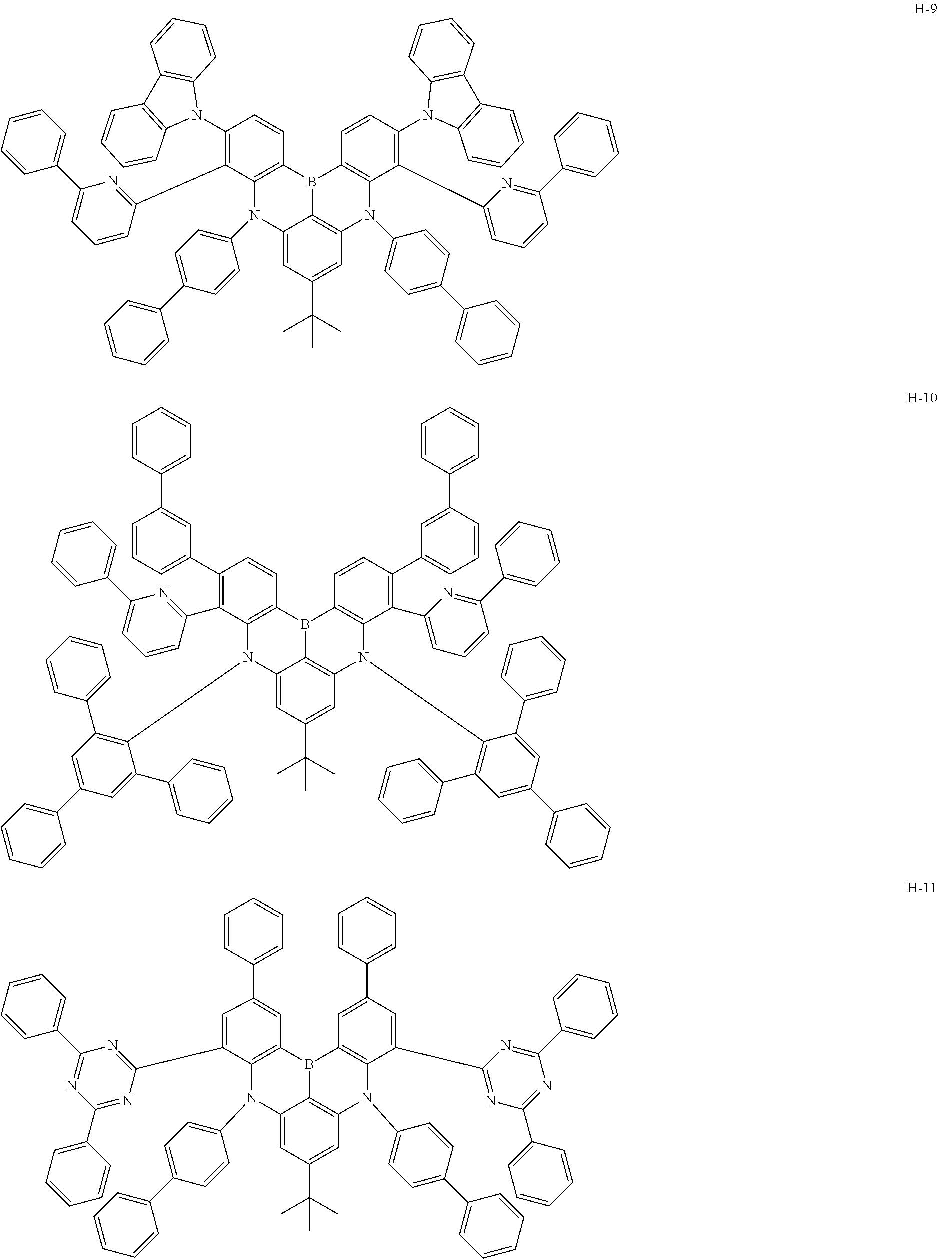 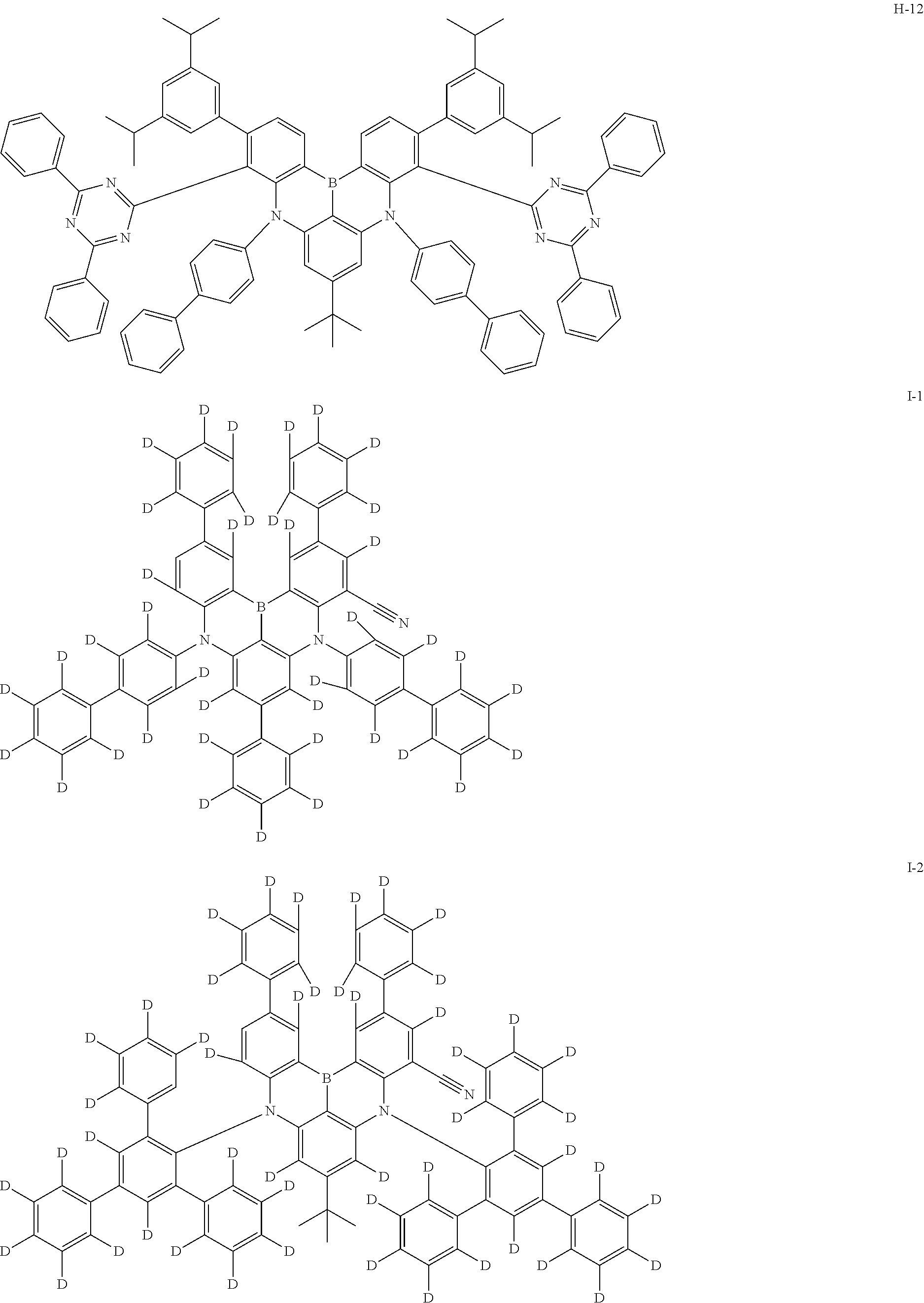 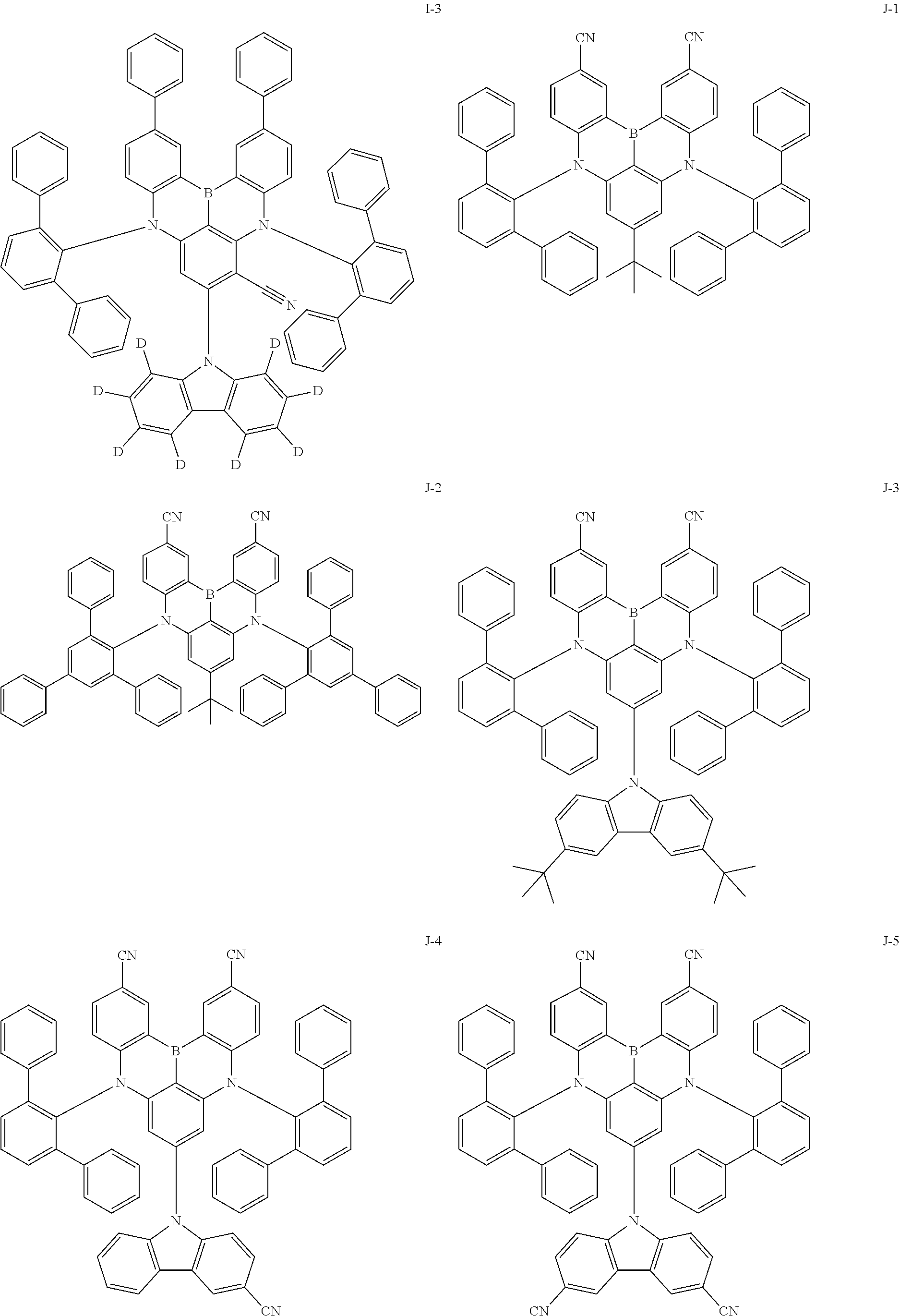 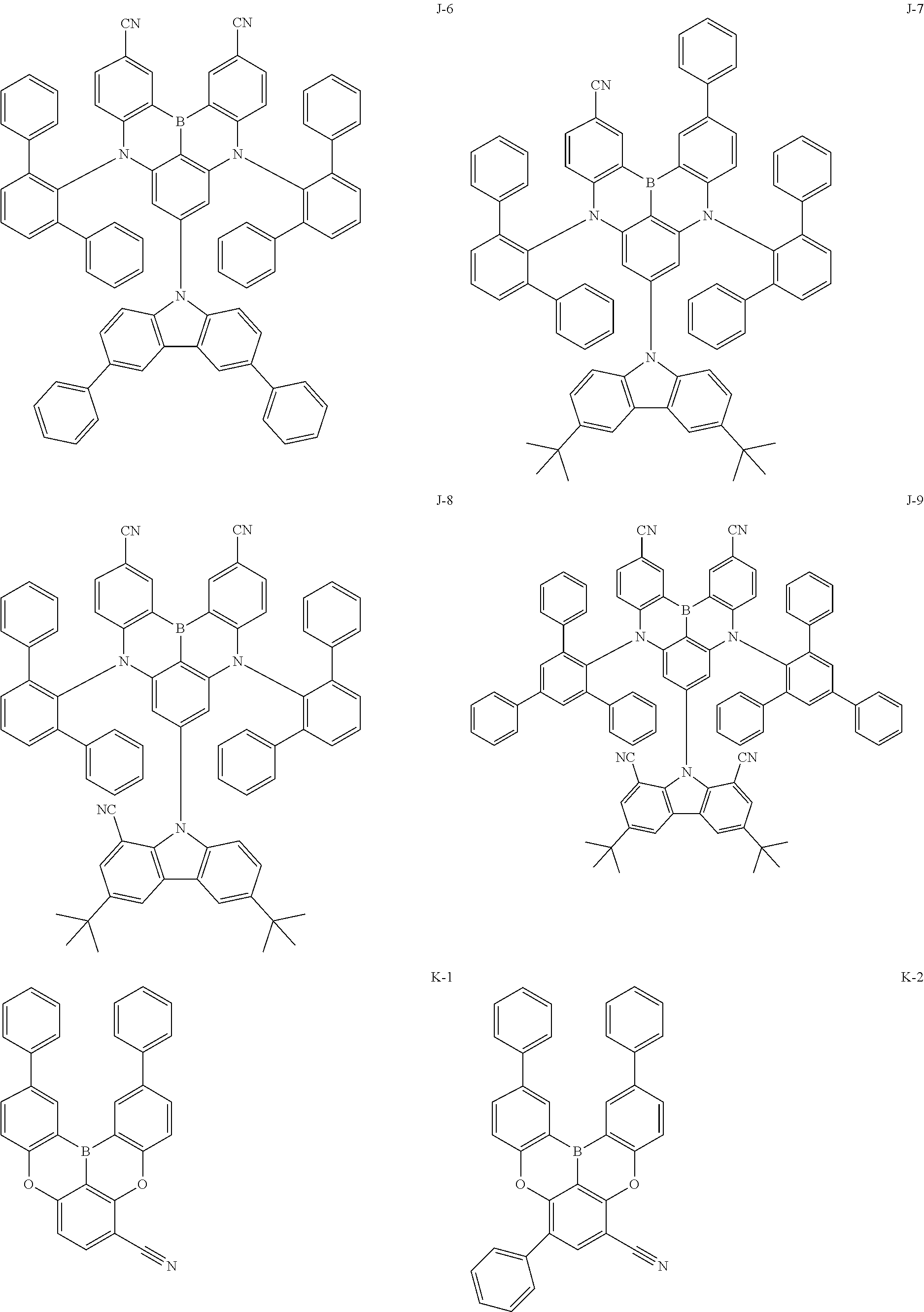 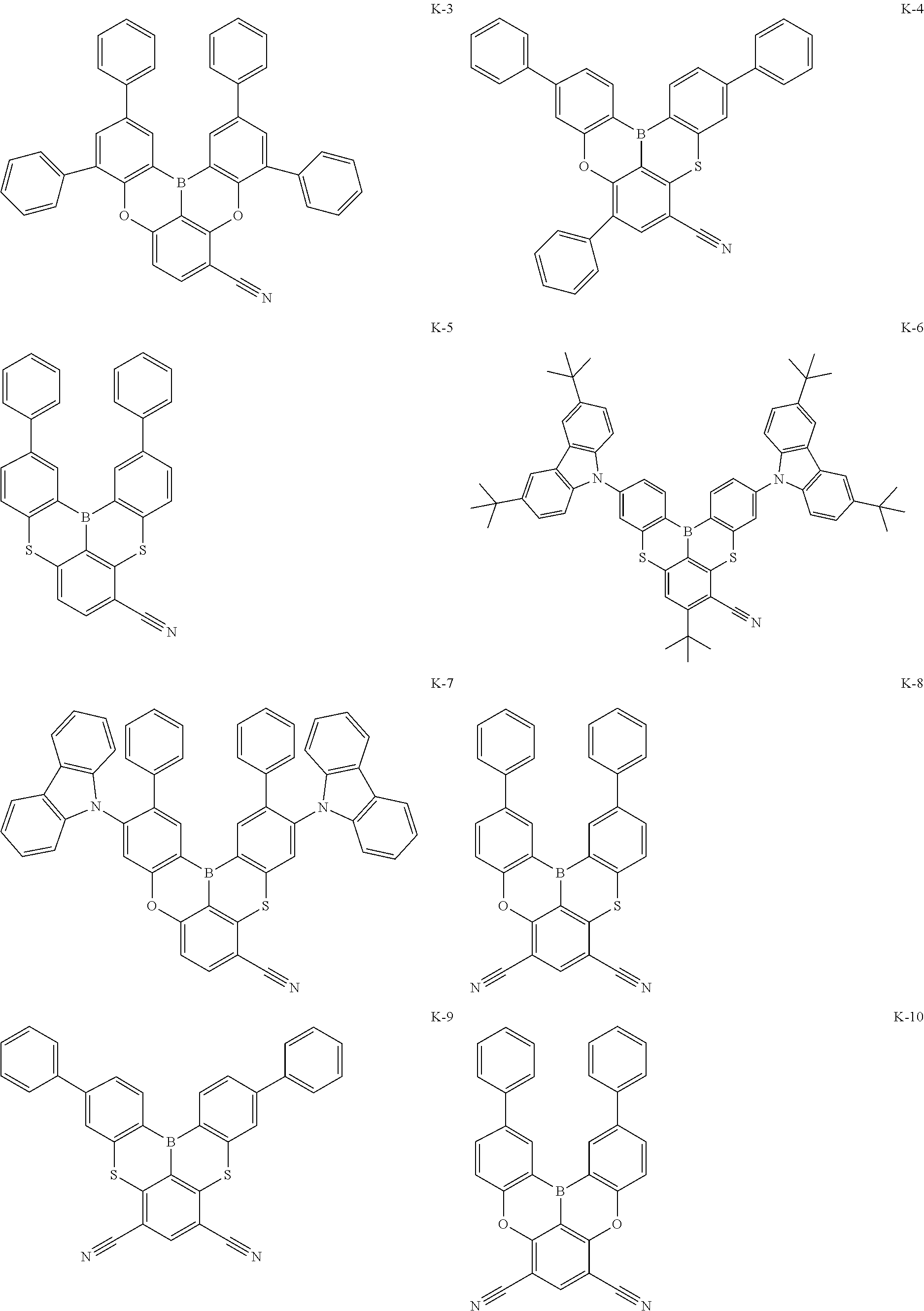 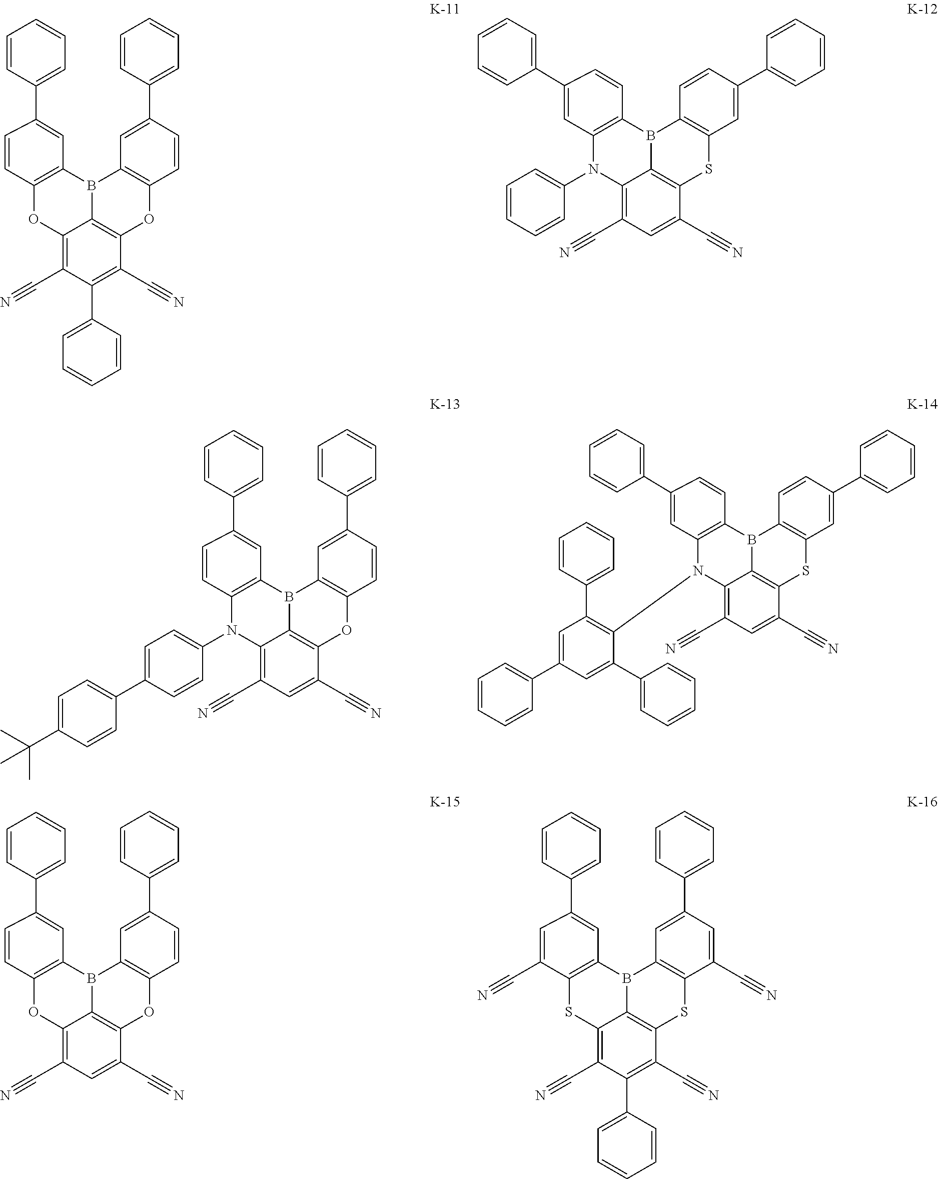 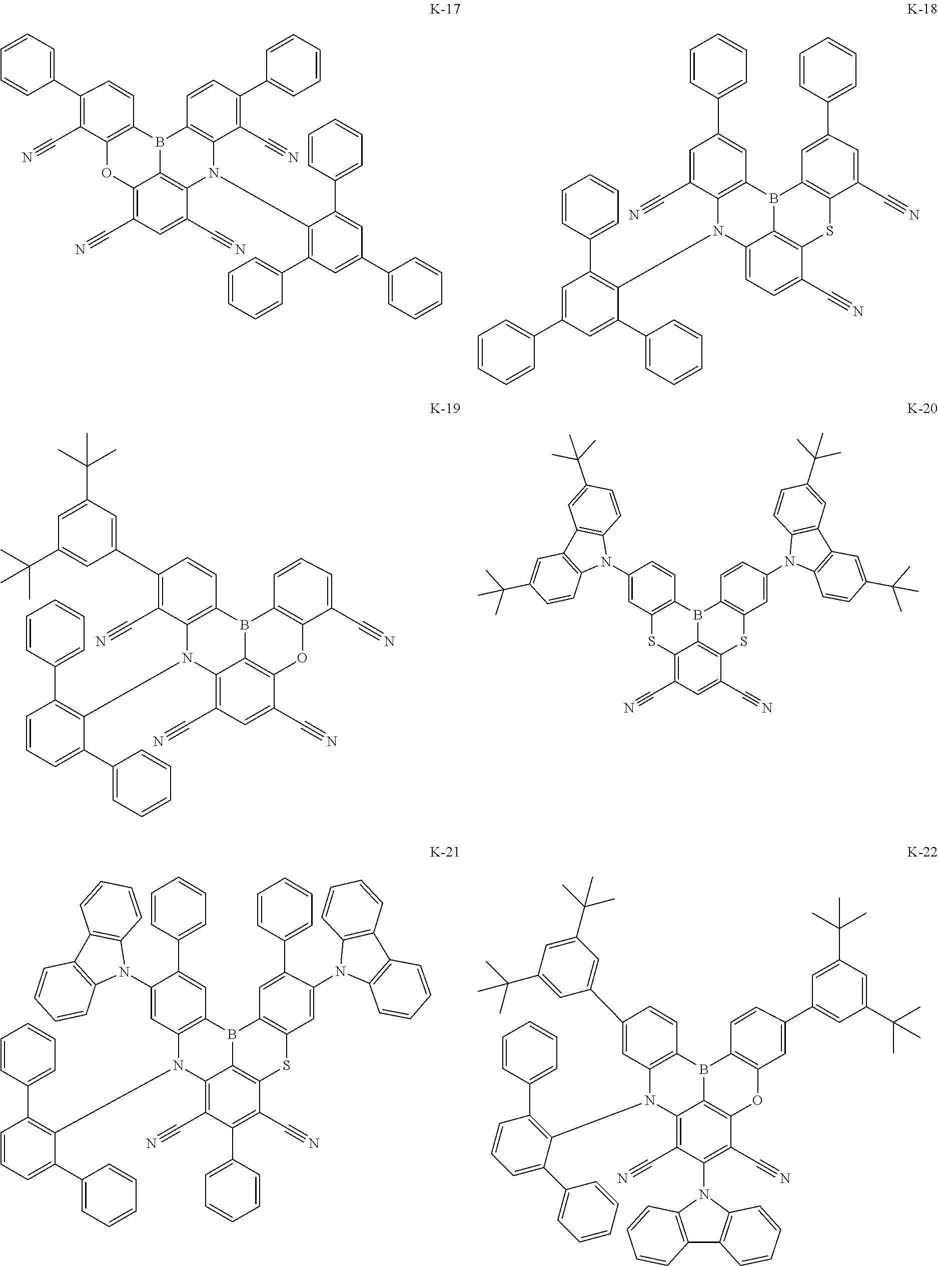 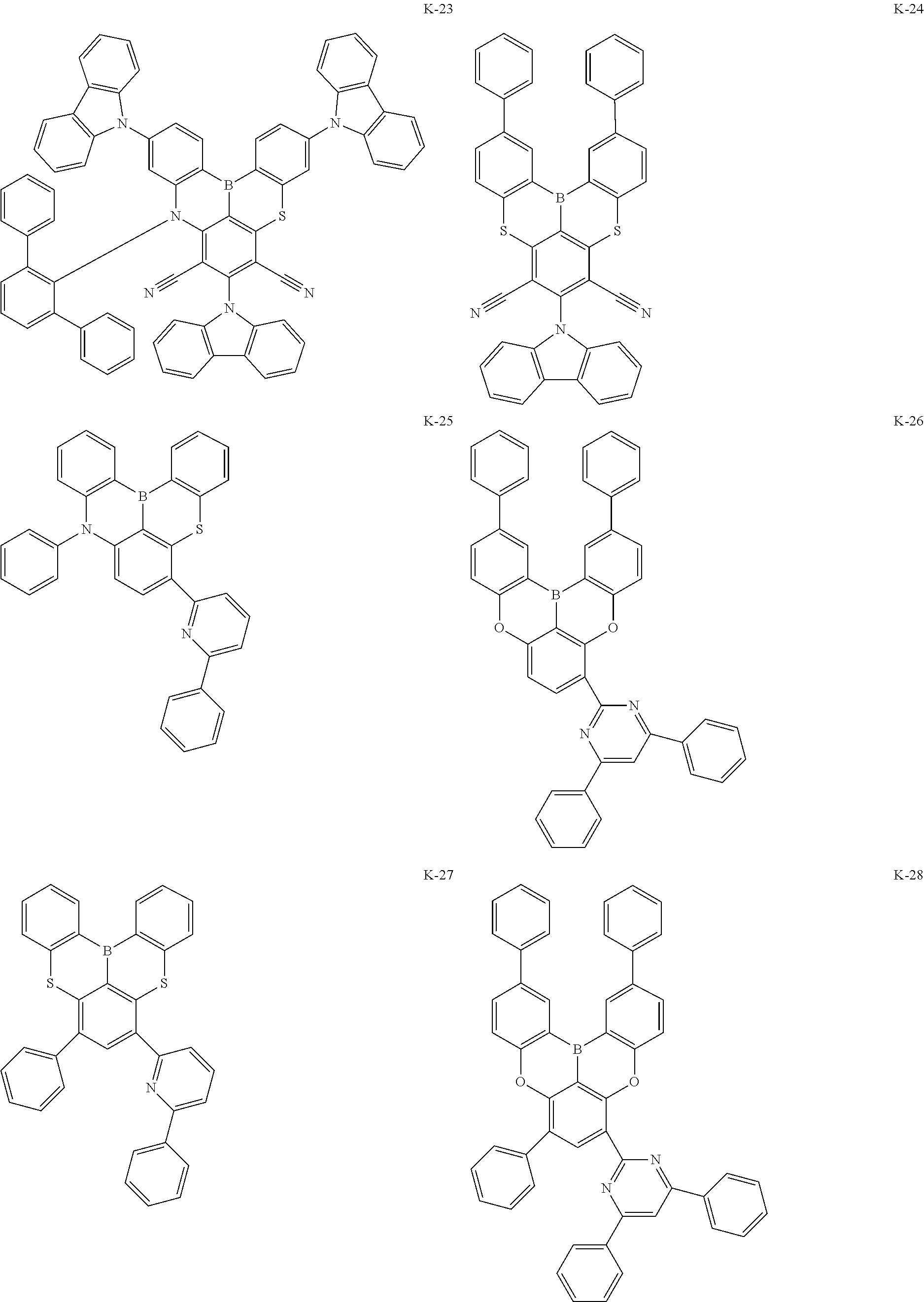 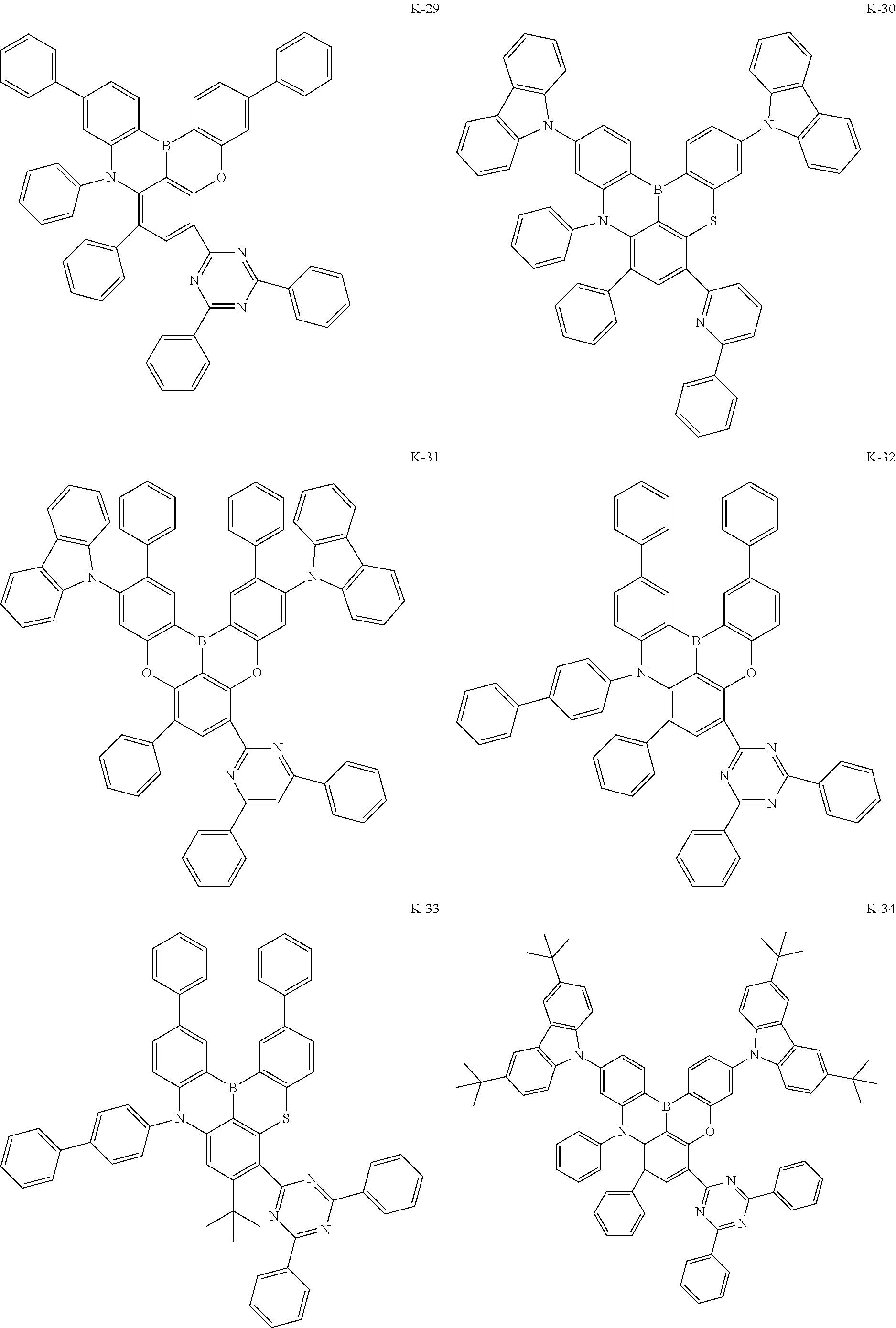 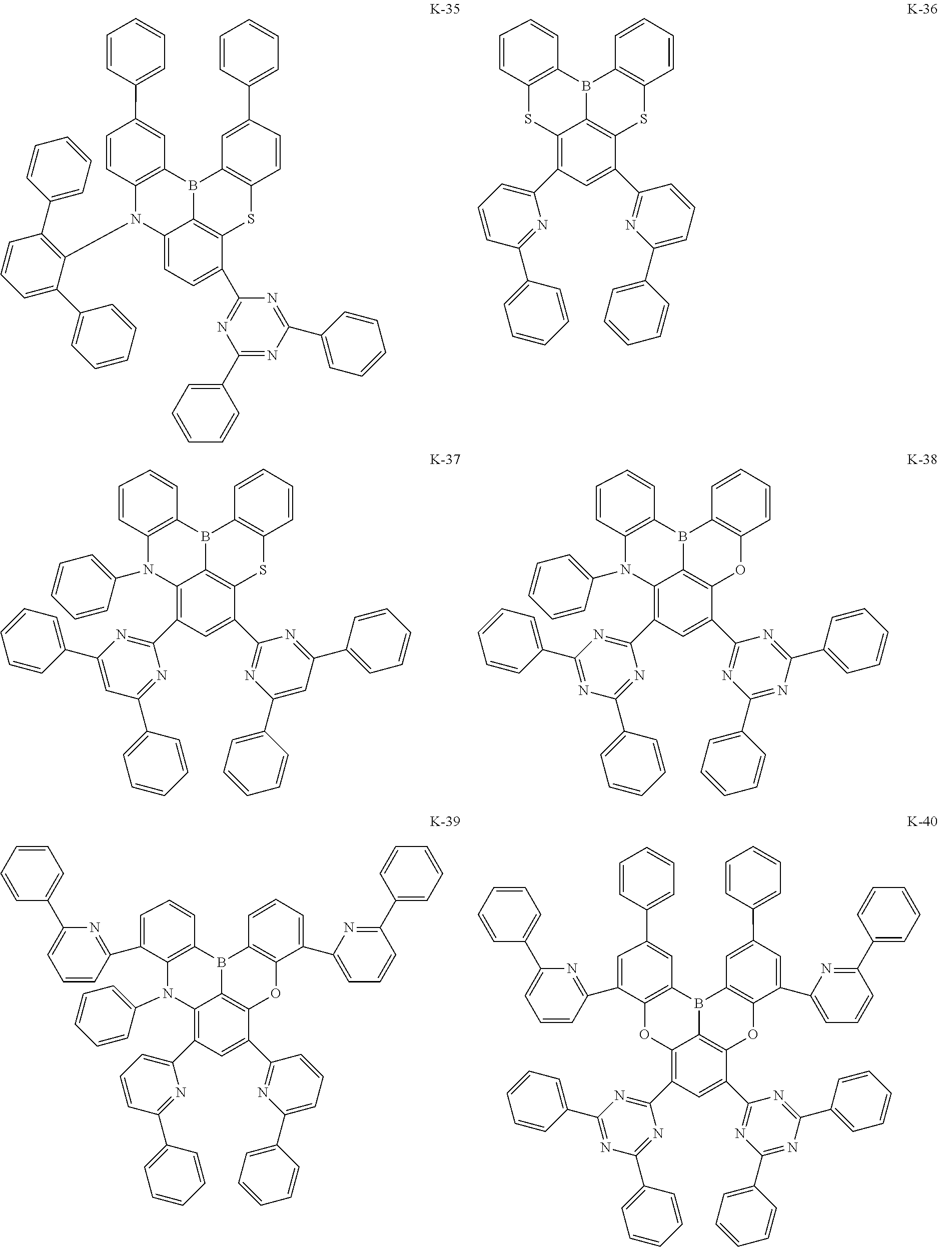 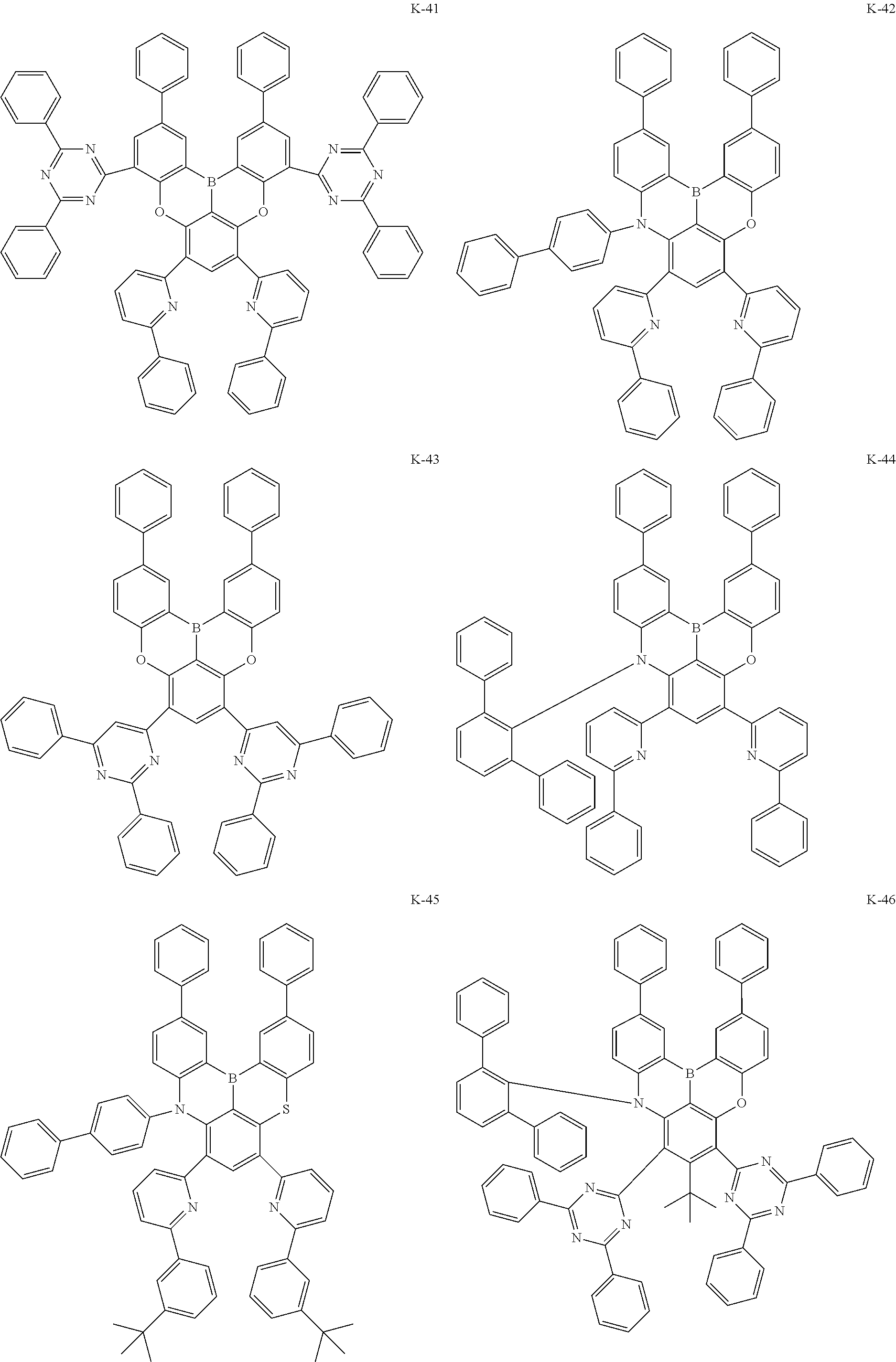 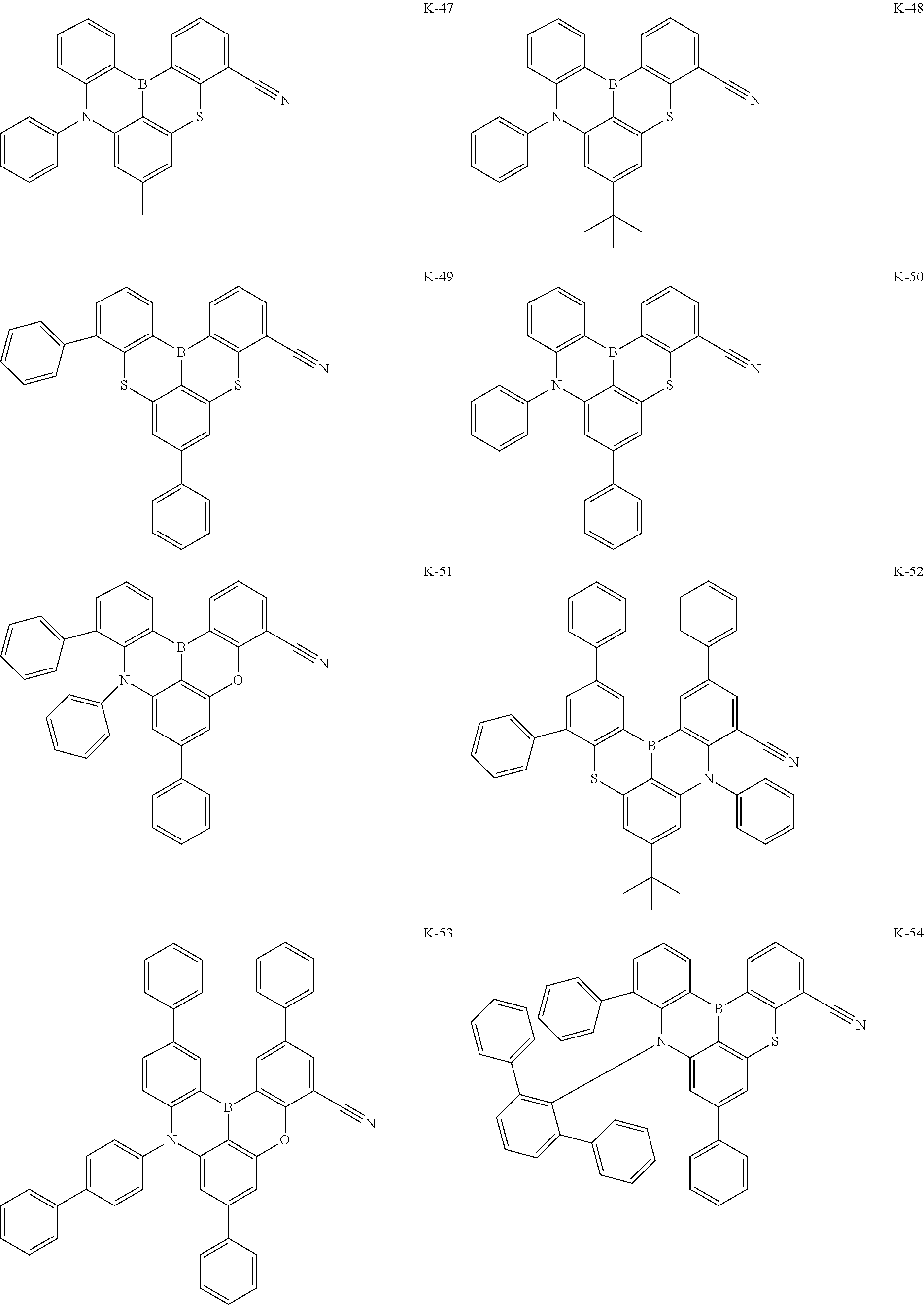 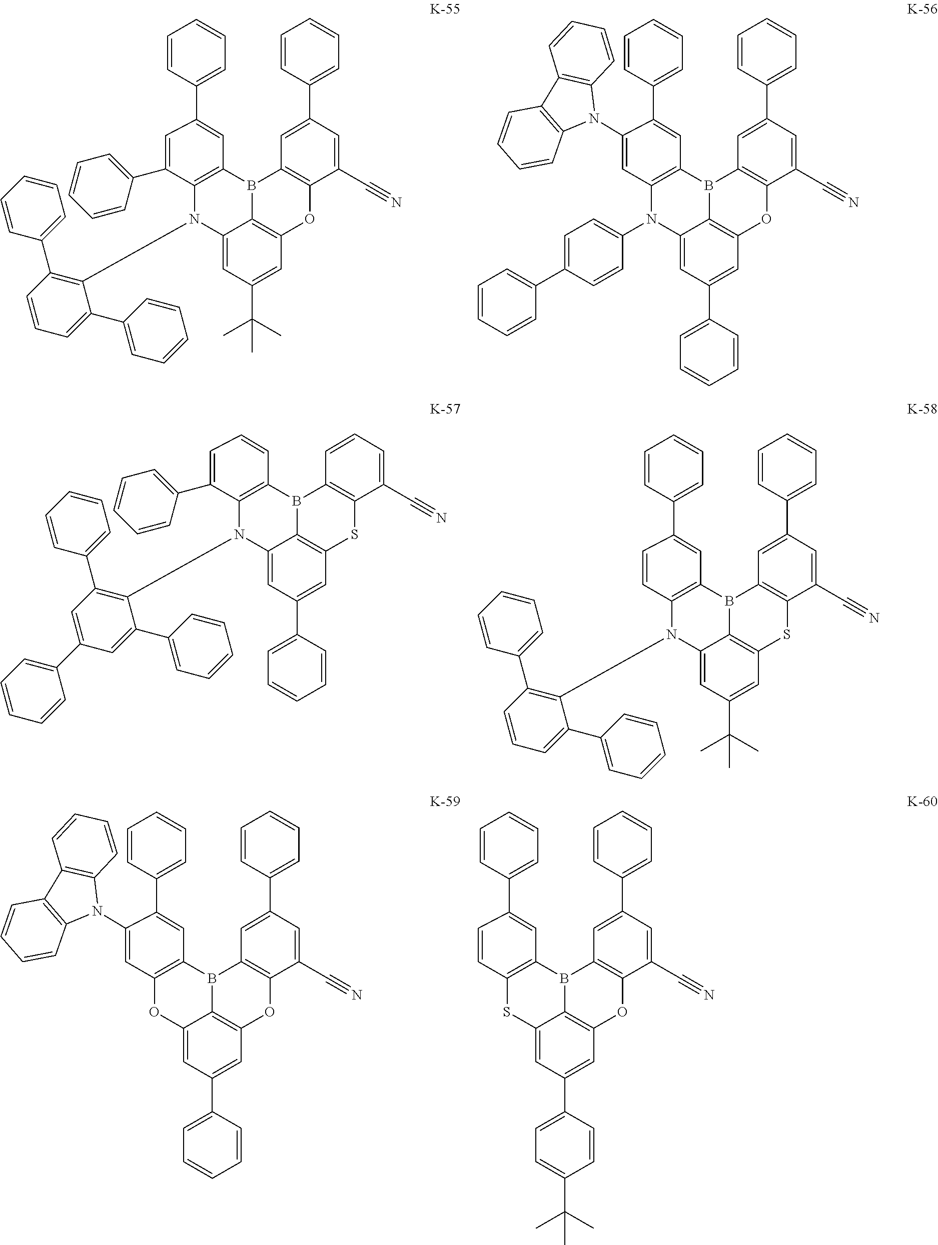 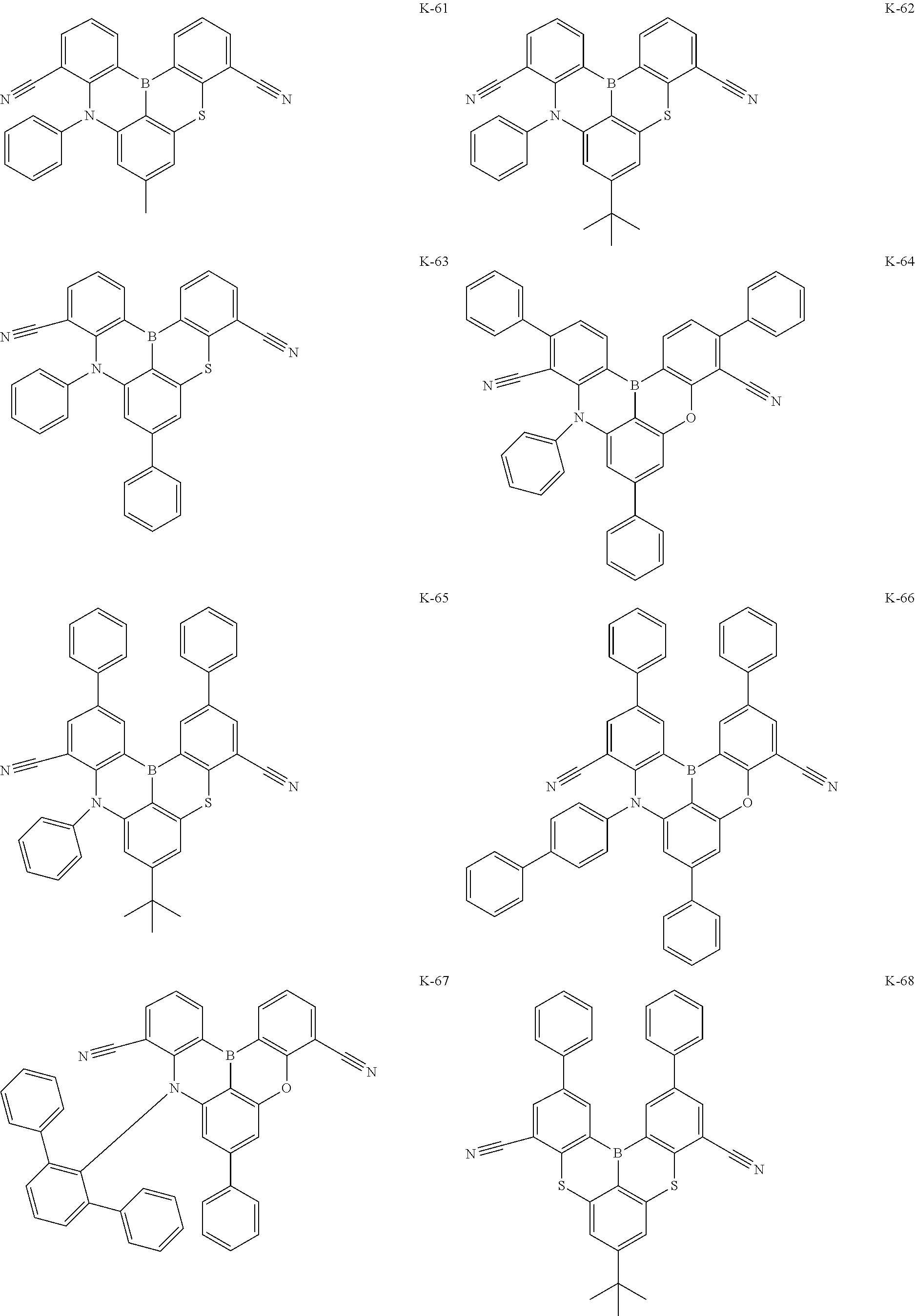 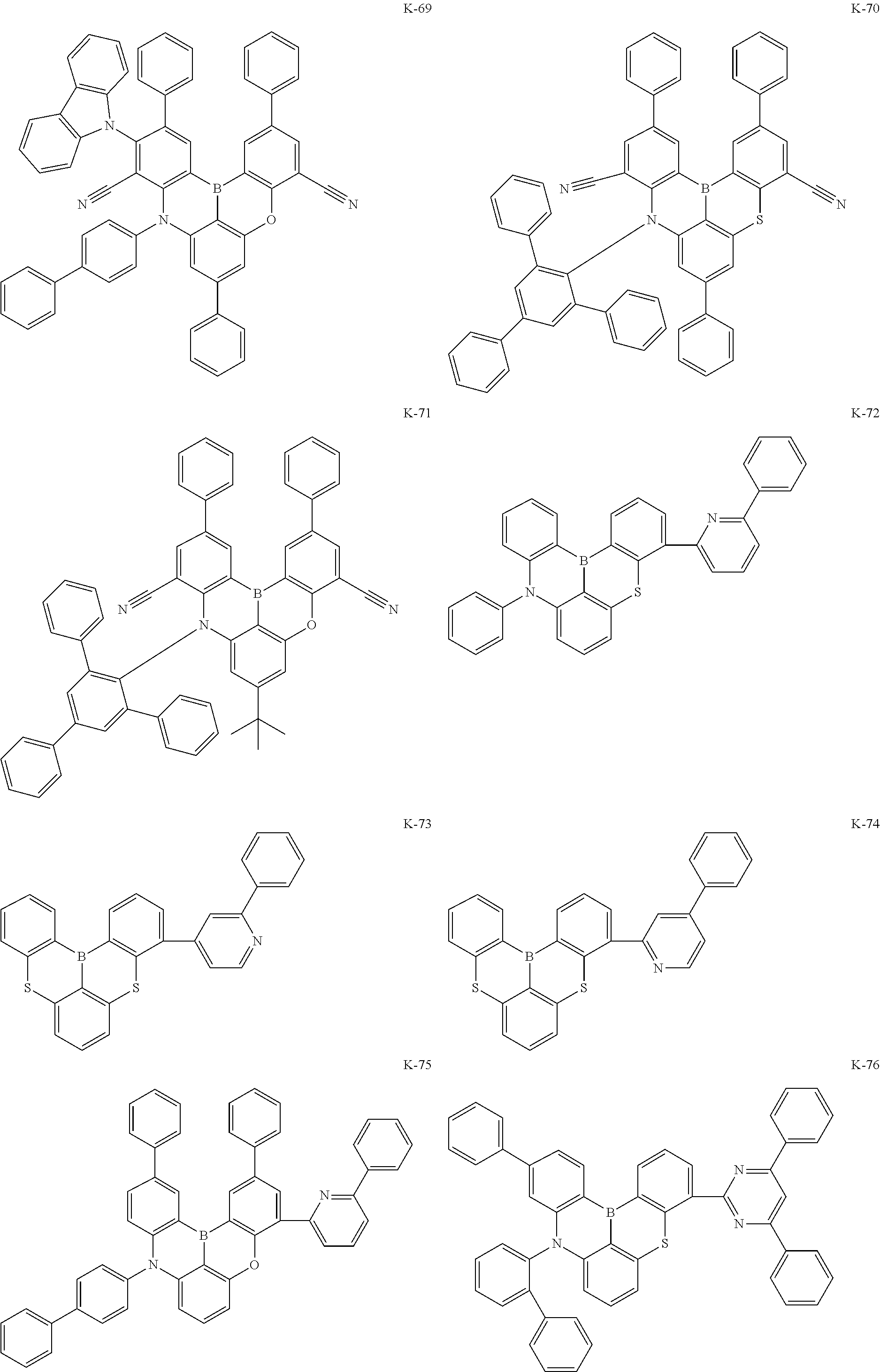 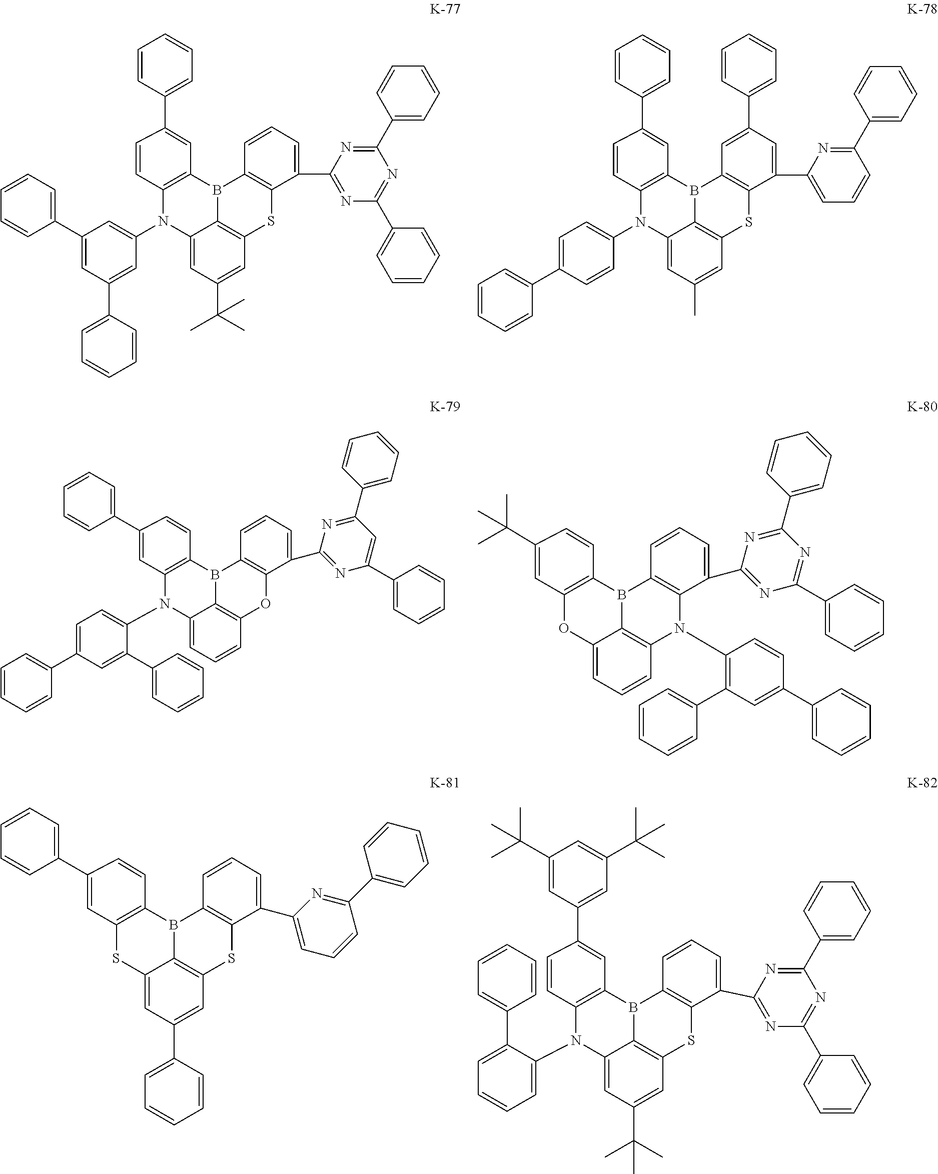 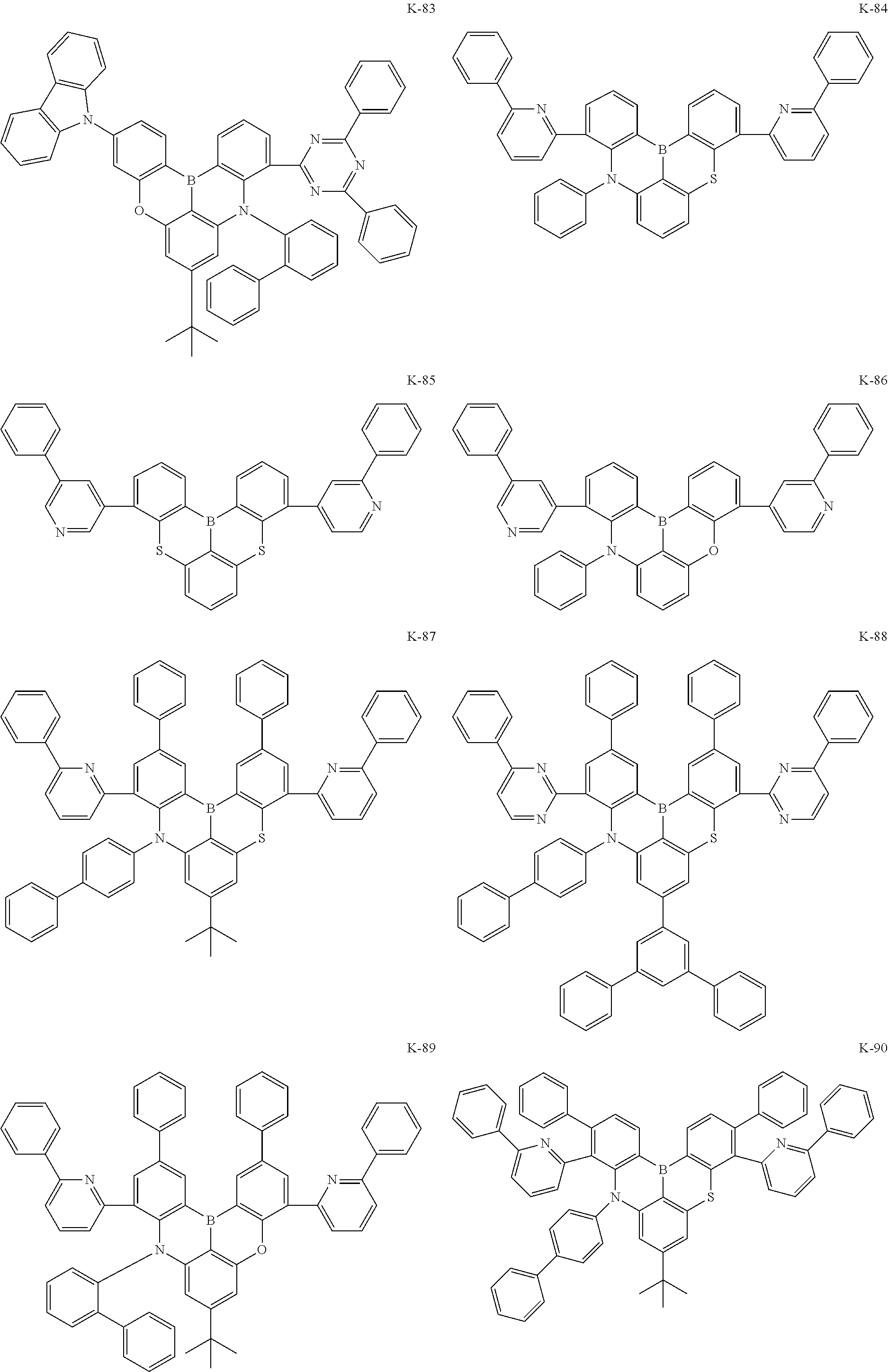 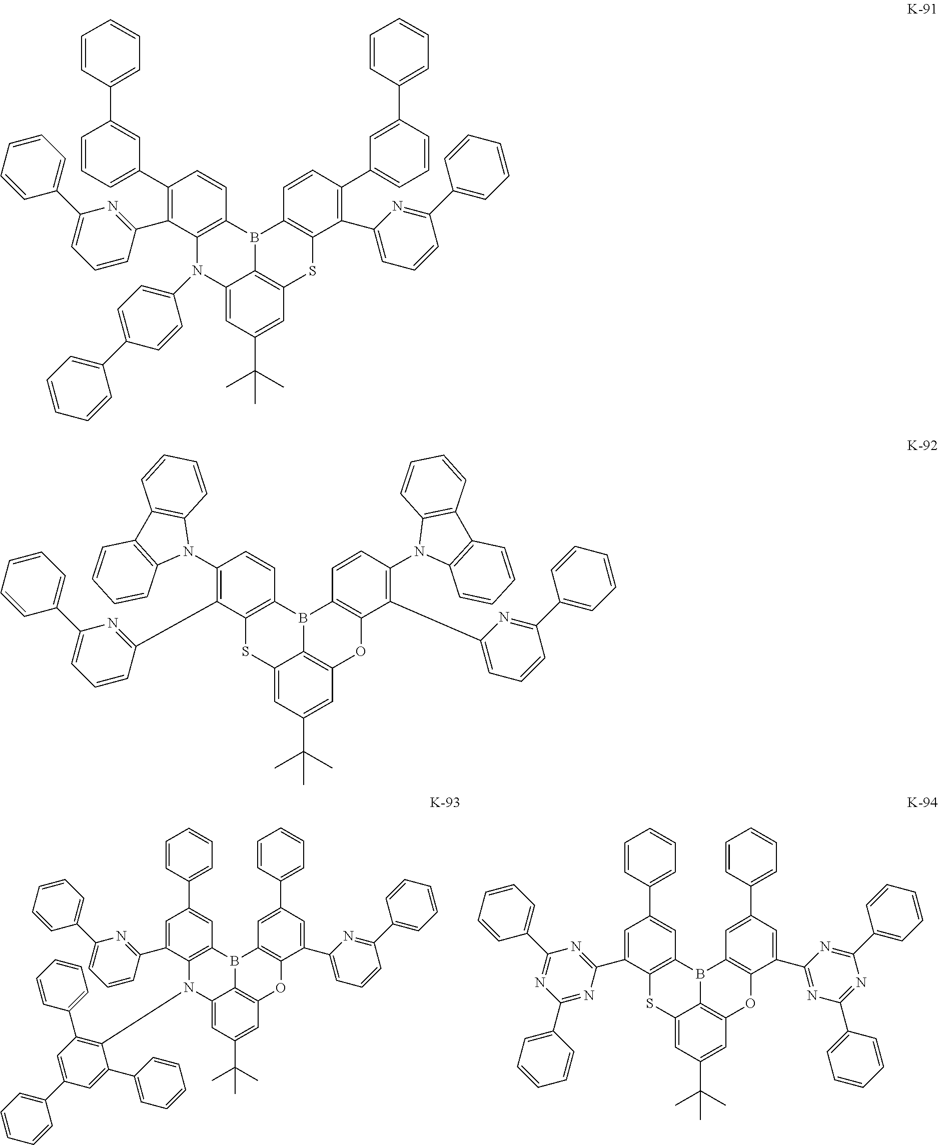 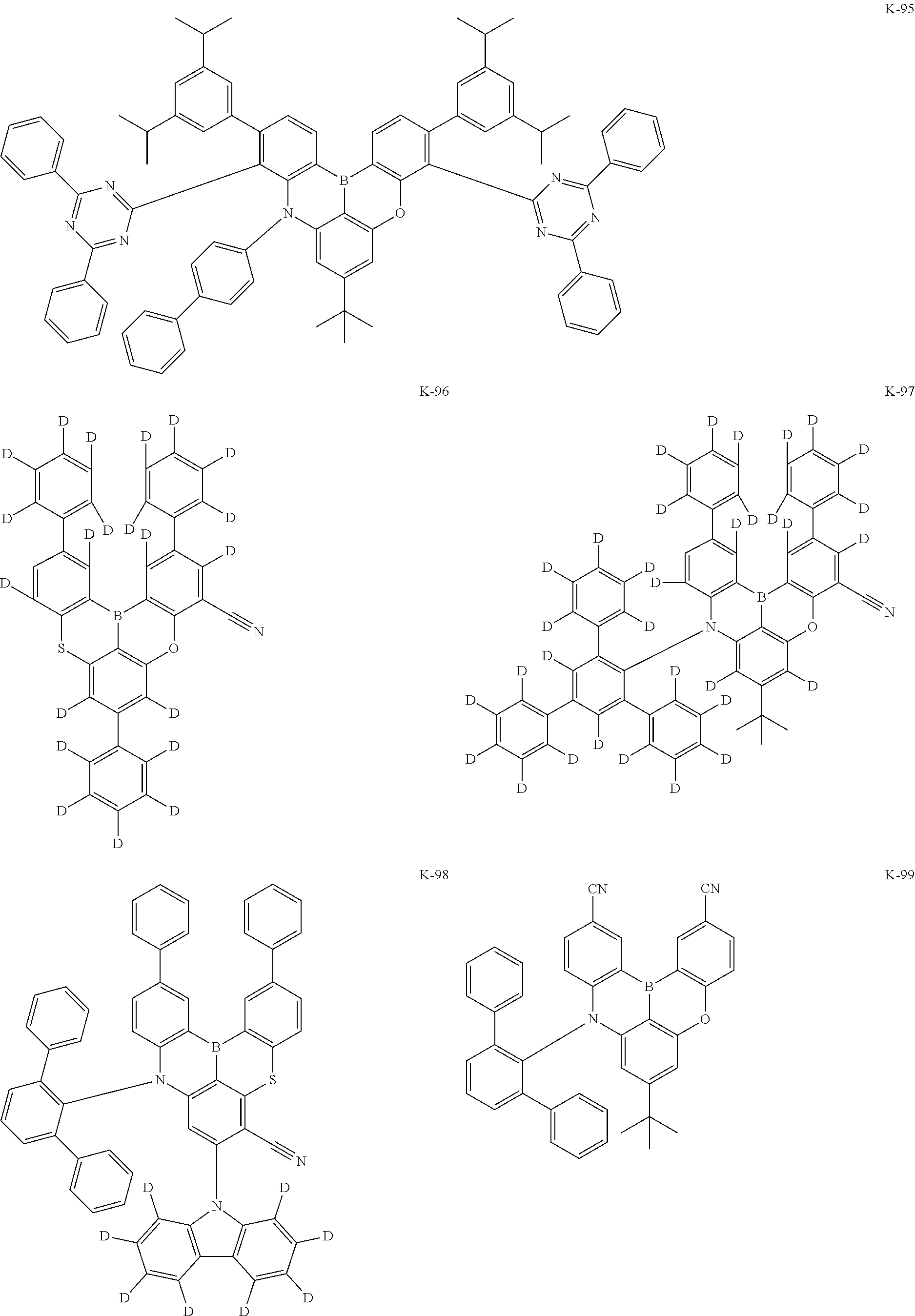 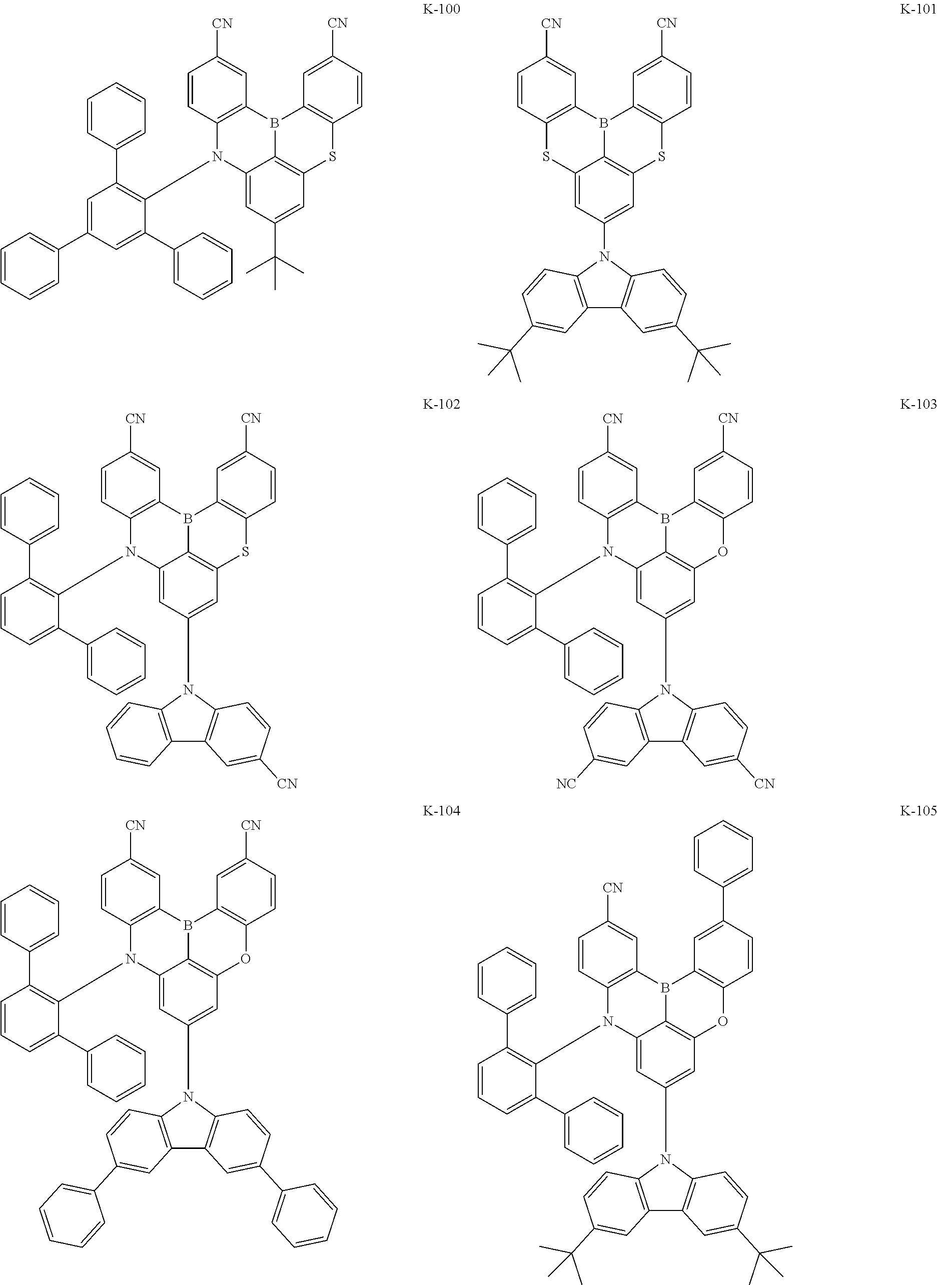 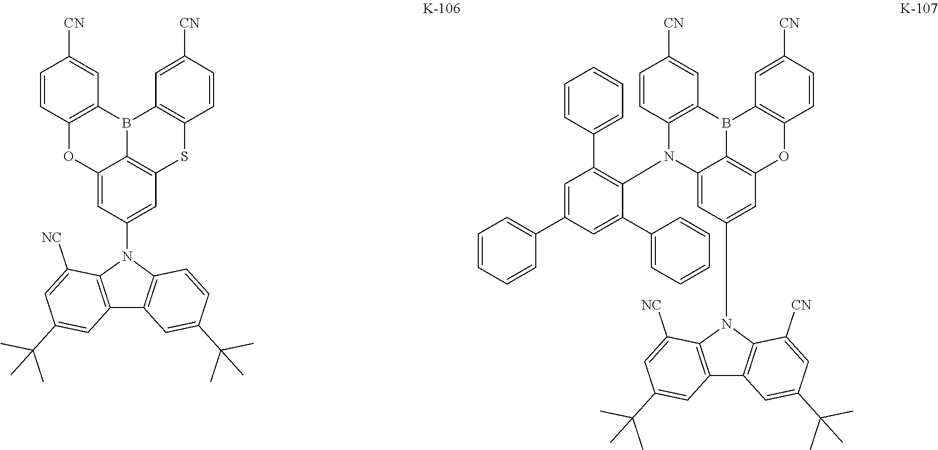 [SMILES: CC(C)(C)c1ccc2c(c1)c1cc(C(C)(C)C)cc(C#N)c1n2-c1cc2c3c(c1)Sc1ccc(C#N)cc1B3c1cc(C#N)ccc1O2 ; CC(C)(C)c1cc(C#N)c2c(c1)c1cc(C(C)(C)C)cc(C#N)c1n2-c1cc2c3c(c1)N(c1c(-c4ccccc4)cc(-c4ccccc4)cc1-c1ccccc1)c1ccc(C#N)cc1B3c1cc(C#N)ccc1O2]
